(19) United States
(12) Patent Application Publication
(10) Pub. No.: US 2023/0058719 A1
(43) Pub. Date: Feb. 23, 2023

(54) ORGANIC ELECTROLUMINESCENT MATERIAL AND DEVICE THEREOF

(71) Applicant: BEIJING SUMMER SPROUT TECHNOLOGY CO., LTD., Beijing (CN)

(72) Inventors: Wei Cai, Beijing (CN); Hongbo Li, Beijing (CN); Zhen Wang, Beijing (CN); Ming Sang, Beijing (CN); Zheng Wang, Beijing (CN); Chi Yuen Raymond Kwong, Beijing (CN); Chuanjun Xia, Beijing (CN)

(73) Assignee: BEIJING SUMMER SPROUT TECHNOLOGY CO., LTD., Beijing (CN)

(21) Appl. No.: 17/856,081

(22) Filed: Jul. 1, 2022

(30) Foreign Application Priority Data
Jul. 2, 2021 (CN) 202110749071.1
Jun. 2, 2022 (CN) 202210613673.9

(51) Int. Cl. H01L 51/00; C07F 15/00; C09K 11/06

(52) U.S. Cl. CPC H01L 51/0085; C07F 15/0033; C09K 11/06; H01L 2251/5384; H01L 51/5012

(57) ABSTRACT

Provided are an organic electroluminescent material and a device comprising the same. The organic electroluminescent material is a metal complex comprising a ligand Lₐ having a structure of Formula 1A and a ligand L_{b} having a structure of Formula 1B. Such new types of compound can be applied to an electroluminescent device to improve luminescence performance, efficiency or a lifetime of the device, exhibit more saturated luminescence and significantly improve overall performance of the device. Further provided are an electroluminescent device comprising the metal complex and a compound composition comprising the metal complex.

### CROSS-REFERENCE TO RELATED APPLICATION(S)

This application claims priority to Chinese Patent Application No. 202110749071.1 filed on Jul. 2, 2021 and Chinese Patent Application No. 202210613673.9 filed on Jun. 2, 2022, the disclosure of which are incorporated herein by reference in their entireties.

### TECHNICAL FIELD

The present disclosure relates to compounds for organic electronic devices, for example, organic light-emitting devices. More particularly, the present disclosure relates to a metal complex comprising a ligand Lₐ having a structure of Formula 1A and a ligand L_{b} having a structure of Formula 1B and an electroluminescent device and compound composition comprising the metal complex.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which includes an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This device laid the foundation for the development of modern organic light-emitting diodes (OLEDs). State-of-the-art OLEDs may include multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may include one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

US20190280221A1 has disclosed a metal complex comprising a ligand having the following structure

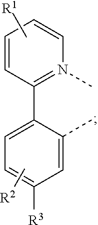

and further disclosed an iridium complex with the following structure

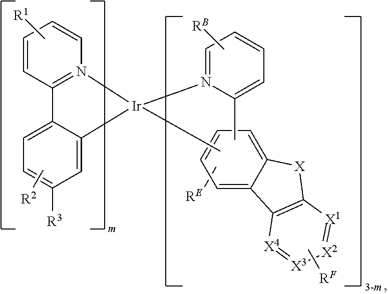

wherein R₃ is selected from alkyl and cycloalkyl. The application has disclosed a metal complex having a particular R₃ substitution and device performance. However, the application has not disclosed or taught that a particular R₂ substitution at a particular position of phenyl of phenylpyridine, a metal complex where R^{E} and R^{F} are particular substitutions and an effect on device performance.

### SUMMARY

The present disclosure aims to provide a series of metal complexes each comprising a ligand Lₐ having a structure of Formula 1A and a ligand L_{b} having a structure of Formula 1B to solve at least part of the preceding problems. These metal complexes may be used as a light-emitting material in an electroluminescent device. Such new types of metal complexes can be applied to the electroluminescent device to improve luminescence performance, efficiency or a lifetime of the device, exhibit more saturated luminescence and significantly improve overall performance of the device.

According to an embodiment of the present disclosure, disclosed is a metal complex having a general formula of M(Lₐ)ₘ(L_{b})ₙ(L_{c})_{q};

wherein

Lₐ, L_{b} and L_{c}, are a first ligand, a second ligand and a third ligand coordinated to the metal M, respectively, and Lₐ, L_{b} and L_{c}, are the same or different; wherein Lₐ, L_{b} and L_{c}, can be optionally joined to form a tetradentate ligand or a multidentate ligand;

the metal M is selected from a metal with a relative atomic mass greater than 40; and

m is selected from 1 or 2, n is selected from 1 or 2, q is selected from 0 or 1, and m+n+q equals an oxidation state of M; when m is 2, two Lₐ may be identical or different; when n is 2, two L_{b} may be identical or different;

wherein Lₐ has, at each occurrence identically or differently, a structure represented by Formula 1A and L_{b} has, at each occurrence identically or differently, a structure represented by Formula 1B:

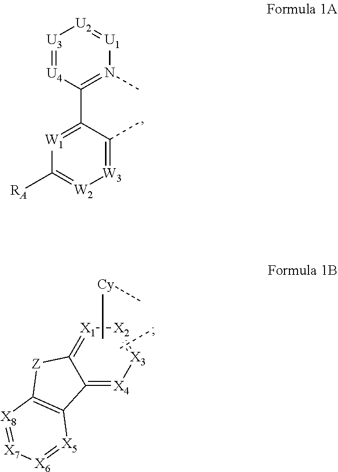

wherein

Z is, at each occurrence identically or differently, selected from the group consisting of O, S, Se, NR′, CR′R′ and SiR′R′; when two R′ are present at the same time, the two R′ are identical or different;

Cy is, at each occurrence identically or differently, selected from a substituted or unsubstituted aromatic ring having 6 to 24 ring atoms, a substituted or unsubstituted heteroaromatic ring having 5 to 24 ring atoms or a combination thereof;

X₁ to X₈ are, at each occurrence identically or differently, selected from C, CRₓ or N, and at least one of X₁ to X₄ is selected from C and joined to Cy;

at least one of X₁ to X₈ is selected from CRₓ, and the Rₓ is cyano or fluorine;

X₁, X₂, X₃ or X₄ is joined to the metal M by a metal-carbon bond or a metal- nitrogen bond;

U₁ to U₄ are, at each occurrence identically or differently, selected from CRᵤ or N; and

W₁ to W₃ are, at each occurrence identically or differently, selected from CR_{w}, or N;

wherein in Formula 1A, R_{A} has a structure represented by Formula 2, and the total number of carbon atoms in Formula 2 is greater than or equal to 2:

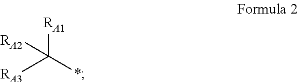

wherein “*” represents a position where Formula 2 is joined to Formula 1A;

R_{A1}, R_{A2}, R_{A3}, R′, Rₓ, Rᵤ and R_{w} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;

adjacent substituents R_{A1}, R_{A2}, R_{A3}, R′, Rₓ, Rᵤ, R_{w} can be optionally joined to form a ring; and

L_{c} is a monoanionic bidentate ligand.

According to another embodiment of the present disclosure, further disclosed is an electroluminescent device including:

an anode,

a cathode, and

an organic layer disposed between the anode and the cathode, wherein at least one layer of the organic layer comprises the metal complex in the preceding embodiments.

According to another embodiment of the present disclosure, further disclosed is a compound composition comprising the metal complex in the preceding embodiments.

The present disclosure discloses the series of metal complexes each comprising the ligand Lₐ having the structure of Formula 1A and the ligand L_{b} having the structure of Formula 1B. Such metal complexes may be used as the light-emitting material in the electroluminescent device and applied to the electroluminescent device to improve the luminescence performance, the efficiency or the lifetime of the device, exhibit more saturated luminescence and significantly improve the overall performance of the device.

### BRIEF DESCRIPTION OF DRAWINGS

FIG. 1 is a schematic diagram of an organic light-emitting apparatus that may comprise a metal complex and a compound composition disclosed herein.

FIG. 2 is a schematic diagram of another organic light-emitting apparatus that may comprise a metal complex and a compound composition disclosed herein.

### DETAILED DESCRIPTION

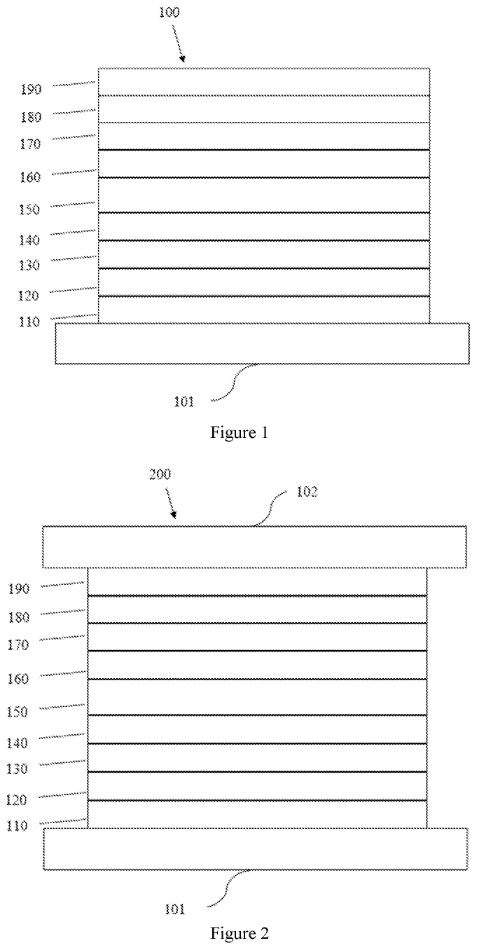

OLEDs can be fabricated on various types of substrates such as glass, plastic, and metal foil. FIG. 1 schematically shows an organic light-emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may include a single layer or multiple layers.

An OLED can be encapsulated by a barrier layer. FIG. 2 schematically shows an organic light emitting device 200 without limitation. FIG. 2 differs from FIG. 1 in that the organic light emitting device include a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (AES-T). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small ΔE_{S-T}. These states may involve CT states. Generally, donor-acceptor luminescent materials are constructed by connecting an electron donor moiety such as amino- or carbazole-derivatives and an electron acceptor moiety such as N-containing six-membered aromatic rings.

Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butylmethylgermanylmethyl, triethylgermanylmethyl, triethylgermanylethyl, triisopropylgermanylmethyl, triisopropylgermanylethyl, trimethylsilylmethyl, trimethylsilylethyl, and trimethylsilylisopropyl, triisopropylsilylmethyl, triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups or heterocycle—as used herein include non-aromatic cyclic groups. Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with an aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates a germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, amino, acyl, carbonyl, a carboxylic acid group, an ester group, sulfinyl, sulfonyl, and phosphino may be substituted with one or more moieties selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl group having 6 to 20 carbon atoms, unsubstituted alkylgermanyl having 3 to 20 carbon atoms, unsubstituted arylgermanyl having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen may also be replaced by their other stable isotopes. The replacement by other stable isotopes in the compounds may be preferred due to its enhancements of device efficiency and stability.

In the compounds mentioned in the present disclosure, multiple substitution refers to a range that includes a di-substitution, up to the maximum available substitution. When substitution in the compounds mentioned in the present disclosure represents multiple substitution (including di-, tri-, and tetra-substitutions etc.), that means the substituent may exist at a plurality of available substitution positions on its linking structure, the substituents present at a plurality of available substitution positions may have the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

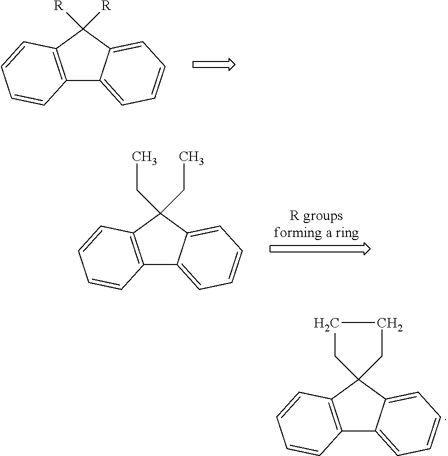

The expression that adjacent substituents can be optionally joined to form a ring is also intended to mean that two substituents bonded to carbon atoms which are directly bonded to each other are joined to each other via a chemical bond to form a ring, which can be exemplified by the following formula:

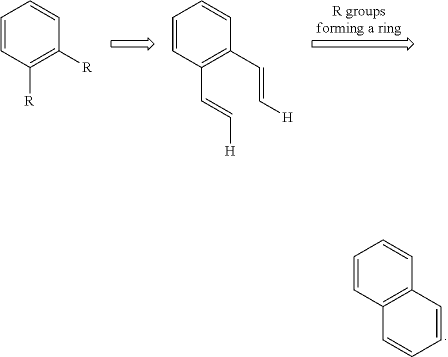

The expression that adjacent substituents can be optionally joined to form a ring is also intended to mean that two substituents bonded to a further distant carbon atom are joined to each other via a chemical bond to form a ring, which can be exemplified by the following formula:

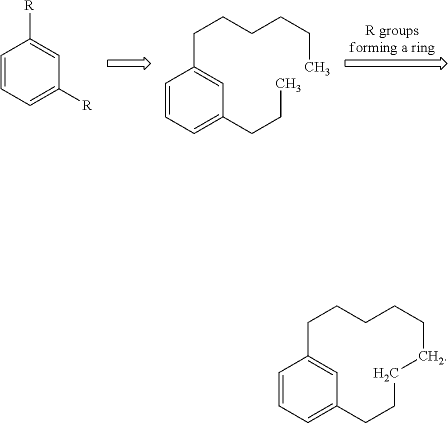

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

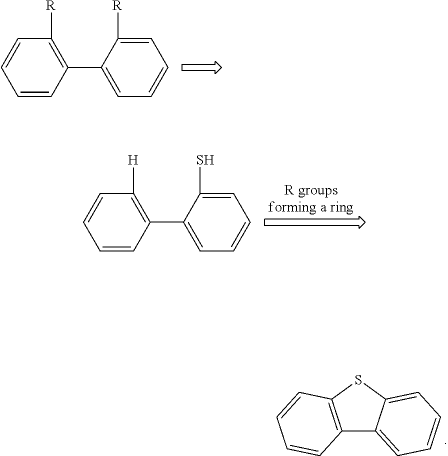

According to an embodiment of the present disclosure, disclosed is a metal complex having a general formula of M(Lₐ)ₘ(L_{b})ₙ(L_{c})_{q};

wherein

Lₐ, L_{b} and L_{c}, are a first ligand, a second ligand and a third ligand coordinated to the metal M, respectively, and Lₐ, L_{b} and L_{c}, are the same or different; wherein Lₐ, L_{b} and L_{c}, can be optionally joined to form a tetradentate ligand or a multidentate ligand;

the metal M is selected from a metal with a relative atomic mass greater than 40; and

m is selected from 1 or 2, n is selected from 1 or 2, q is selected from 0 or 1, and m+n+q equals an oxidation state of M; when m is 2, two Lₐ may be identical or different; when n is 2, two L_{b} may be identical or different;

wherein Lₐ has, at each occurrence identically or differently, a structure represented by Formula 1A and L_{b} has, at each occurrence identically or differently, a structure represented by Formula 1B:

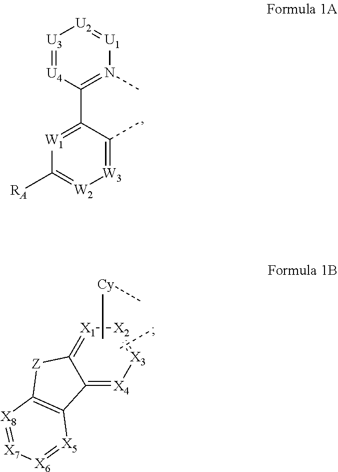

wherein

Z is, at each occurrence identically or differently, selected from the group consisting of O, S, Se, NR′, CR′R′ and SiR′R′; when two R′ are present at the same time, the two R′ are identical or different;

Cy is, at each occurrence identically or differently, selected from a substituted or unsubstituted aromatic ring having 6 to 24 ring atoms, a substituted or unsubstituted heteroaromatic ring having 5 to 24 ring atoms or a combination thereof;

X₁ to X₈ are, at each occurrence identically or differently, selected from C, CRₓ or N, and at least one of X₁ to X₄ is selected from C and joined to Cy;

at least one of X₁ to X₈ is selected from CRₓ, and the Rₓ is cyano or fluorine;

X₁, X₂, X₃ or X₄ is joined to the metal M by a metal-carbon bond or a metal-nitrogen bond;

U₁ to U₄ are, at each occurrence identically or differently, selected from CRᵤ or N; and

W₁ to W₃ are, at each occurrence identically or differently, selected from CR_{w} or N;

wherein in Formula 1A, R_{A} has a structure represented by Formula 2, and the total number of carbon atoms in Formula 2 is greater than or equal to 2:

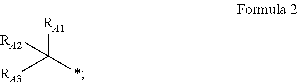

wherein “*” represents a position where Formula 2 is joined to Formula 1A;

R_{A1}, R_{A2}, R_{A3}, R′, Rₓ, Rᵤ and R_{w} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;

adjacent substituents R_{A1}, R_{A2}, R_{A3}, R′, Rₓ, Rᵤ, R_{w} can be optionally joined to form a ring; and

L_{c} is a monoanionic bidentate ligand.

In the present disclosure, the expression “adjacent substituents R_{A1}, R_{A2}, R_{A3}, R′, Rₓ, Rᵤ, R_{w} can be optionally joined to form a ring” is intended to mean that any one or more of groups of adjacent substituents, such as substituents R_{A1} and R_{A2}, substituents R_{A1} and R_{A3}, substituents R_{A2} and R_{A3}, substituents R_{A1} and Rᵤ, substituents Rᵤ and R_{A3}, substituents R_{A2} and Rᵤ, two substituents R′, substituents R′ and Rₓ, two substituents Rₓ, two substituents Rᵤ, and two substituents R_{w}, can be joined to form a ring. Obviously, it is possible that none of these substituents are joined to form a ring.

According to an embodiment of the present disclosure, L_{c} is, at each occurrence identically or differently, selected from a structure represent by any one of the group consisting of the following:

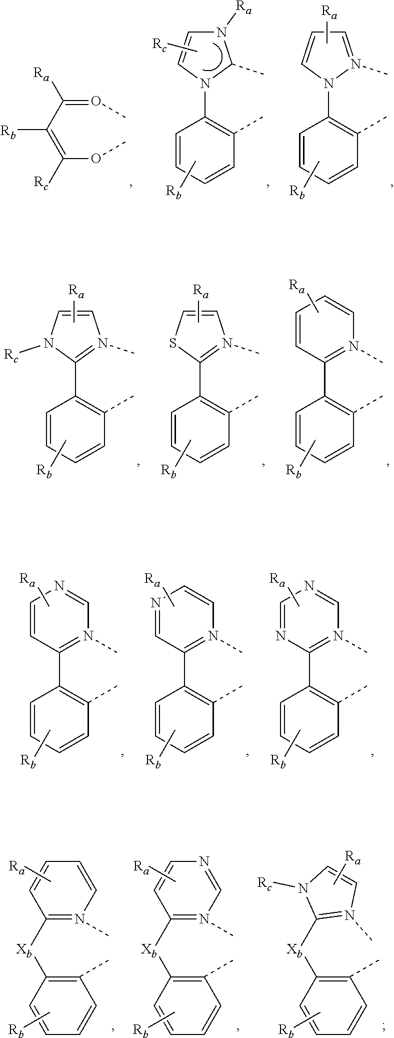

wherein

Rₐ, R_{b} and R_{c} represent, at each occurrence identically or differently, mono-substitution, multiple substitutions or non-substitution;

X_{b} is, at each occurrence identically or differently, selected from the group consisting of: O, S, Se, NR_{N1} and CR_{C1}R_{C2};

Rₐ, R_{b}, R_{c}, R_{N1}, R_{C1} and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof, and

adjacent substituents Rₐ, R_{b}, R_{c}, R_{N1}, R_{C1} and R_{C2} can be optionally joined to form a ring.

In the present disclosure, the expression that “adjacent substituents Rₐ, R_{b}, R_{c}, R_{N1}, R_{C1} and R_{C2} can be optionally joined to form a ring” is intended to mean that any one or more of groups of adjacent substituents, such as two substituents Rₐ, two substituents R_{b}, two substituents R_{c}, substituents Rₐ and R_{b}, substituents Rₐ and R_{c}, substituents R_{b} and R_{c}, substituents Rₐ and R_{N1}, substituents R_{b} and R_{N1}, substituents Rₐ and R_{C1}, substituents Rₐ and R_{C2}, substituents R_{b} and R_{C1}, substituents R_{b} and R_{C2}, and substituents R_{C1} and R_{C2}, can be joined to form a ring. Obviously, it is possible that none of these substituents are joined to form a ring.

According to an embodiment of the present disclosure, Cy is selected from any structure of the group consisting of the following:

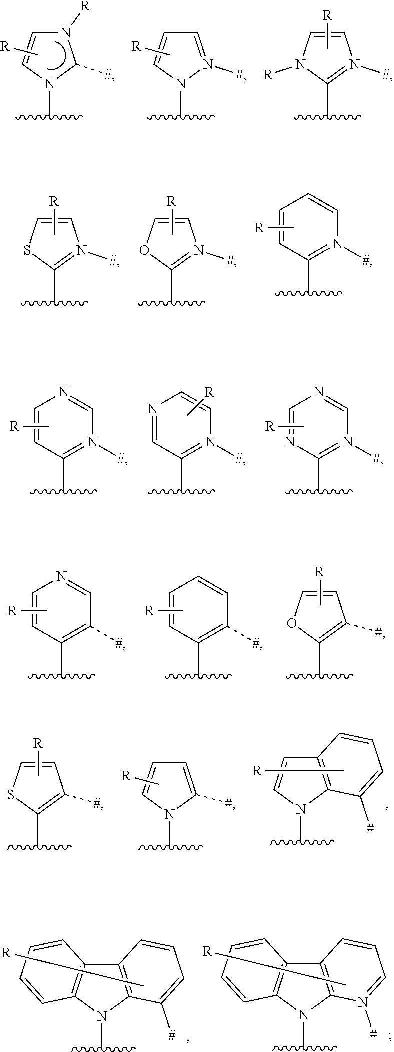

wherein

R represents, at each occurrence identically or differently, mono-substitution, multiple substitutions or non-substitution; and when multiple R are present at the same time in any structure, the multiple R are the same or different;

R is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;

adjacent substituents R can be optionally joined to form a ring; and

“#” represents a position where Cy is joined to the metal M, and “

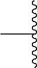

” represents a position where Cy is joined to X₁, X₂, X₃ or X₄.

In the present disclosure, the expression that “adjacent substituents R can be optionally joined to form a ring” is intended to mean that any one or more of groups of any two adjacent substituents R can be joined to form a ring. Obviously, it is possible that none of these substituents are joined to form a ring.

According to an embodiment of the present disclosure, L_{b} has a structure represented by any of Formulas 1Ba to 1Bf:

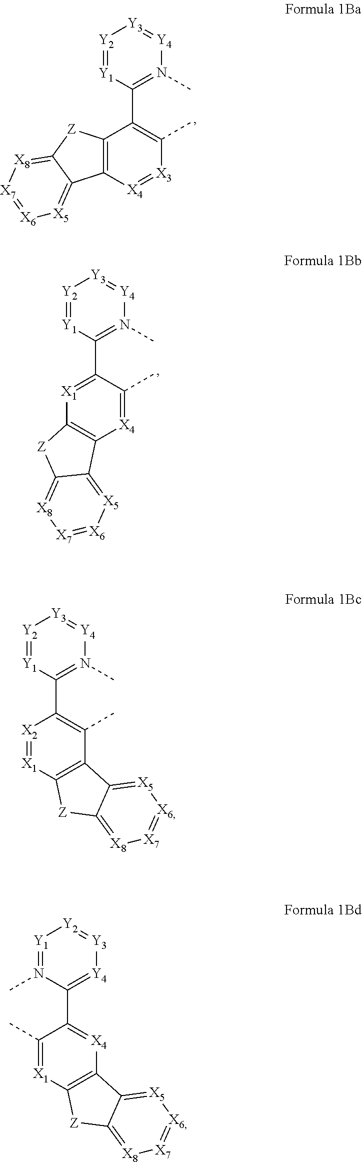

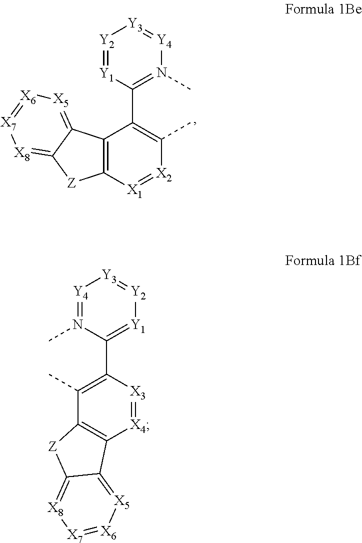

wherein

Z is, at each occurrence identically or differently, selected from the group consisting of O, S, Se, NR′, CR′R′ and SiR′R′; when two R′ are present at the same time, the two R′ are identical or different;

in Formulas 1Ba and 1Bf, X₃ to X₈ are, at each occurrence identically or differently, selected from CRₓ or N;

in Formulas 1Bb and 1Bd, X₁ and X₄ to X₈ are, at each occurrence identically or differently, selected from CRₓ or N;

in Formulas 1Bc and 1Be, X₁ and X₂ and X₅ to X₈ are, at each occurrence identically or differently, selected from CRₓ or N;

at least one of X₁ to X₈ is selected from CRₓ, and the Rₓ is cyano or fluorine;

Y₁ to Y₄ are, at each occurrence identically or differently, selected from CR_{y} or N;

R′, Rₓ and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof, and

adjacent substituents R′, Rₓ, R_{y} can be optionally joined to form a ring.

In this embodiment, the expression that “adjacent substituents R′, Rₓ, R_{y} can be optionally joined to form a ring” is intended to mean that any one or more of groups of adjacent substituents, such as two substituents R′, two substituents Rₓ, two substituents R_{y}, and substituents R′ and Rₓ, can be joined to form a ring. Obviously, it is possible that none of these substituents are joined to form a ring.

According to an embodiment of the present disclosure, the metal M is, at each occurrence identically or differently, selected from the group consisting of Cu, Ag, Au, Ru, Rh, Pd, Os, Ir and Pt.

According to an embodiment of the present disclosure, the metal M is, at each occurrence identically or differently, selected from Pt or Jr.

According to an embodiment of the present disclosure, a metal complex Ir(Lₐ)ₘ(L_{b})₃₋ₘ has a structure represented by Formula 3:

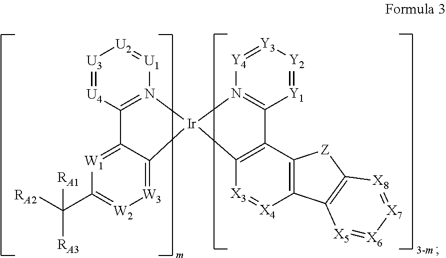

wherein

Z is, at each occurrence identically or differently, selected from the group consisting of O, S, Se, NR′, CR′R′ and SiR′R′; when two R′ are present at the same time, the two R′ are identical or different;

X₃ to X₈ are, at each occurrence identically or differently, selected from CRₓ or N;

at least one of X₃ to X₈ is selected from CRₓ, and the Rₓ is cyano or fluorine;

Y₁ to Y₄ are, at each occurrence identically or differently, selected from CR_{y} or N;

U₁ to U₄ are, at each occurrence identically or differently, selected from CRᵤ or N;

W₁ to W₃ are, at each occurrence identically or differently, selected from CRv or N;

R_{A1}, R_{A2}, R_{A3}, R′, Rₓ, R_{y}, Rᵤ and R_{w} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof, and the total number of carbon atoms in R_{A1}, R_{A2} and R_{A3} is greater than or equal to 1;

adjacent substituents R_{A1}, R_{A2}, R_{A3} can be optionally joined to form a ring; and

adjacent substituents R′, Rₓ, R_{y}, Rᵤ, R_{w} can be optionally joined to form a ring.

In the present disclosure, the expression that “adjacent substituents R_{A1}, R_{A2}, R_{A3} can be optionally joined to form a ring” is intended to mean that any one or more of groups of adjacent substituents, such as substituents R_{A1} and R_{A2}, substituents R_{A1} and R_{A3}, and substituents R_{A2} and R_{A3}, can be joined to form a ring. Obviously, it is possible that none of these substituents are joined to form a ring.

In the present disclosure, the expression that “adjacent substituents R′, Rₓ, R_{y}, Rᵤ, R_{w}can be optionally joined to form a ring” is intended to mean that any one or more of groups of adjacent substituents, such as two substituents R′, substituents R′ and Rₓ, two substituents Rₓ, two substituents Rᵤ, two substituents R_{w}, and two substituents R_{y}, can be joined to form a ring. Obviously, it is possible that none of these substituents are joined to form a ring.

According to an embodiment of the present disclosure, the metal complex Ir(Lₐ)ₘ(L_{b})₃₋ₘ has a structure represented by Formula 4 or Formula 5:

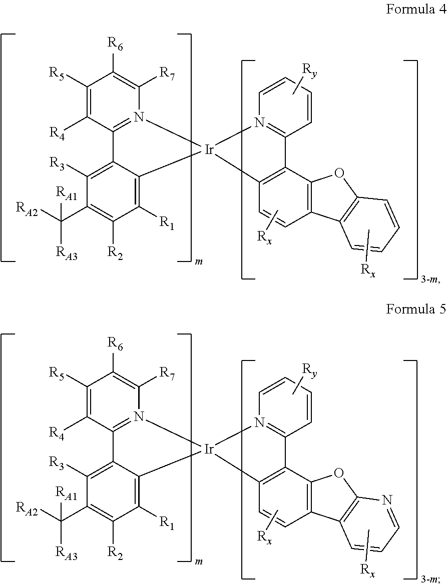

wherein

Rₓ and R_{y} represent, at each occurrence identically or differently, mono-substitution, multiple substitutions or non-substitution;

R_{A1}, R_{A2}, R_{A3}, Rₓ, R_{y} and R₁ to R₇ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof, and the total number of carbon atoms in R_{A1}, R_{A2} and R_{A3} is greater than or equal to 1;

at least one Rₓ is cyano or fluorine;

adjacent substituents R_{A1}, R_{A2}, R_{A3} can be optionally joined to form a ring; and

adjacent substituents Rₓ, R_{y}, R₁ to R₇ can be optionally joined to form a ring.

In the present disclosure, the expression that “adjacent substituents Rₓ, R_{y}, R₁ to R₇ can be optionally joined to form a ring” is intended to mean that any one or more of groups of adjacent substituents, such as substituents R₁ and R₂, substituents R₃ and R₄, substituents R₄ and R₅, substituents R₅ and R₆, substituents R₆ and R₇, two substituents Rₓ, and two substituents R_{y}, can be joined to form a ring. Obviously, it is possible that none of these substituents are joined to form a ring.

According to an embodiment of the present disclosure, Z is selected from the group consisting of: O and S.

According to an embodiment of the present disclosure, Z is selected from O.

According to an embodiment of the present disclosure, X₁ to X₈ are, at each occurrence identically or differently, selected from C or CRₓ.

According to an embodiment of the present disclosure, X₃ to X₈ are, at each occurrence identically or differently, selected from C or CRₓ.

According to an embodiment of the present disclosure, at least one of X₁ to X₈ is selected from N. For example, one of X₁ to X₈ is selected from N, or two of X₁ to X₈ are selected from N.

According to an embodiment of the present disclosure, at least one of X₃ to X₈ is selected from N. For example, one of X₃ to X₈ is selected from N, or two of X₃ to X₈ are selected from N.

According to an embodiment of the present disclosure, W₁ to W₃ are, at each occurrence identically or differently, selected from C or CR_{w}.

According to an embodiment of the present disclosure, U₁ to U₄ are, at each occurrence identically or differently, selected from C or CRᵤ.

According to an embodiment of the present disclosure, Y₁ to Y₄ are, at each occurrence identically or differently, selected from C or CR_{y}.

According to an embodiment of the present disclosure, at least one of W₁ to W₃ is selected from N. For example, one of W₁ to W₃ is selected from N, or two of W₁ to W₃ are selected from N.

According to an embodiment of the present disclosure, at least one of U₁ to U₄ is selected from N. For example, one of U₁ to U₄ is selected from N, or two of U₁ to U₄ are selected from N.

According to an embodiment of the present disclosure, at least one of Y₁ to Y₄ is selected from N. For example, one of Y₁ to Y₄ is selected from N, or two of Y₁ to Y₄ are selected from N.

According to an embodiment of the present disclosure, R_{w} and Rᵤ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof.

According to an embodiment of the present disclosure, R_{w} and Rᵤ are, at each occurrence identically or differently, selected from the group consisting of: hydrogen, deuterium, substituted or unsubstituted alkyl having 1 to 10 carbon atoms, substituted or unsubstituted cycloalkyl having 3 to 10 ring carbon atoms, substituted or unsubstituted aryl having 6 to 10 carbon atoms and combinations thereof.

According to an embodiment of the present disclosure, R_{w} and Rᵤ are, at each occurrence identically or differently, selected from the group consisting of: hydrogen, deuterium, substituted or unsubstituted alkyl having 1 to 10 carbon atoms, substituted or unsubstituted cycloalkyl having 3 to 10 ring carbon atoms and combinations thereof.

According to an embodiment of the present disclosure, R_{y} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof.

According to an embodiment of the present disclosure, R_{y} is, at each occurrence identically or differently, selected from the group consisting of: hydrogen, deuterium, substituted or unsubstituted alkyl having 1 to 10 carbon atoms, substituted or unsubstituted cycloalkyl having 3 to 10 ring carbon atoms, substituted or unsubstituted aryl having 6 to 10 carbon atoms and combinations thereof.

According to an embodiment of the present disclosure, R_{y} is, at each occurrence identically or differently, selected from the group consisting of: hydrogen, deuterium, substituted or unsubstituted alkyl having 1 to 10 carbon atoms, substituted or unsubstituted cycloalkyl having 3 to 10 ring carbon atoms and combinations thereof.

According to an embodiment of the present disclosure, U₁ to U₄ are, at each occurrence identically or differently, selected from CRᵤ, and the total number of carbon atoms in Rᵤ is at least 4.

According to an embodiment of the present disclosure, at least one of U₁ to U₄ is selected from CRᵤ, and the Rᵤ is selected from the group consisting of: substituted or unsubstituted alkyl having 1 to 20 carbon atoms, substituted or unsubstituted cycloalkyl having 3 to 20 ring carbon atoms and combinations thereof.

According to an embodiment of the present disclosure, the total number of carbon atoms in all Rᵤ is at least 4.

According to an embodiment of the present disclosure, at least one of U₁ to U₄ is selected from CRᵤ, and the Rᵤ is selected from the group consisting of: substituted or unsubstituted alkyl having 1 to 12 carbon atoms, substituted or unsubstituted cycloalkyl having 3 to 12 ring carbon atoms and combinations thereof.

According to an embodiment of the present disclosure, U₂ and/or U₃ is selected from CRᵤ, and the Rᵤ is selected from the group consisting of: substituted or unsubstituted alkyl having 1 to 12 carbon atoms, substituted or unsubstituted cycloalkyl having 3 to 12 ring carbon atoms and combinations thereof, and the total number of carbon atoms in all Rᵤ is at least 4.

According to an embodiment of the present disclosure, U₂ or U₃ is selected from CRᵤ, and the Rᵤ is selected from substituted or unsubstituted alkyl having 3 to 12 carbon atoms, substituted or unsubstituted cycloalkyl having 3 to 12 ring carbon atoms or a combination thereof.

According to an embodiment of the present disclosure, U₂ or U₃ is selected from CRᵤ, and the Rᵤ is selected from substituted or unsubstituted alkyl having 4 to 12 carbon atoms, substituted or unsubstituted cycloalkyl having 4 to 12 ring carbon atoms or a combination thereof.

According to an embodiment of the present disclosure, at least one of U₁ to U₄ is selected from CR₁, and the Rᵤ is selected from the group consisting of: substituted or unsubstituted alkyl having 3 to 12 carbon atoms, substituted or unsubstituted cycloalkyl having 3 to 12 ring carbon atoms and combinations thereof.

According to an embodiment of the present disclosure, at least one of U₁ to U₄ is selected from CR₁, and the Rᵤ has a structure represented by Formula 2.

According to an embodiment of the present disclosure, U₂ or U₃ is selected from CRᵤ, and the Rᵤ has a structure represented by Formula 2.

According to an embodiment of the present disclosure, R_{A1}, R_{A2} and R_{A3} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof, and the total number of carbon atoms in R_{A1}, R_{A2} and R_{A3} is greater than or equal to 3.

According to an embodiment of the present disclosure, the total number of carbon atoms in Formula 2 is greater than or equal to 4.

According to an embodiment of the present disclosure, R_{A1}, R_{A2} and R_{A3} are, at each occurrence identically or differently, selected from the group consisting of: hydrogen, deuterium, halogen, substituted or unsubstituted alkyl having 1 to 6 carbon atoms, substituted or unsubstituted cycloalkyl having 3 to 6 ring carbon atoms, substituted or unsubstituted heteroalkyl having 1 to 6 carbon atoms, a substituted or unsubstituted heterocyclic group having 3 to 6 ring atoms, substituted or unsubstituted arylalkyl having 7 to 13 carbon atoms, substituted or unsubstituted aryl having 6 to 12 carbon atoms, substituted or unsubstituted heteroaryl having 3 to 12 carbon atoms, a cyano group and combinations thereof, and the total number of carbon atoms in R_{A1}, R_{A2} and R_{A3} is greater than or equal to 3.

According to an embodiment of the present disclosure, R_{A1}, R_{A2} and R_{A3} are, at each occurrence identically or differently, selected from the group consisting of: substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms and combinations thereof.

According to an embodiment of the present disclosure, R_{A1}, R_{A2} and R_{A3} are, at each occurrence identically or differently, selected from the group consisting of: substituted or unsubstituted alkyl having 1 to 6 carbon atoms or substituted or unsubstituted cycloalkyl having 3 to 6 ring carbon atoms; and the total number of carbon atoms in R_{A1}, R_{A2} and R_{A3} is greater than or equal to 3 and less than or equal to 9.

According to an embodiment of the present disclosure, two of R_{A1}, R_{A2} and R_{A3} are, identically or differently, selected from the group consisting of: substituted or unsubstituted alkyl having 1 to 6 carbon atoms or substituted or unsubstituted cycloalkyl having 3 to 6 ring carbon atoms; and another one of R_{A1}, R_{A2} and R_{A3} is selected from the group consisting of: deuterium, fluorine, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, a cyano group and combinations thereof.

According to an embodiment of the present disclosure, two of R_{A1}, R_{A2} and R_{A3} are, identically or differently, selected from the group consisting of: substituted or unsubstituted alkyl having 1 to 6 carbon atoms or substituted or unsubstituted cycloalkyl having 3 to 6 ring carbon atoms; and another one of R_{A1}, R_{A2} and R_{A3} is selected from the group consisting of: deuterium, fluorine, substituted or unsubstituted aryl having 6 to 18 carbon atoms, substituted or unsubstituted heteroaryl having 3 to 18 carbon atoms, substituted or unsubstituted alkylsilyl having 3 to 12 carbon atoms, substituted or unsubstituted alkylgermanyl having 3 to 12 carbon atoms, a cyano group and combinations thereof.

According to an embodiment of the present disclosure, Formula 2 is, at each occurrence identically or differently, selected from the group consisting of A-1 to A-83, wherein the specific structures of A-1 to A-83 are referred to claim 14.

According to an embodiment of the present disclosure, hydrogen in A-1 to A-83 can be partially or fully substituted with deuterium.

According to an embodiment of the present disclosure, at least one of X₁ to X₈ is selected from CRₓ, and the Rₓ is cyano or fluorine.

According to an embodiment of the present disclosure, at least one of X₃ to X₈ is selected from CRₓ, and the Rₓ is cyano or fluorine.

According to an embodiment of the present disclosure, at least one of X₅ to X₈ is selected from CRₓ, and the Rₓ is cyano or fluorine.

According to an embodiment of the present disclosure, at least one of X₇ or X₈ is selected from CRₓ, and the Rₓ is cyano or fluorine.

According to an embodiment of the present disclosure, X₈ is selected from CRₓ.

According to an embodiment of the present disclosure, when X₈ is selected from N, at least one of X₁ to X₇ is selected from CRₓ, and the Rₓ is cyano; when the rest of X₁ to X₇ is(are) selected from CRₓ, Rₓ is selected from hydrogen, deuterium, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group and combinations thereof.

According to an embodiment of the present disclosure, at least two of X₃ to X₈ are CRₓ, one Rₓ is cyano or fluorine, and at least another one Rₓ is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof.

According to an embodiment of the present disclosure, at least two of X₅ to X₈ are CRₓ, one Rₓ is cyano or fluorine, and at least another one Rₓ is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, a cyano group, a hydroxyl group, a sulfanyl group and combinations thereof.

According to an embodiment of the present disclosure, X₇ and X₈ are selected from CRₓ, one Rₓ is cyano or fluorine, and another one Rₓ is selected from the group consisting of: deuterium, halogen, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 12 carbon atoms and combinations thereof.

According to an embodiment of the present disclosure, Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 6 to 20 carbon atoms, substituted or unsubstituted amino having 0 to 20 carbon atoms, a cyano group, a hydroxyl group, a sulfanyl group and combinations thereof.

According to an embodiment of the present disclosure, Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof.

According to an embodiment of the present disclosure, R′ is, at each occurrence identically or differently, selected from substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 12 carbon atoms or a combination thereof.

According to an embodiment of the present disclosure, R′ is selected from methyl, phenyl or deuterated methyl.

According to an embodiment of the present disclosure, Lₐ is, at each occurrence identically or differently, selected from the group consisting of: Lₐ₁₋₁ to Lₐ₁₋₁₂₁, Lₐ₂₋₁ to Lₐ₂₋₁₁₆ and L_{aD-1} to L_{aD-128}, wherein the specific structures of Lₐ₁₋₁ to Lₐ₁₋₁₂₁, Lₐ₂₋₁ to Lₐ₂₋₁₁₆ and L_{aD-1} to L_{aD-128} are referred to claim 17.

According to an embodiment of the present disclosure, hydrogen in Lₐ₁₋₁ to Lₐ₁₋₁₂₁, Lₐ₂₋₁ to Lₐ₂₋₁₁₆ and L_{aD-1} to L_{aD-128} can be partially or fully substituted with deuterium.

According to an embodiment of the present disclosure, L_{b} is, at each occurrence identically or differently, selected from the group consisting of: L_{b1-1} to L_{b1-355}, L_{b2-1} to L_{b2-283} and L_{bx-1} to L_{bx-76}, wherein the specific structures of L_{b1-1} to L_{b1-355}, L_{b2-1} to L_{b2-283} and L_{bx-1} to L_{bx-76} are referred to claim 18.

According to an embodiment of the present disclosure, hydrogen in L_{b1-1} to L_{b1-355}, L_{b2-1} to L_{b2-283} and L_{bx-1} to L_{bx-76} can be partially or fully substituted with deuterium.

According to an embodiment of the present disclosure, L_{c} is, at each occurrence identically or differently, selected from the group consisting of L_{c1} to L_{c360}, wherein the specific structures of L_{c1} to L_{c360} are referred to claim 19.

According to an embodiment of the present disclosure, the metal complex has a structure of Ir(Lₐ)₂L_{b}, wherein the two Lₐ are identical or different, Lₐ is, at each occurrence identically or differently, selected from the group consisting of Lₐ₁₋₁ to Lₐ₁₋₁₂₁, Lₐ₂₋₁ to Lₐ₂₋₁₁₆ and L_{aD-1} to L_{aD-128}, and L_{b} is selected from the group consisting of L_{b1-1} to L_{b1-355}, L_{b2-1} to L_{b2-283} and L_{bx-1} to L_{bx-76}.

According to an embodiment of the present disclosure, the metal complex has a structure of IrLₐ(L_{b})₂, wherein the two L_{b} are identical or different, Lₐ is selected from the group consisting of Lₐ₁₋₁ to Lₐ₁₋₁₂₁, Lₐ₂₋₁ to Lₐ₂₋₁₁₆ and L_{aD-1} to L_{aD-128}, and L_{b} is, at each occurrence identically or differently, selected from the group consisting of L_{b1-1} to L_{b1-355}, L_{b2-1} to L_{b2-283} and L_{bx-1} to L_{bx-76}.

According to an embodiment of the present disclosure, the metal complex has a structure of Ir(Lₐ)(L_{b})(L_{c}), wherein Lₐ is selected from the group consisting of Lₐ₁₋₁ to Lₐ₁₋₁₂₁, Lₐ₂₋₁ to Lₐ₂₋₁₁₆ and L_{aD-1} to L_{aD-128}, L_{b} is selected from the group consisting of L_{b1-1} to L_{b1-355}, L_{b2-1} to L_{b2-283} and L_{bx-1} to L_{bx-76}, and L_{c} is selected from the group consisting of L_{c1}to L_{c360}, wherein the specific structures of L_{c1} to L_{c360} are referred to claim 19.

According to an embodiment of the present disclosure, the metal complex is selected from the group consisting of Metal Complex 1 to Metal Complex 1488, wherein the specific structures of Metal Complex 1 to Metal Complex 1488 are referred to claim 20.

According to an embodiment of the present disclosure, Lₐ is, at each occurrence identically or differently, selected from the group consisting of Lₐ₁₋₁ to Lₐ₁₋₁₂₃, Lₐ₂₋₁ to Lₐ₂₋₁₁₆ and L_{aD-1} to L_{aD-128}, wherein the specific structures of Lₐ₁₋₁ to Lₐ₁₋₁₂₃, Lₐ₂₋₁ to Lₐ₂₋₁₁₆ and L_{aD-1} to L_{aD-128} are referred to claim 17.

According to an embodiment of the present disclosure, hydrogen in Lₐ₁₋₁ to Lₐ₁₋₁₂₃, Lₐ₂₋₁ to Lₐ₂₋₁₁₆ and L_{aD-1} to L_{aD-128} can be partially or fully substituted with deuterium.

According to an embodiment of the present disclosure, L_{b} is, at each occurrence identically or differently, selected from the group consisting of L_{b1-1} to L_{b1-357}, L_{b2-1} to L_{b2-285} and L_{bx-1} to L_{bx-76}, wherein the specific structures of L_{b1-1} to L_{b1-357}, L_{b2-1} to L_{b2-285} and L_{bx-1} to L_{bx-76} are referred to claim 18.

According to an embodiment of the present disclosure, hydrogen in L_{b1-1} to L_{b1-357}, L_{b2-1} to L_{b2-285} and L_{bx-1} to L_{bx-76} can be partially or fully substituted with deuterium.

According to an embodiment of the present disclosure, L_{c} is, at each occurrence identically or differently, selected from the group consisting of L_{c1} to L_{c360}, wherein the specific structures of L_{c1} to L_{c360} are referred to claim 19.

According to an embodiment of the present disclosure, the metal complex has a structure of Ir(Lₐ)₂L_{b}, wherein the two Lₐ are identical or different, Lₐ is, at each occurrence identically or differently, selected from the group consisting of Lₐ₁₋₁ to Lₐ₁₋₁₂₃, Lₐ₂₋₁ to Lₐ₂₋₁₁₆ and L_{aD-1} to L_{aD-128}, and L_{b} is selected from the group consisting of L_{b1-1} to L_{b1-357}, L_{b2-1} to L_{b2-285} and L_{bx-1} to L_{bx-76}.

According to an embodiment of the present disclosure, the metal complex has a structure of IrLₐ(L_{b})₂, wherein the two L_{b} are identical or different, Lₐ is selected from the group consisting of Lₐ₁₋₁ to Lₐ₁₋₁₂₃, Lₐ₂₋₁ to Lₐ₂₋₁₁₆ and L_{aD-1} to L_{aD-128}, and L_{b} is, at each occurrence identically or differently, selected from the group consisting of L_{b1-1} to L_{b1-357}, L_{b2-1} to L_{b2-285} and L_{bx-1} to L_{bx-76}.

According to an embodiment of the present disclosure, the metal complex has a structure of Ir(Lₐ)(L_{b})(L_{c}), wherein Lₐ is selected from the group consisting of Lₐ₁₋₁ to Lₐ₁₋₁₂₃, Lₐ₂₋₁ to Lₐ₂₋₁₁₆ and L_{aD-1} to L_{aD-128}, L_{b} is selected from the group consisting of L_{b1-1} to L_{b1-357}, L_{b2-1} to L_{b2-285} and L_{bx-1} to L_{bx-76}, and L_{c} is selected from the group consisting of L_{c1} to L_{c360}, wherein the specific structures of L_{c1} to L_{c360} are referred to claim 19.

According to an embodiment of the present disclosure, the metal complex is selected from the group consisting of Metal Complex 1 to Metal Complex 1504, wherein the specific structures of Metal Complex 1 to Metal Complex 1504 are referred to claim 20.

According to an embodiment of the present disclosure, further disclosed is an electroluminescent device including:

an anode,

a cathode, and

an organic layer disposed between the anode and the cathode, wherein at least one layer of the organic layer comprises the metal complex according to any one of the preceding embodiments.

According to an embodiment of the present disclosure, the organic layer comprising the metal complex in the electroluminescent device is an emissive layer.

According to an embodiment of the present disclosure, the electroluminescent device emits green light.

According to an embodiment of the present disclosure, the electroluminescent device emits white light.

According to an embodiment of the present disclosure, the emissive layer of the electroluminescent device further comprises a first host compound.

According to an embodiment of the present disclosure, the emissive layer of the electroluminescent device further comprises a first host compound and at least one second host compound.

According to an embodiment of the present disclosure, at least one of the first host compound and the second host compound in the electroluminescent device comprises at least one chemical group selected from the group consisting of: benzene, pyridine, pyrimidine, triazine, carbazole, azacarbazole, indolocarbazole, dibenzothiophene, azadibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene, and combinations thereof.

According to an embodiment of the present disclosure, the first host compound in the electroluminescent device has a structure represented by Formula X:

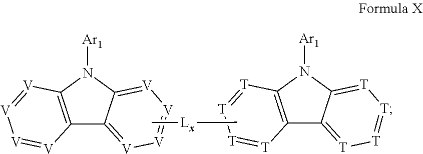

wherein

Lₓ is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or combinations thereof;

V is, at each occurrence identically or differently, selected from C, CRᵥ or N, and at least one of V is C and is attached to Lₓ;

T is, at each occurrence identically or differently, selected from C, CRₜ or N, and at least one of T is C and is attached to Lₓ;

Rᵥ and Rₜ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

Ar₁ is, at each occurrence identically or differently, selected from substituted or unsubstituted aryl having 6 to 30 carbon atoms, substituted or unsubstituted heteroaryl having 3 to 30 carbon atoms or combinations thereof;

adjacent substituents Rᵥ and Rₜ can be optionally joined to form a ring.

Herein, the expression that “adjacent substituents Rᵥ and Rₜ can be optionally joined to form a ring” is intended to mean that any one or more of groups of adjacent substituents, such as two substituents Rᵥ, two substituents Rₜ, and substituents Rᵥ and Rₜ, can be joined to form a ring. Obviously, it is possible that none of these substituents are joined to form a ring.

According to an embodiment of the present disclosure, the first host compound in the electroluminescent device has a structure represented by one of Formula X-a to Formula X-j:

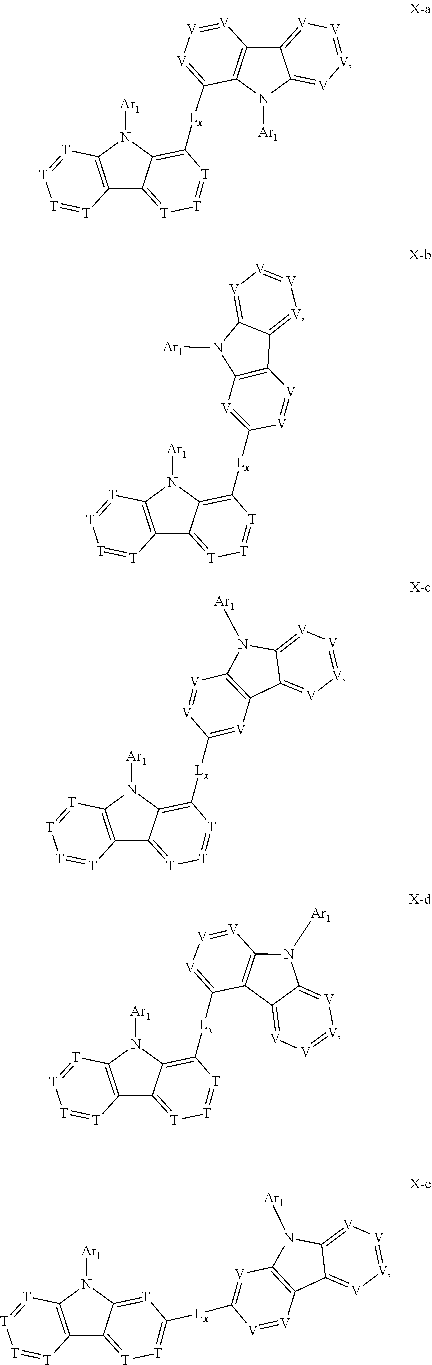

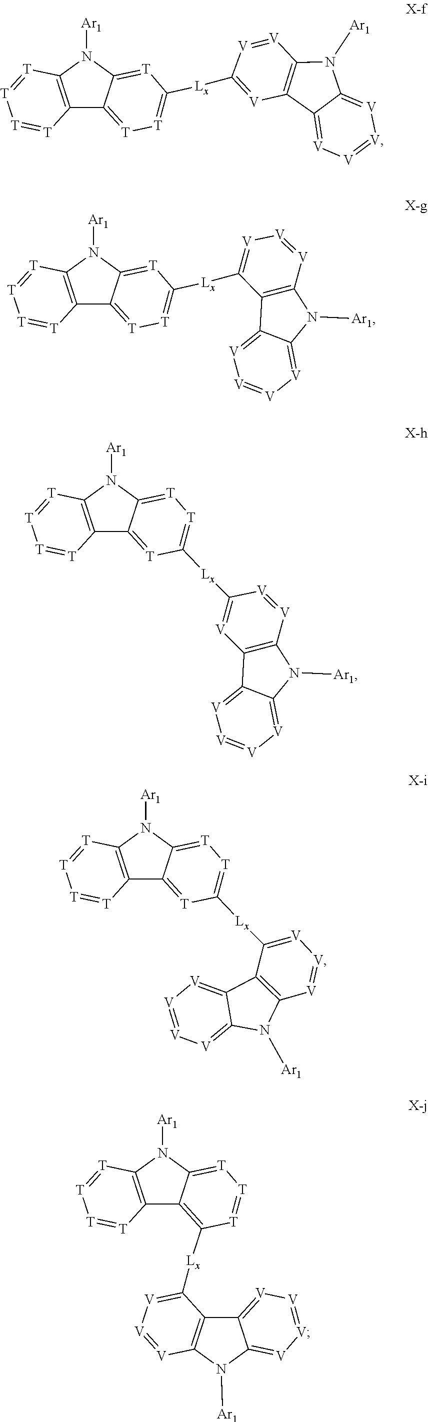

wherein

Lₓ is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or combinations thereof;

V is, at each occurrence identically or differently, selected from CRᵥ or N;

T is, at each occurrence identically or differently, selected from CRₜ or N;

Rᵥ and Rₜ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

Ar₁ is, at each occurrence identically or differently, selected from substituted or unsubstituted aryl having 6 to 30 carbon atoms, substituted or unsubstituted heteroaryl having 3 to 30 carbon atoms or combinations thereof;

adjacent substituents Rᵥ and Rₜ can be optionally joined to form a ring.

According to an embodiment of the present disclosure, in the electroluminescent device, the metal complex is doped in the first host compound and the second host compound, and the weight of the metal complex accounts for 1% to 30% of the total weight of the emissive layer.

According to an embodiment of the present disclosure, in the electroluminescent device, the metal complex is doped in the first host compound and the second host compound, and the weight of the metal complex accounts for 3% to 13% of the total weight of the emissive layer.

According to another embodiment of the present disclosure, a compound composition is further disclosed. The compound composition comprises the metal complex described in any one of the above-mentioned embodiments.

Combination with Other Materials

The materials described in the present disclosure for a particular layer in an organic light-emitting device can be used in combination with various other materials present in the device. The combinations of these materials are described in more detail in U.S. Pat. App. No. 20160359122 at paragraphs 0132-0161, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The materials described herein as useful for a particular layer in an organic light-emitting device may be used in combination with a variety of other materials present in the device. For example, dopants disclosed herein may be used in combination with a wide variety of hosts, transport layers, blocking layers, injection layers, electrodes and other layers that may be present. The combination of these materials is described in detail in paragraphs 0080-0101 of U.S. Pat. App. No. 20150349273, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

In the embodiments of material synthesis, all reactions were performed under nitrogen protection unless otherwise stated. All reaction solvents were anhydrous and used as received from commercial sources. Synthetic products were structurally confirmed and tested for properties using one or more conventional equipment in the art (including, but not limited to, nuclear magnetic resonance instrument produced by BRUKER, liquid chromatograph produced by SHIMADZU, liquid chromatograph-mass spectrometry produced by SHIMADZU, gas chromatograph-mass spectrometry produced by SHIMADZU, differential Scanning calorimeters produced by SHIMADZU, fluorescence spectrophotometer produced by SHANGHAI LENGGUANG TECH., electrochemical workstation produced by WUHAN CORRTEST, and sublimation apparatus produced by ANHUI BEQ, etc.) by methods well known to the persons skilled in the art. In the embodiments of the device, the characteristics of the device were also tested using conventional equipment in the art (including, but not limited to, evaporator produced by ANGSTROM ENGINEERING optical testing system produced by SUZHOU FATAR, life testing system produced by SUZHOU FATAR, and ellipsometer produced by BEIJING ELLITOP, etc.) by methods well known to the persons skilled in the art. As the persons skilled in the art are aware of the above-mentioned equipment use, test methods and other related contents, the inherent data of the sample can be obtained with certainty and without influence, so the above related contents are not further described in this patent.

### Material Synthesis Example

The method for preparing a compound in the present disclosure is not limited herein. Typically, the following compounds are used as examples without limitations, and synthesis routes and preparation methods thereof are described below.

### Synthesis Example 1: Synthesis of Metal Complex 241

Step 1:

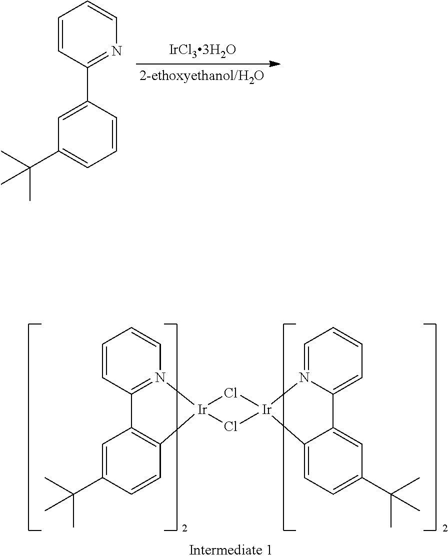

2-(3-t-butylphenyl)-pyridine (3.6 g, 17.1 mmol), iridium trichloride trihydrate (1.6 g, 4.5 mmol), 120 mL of 2-ethoxyethanol and 40 mL of water were sequentially added to a dry 500 mL round-bottom flask, purged with nitrogen three times, and heated and stirred for 24 h at 130° C. under nitrogen protection. The solution was cooled, filtered, washed three times with methanol and n-hexane respectively, and suction-filtrated to dryness to obtain 2.8 g of Intermediate 1 (with a yield of 96%).

Step 2:

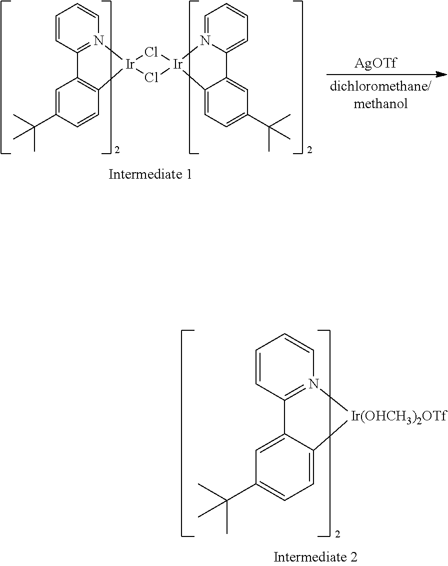

Intermediate 1 (2.8 g, 2.2 mmol), 100 mL of anhydrous dichloromethane, 10 mL of methanol and silver trifluoromethanesulfonate (1.2 g, 4.8 mmol) were sequentially added to a dry 250 mL round-bottom flask, purged with nitrogen three times, and stirred overnight at room temperature under nitrogen protection. The solution was filtered through Celite and washed twice with dichloromethane. The organic phases below were collected and concentrated under reduced pressure to obtain 3.6 g of Intermediate 2 as a yellow solid (with a yield of 99%).

Step 3:

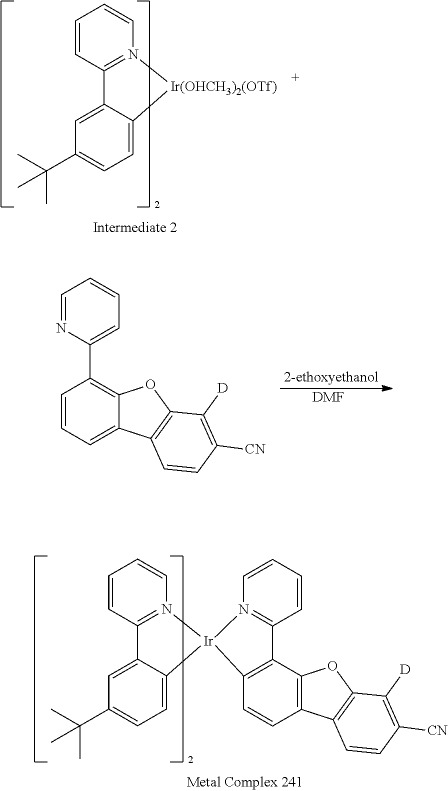

Intermediate 2 (3.6 g, 4.4 mmol), Intermediate 3 (1.8 g, 6.6 mmol), 2-ethoxyethanol (50 mL) and DMF (50 mL) were sequentially added into a dry 250 mL round-bottom flask and heated to react for 96 h at 100° C. under N₂ protection. The reaction was cooled, filtered through Celite, and washed twice with methanol and n-hexane separately. Yellow solids on the Celite were dissolved with dichloromethane. The organic phases were collected, concentrated under reduced pressure, and purified through column chromatography to obtain Metal Complex 241 as a yellow solid (2.8 g with a yield of 72%). The product structure was confirmed as the target product with a molecular weight of 883.3.

### Synthesis Example 2: Synthesis of Metal Complex 13

Step 1:

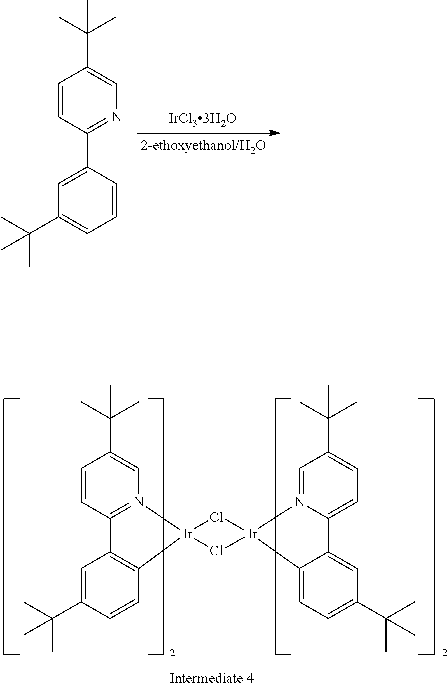

5-t-butyl-2-(3-t-butylphenyl)-pyridine (4.7 g, 17.6 mmol), iridium trichloride trihydrate (1.5 g, 4.2 mmol), 120 mL of 2-ethoxyethanol and 40 mL of water were sequentially added to a dry 500 mL round-bottom flask, purged with nitrogen three times, and heated and stirred for 24 h at 130° C. under nitrogen protection. The solution was cooled, filtered, washed three times with methanol and n-hexane respectively, and suction-filtrated to dryness to obtain 3.0 g of Intermediate 4 (with a yield of 96%).

Step 2:

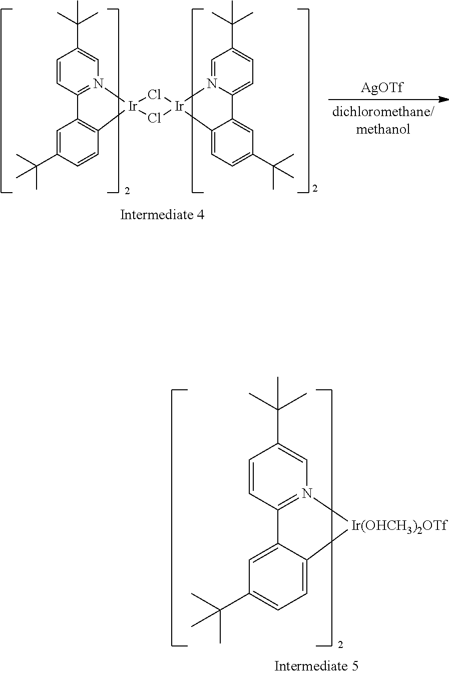

Intermediate 4 (3.0 g, 2.0 mmol), 100 mL of anhydrous dichloromethane, 10 mL of methanol and silver trifluoromethanesulfonate (1.1 g, 4.3 mmol) were sequentially added to a dry 250 mL round-bottom flask, purged with nitrogen three times, and stirred overnight at room temperature under nitrogen protection. The solution was filtered through Celite and washed twice with dichloromethane. The organic phases below were collected and concentrated under reduced pressure to obtain 3.7 g of Intermediate 5 as a yellow solid (with a yield of 100%).

Step 3:

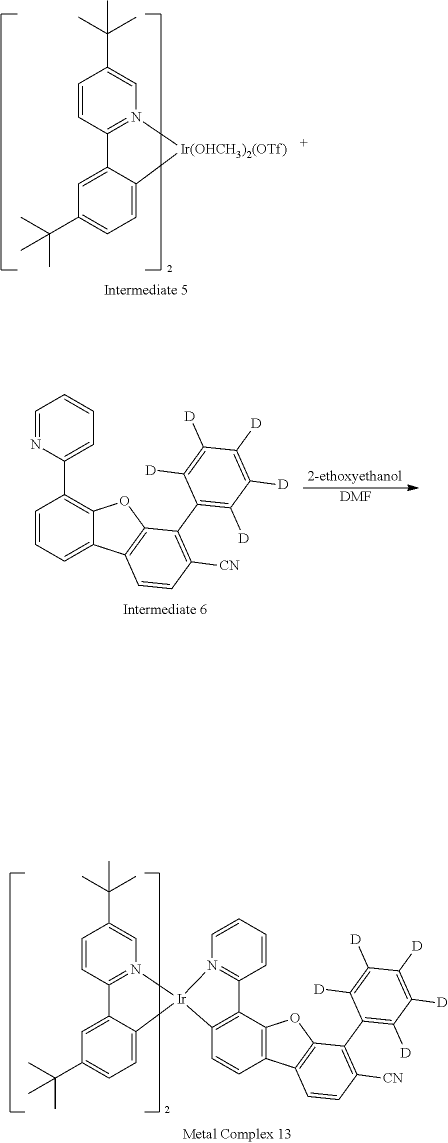

Intermediate 5 (3.7 g, 4.0 mmol), Intermediate 6 (2.1 g, 6.0 mmol), 2-ethoxyethanol (50 mL) and DMF (50 mL) were sequentially added into a dry 250 mL round-bottom flask and heated to react for 96 h at 100° C. under N₂ protection. The reaction was cooled, filtered through Celite, and washed twice with methanol and n-hexane separately. Yellow solids on the Celite were dissolved with dichloromethane. The organic phases were collected, concentrated under reduced pressure, and purified through column chromatography to obtain Metal Complex 13 as a yellow solid (2.1 g with a yield of 45%). The product structure was confirmed as the target product with a molecular weight of 1075.5.

### Synthesis Example 3: Synthesis of Metal Complex 1490

Step 1:

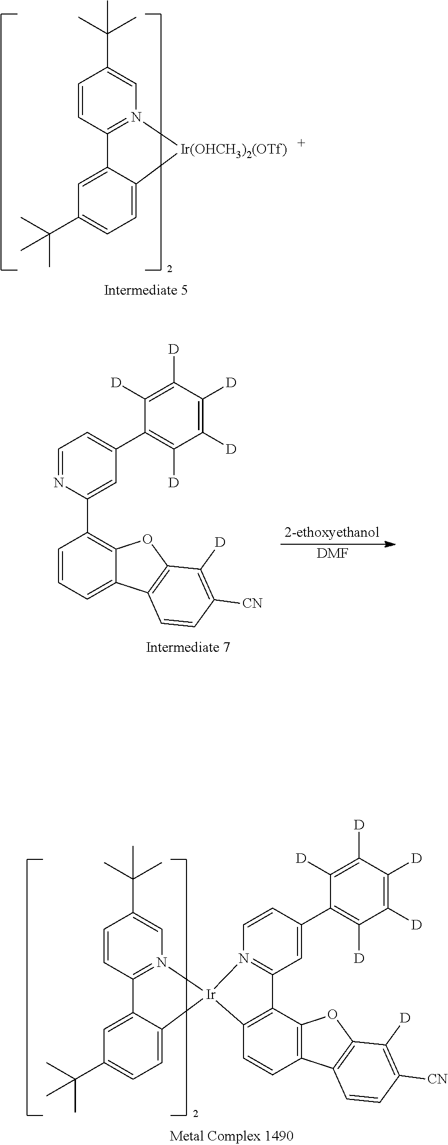

Intermediate 5 (2.7 g, 2.8 mmol), Intermediate 7 (1.5 g, 4.3 mmol), 50 mL of 2-ethoxyethanol and 50 mL of N,N-dimethylformamide were sequentially added to a dry 250 mL round-bottom flask, purged with nitrogen three times, and heated at 100° C. for 96 h under nitrogen protection. The reaction was cooled, filtered through Celite, and washed twice with methanol and n-hexane respectively. Yellow solids on the Celite were dissolved in dichloromethane. The organic phases were collected, concentrated under reduced pressure, and purified through column chromatography to obtain Metal Complex 133 as a yellow solid (1.7 g with a yield of 56.4%). The product was confirmed as the target product with a molecular weight of 1076.5.

### Synthesis Example 4: Synthesis of Metal Complex 1496

Step 1:

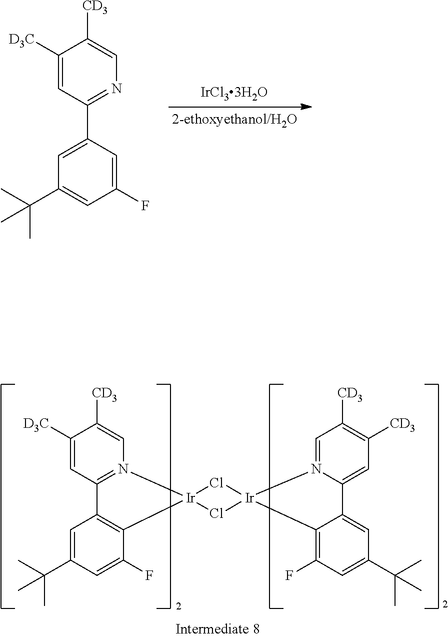

2-(3-(t-butyl)-5-fluorophenyl)-4,5-bis(methyl-d3)pyridine (3.4 g, 12.9 mmol), iridium trichloride trihydrate (1.8 g, 5.1 mmol), 45 mL of 2-ethoxyethanol and 15 mL of water were sequentially added to a dry 250 mL round-bottom flask, purged with nitrogen three times, and heated and stirred for 24 h at 130° C. under nitrogen protection. The solution was cooled, filtered, washed three times with methanol and n-hexane respectively, and suction-filtrated to dryness to obtain 3.1 g of Intermediate 8 (with a yield of 81%).

Step 2:

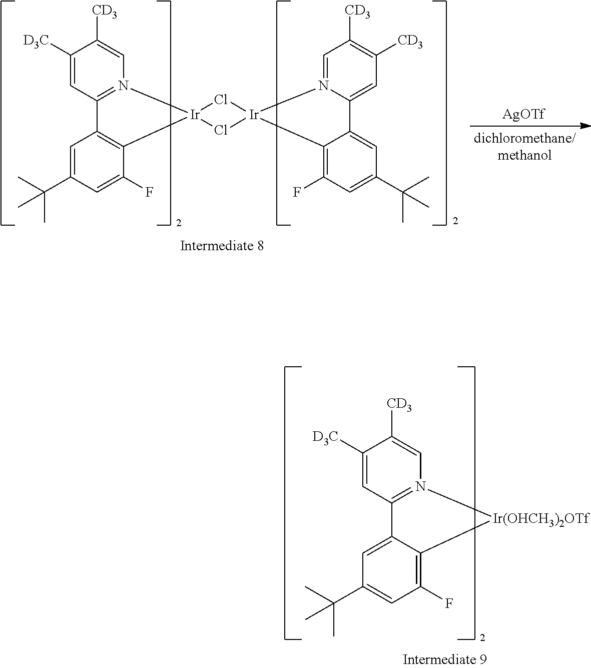

Intermediate 8 (3.1 g, 2.1 mmol), 100 mL of anhydrous dichloromethane, 10 mL of methanol and silver trifluoromethanesulfonate (1.2 g, 4.7 mmol) were sequentially added to a dry 250 mL round-bottom flask, purged with nitrogen three times, and stirred overnight at room temperature under nitrogen protection. The solution was filtered through Celite and washed twice with dichloromethane. The organic phases below were collected and concentrated under reduced pressure to obtain 3.7 g of Intermediate 9 as a yellow solid (with a yield of 95%).

Step 3:

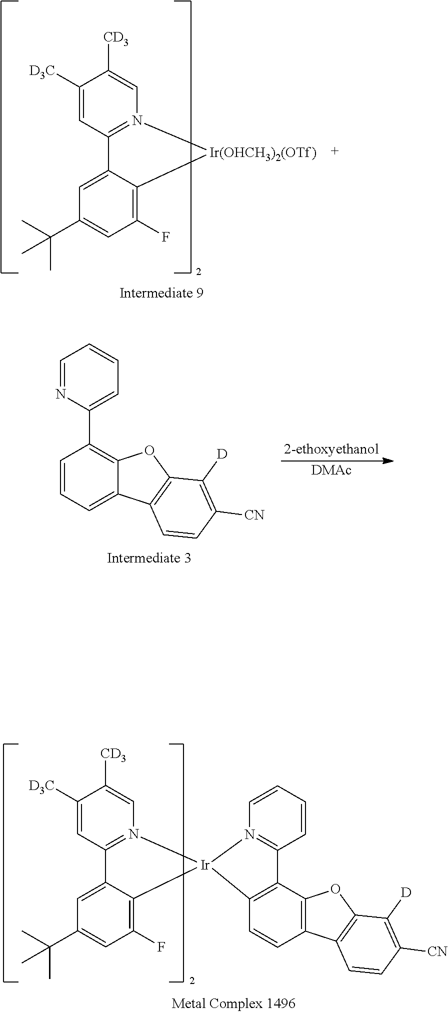

Intermediate 9 (2.0 g, 2.1 mmol), Intermediate 3 (0.9 g, 3.3 mmol), 2-ethoxyethanol (40 mL) and DMAc (40 mL) were sequentially added into a dry 250 mL round-bottom flask and heated to react for 96 h at 100° C. under N₂ protection. The reaction was cooled, filtered, and washed twice with methanol, n-hexane and dichloromethane separately to obtain Metal Complex 1496 as a yellow solid (0.5 g with a yield of 24%). The product structure was confirmed as the target product with a molecular weight of 987.4.

Those skilled in the art will appreciate that the above preparation methods are merely exemplary. Those skilled in the art can obtain other compound structures of the present disclosure through the modifications of the preparation methods.

### Device Example

### Device Example 1

First, a glass substrate having an indium tin oxide (ITO) anode with a thickness of 80 nm was cleaned and then treated with oxygen plasma and UV ozone. After the treatment, the substrate was dried in a glovebox to remove moisture. Then, the substrate was mounted on a substrate holder and placed in a vacuum chamber. Organic layers specified below were sequentially deposited through vacuum thermal evaporation on the ITO anode at a rate of 0.2 to 2 Angstroms per second and a vacuum degree of about 10⁻⁸ torr. Compound HI was used as a hole injection layer (HIL). Compound HT was used as a hole transporting layer (HTL). Compound H1 was used as an electron blocking layer (EBL). Metal Complex 241 of the present disclosure was doped in Compound H1 and Compound H2 as a dopant, and the resulting mixture was deposited for use as an emissive layer (EML). On the EML, Compound HB was deposited as a hole blocking layer (HBL). On the HBL, Compound ET and 8-hydroxyquinolinolato-lithium (Liq) were co-deposited for use as an electron transporting layer (ETL). Finally, 8-hydroxyquinolinolato-lithium (Liq) was deposited as an electron injection layer with a thickness of 1 nm and A1 was deposited as a cathode with a thickness of 120 nm. The device was transferred back to the glovebox and encapsulated with a glass lid to complete the device.

### Device Example 2

The implementation mode in Device Example 2 was the same as that in Device Example 1, except that in the EML, Metal Complex 241 of the present disclosure was replaced with Metal Complex 1490.

### Device Comparative Example 1

The implementation mode in Device Comparative Example 1 was the same as that in Device Example 1, except that in the EML, Metal Complex 241 of the present disclosure was replaced with Compound GD1.

Detailed structures and thicknesses of layers of the devices are shown in the following table. A layer using more than one material is obtained by doping different compounds at their weight ratio as recorded.

TABLE 1
Part of device structures in Device Example 1, Device Example 2 and Device Comparative Example 1

| Device ID | HIL | HTL | EBL | EML | HBL | ETL |
|---|---|---|---|---|---|---|
| Example 1 | Compound | Compound | Compound | Compound | Compound | Compound ET:Liq |
| | HI | HT | H1 | H1:Compound | HB | (40:60) (350 Å) |
| | (100 Å) | (350 Å) | (50 Å) | H2:Metal Complex | (50 Å) | |
| | | | | 241 (47:47:6) (400 | | |
| | | | | Å) | | |
| Example 2 | Compound | Compound | Compound | Compound | Compound | Compound ET:Liq |
| | HI | HT | H1 | H1:Compound | HB | (40:60) (350 Å) |
| | (100 Å) | (350 Å) | (50 Å) | H2:Metal Complex | (50 Å) | |
| | | | | 1490 (47:47:6) (400 | | |
| | | | | Å) | | |
| Comparative | Compound | Compound | Compound | Compound | Compound | Compound ET:Liq |
| Example 1 | HI | HT | H1 | H1:Compound | HB | (40:60) (350 Å) |
| | (100 Å) | (350 Å) | (50 Å) | H2:GD1 (47:47:6) | (50 Å) | |
| | | | | (400 Å) | | |

The structures of the materials used in the devices are shown as follows:

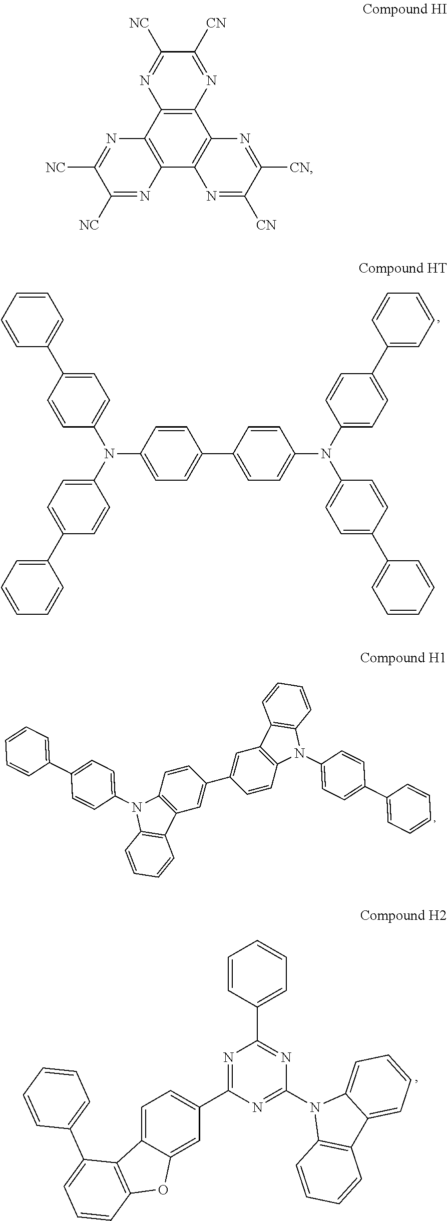 [SMILES: N#Cc1nc2c3nc(C#N)c(C#N)nc3c3nc(C#N)c(C#N)nc3c2nc1C#N ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2nc(-c3ccc4c(c3)oc3cccc(-c5ccccc5)c34)nc(-n3c4ccccc4c4ccccc43)n2)cc1]

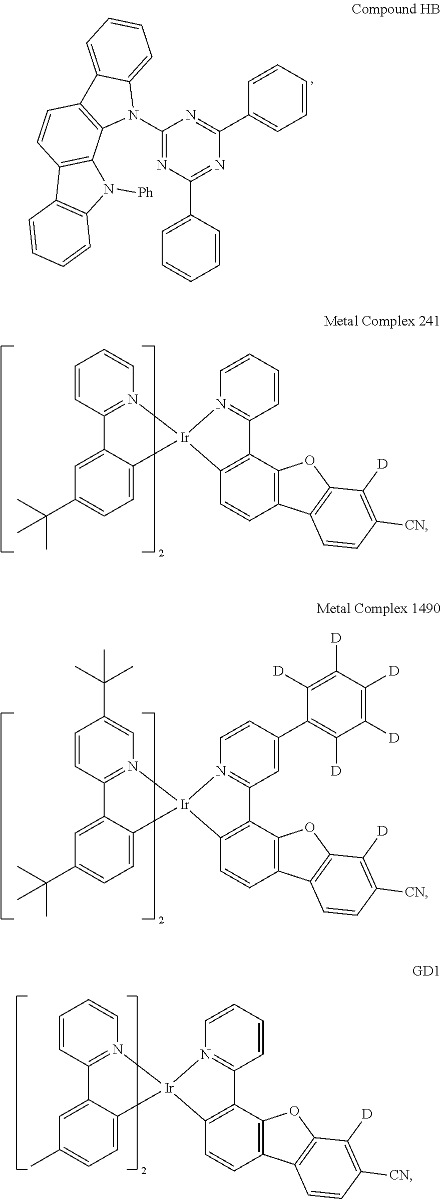

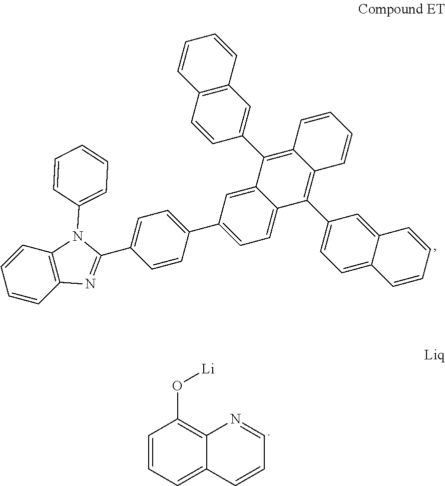

Current-voltage-luminance (IVL) characteristics of the devices were measured. CIE data, maximum emission wavelengths λₘₐₓ, full widths at half maximum (FWHMs) and current efficiency (CE) of the devices were measured at 1000 cd/m²; external quantum efficiency (EQE) data was tested at a constant current of 15 mA/cm²; and lifetime (LT97) data was tested at a constant current of 80 mA/cm². The data was recorded and shown in Table 2.

TABLE 2
Device data in Device Example 1, Device Example
2 and Device Comparative Example 1

| | | | FWHM | CE | | |
|---|---|---|---|---|---|---|
| Device ID | CIE (x, y) | λₘₐₓ (nm) | (nm) | (cd/A) | EQE (%) | LT 97(h) |
| Example 1 | (0.339, 0.635) | 529 | 45.7 | 91 | 23.35 | 25 |
| Example 2 | (0.474, 0.521) | 561 | 77.1 | 86 | 23.28 | 80.4 |
| Comparative | (0.354, 0.624) | 531 | 52.2 | 87 | 22.83 | 1.8 |
| Example 1 | | | | | | |

From the data shown in Table 2, compared to those in Device Comparative Example 1, the CE and EQE in Device Example 1 are improved by 4.6% and 2.3%, respectively, and the lifetime in Device Example 1 reaches 25 h, which is unexpectedly and significantly improved by 13.9 times compared to the lifetime (1.8 h) in Device Comparative Example 1 In addition, compared to those in Device Comparative Example 1, the λₘₐₓ in Device Example 1 is blue-shifted by 2 nm, and the FWHM in Device Example 1 is narrowed by 6.5 nm, providing more saturated green light. Compared to Device Comparative Example 1, Device Example 1 has higher efficiency and an excellent lifetime, exhibits more saturated green light and has significantly improved overall performance of the device, indicating that the metal complex of the present disclosure has a substituent R_{A} at a particular substitution position in a ligand Lₐ and has an excellent effect of improving the device performance compared to the metal complex having a substituent not represented by Formula 2 at the particular substitution position in the ligand Lₐ.

On the basis of Example 1, the metal complex in Example 2 further has substitutions in the ligands Lₐ and L_{b}. On the basis that Device Example 1 has excellent device performance, the maximum emission wavelength in Device Example 2 can be adjusted to obtain a device emitting yellow light, and the device lifetime in Device Example 2 is improved by about 3.22 times. At present, in a white light OLED lamp for daily use, white light is mainly generated through a cooperation of a yellow light light-emitting unit and a blue light light-emitting unit. The metal complex of the present disclosure can show excellent device performance through a further modification of substituents and has broad prospects in commercial applications of yellow light or white light.

### Device Comparative Example 2

The implementation mode in Device Comparative Example 2 was the same as that in Device Example 1, except that in the EML, Metal Complex 241 of the present disclosure was replaced with Compound GD2.

Detailed structures and thicknesses of layers of the device are shown in the following table. A layer using more than one material is obtained by doping different compounds at their weight ratio as recorded.

TABLE 3
Device structure in Device Comparative Example 2

| Device ID | HIL | HTL | EBL | EML | HBL | ETL |
|---|---|---|---|---|---|---|
| Comparative | Compound | Compound | Compound | Compound | Compound | Compound ET:Liq |
| Example 2 | HI | HT | H1 | H1:Compound | HB | (40:60) (350 Å) |
| | (100 Å) | (350 Å) | (50 Å) | H2:GD2 (47:47:6) | (50 Å) | |
| | | | | (400 Å) | | |

The structure of the new material used in the device is shown as follows:

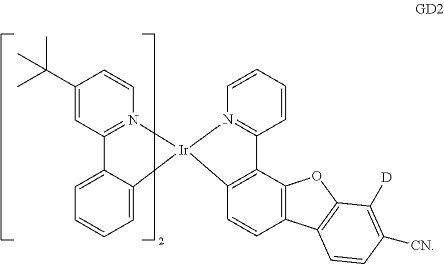

IVL characteristics of the device were measured. CIE data, a maximum emission wavelength λₘₐₓ and an FWHM of the device were measured at 1000 cd/m²; and EQE data was tested at a constant current of 15 mA/cm². The data was recorded and shown in Table 4.

TABLE 4
Device data in Device Comparative Example 2

| | | | FWHM | |
|---|---|---|---|---|
| Device ID | CIE (x, y) | λₘₐₓ (nm) | (nm) | EQE (%) |
| Example 1 | (0.339, 0.635) | 529 | 45.7 | 23.35 |
| Comparative | (0.343, 0.633) | 528 | 50.8 | 21.05 |
| Example 2 | | | | |

From the data shown in Table 4, compared to those in Device Comparative Example 2, the FWHM in Device Example 1 is narrowed by 5.1 nm, and the EQE in Device Example 1 is improved by 10.9%. Device Example 1 has higher efficiency, more saturated green light and significantly improved overall performance of the device, indicating that the metal complex of the present disclosure has a substituent R_{A} at a particular substitution position in a ligand Lₐ and has an excellent effect of improving the device performance compared to the metal complex having a substituent represented by Formula 2 at a non-particular substitution position in the ligand Lₐ.

### Device Example 3

The implementation mode in Device Example 3 was the same as that in Device Example 1, except that in the EML, Metal Complex 241 of the present disclosure was replaced with Metal Complex 13 of the present disclosure, and in the EML, a ratio of Compound H1, Compound H2 and Metal Complex 13 was 63:31:6.

### Device Comparative Example 3

The implementation in Device Comparative Example 3 was the same as that in Device Example 3, except that in the EML, Metal Complex 13 of the present disclosure was replaced with Compound GD3.

Detailed structures and thicknesses of layers of the devices are shown in the following table. A layer using more than one material is obtained by doping different compounds at their weight ratio as recorded.

TABLE 5
Device structures in Device Example 3 and Device Comparative Example 3

| Device ID | HIL | HTL | EBL | EML | HBL | ETL |
|---|---|---|---|---|---|---|
| Example 3 | Compound | Compound | Compound | Compound | Compound | Compound ET:Liq |
| | HI | HT | H1 | H1:Compound | HB | (40:60) (350 Å) |
| | (100 Å) | (350 Å) | (50 Å) | H2:Metal Complex | (50 Å) | |
| | | | | 13 (63:31:6) (400 | | |
| | | | | Å) | | |
| Comparative | Compound | Compound | Compound | Compound | Compound | Compound ET:Liq |
| Example 3 | HI | HT | H1 | H1:Compound | HB | (40:60) (350 Å) |
| | (100 Å) | (350 Å) | (50 Å) | H2:GD3 (63:31:6) | (50 Å) | |
| | | | | (400 Å) | | |

The structures of the new materials used in the devices are shown as follows:

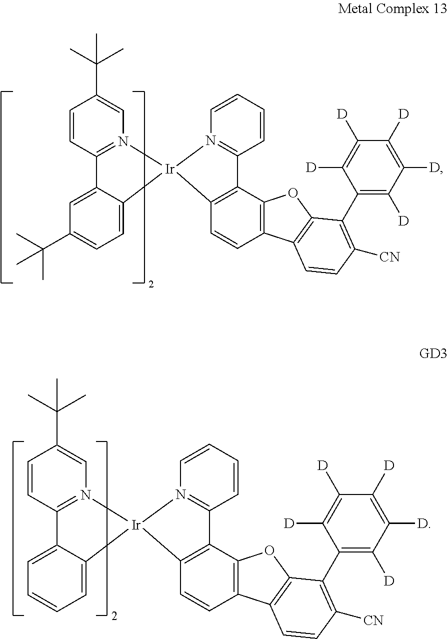

IVL characteristics of the devices were measured. CIE data, maximum emission wavelengths λₘₐₓ, FWHMs and CE of the devices were measured at 1000 cd/m²; EQE data was tested at a constant current of 15 mA/cm²; and lifetime (LT97) data was tested at a constant current of 80 mA/cm². The data was recorded and shown in Table 6.

TABLE 6
Device data in Device Example 3 and Device Comparative Example 3

| | | | FWHM | CE | | |
|---|---|---|---|---|---|---|
| Device ID | CIE (x, y) | λₘₐₓ (nm) | (nm) | (cd/A) | EQE (%) | LT 97(h) |
| Example 3 | (0.367, 0.616) | 535 | 43.3 | 107 | 24.52 | 47.3 |
| Comparative | (0.345, 0.633) | 532 | 36.8 | 106 | 23.89 | 31.7 |
| Example 3 | | | | | | |

From the data shown in Table 6, compared to that in Device Comparative Example 3, the CE in Device Example 3 is slightly improved, and although the FWHM in Device Example 3 is 6.5 nm wider than that in Device Comparative Example 3, the FWHM (43.3 nm) in Device Example 3 is already at a relatively high level. Most importantly, compared to the already very excellent EQE and lifetime in Comparative Example 3, the EQE and lifetime in Example 3 are improved by 2.6% and 49.2%, respectively, which is very rare and commendable. Compared to Device Comparative Example 3, Device Example 3 has higher efficiency and an excellent lifetime, indicating that the metal complex of the present disclosure has a substituent R_{A} at a particular substitution position in a ligand Lₐ and can significantly improve overall performance of the device compared to the metal complex not having a substituent represented by Formula 2 at the particular substitution position in the ligand Lₐ.

The above results show that the metal complex disclosed in the present disclosure comprises the ligand Lₐ having the structure of Formula 1A (having the substituent represented by Formula 2 at the particular substitution position) and the ligand L_{b} having the structure of Formula 1B (having a particular substituent at the particular substitution position), and in the case where the device efficiency can be maintained at a high level in the art, compared to the metal complex having the substituent not represented by Formula 2 at the particular substitution position in the ligand Lₐ and the metal complex having the substituent represented by Formula 2 at the non-particular substitution position in the ligand Lₐ, the metal complex disclosed in the present disclosure can further improve the luminescence performance, efficiency or lifetime of the device, exhibit more saturated luminescence and significantly improve the overall performance of the device. The metal complex disclosed in the present disclosure has huge advantages and broad prospects in industrial applications.

It is to be understood that various embodiments described herein are merely examples and not intended to limit the scope of the present disclosure. Therefore, it is apparent to the persons skilled in the art that the present disclosure as claimed may include variations from specific embodiments and preferred embodiments described herein. Many of materials and structures described herein may be substituted with other materials and structures without departing from the spirit of the present disclosure. It is to be understood that various theories as to why the present disclosure works are not intended to be limitative.

What is claimed is:

1. A metal complex having a general formula of M(Lₐ)ₘ(L_{b})ₙ(L_{c})_{q},
wherein
Lₐ, L_{b} and L_{c} are a first ligand, a second ligand and a third ligand coordinated to the metal M, respectively, and Lₐ, L_{b} and L_{c} are the same or different; wherein Lₐ, L_{b} and L_{c} can be optionally joined to form a tetradentate ligand or a multidentate ligand;
the metal M is selected from a metal with a relative atomic mass greater than 40; and
m is selected from 1 or 2, n is selected from 1 or 2, q is selected from 0 or 1, and m+n+q equals an oxidation state of M; when m is 2, two Lₐ may be identical or different; when n is 2, two L_{b} may be identical or different;
wherein Lₐ has, at each occurrence identically or differently, a structure represented by Formula 1A; and L_{b} has, at each occurrence identically or differently, a structure represented by Formula 1B: 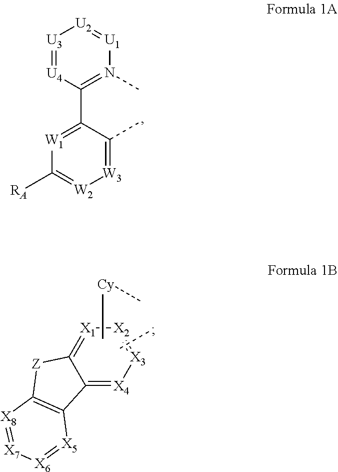
wherein
Z is, at each occurrence identically or differently, selected from the group consisting of O, S, Se, NR′, CR′R′ and SiR′R′; when two R′ are present at the same time, the two R′ are identical or different;
Cy is, at each occurrence identically or differently, selected from a substituted or unsubstituted aromatic ring having 6 to 24 ring atoms, a substituted or unsubstituted heteroaromatic ring having 5 to 24 ring atoms or a combination thereof,
X₁ to X₈ are, at each occurrence identically or differently, selected from C, CRₓ or N, and at least one of X₁ to X₄ is selected from C and joined to Cy;
at least one of X₁ to X₈ is selected from CRₓ, and the Rₓ is cyano or fluorine;
X₁, X₂, X₃ or X₄ is joined to the metal M by a metal-carbon bond or a metal-nitrogen bond;
U₁ to U₄ are, at each occurrence identically or differently, selected from CRᵤ or N; and
W₁ to W₃ are, at each occurrence identically or differently, selected from CR_{w} or N;
wherein in Formula 1A, R_{A} has a structure represented by Formula 2, and the total number of carbon atoms in Formula 2 is greater than or equal to 2: 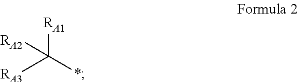
wherein “*” represents a position where Formula 2 is joined to Formula 1A;
R_{A1}, R_{A2}, R_{A3}, R′, Rₓ, Rᵤ and R_{w} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof,
adjacent substituents R_{A1}, R_{A2}, R_{A3}, R′, Rₓ, Rᵤ, R_{w} can be optionally joined to form a ring; and
L_{c} is a monoanionic bidentate ligand.

2. The metal complex according to claim 1, wherein Cy is, at each occurrence identically or differently, selected from any structure of the group consisting of the following: 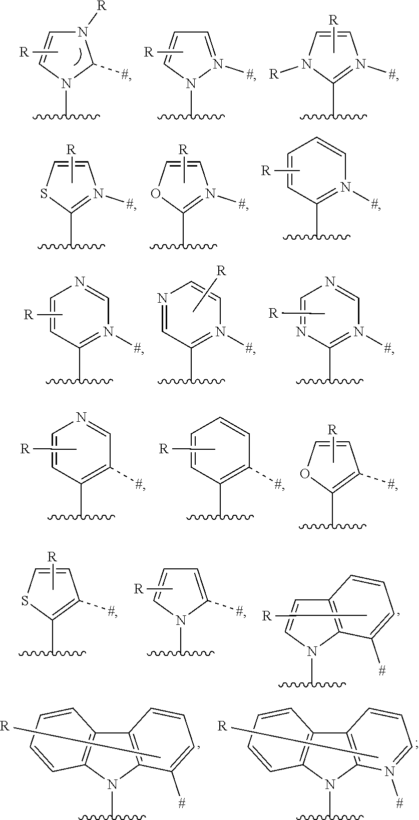
wherein
R represents, at each occurrence identically or differently, mono-substitution, multiple substitutions or non-substitution; and when multiple R are present at the same time in any structure, the multiple R are the same or different;
R is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof,
adjacent substituents R can be optionally joined to form a ring; and
“#” represents a position where Cy is joined to the metal M, and “ 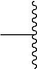
” represents a position where Cy is joined to X₁, X₂, X₃ or X₄.

3. The metal complex according to claim 1, wherein L_{b} has a structure represented by any of Formulas 1Ba to 1Bf: 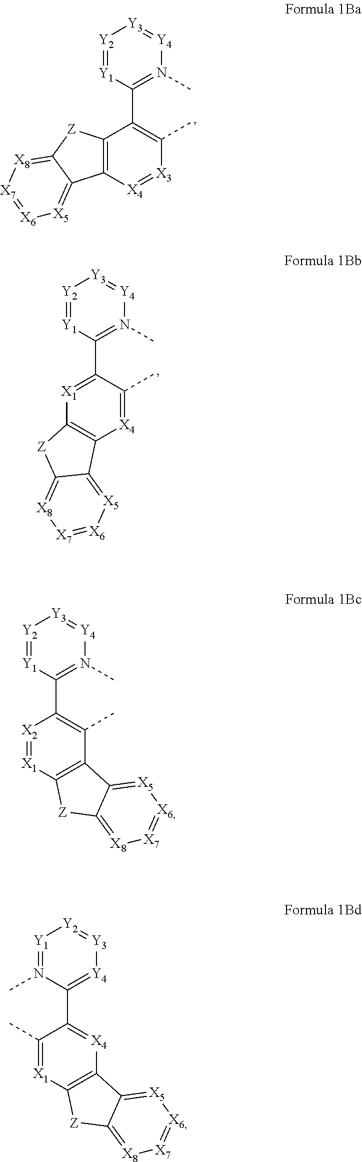 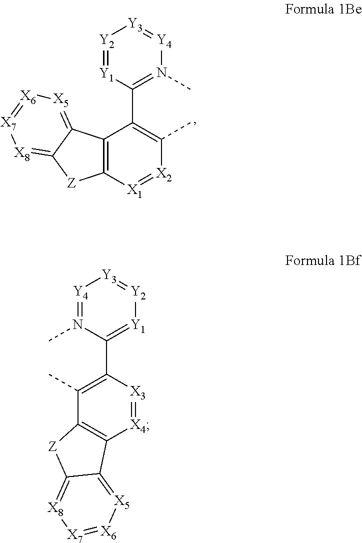
wherein
Z is, at each occurrence identically or differently, selected from the group consisting of O, S, Se, NR′, CR′R′ and SiR′R′; when two R′ are present at the same time, the two R′ are identical or different;
X₁ to X₈ are, at each occurrence identically or differently, selected from CRₓ or N;
at least one of X₁ to X₈ is selected from CRₓ, and the Rₓ is cyano or fluorine;
Y₁ to Y₄ are, at each occurrence identically or differently, selected from CR_{y} or N;
R′, Rₓ and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof, and
adjacent substituents R′, Rₓ, R_{y} can be optionally joined to form a ring.

4. The metal complex according to claim 1, wherein a metal complex Ir(Lₐ)ₘ(L_{b})₃₋ₘ has a structure represented by Formula 3: 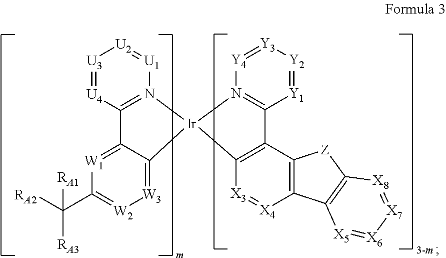
wherein
Z is, at each occurrence identically or differently, selected from the group consisting of O, S, Se, NR′, CR′R′ and SiR′R′; when two R′ are present at the same time, the two R′ are identical or different;
X₃ to X₈ are, at each occurrence identically or differently, selected from CRₓ or N;
at least one of X₃ to X₈ is selected from CRₓ, and the Rₓ is cyano or fluorine;
Y₁ to Y₄ are, at each occurrence identically or differently, selected from CR_{y} or N;
U₁ to U₄ are, at each occurrence identically or differently, selected from CRᵤ or N;
W₁ to W₃ are, at each occurrence identically or differently, selected from CR_{w} or N;
R_{A1}, R_{A2}, R_{A3}, R′, Rₓ, R_{y}, Rᵤ and Rᵥ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof,
the total number of carbon atoms in R_{A1}, R_{A2} and R_{A3} is greater than or equal to 1;
adjacent substituents R_{A1}, R_{A2}, R_{A3} can be optionally joined to form a ring; and
adjacent substituents R′, Rₓ, R_{y}, Rᵤ, R_{w} can be optionally joined to form a ring.

5. The metal complex according to claim 1, wherein Z is selected from the group consisting of: O and S; preferably, Z is O.

6. The metal complex according to claim 1, wherein X₁ to X₈ are, at each occurrence identically or differently, selected from C or CRₓ.

7. The metal complex according to claim 1, wherein at least one of X₁ to X₈ is selected from N; preferably, X₈ is selected from N.

8. The metal complex according to claim 1, wherein W₁ to W₃ are, at each occurrence identically or differently, selected from CR_{w}, and/or U₁ to U₄ are, at each occurrence identically or differently, selected from CRᵤ; and Rᵥ and Rᵤ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof,
preferably, R_{w} and Rᵤ are, at each occurrence identically or differently, selected from the group consisting of: hydrogen, deuterium, substituted or unsubstituted alkyl having 1 to 10 carbon atoms, substituted or unsubstituted cycloalkyl having 3 to 10 ring carbon atoms, substituted or unsubstituted aryl having 6 to 10 carbon atoms and combinations thereof, and
more preferably, R_{w} and Rᵤ are, at each occurrence identically or differently, selected from the group consisting of: hydrogen, deuterium, substituted or unsubstituted alkyl having 1 to 10 carbon atoms, substituted or unsubstituted cycloalkyl having 3 to 10 ring carbon atoms and combinations thereof.

9. The metal complex according to claim 3, wherein Y₁ to Y₄ are, at each occurrence identically or differently, selected from CR_{y}, and R_{y} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof,
preferably, R_{y} is, at each occurrence identically or differently, selected from the group consisting of: hydrogen, deuterium, substituted or unsubstituted alkyl having 1 to 10 carbon atoms, substituted or unsubstituted cycloalkyl having 3 to 10 ring carbon atoms, substituted or unsubstituted aryl having 6 to 10 carbon atoms and combinations thereof, and
more preferably, R_{y} is, at each occurrence identically or differently, selected from the group consisting of: hydrogen, deuterium, substituted or unsubstituted alkyl having 1 to 10 carbon atoms, substituted or unsubstituted cycloalkyl having 3 to 10 ring carbon atoms and combinations thereof.

10. The metal complex according to claim 1, wherein at least one of U₁ to U₄ is selected from CRᵤ, and the Rᵤ is selected from the group consisting of: substituted or unsubstituted alkyl having 1 to 20 carbon atoms, substituted or unsubstituted cycloalkyl having 3 to 20 ring carbon atoms and combinations thereof;
preferably, at least one of U₁ to U₄ is selected from CRᵤ, and the Rᵤ is selected from the group consisting of: substituted or unsubstituted alkyl having 3 to 12 carbon atoms, substituted or unsubstituted cycloalkyl having 3 to 12 ring carbon atoms and combinations thereof, and
more preferably, U₂ or U₃ is selected from CRᵤ, and the Rᵤ is selected from substituted or unsubstituted alkyl having 4 to 12 carbon atoms, substituted or unsubstituted cycloalkyl having 4 to 12 ring carbon atoms or a combination thereof.

11. The metal complex according to claim 1, wherein at least one of U₁ to U₄ is selected from CRᵤ, and the Rᵤ has a structure represented by Formula 2; and
preferably, U₂ or U₃ is selected from CRᵤ, and the Rᵤ has a structure represented by Formula 2.

12. The metal complex according to claim 1, wherein the total number of carbon atoms in R_{A1}, R_{A2} and R_{A3} is greater than or equal to 3;
preferably, R_{A1}, R_{A2} and R_{A3} are, at each occurrence identically or differently, selected from the group consisting of: hydrogen, deuterium, halogen, substituted or unsubstituted alkyl having 1 to 6 carbon atoms, substituted or unsubstituted cycloalkyl having 3 to 6 ring carbon atoms, substituted or unsubstituted heteroalkyl having 1 to 6 carbon atoms, a substituted or unsubstituted heterocyclic group having 3 to 6 ring atoms, substituted or unsubstituted arylalkyl having 7 to 13 carbon atoms, substituted or unsubstituted aryl having 6 to 12 carbon atoms, substituted or unsubstituted heteroaryl having 3 to 12 carbon atoms, a cyano group and combinations thereof, and the total number of carbon atoms in R_{A1}, R_{A2} and R_{A3} is greater than or equal to 3; and
more preferably, R_{A1}, R_{A2} and R_{A3} are, at each occurrence identically or differently, selected from the group consisting of: substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms and combinations thereof.

13. The metal complex according to claim 1, wherein two of R_{A1}, R_{A2} and R_{A3} are, identically or differently, selected from the group consisting of: substituted or unsubstituted alkyl having 1 to 6 carbon atoms or substituted or unsubstituted cycloalkyl having 3 to 6 ring carbon atoms; and another one of R_{A1}, R_{A2} and R_{A3} is selected from the group consisting of: deuterium, fluorine, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, a cyano group and combinations thereof, and
preferably, two of R_{A1}, R_{A2} and R_{A3} are, identically or differently, selected from the group consisting of: substituted or unsubstituted alkyl having 1 to 6 carbon atoms or substituted or unsubstituted cycloalkyl having 3 to 6 ring carbon atoms; and another one of R_{A1}, R_{A2} and R_{A3} is selected from the group consisting of: deuterium, fluorine, substituted or unsubstituted aryl having 6 to 18 carbon atoms, substituted or unsubstituted heteroaryl having 3 to 18 carbon atoms, substituted or unsubstituted alkylsilyl having 3 to 12 carbon atoms, substituted or unsubstituted alkylgermanyl having 3 to 12 carbon atoms, a cyano group and combinations thereof.

14. The metal complex according to claim 1, wherein Formula 2 is, at each occurrence identically or differently, selected from the group consisting of the following: 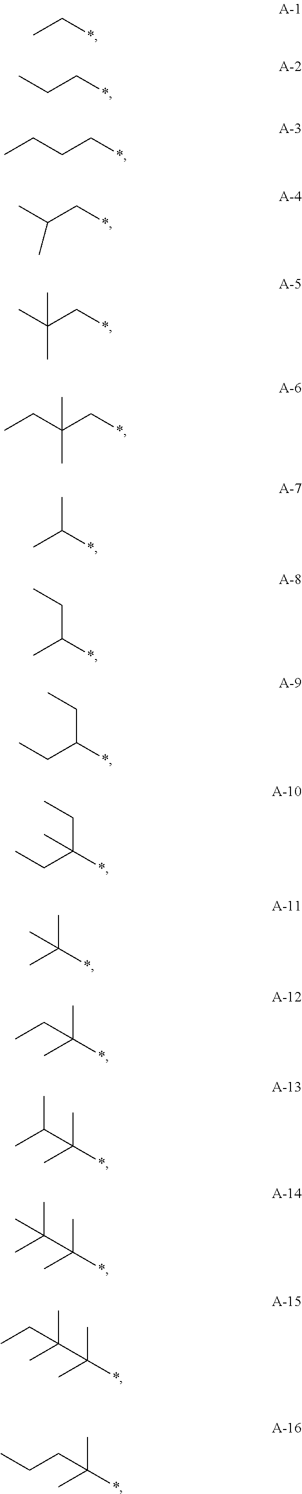 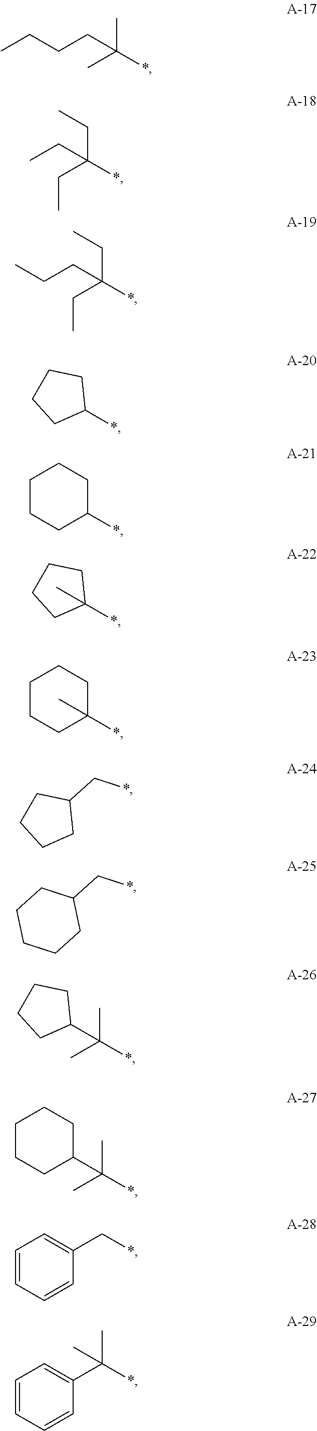 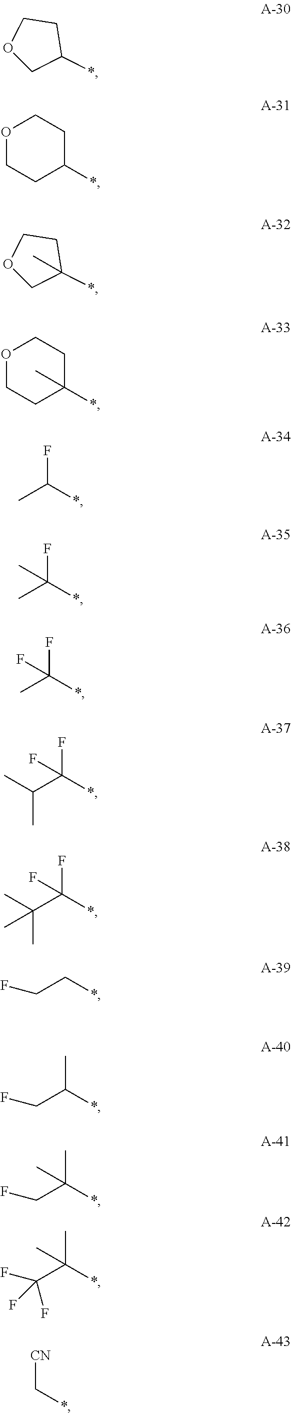 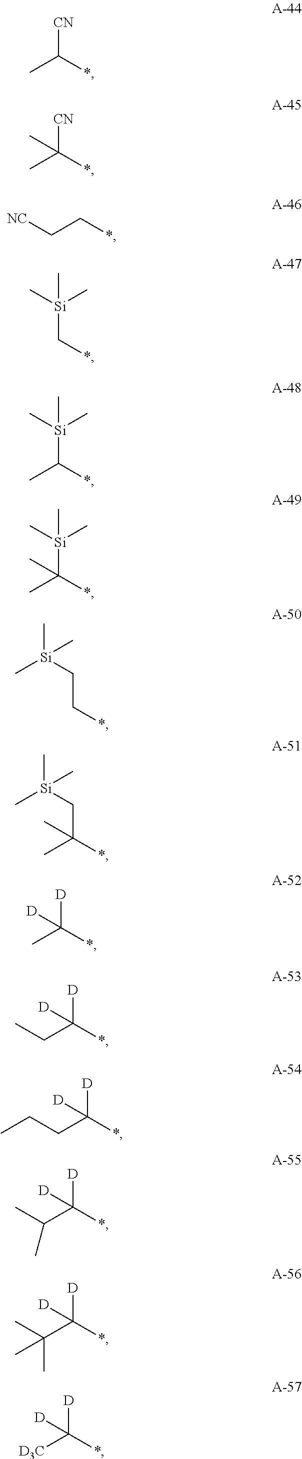 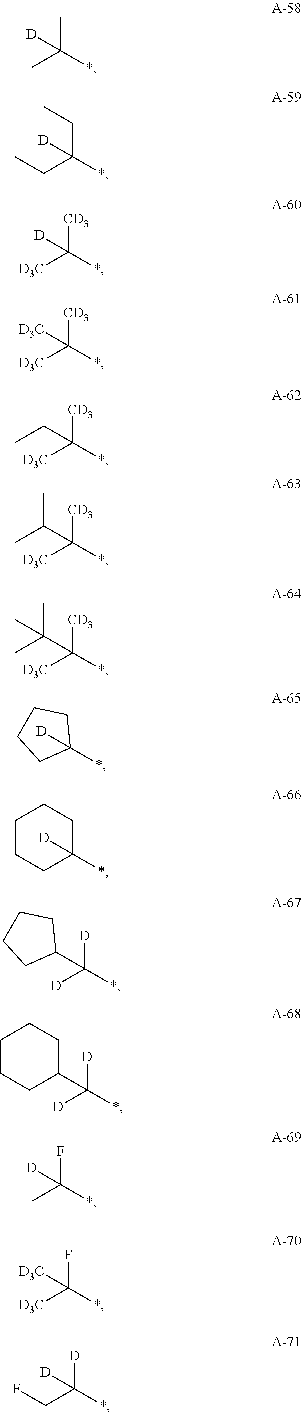 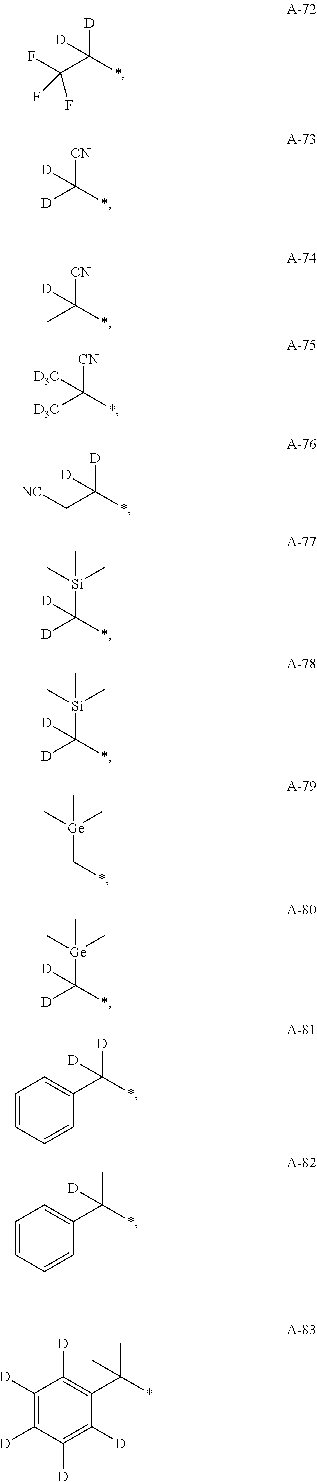
and combinations thereof;
wherein “*” represents a position where Formula 2 is joined to Formula 1A; and
optionally, hydrogen in the groups A-1 to A-83 can be partially or fully substituted with deuterium.

15. The metal complex according to claim 1, wherein at least one of X₃ to X₈ is selected from CRₓ, and the Rₓ is cyano or fluorine;
preferably, at least one of X₅ to X₈ is selected from CRₓ, and the Rₓ is cyano or fluorine; and
more preferably, at least one of X₇ or X₈ is selected from CRₓ, and the Rₓ is cyano or fluorine.

16. The metal complex according to claim 1, wherein at least two of X₃ to X₈ are selected from CRₓ, one of the Rₓ is selected from cyano or fluorine, and at least another one of the Rₓ is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof,
preferably, at least two of X₅ to X₈ are selected from CRₓ, one of the Rₓ is selected from cyano or fluorine, and at least another one of the Rₓ is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, a cyano group, a hydroxyl group, a sulfanyl group and combinations thereof, and
more preferably, X₇ and X₈ are selected from CRₓ, one of the Rₓ is selected from cyano or fluorine, and another one of the Rₓ is selected from the group consisting of: deuterium, halogen, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 12 carbon atoms and combinations thereof.

17. The metal complex according to claim 1, wherein Lₐ is, at each occurrence identically or differently, selected from the group consisting of the following: 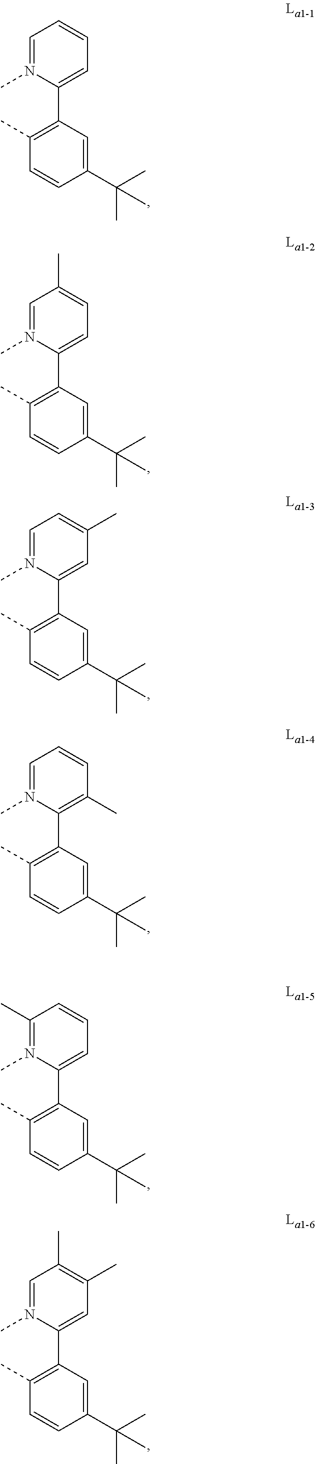 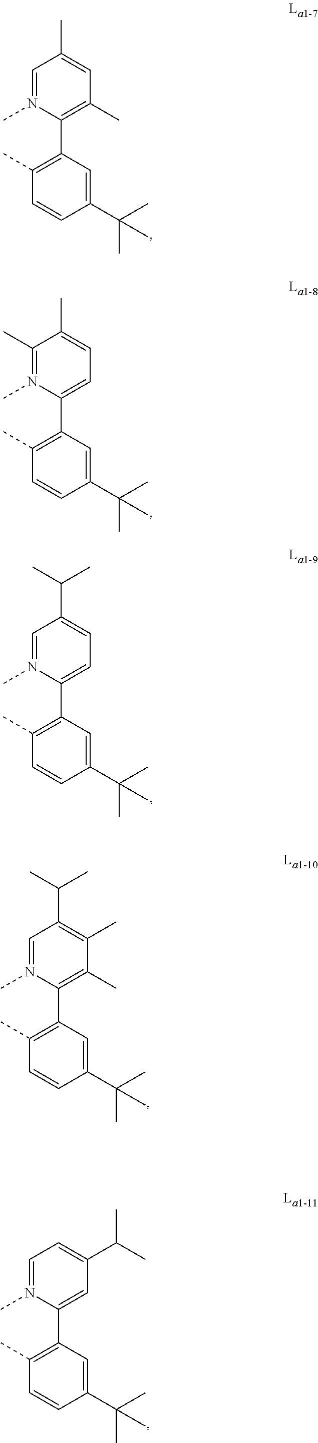 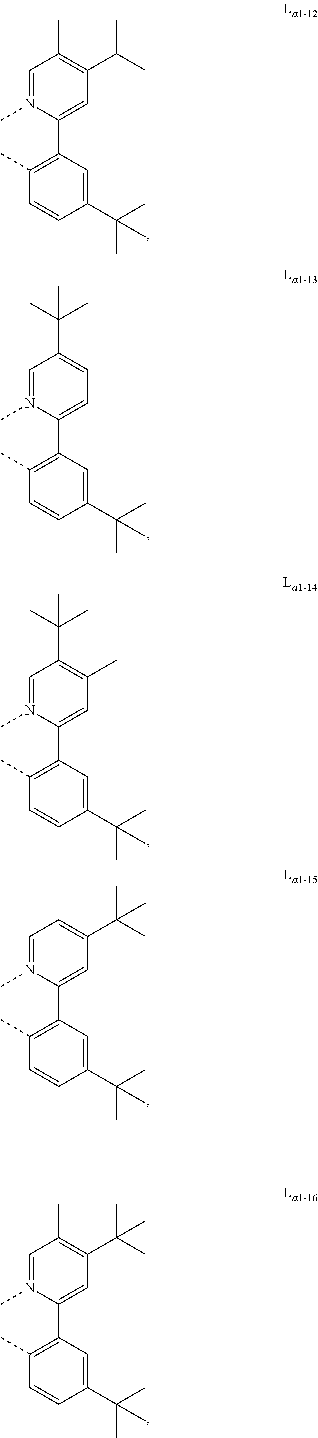 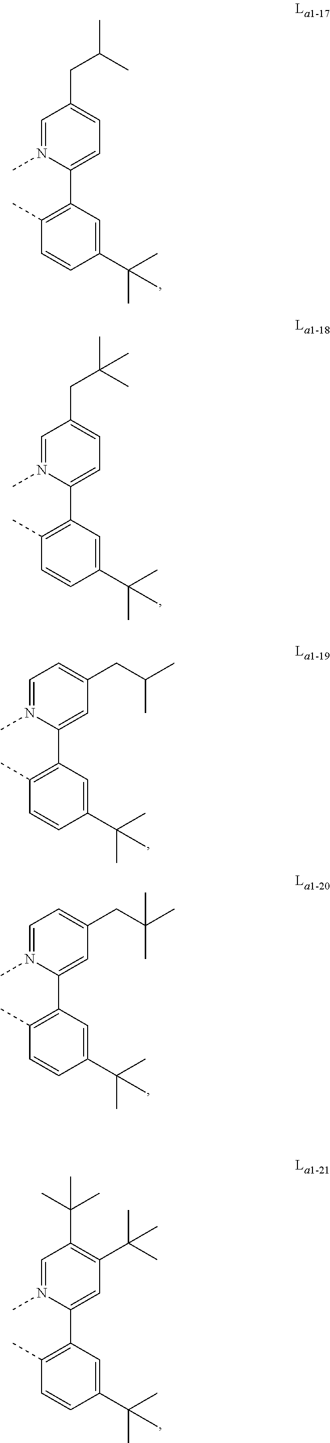 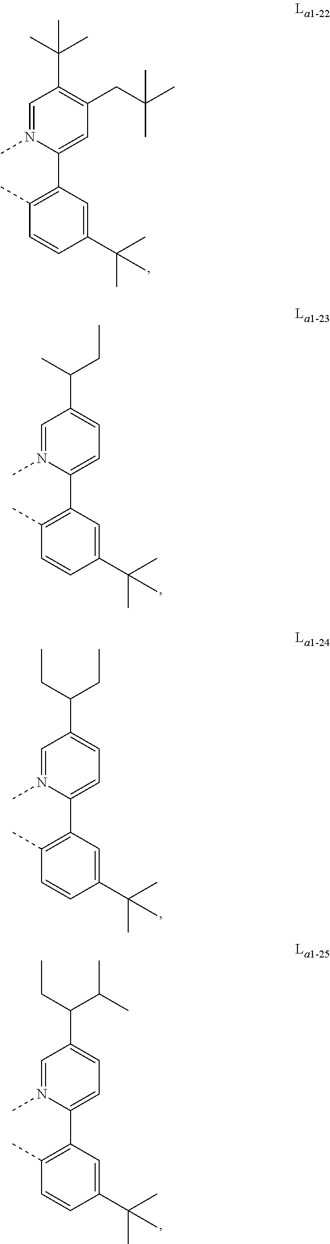 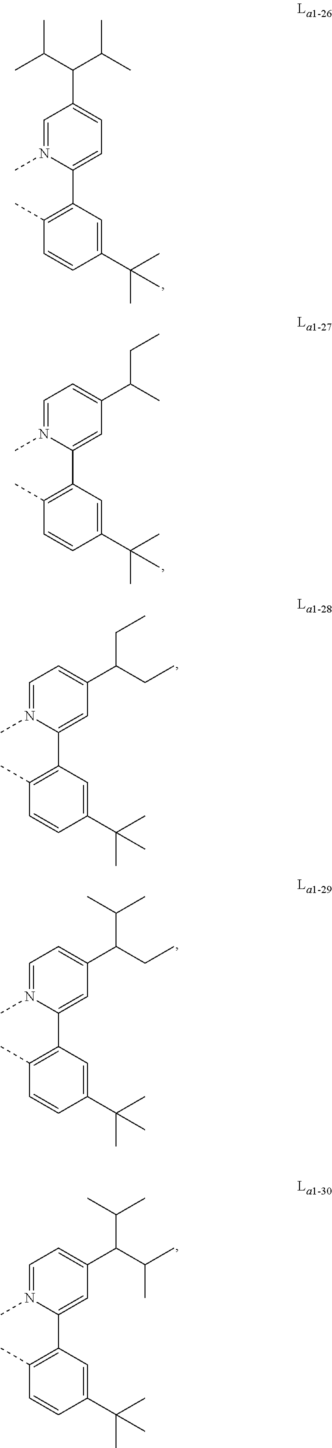 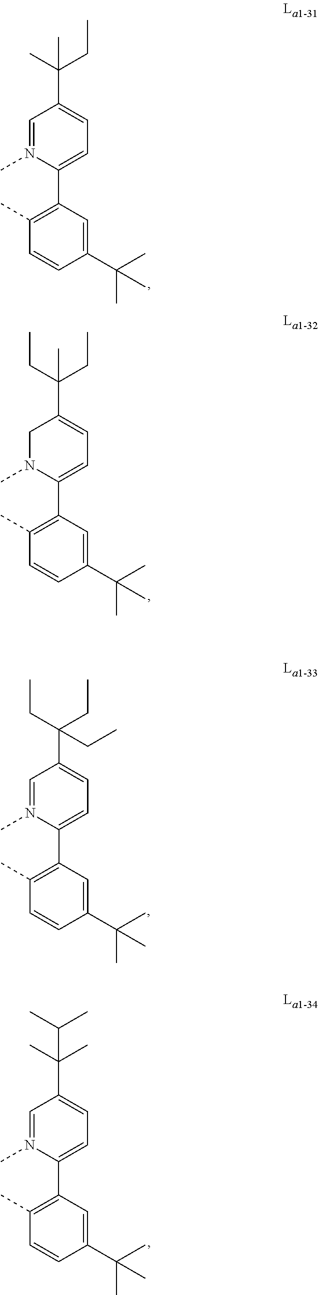 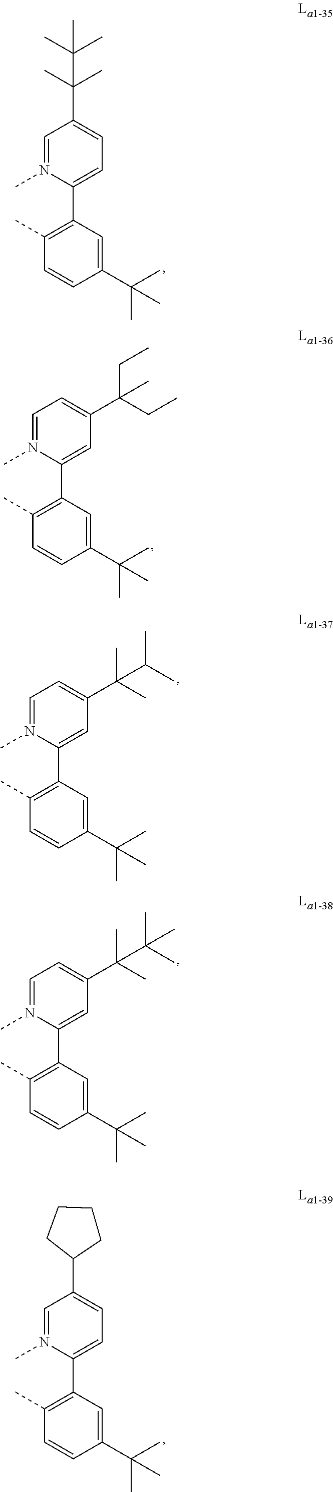 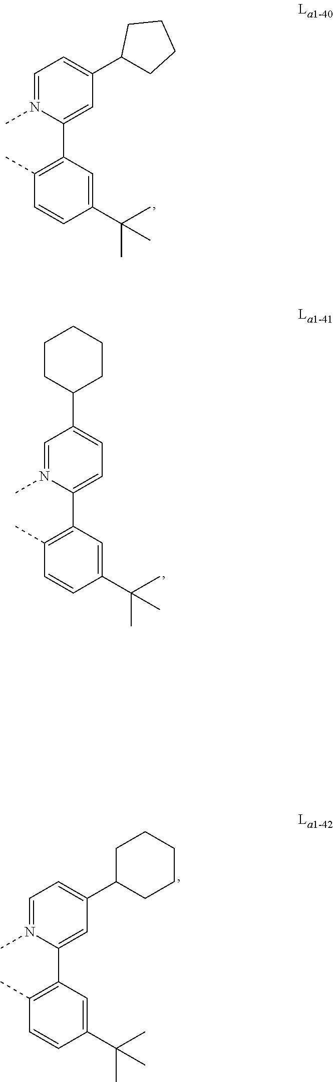 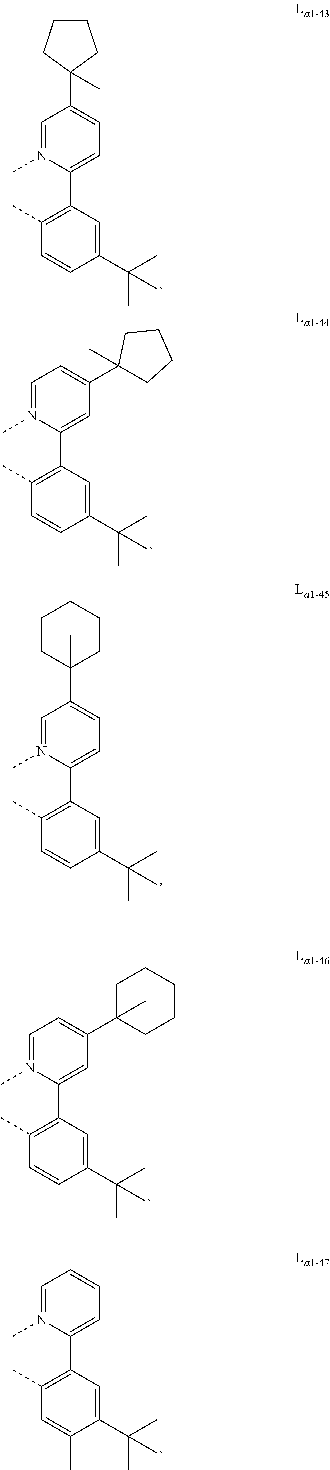 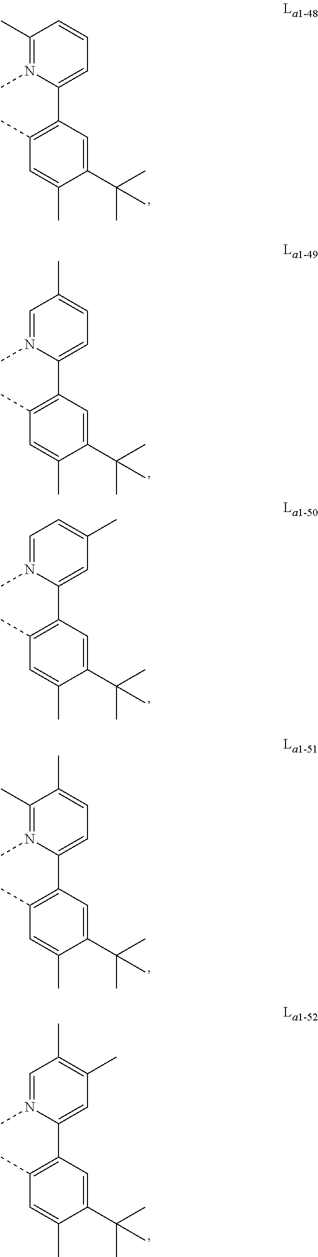 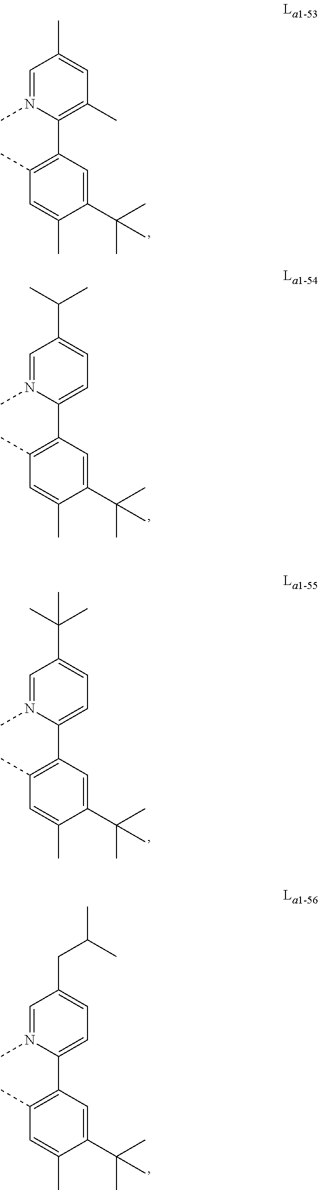 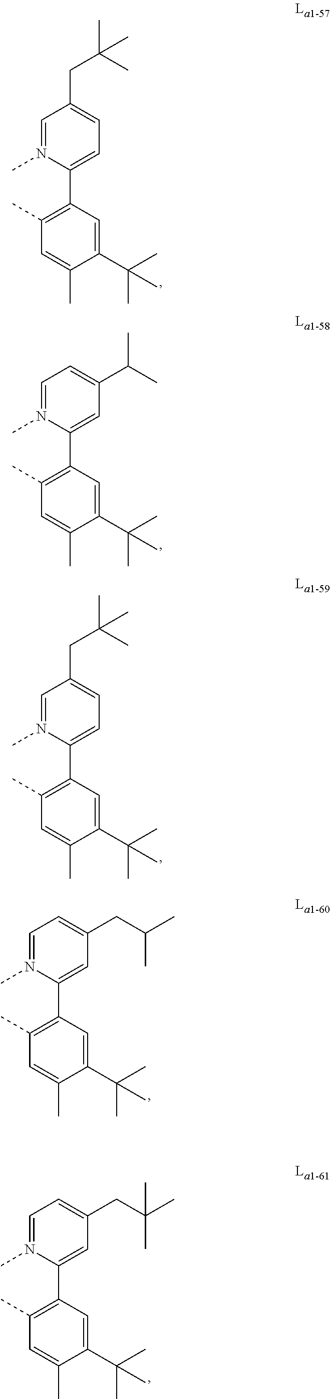 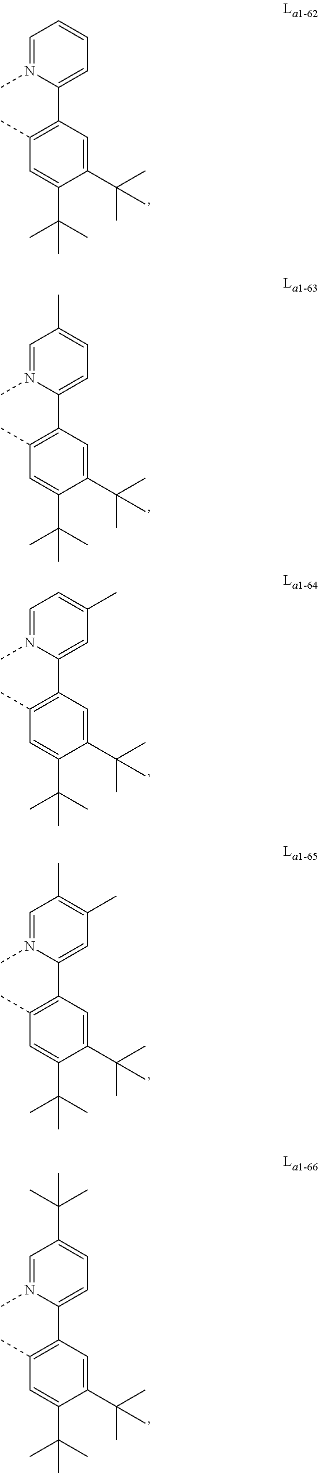 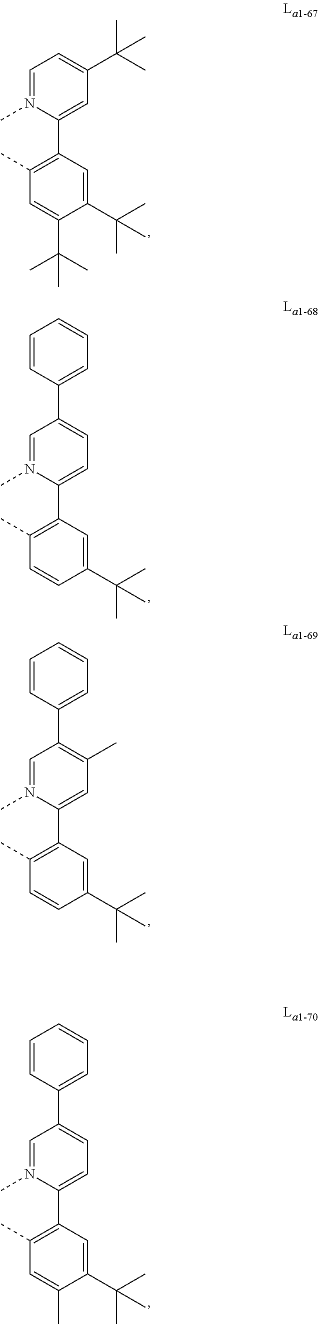 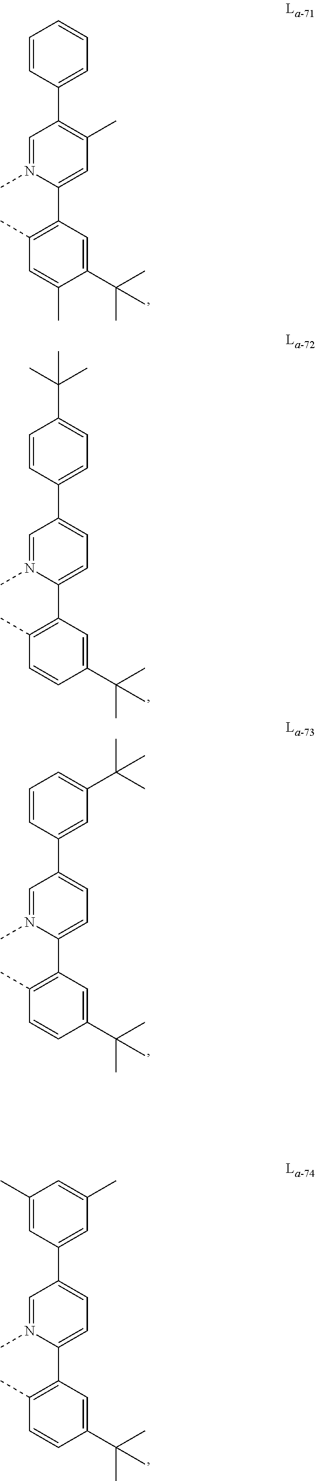 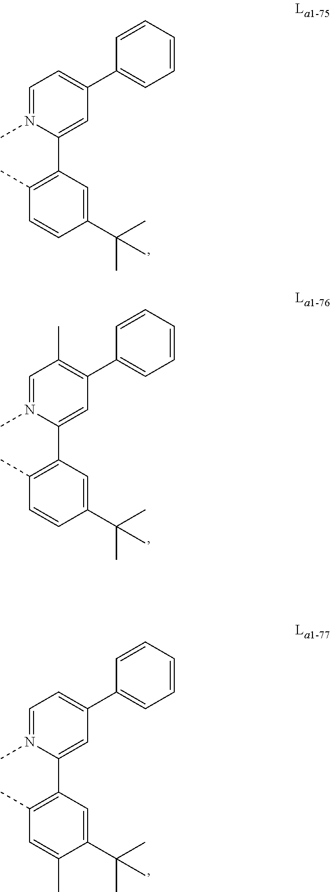 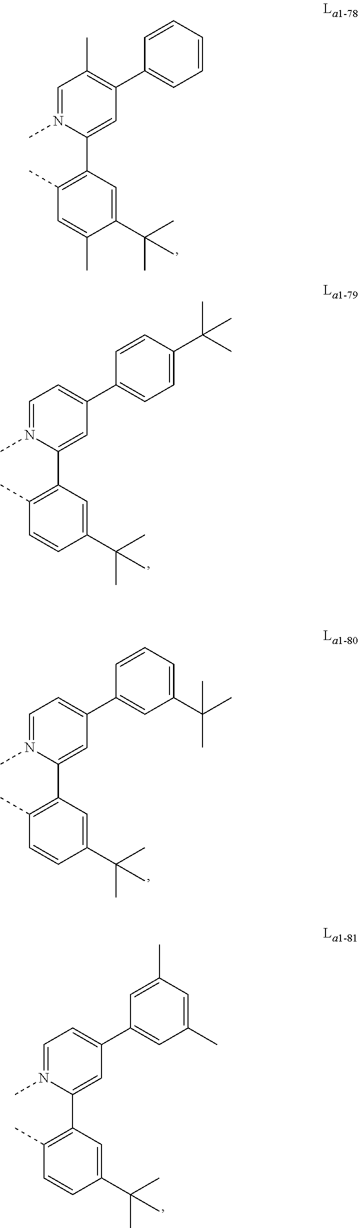 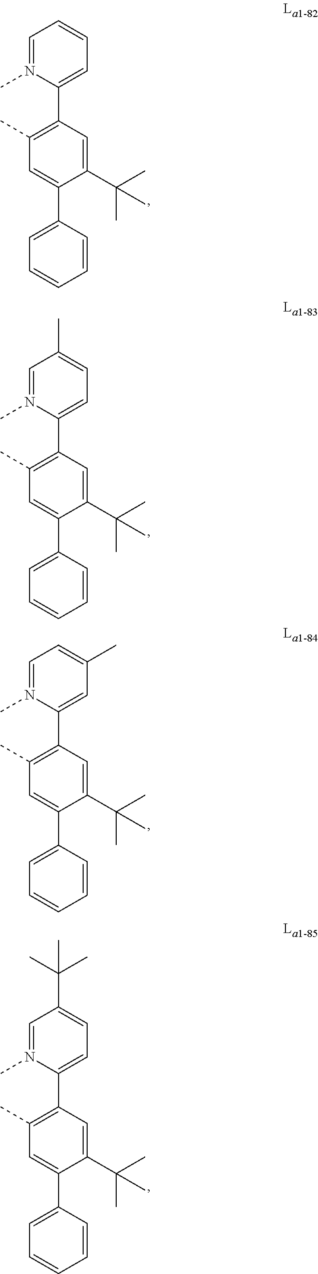 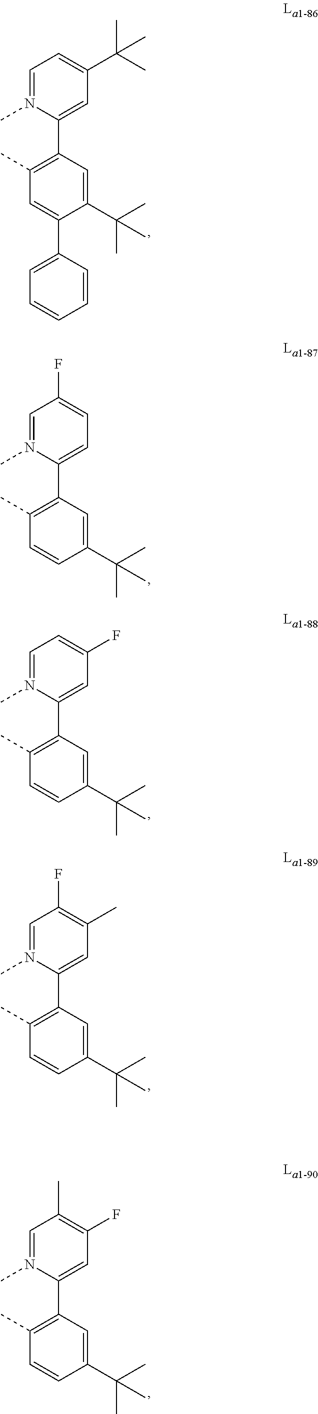 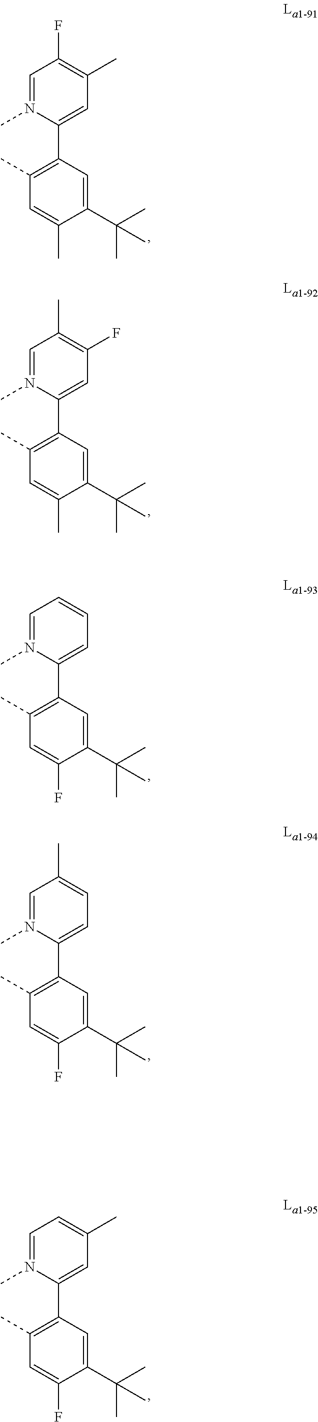 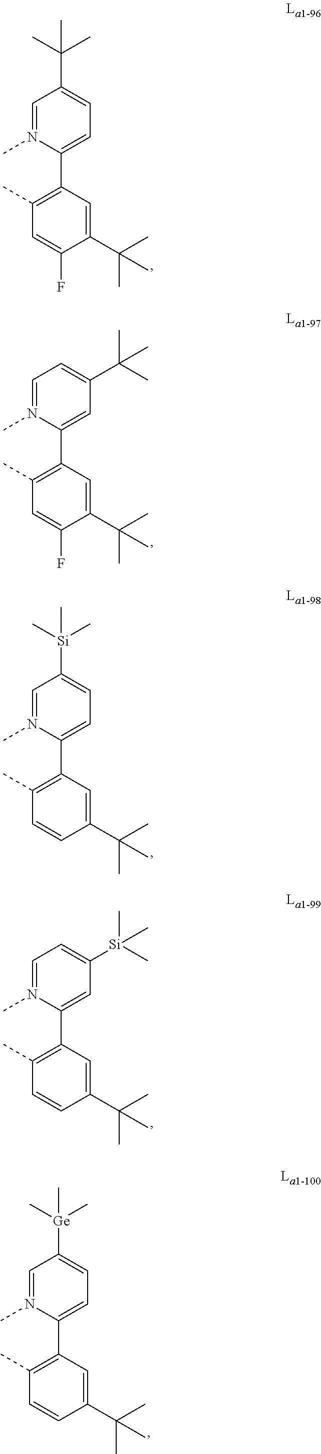 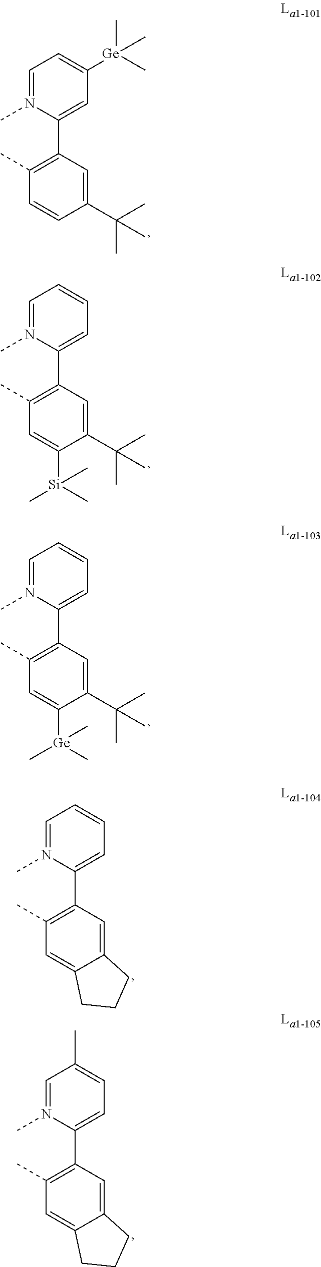 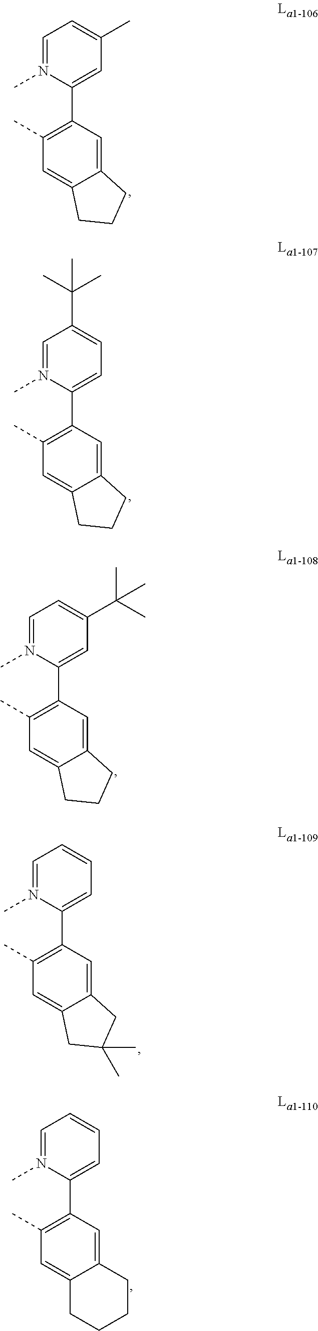 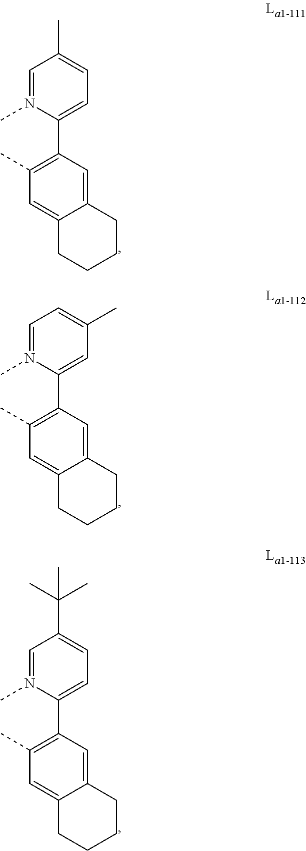 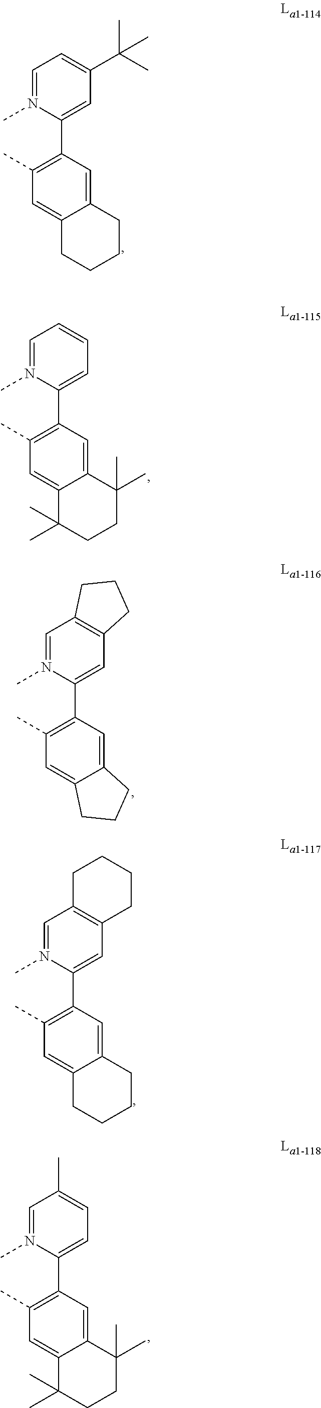 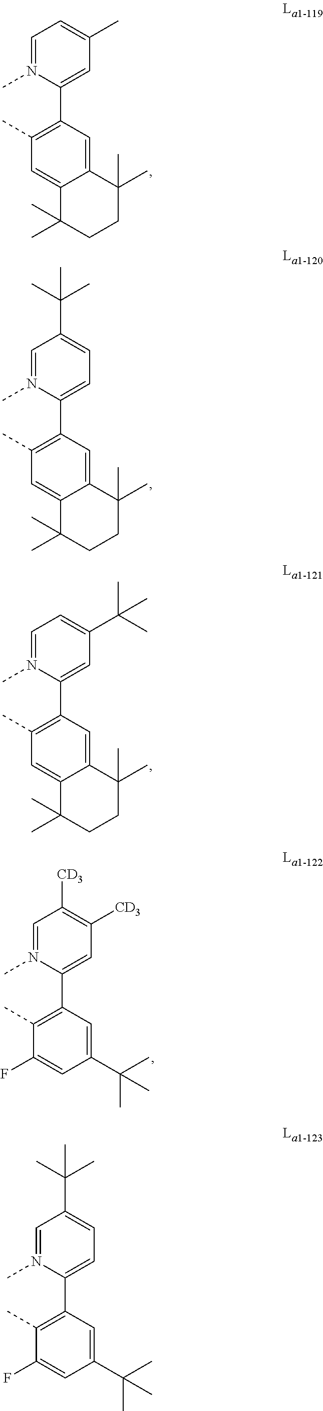 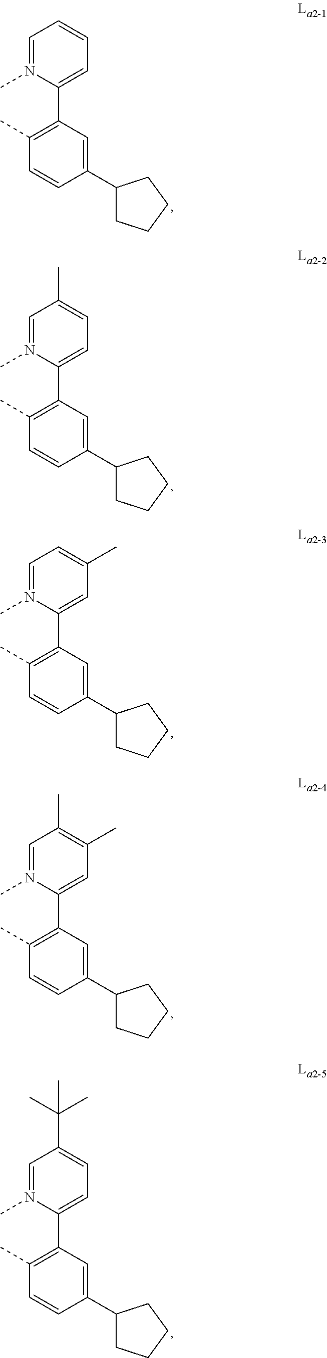 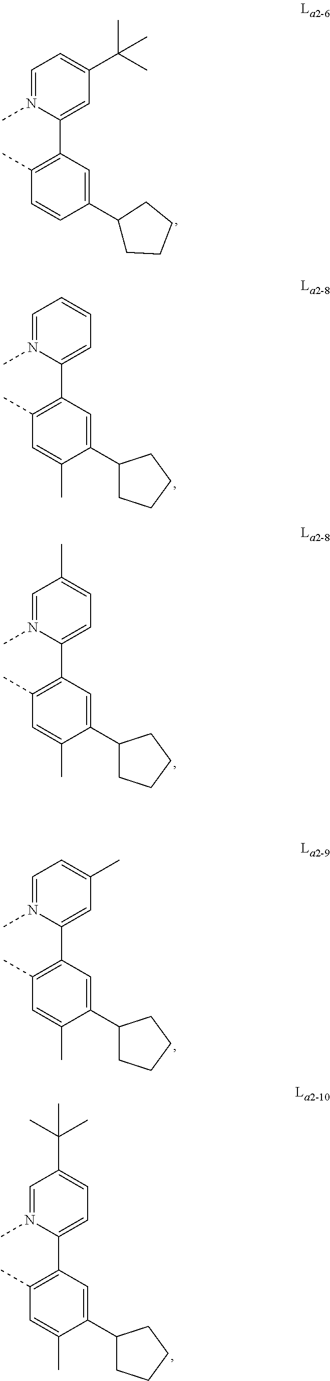 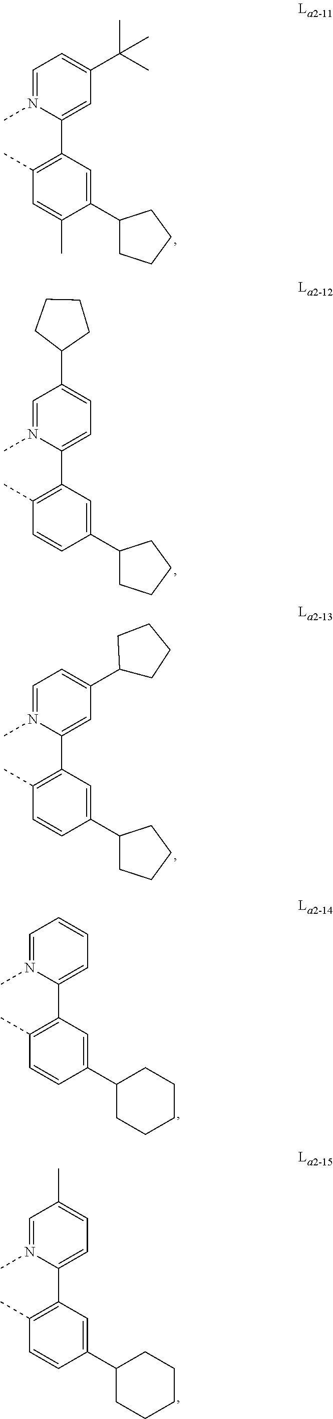 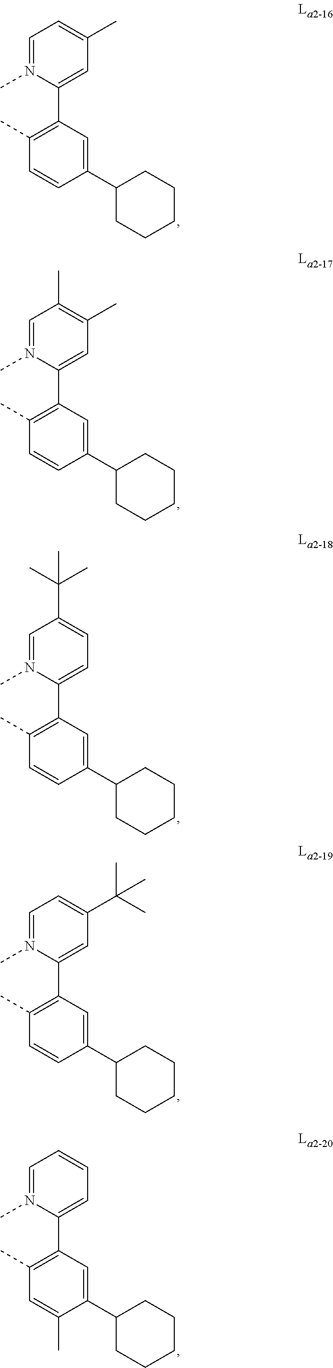 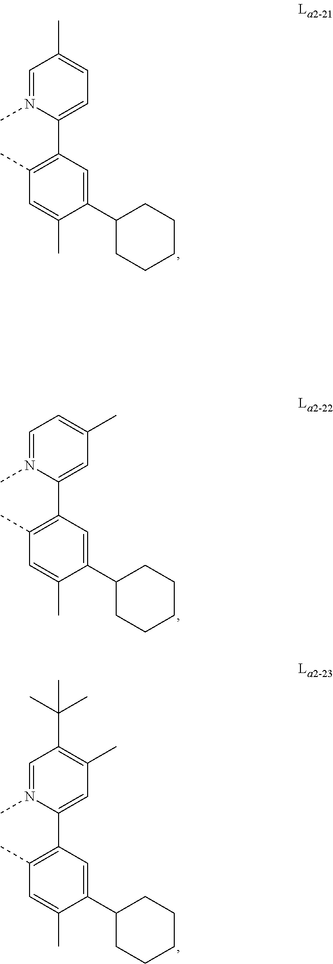 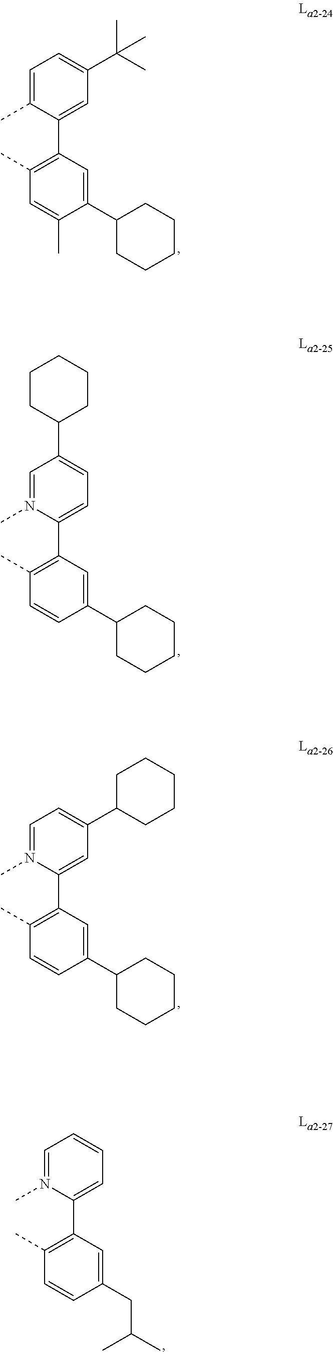 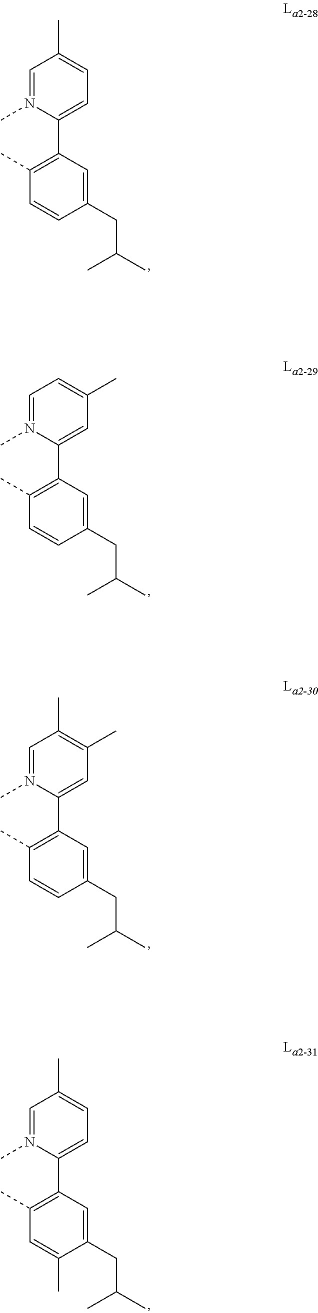 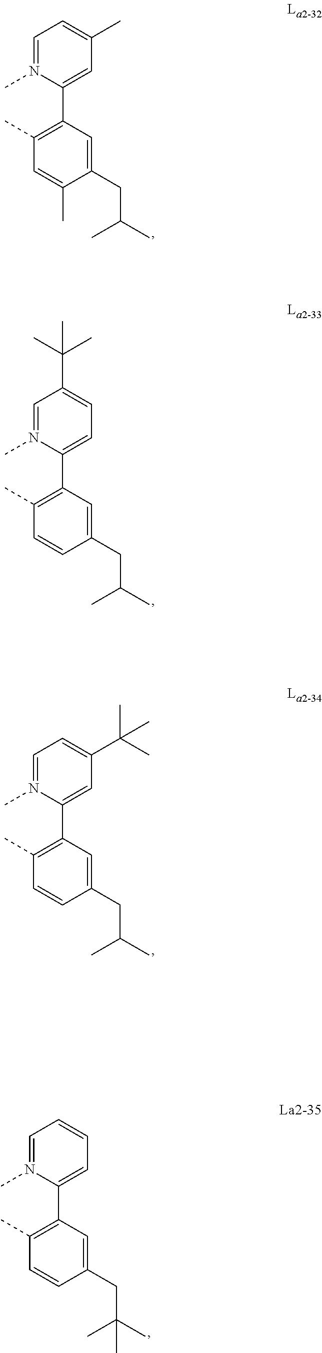 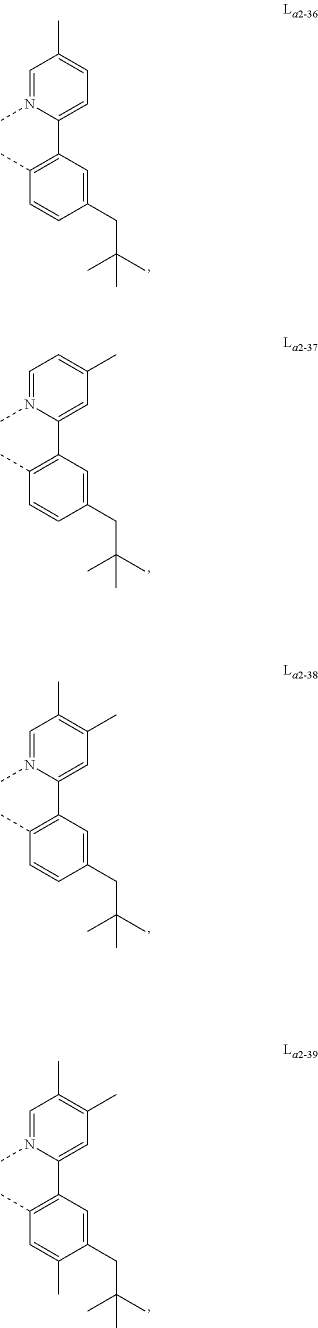 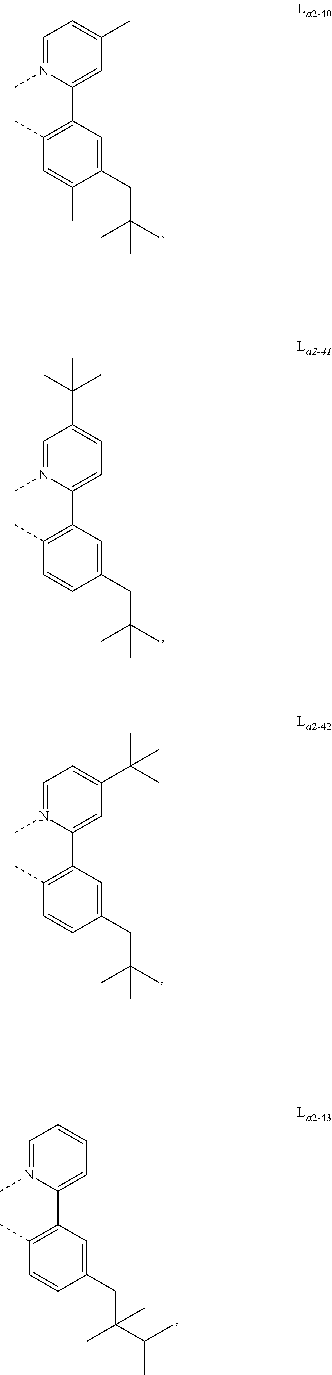 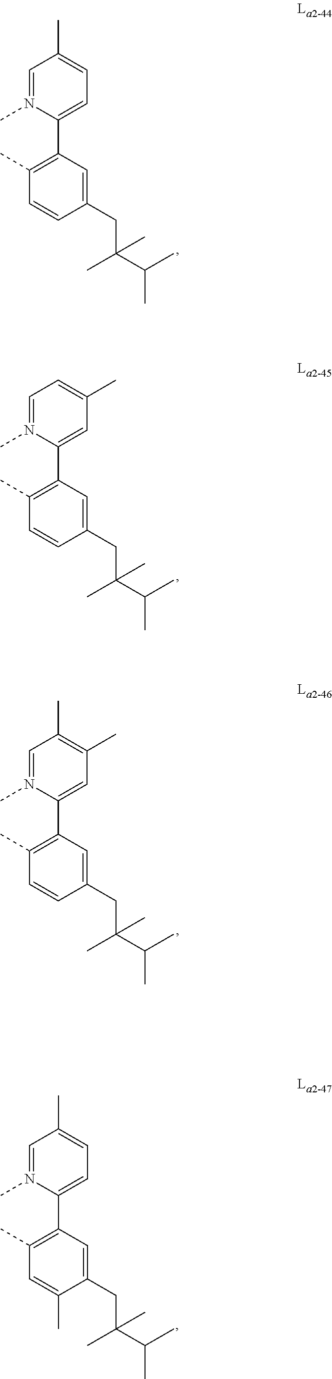 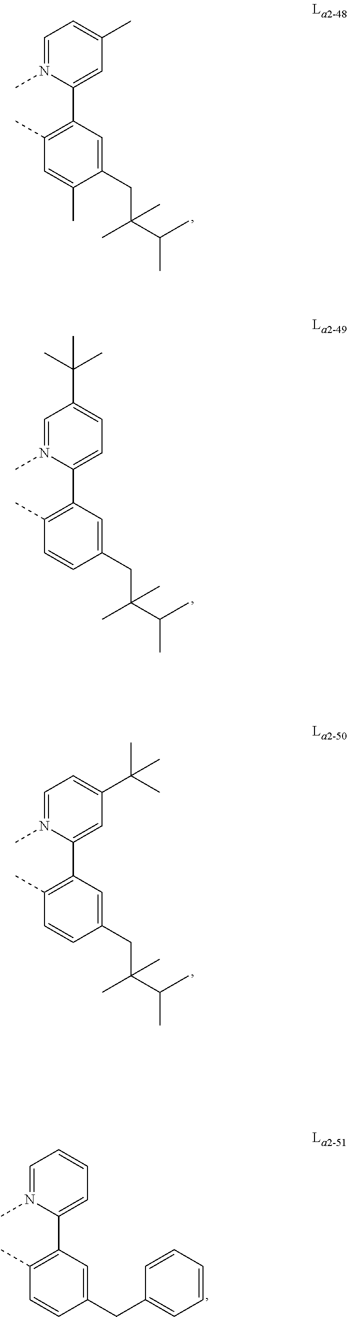 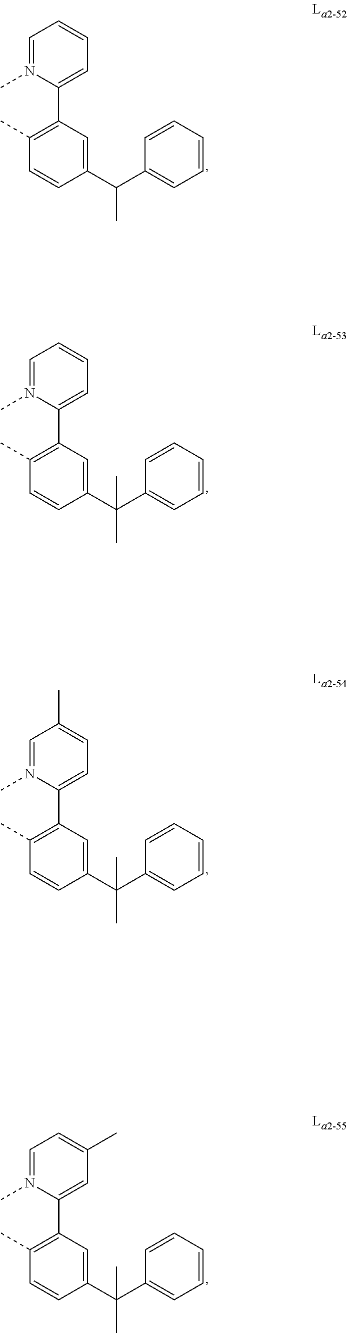 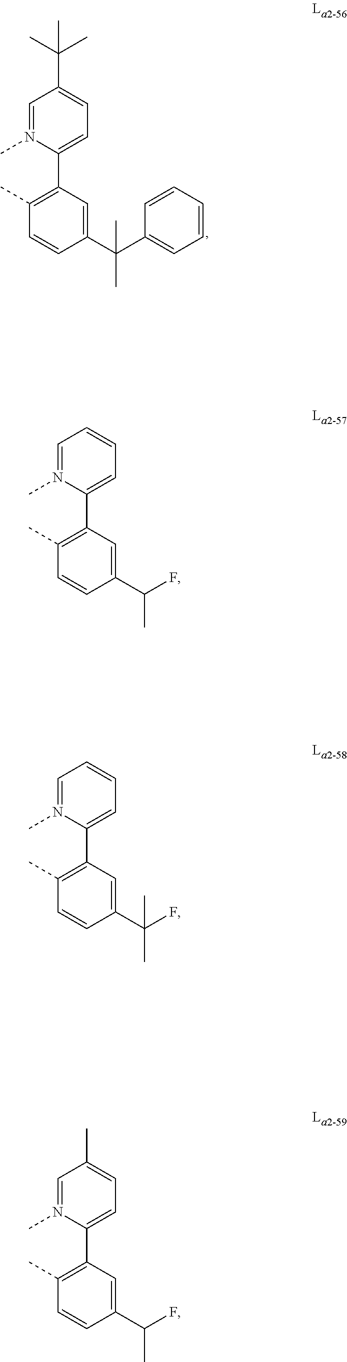 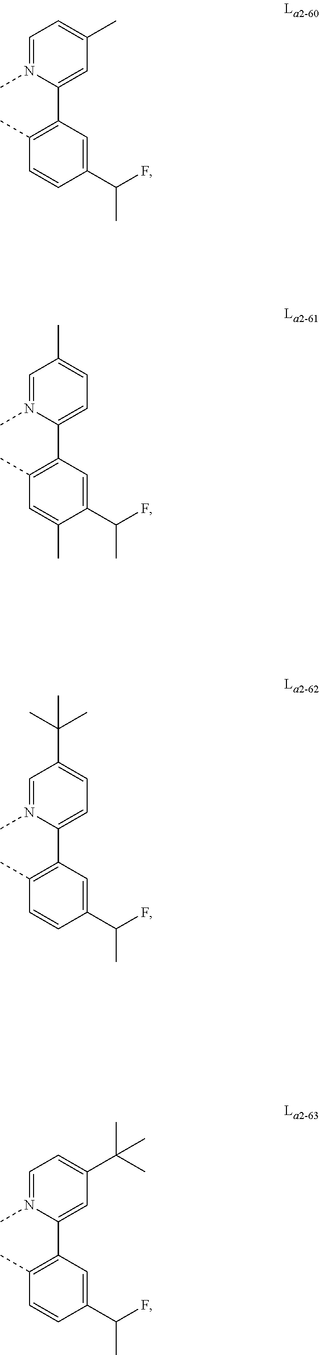 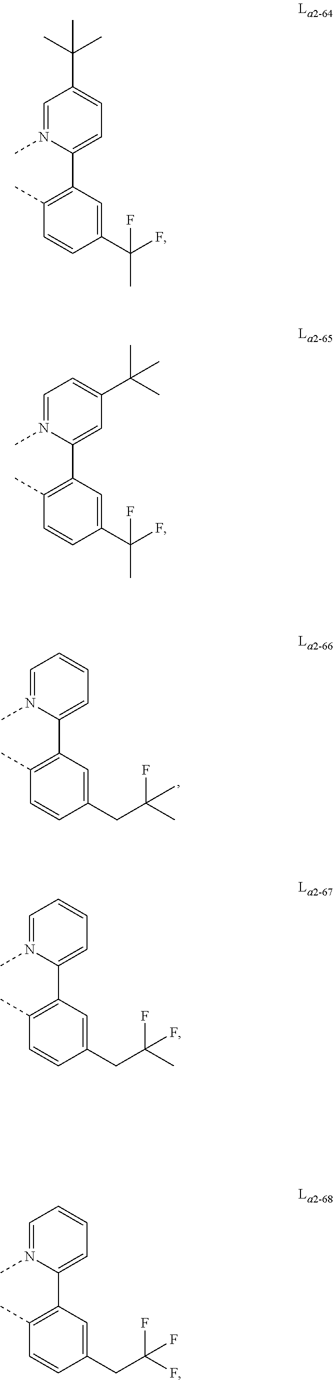 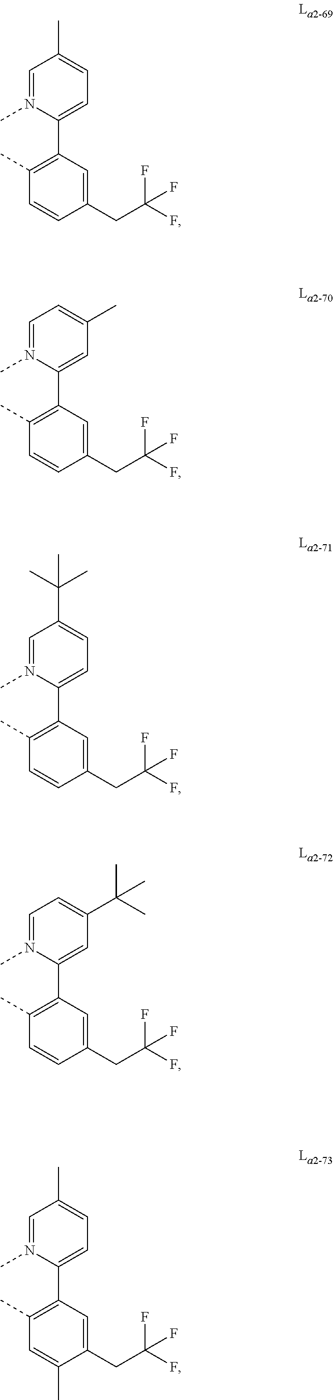 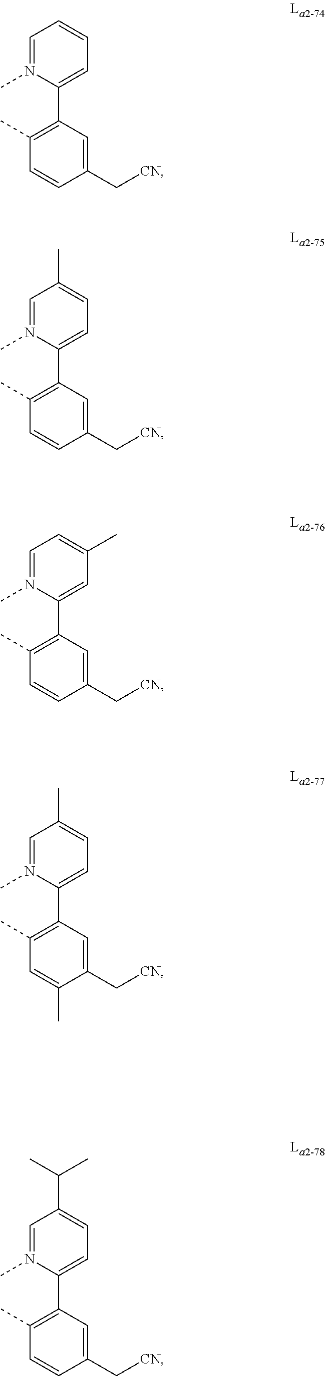 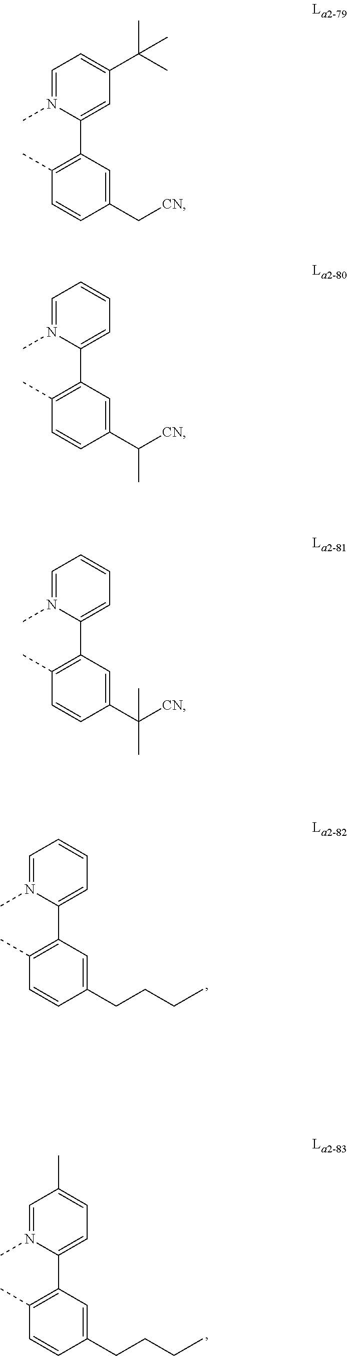 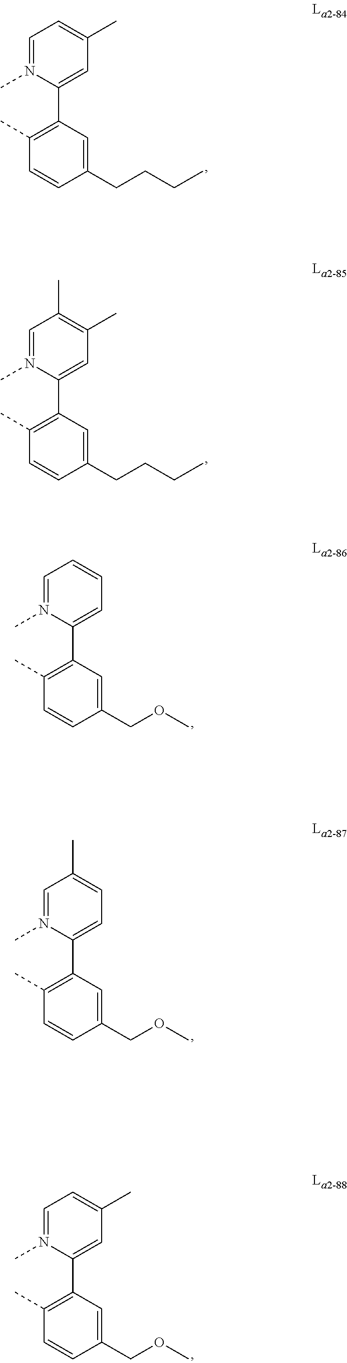 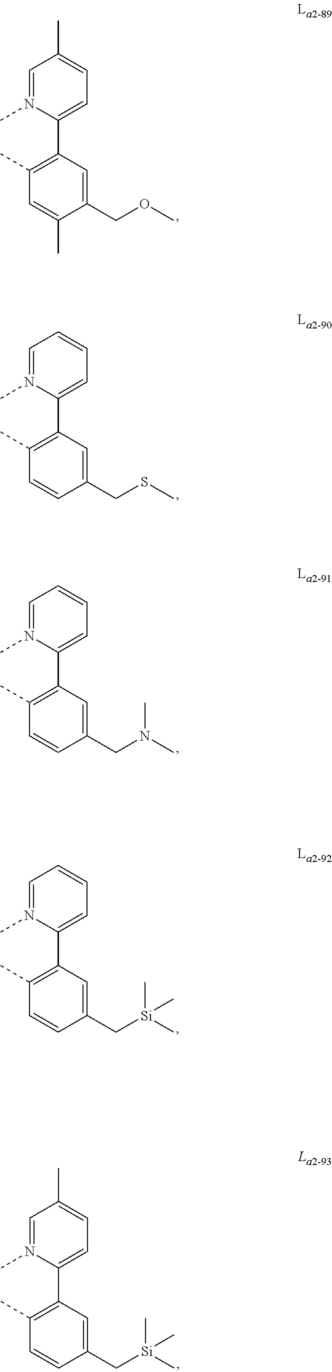 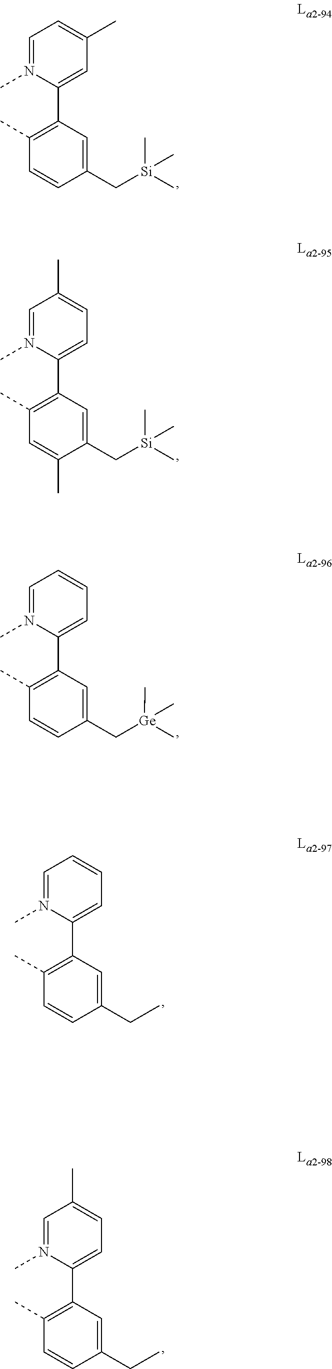 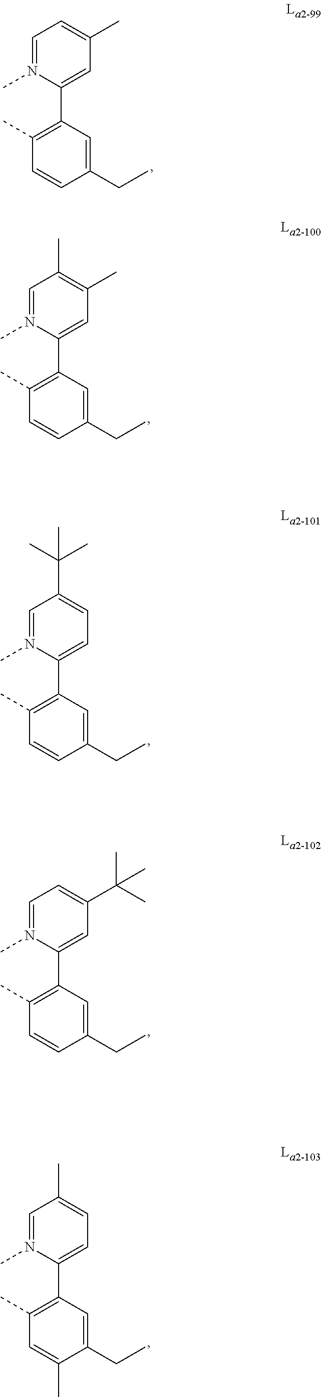 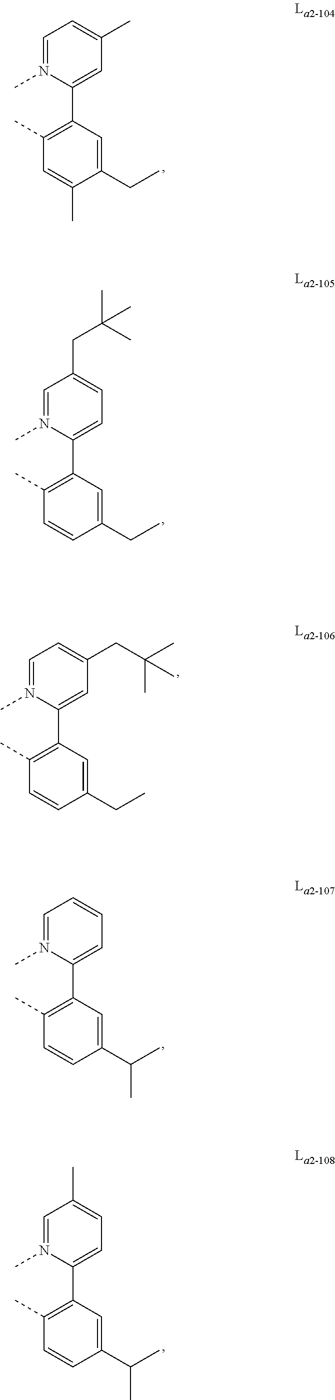 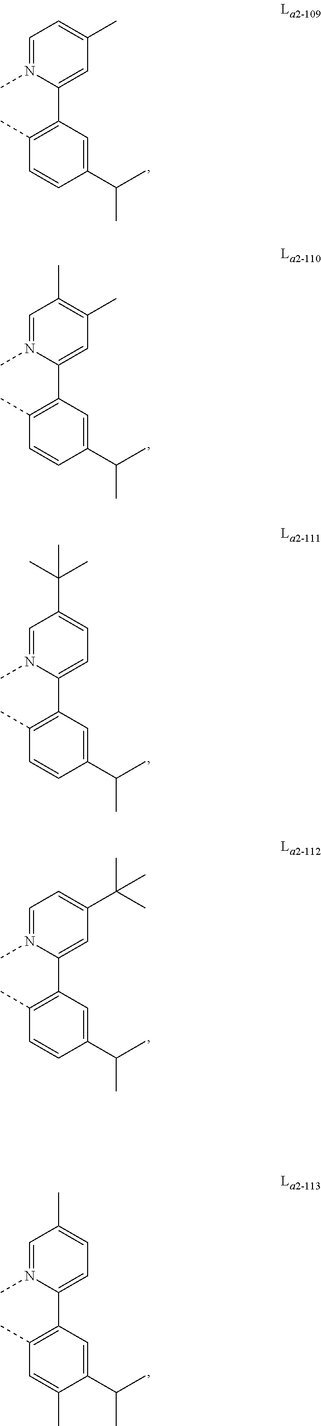 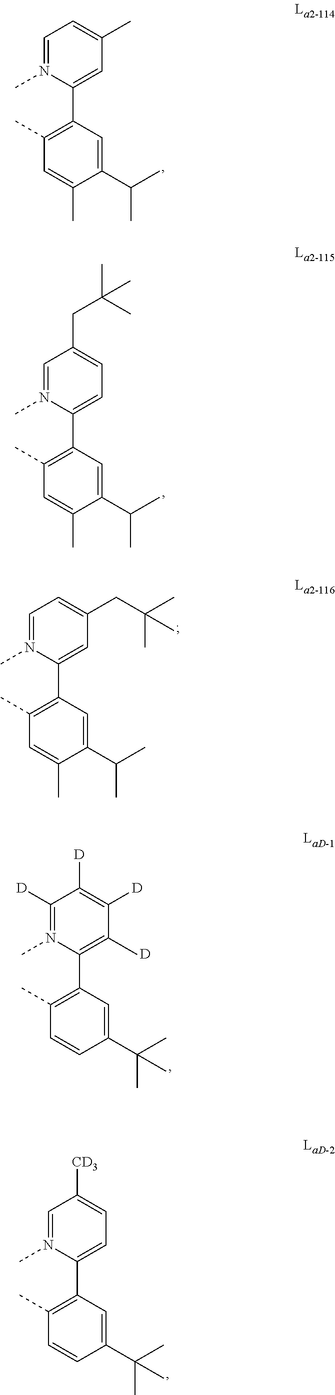 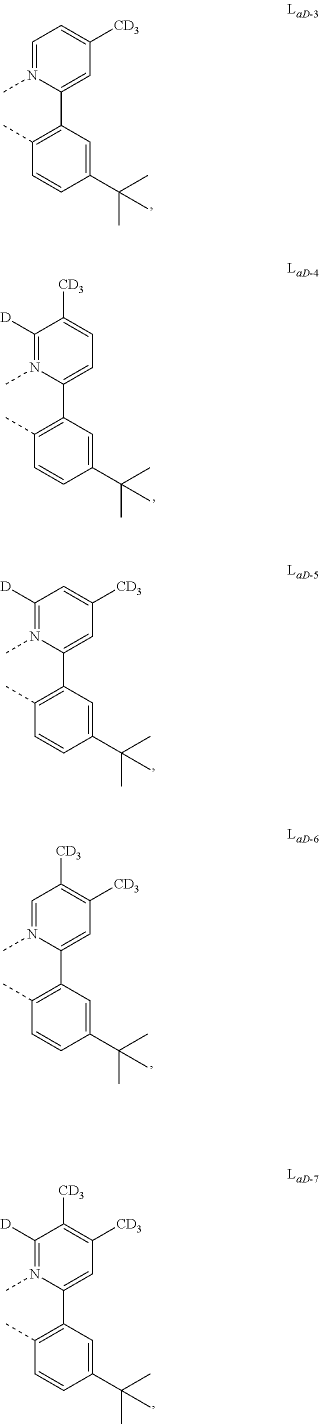 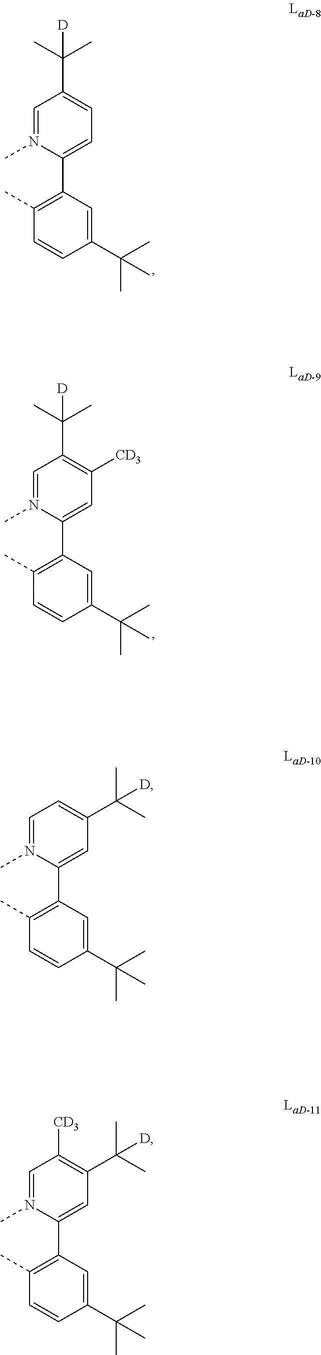 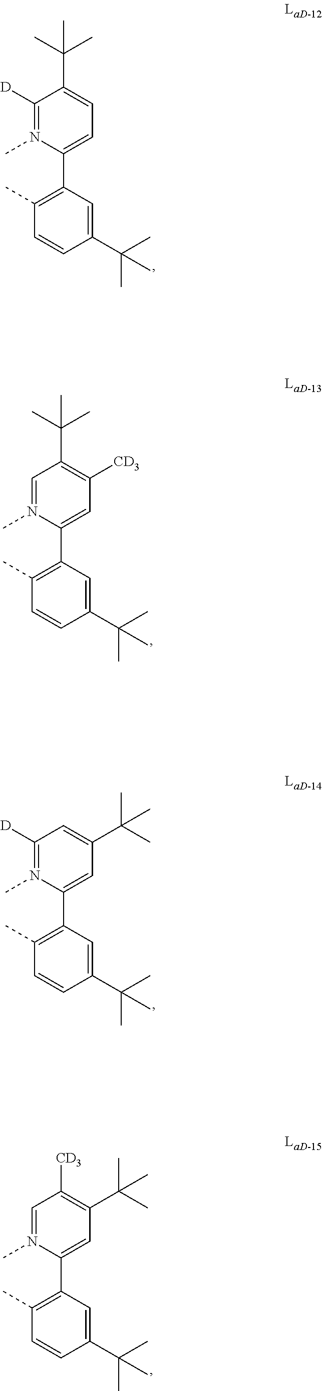 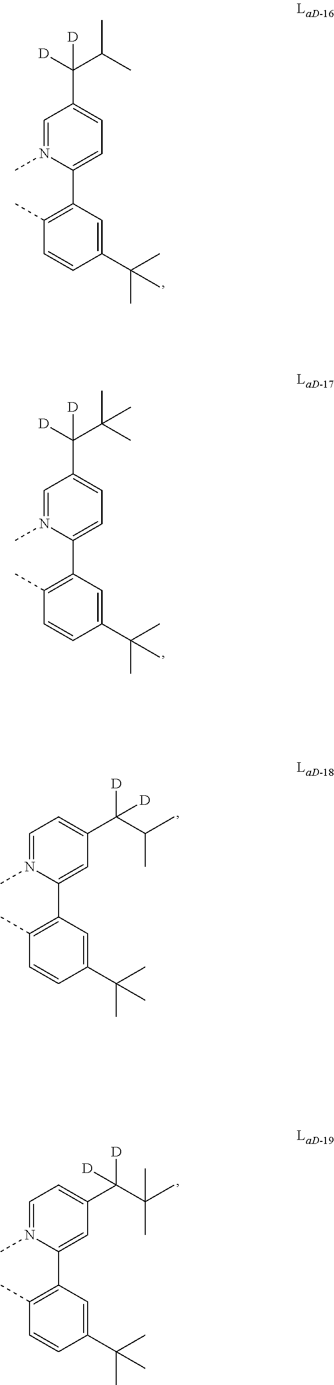 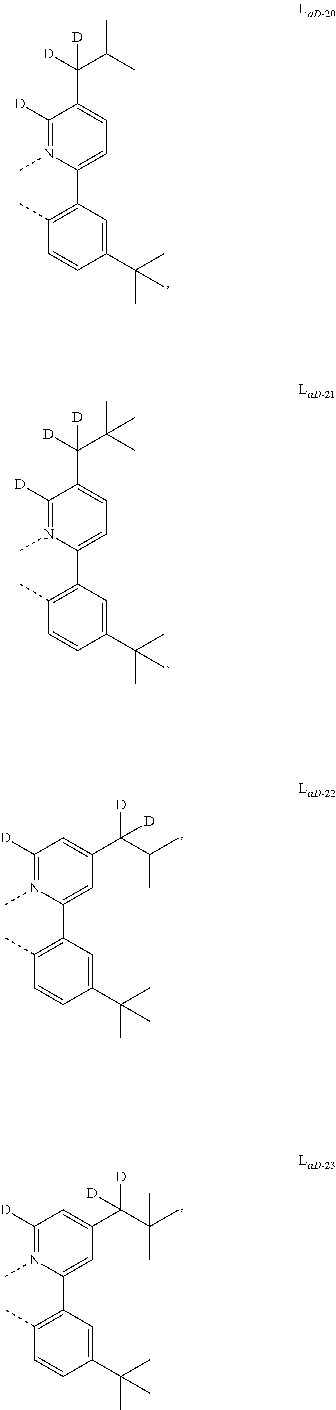 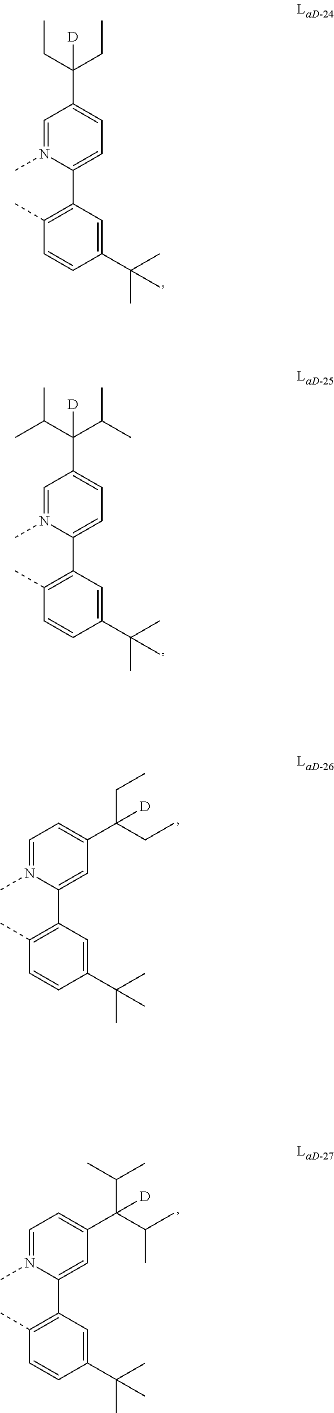 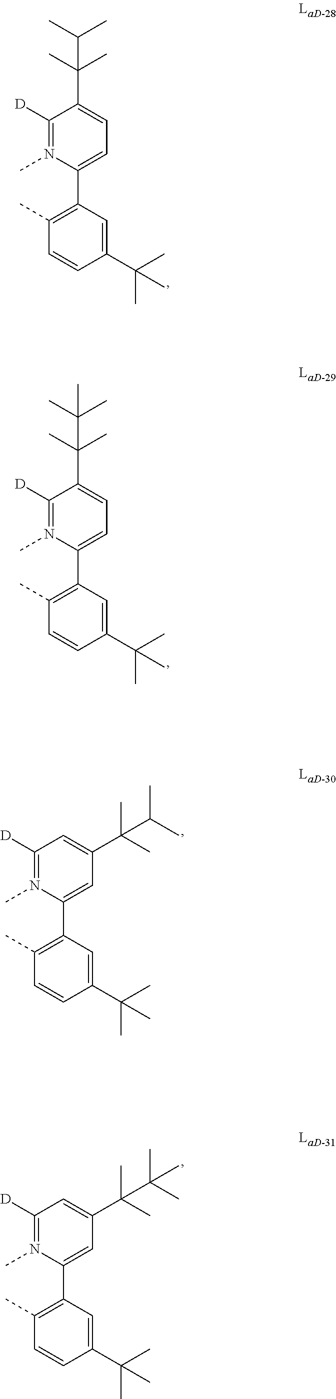 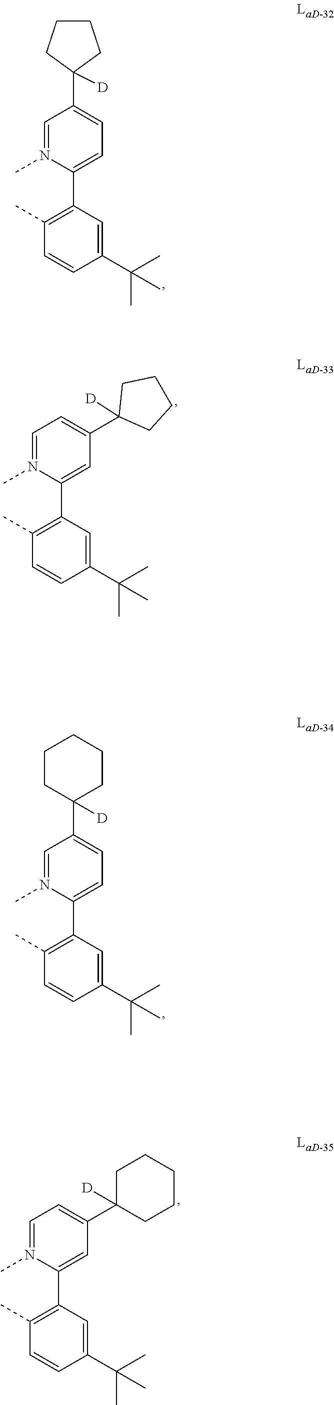 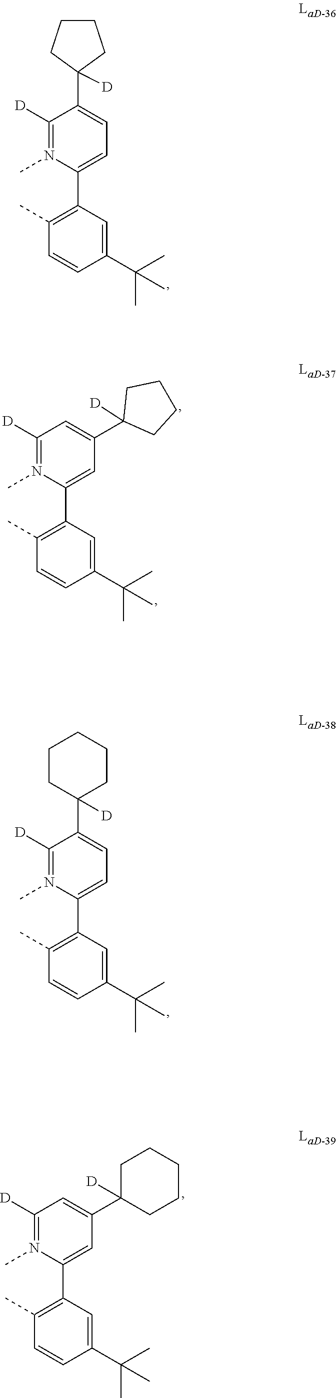 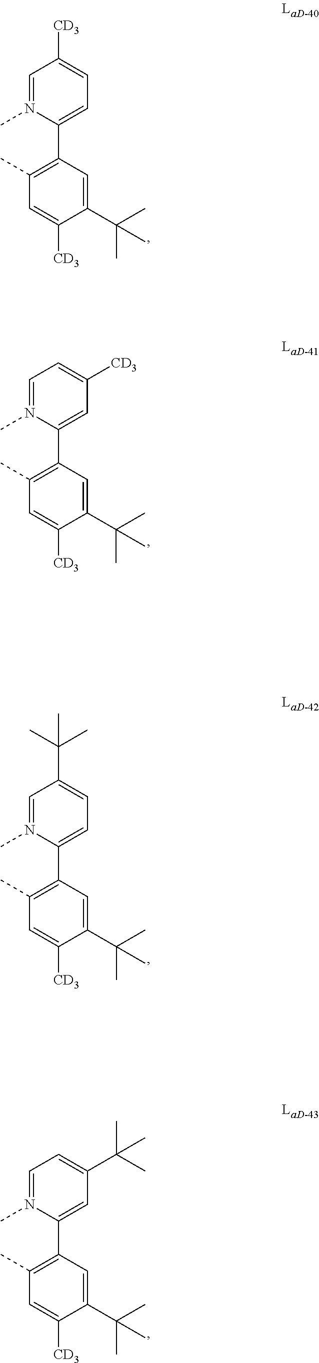 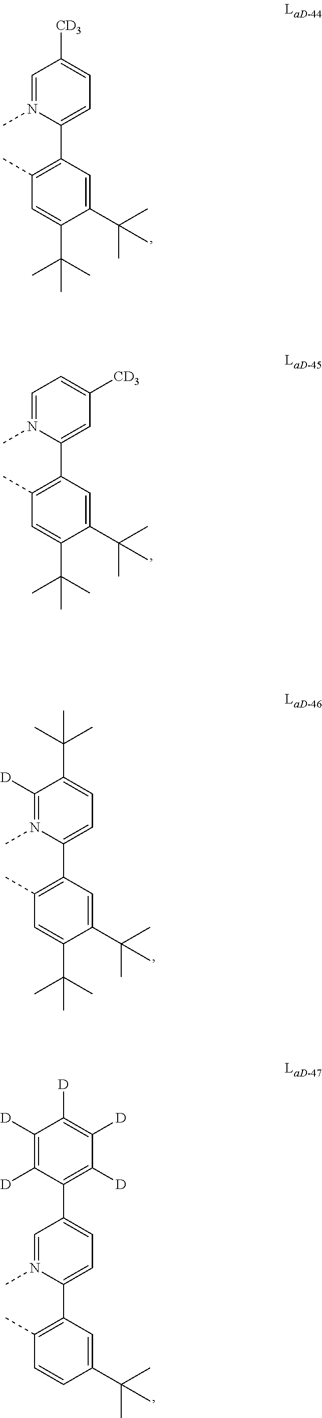 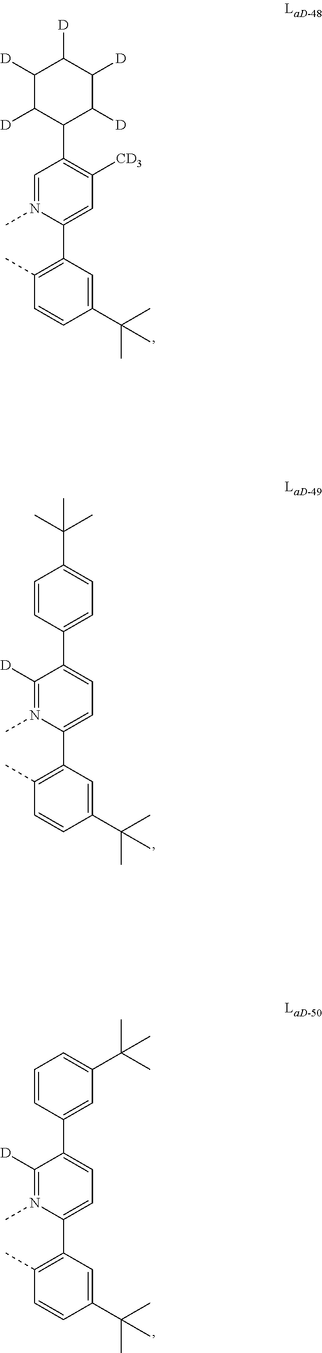 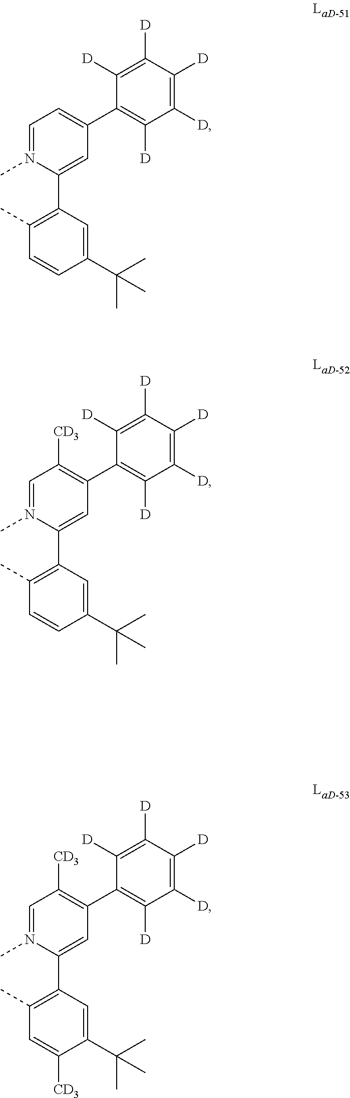 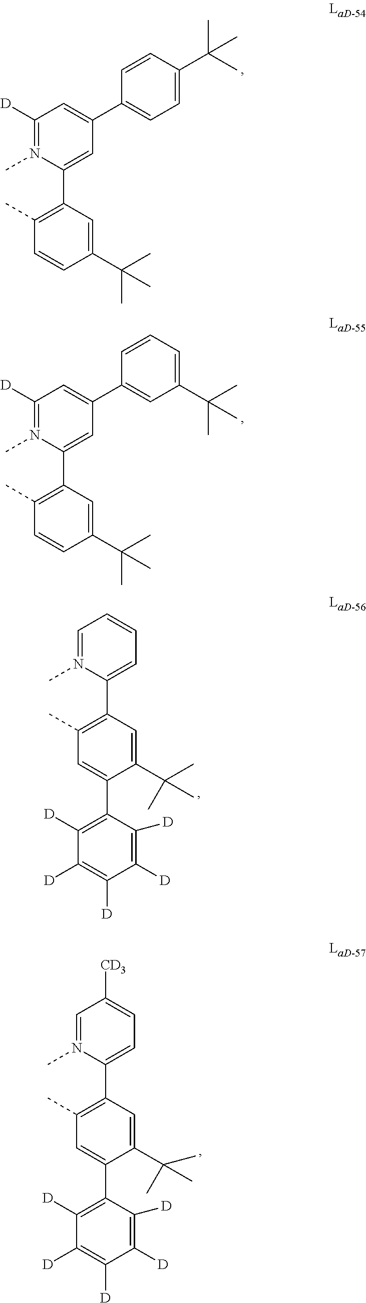 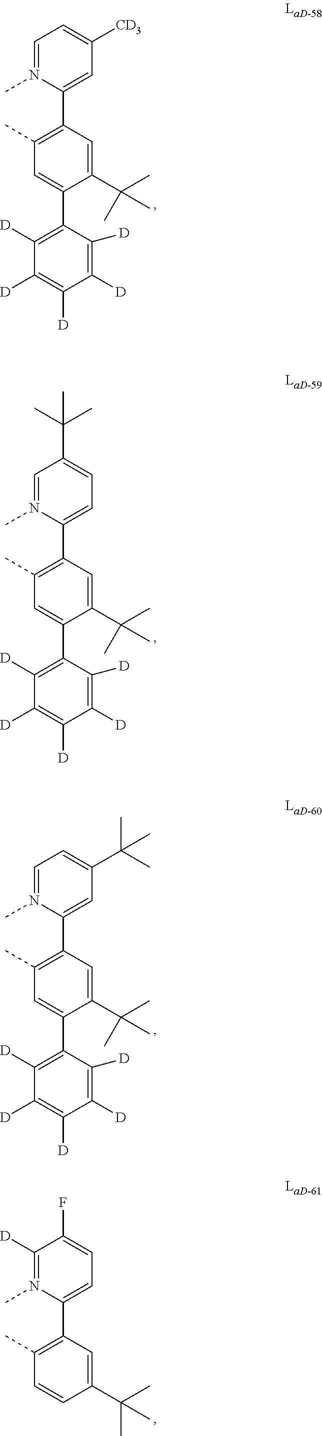 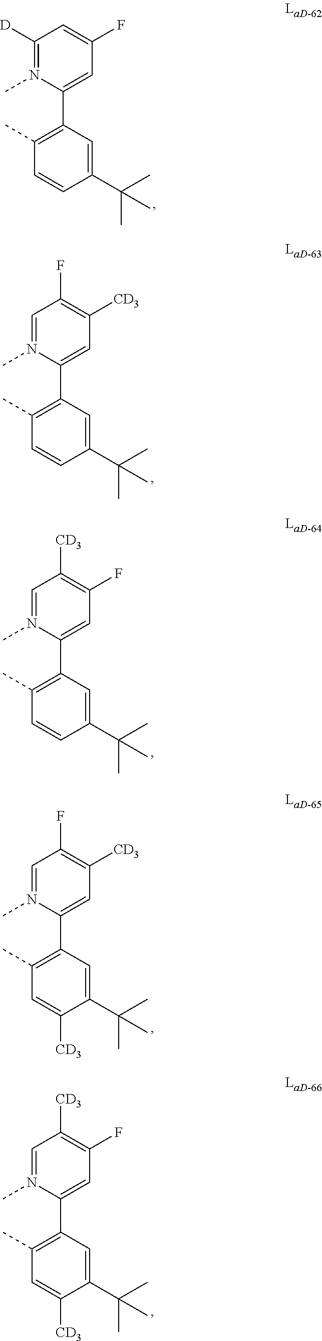 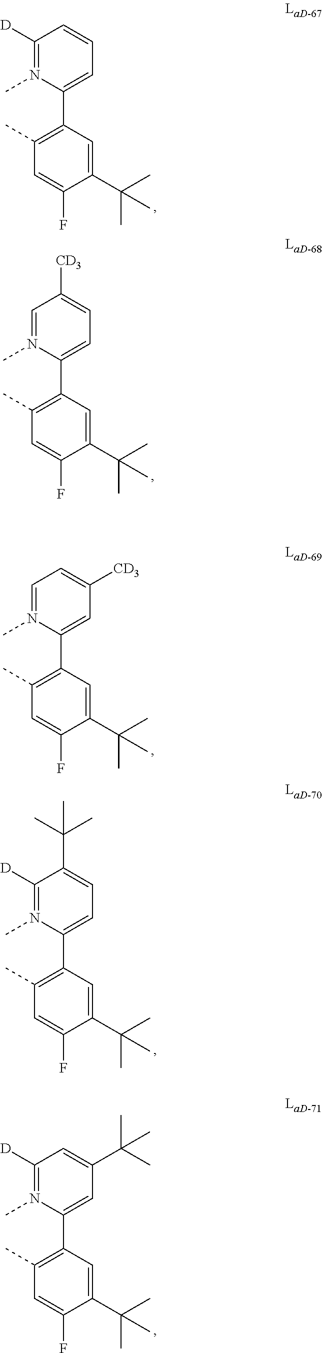 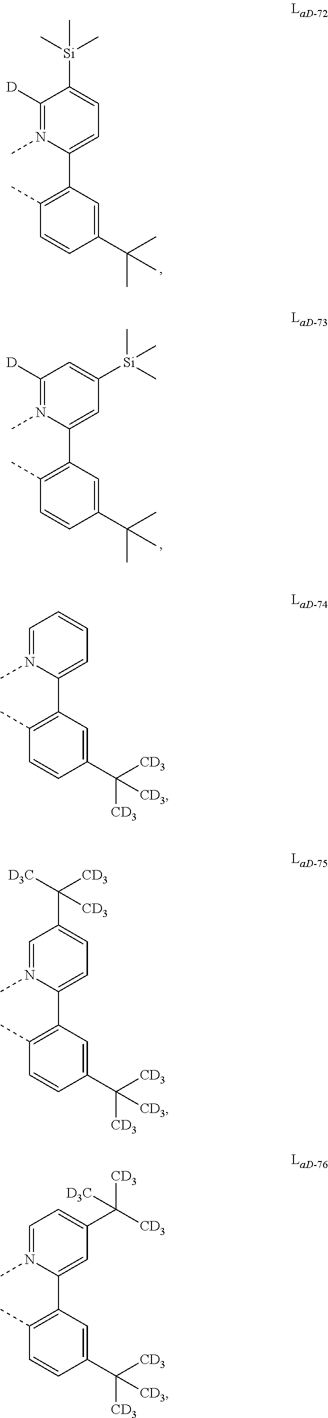 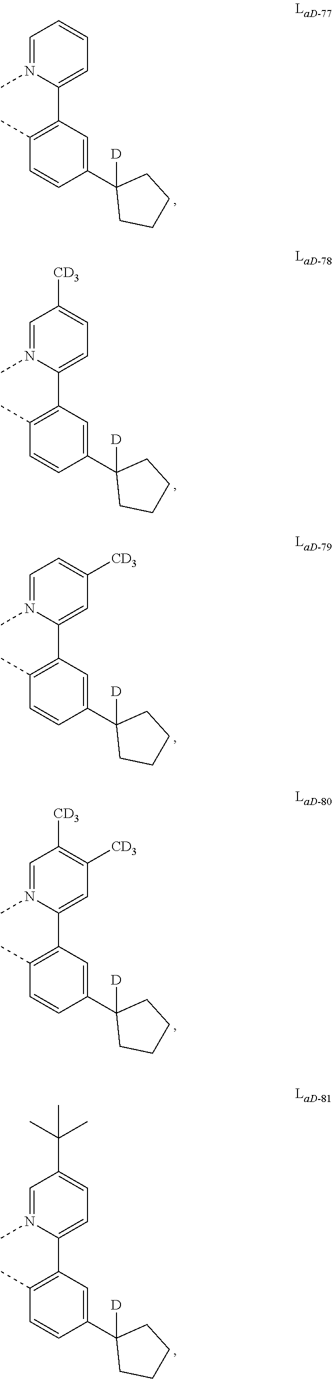 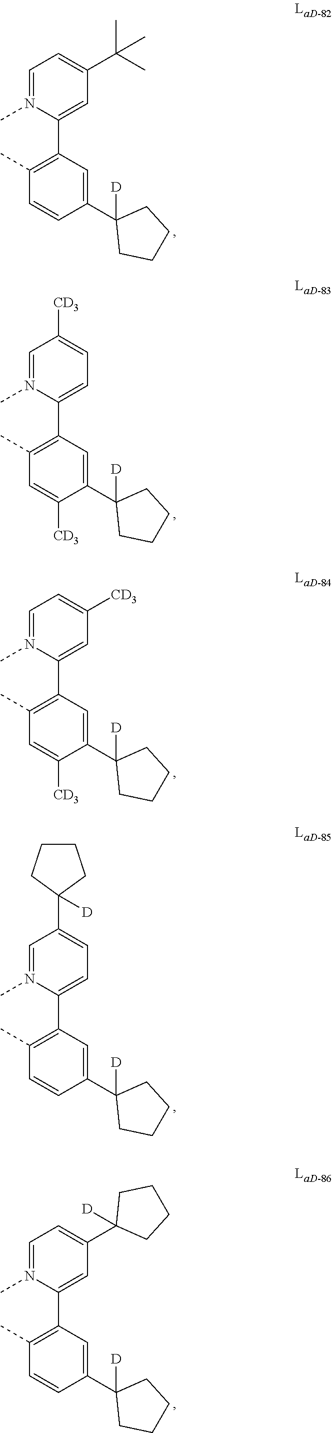 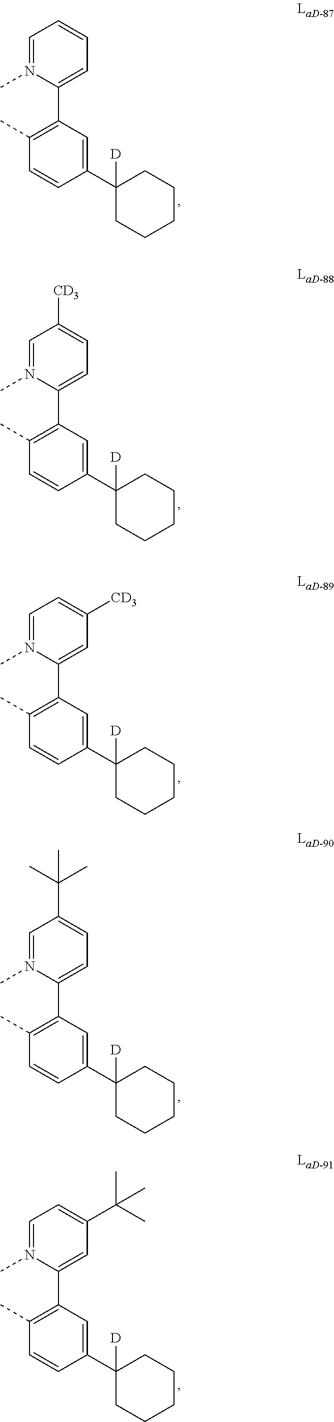 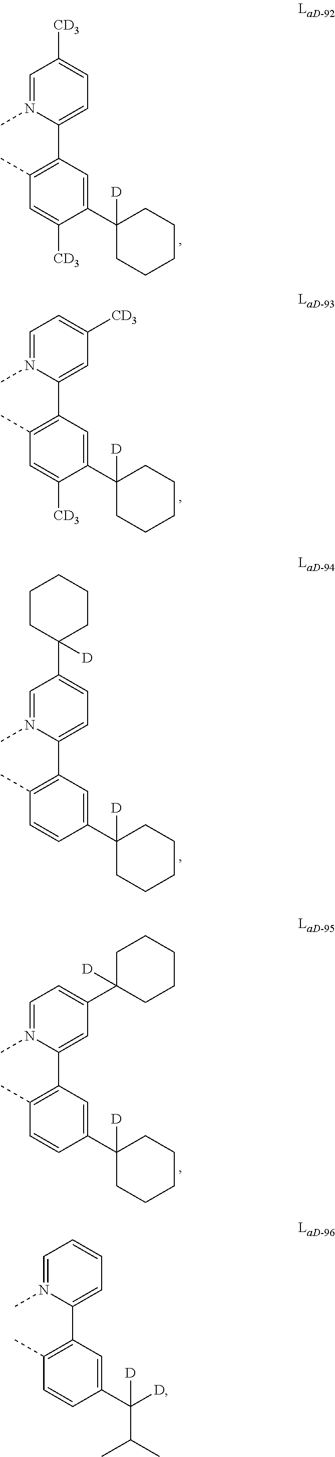 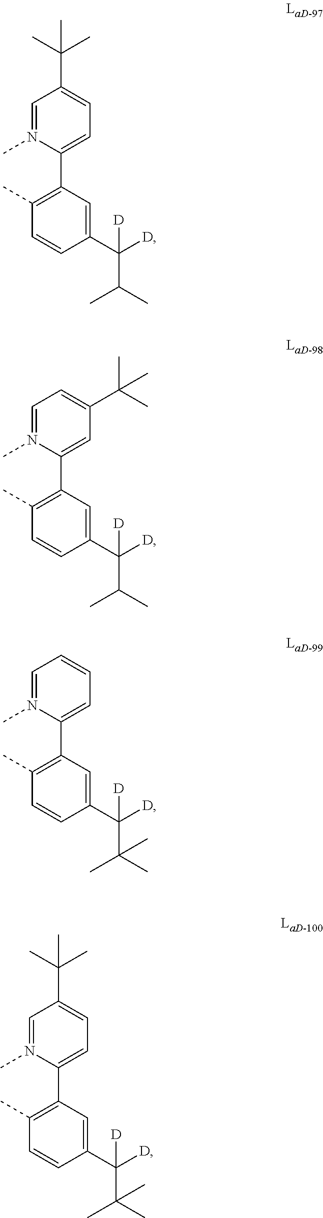 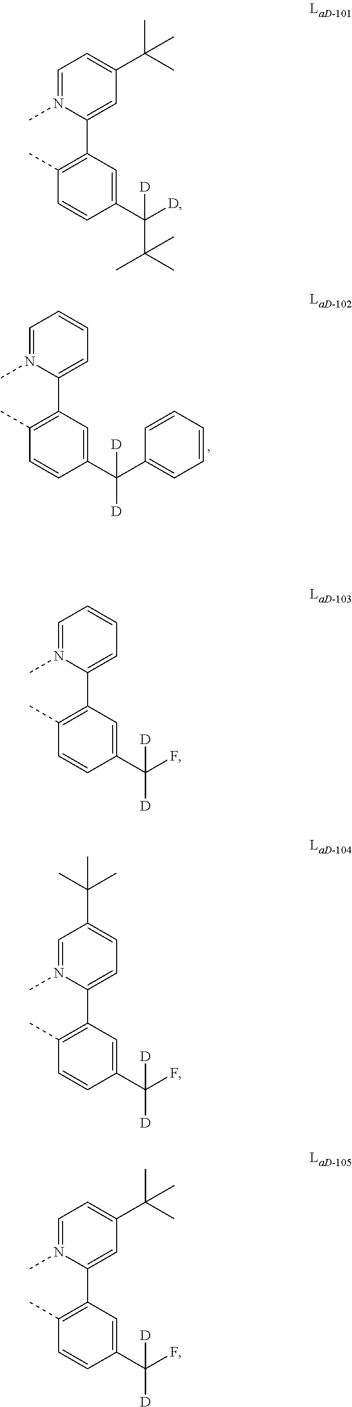 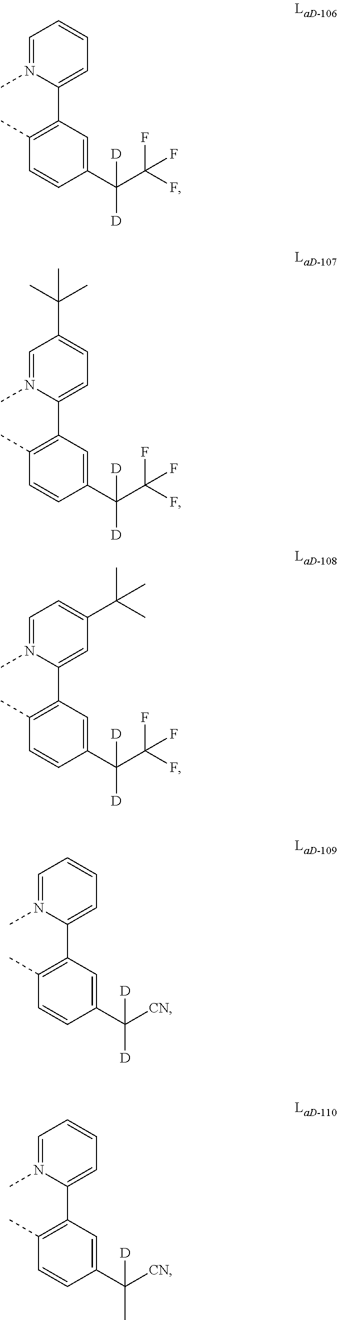 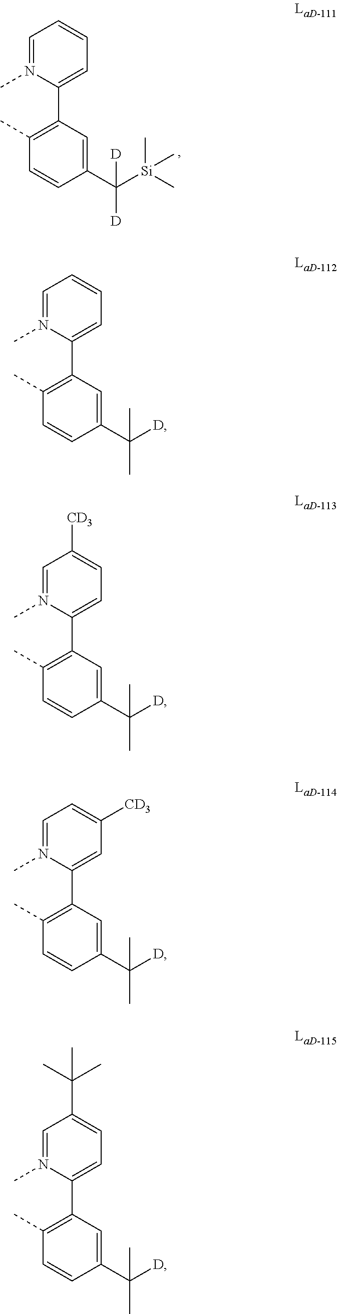 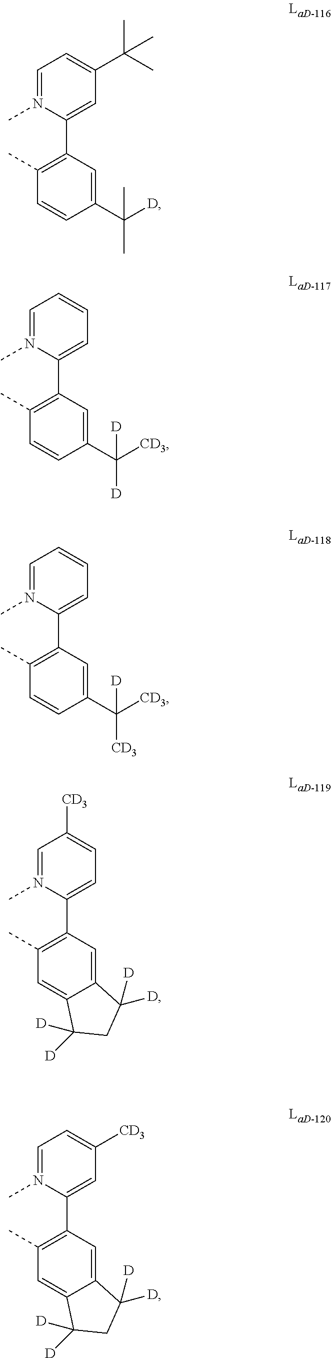 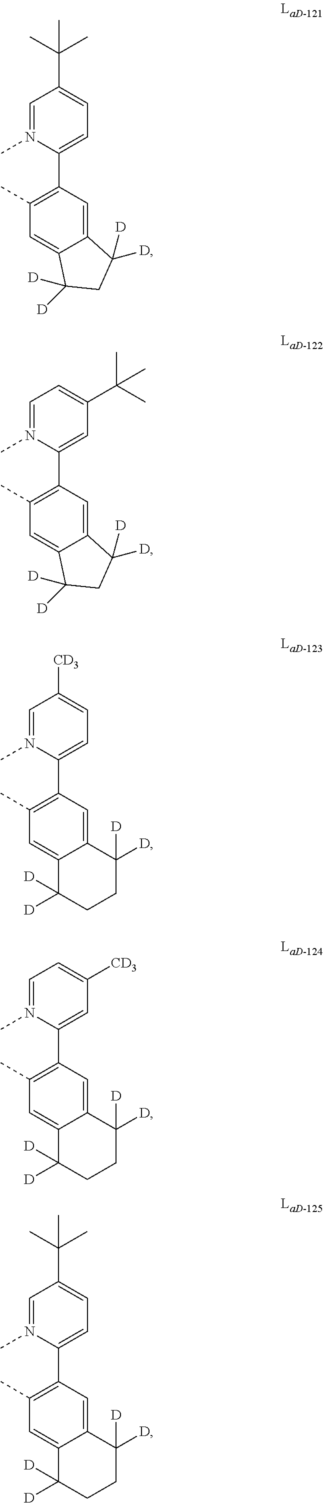 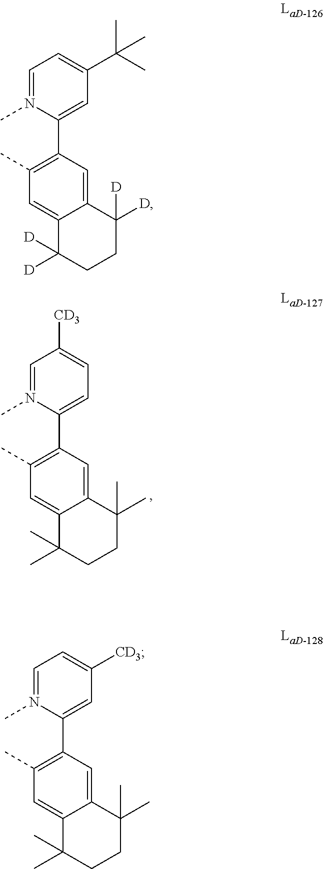
wherein optionally, hydrogen in Lₐ₁₋₁ to Lₐ₁₋₁₂₃, Lₐ₂₋₁ to Lₐ₂₋₁₁₆ and L_{aD-1} to L_{aD-128} can be partially or fully substituted with deuterium.

18. The metal complex according to claim 1, wherein L_{b} is, at each occurrence identically or differently, selected from the group consisting of the following: 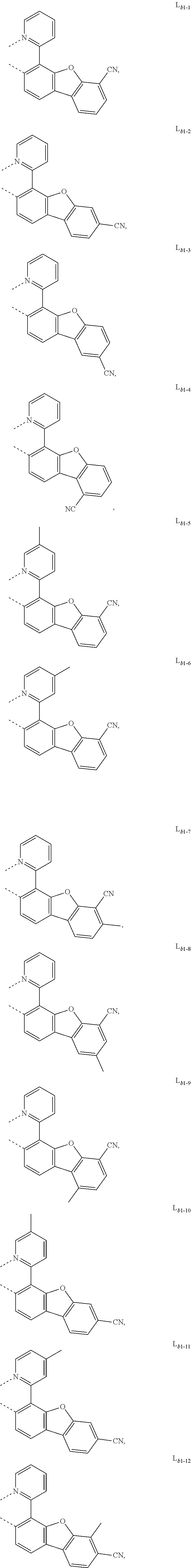 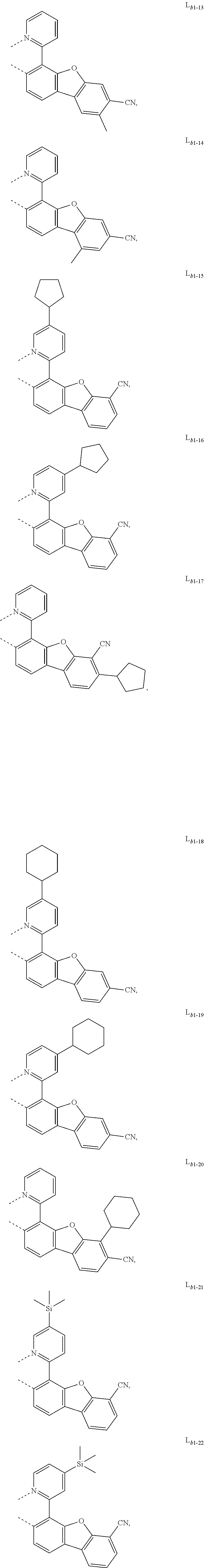 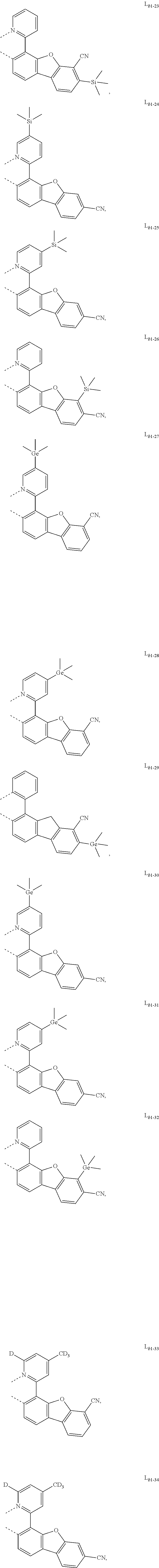 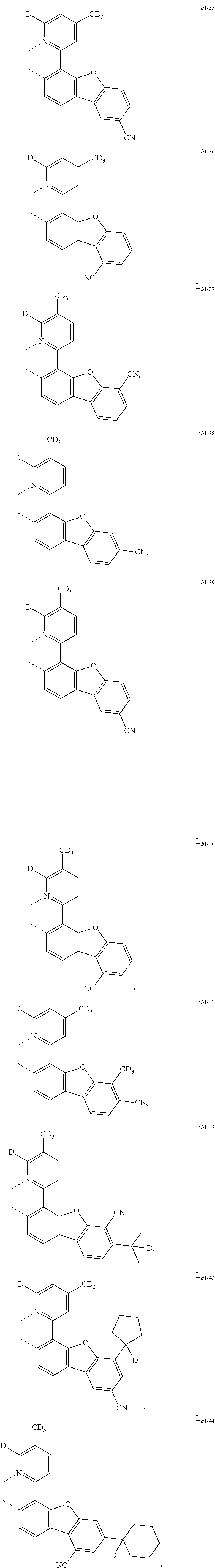 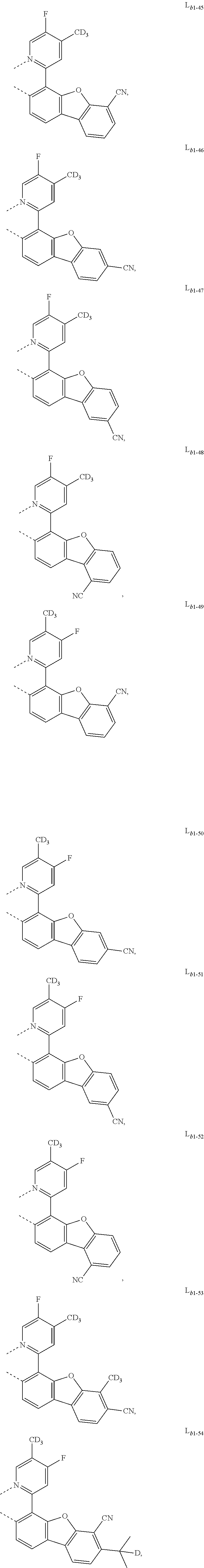 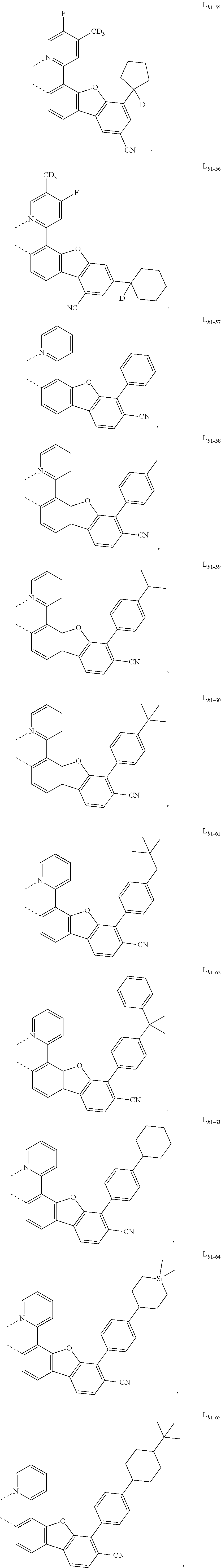 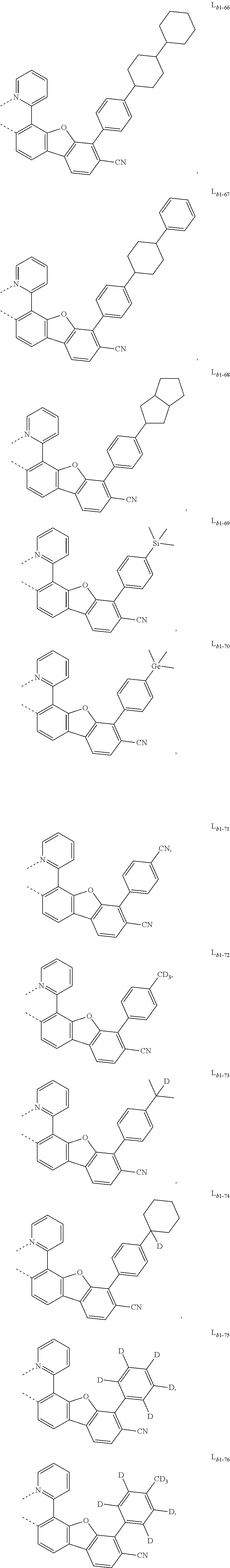 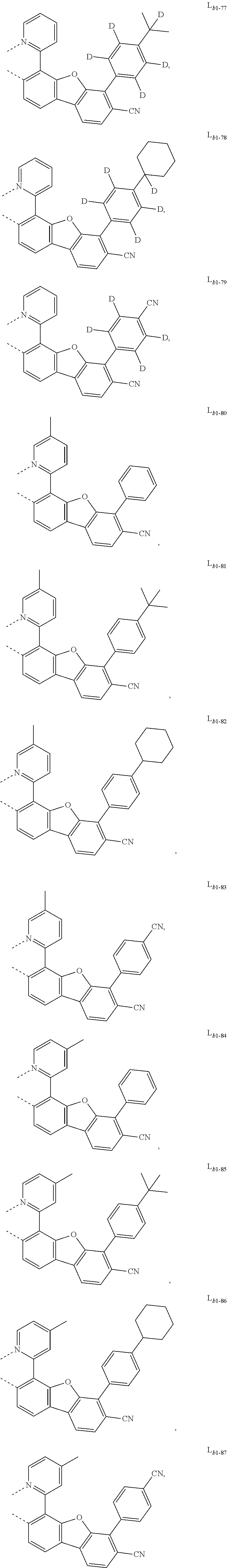 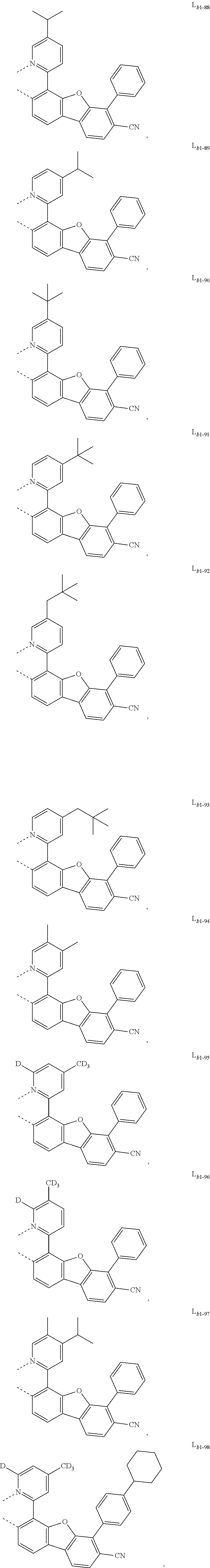 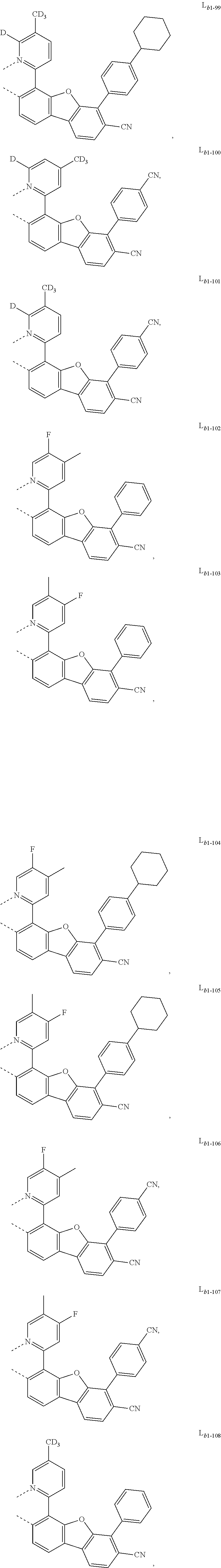 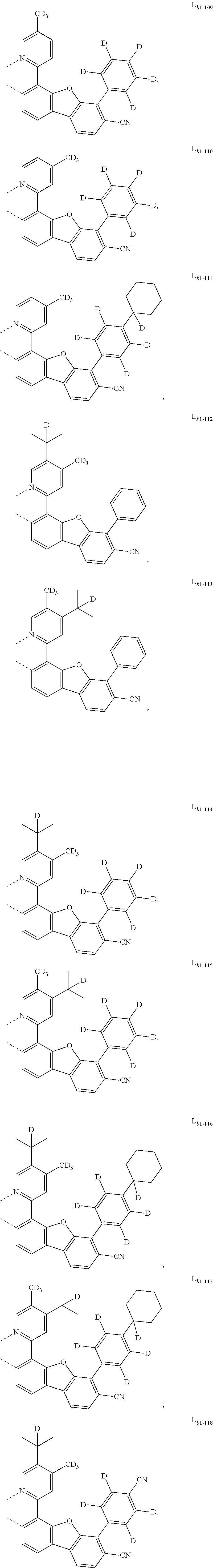 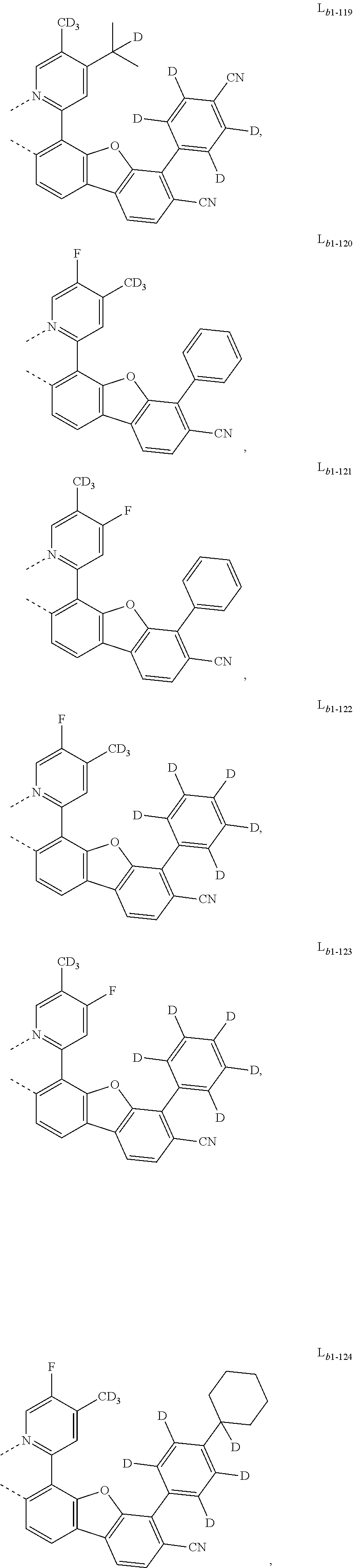 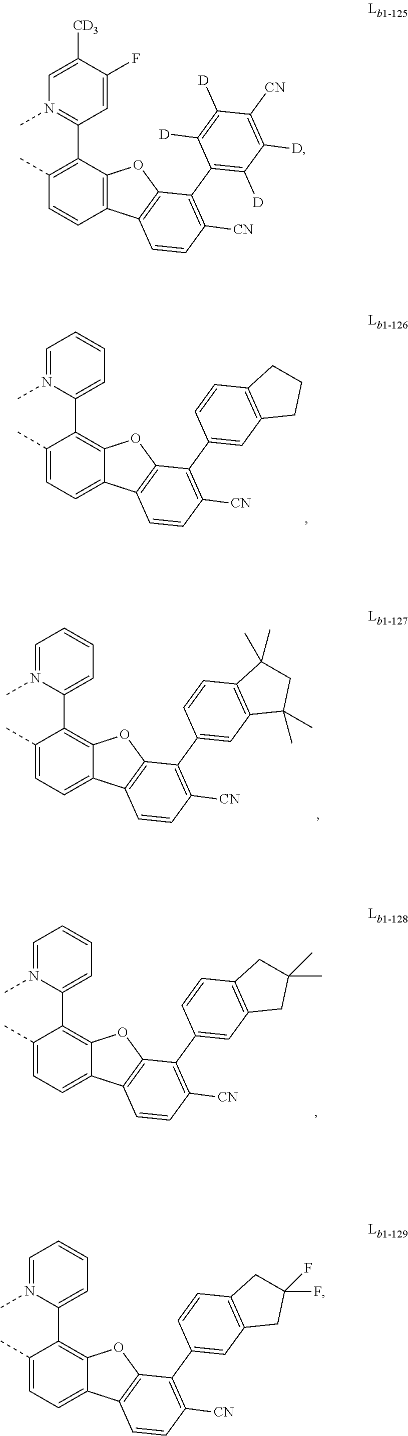 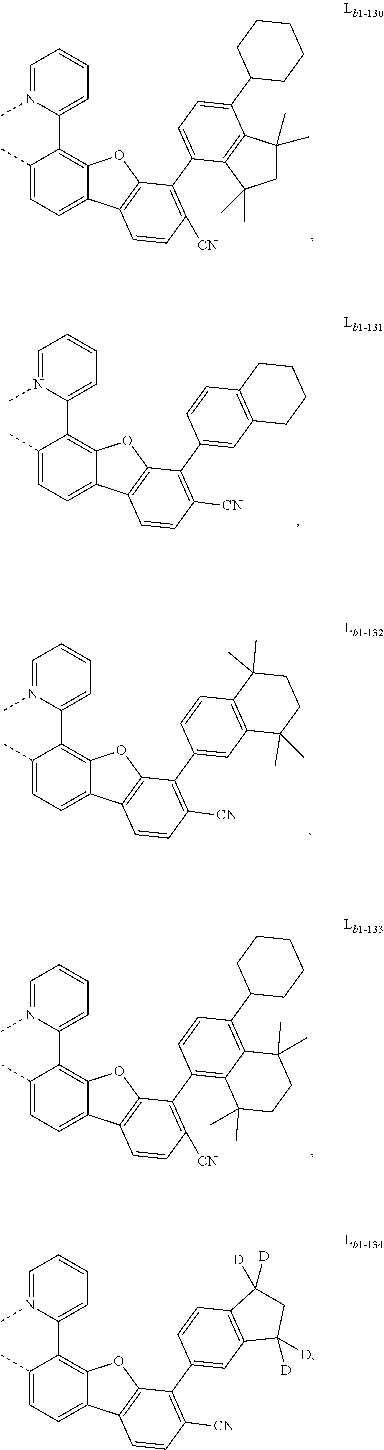 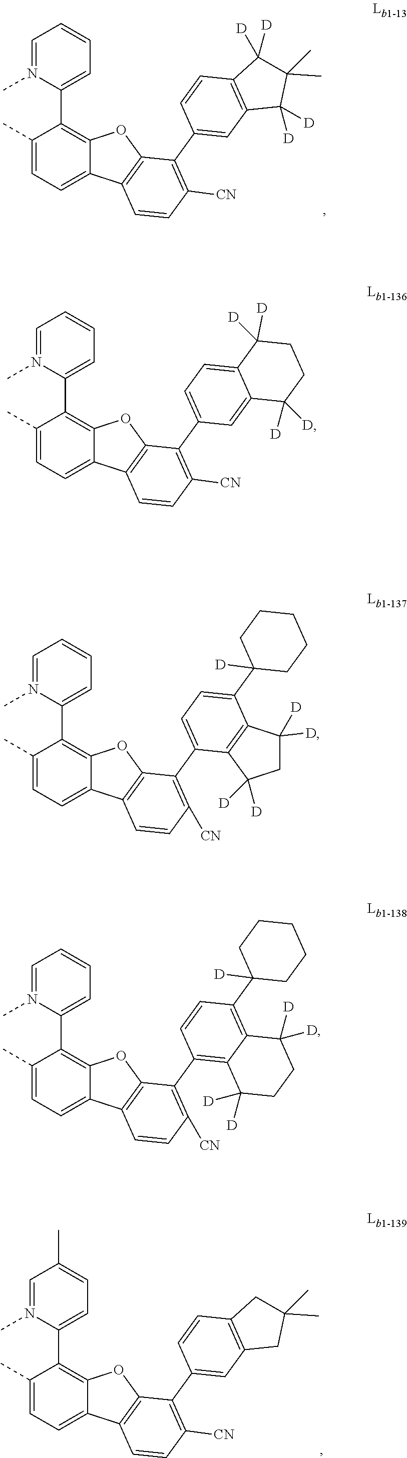 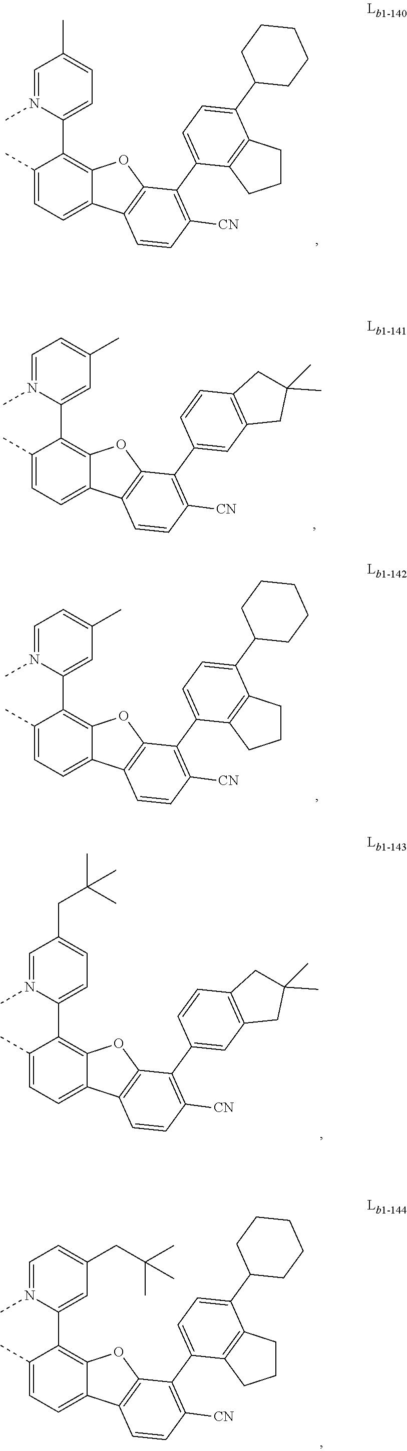 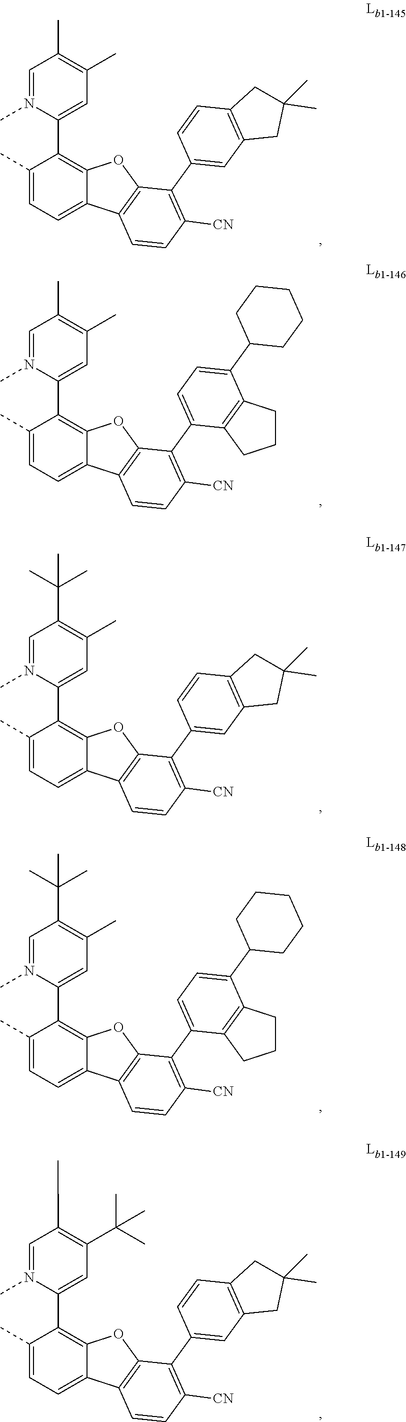 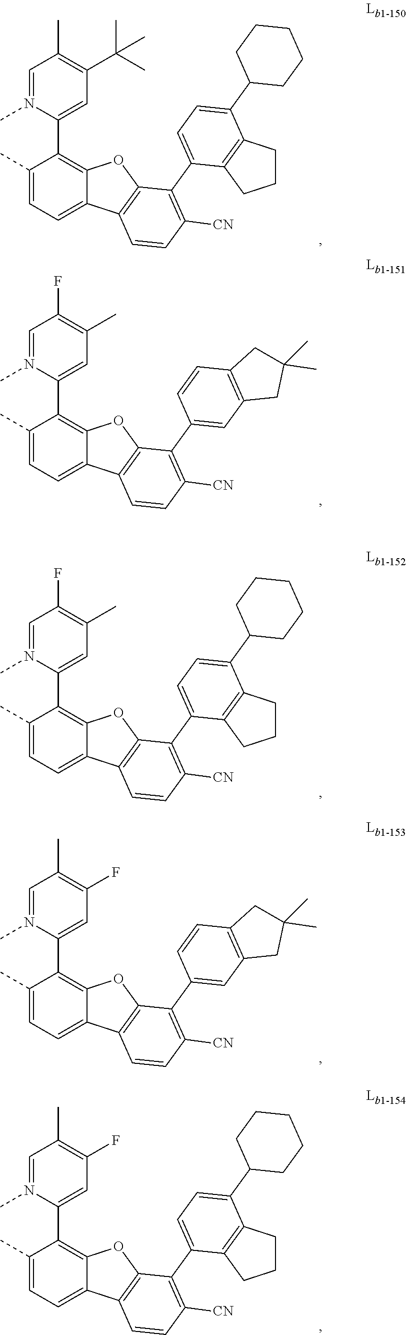 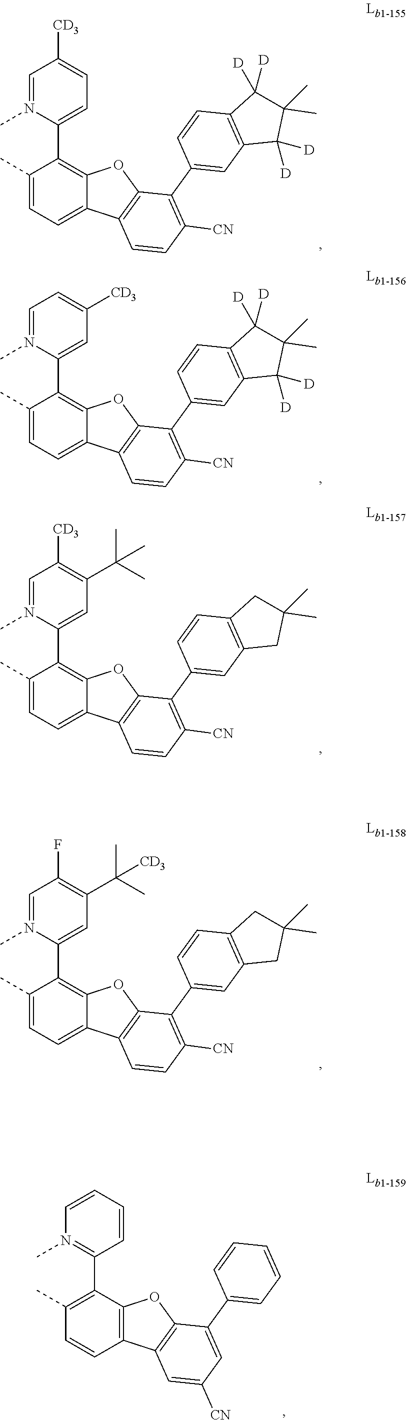 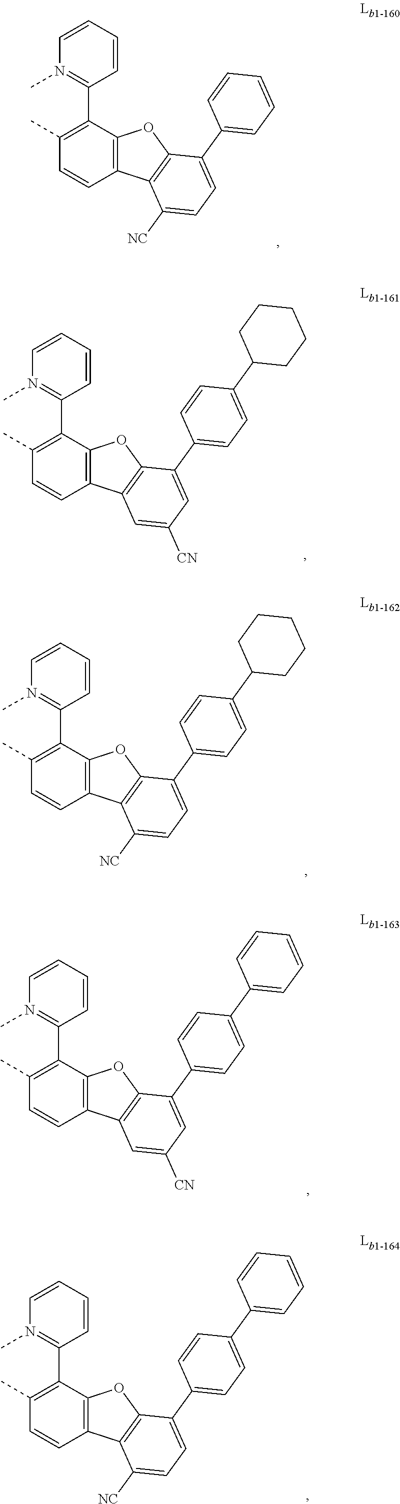 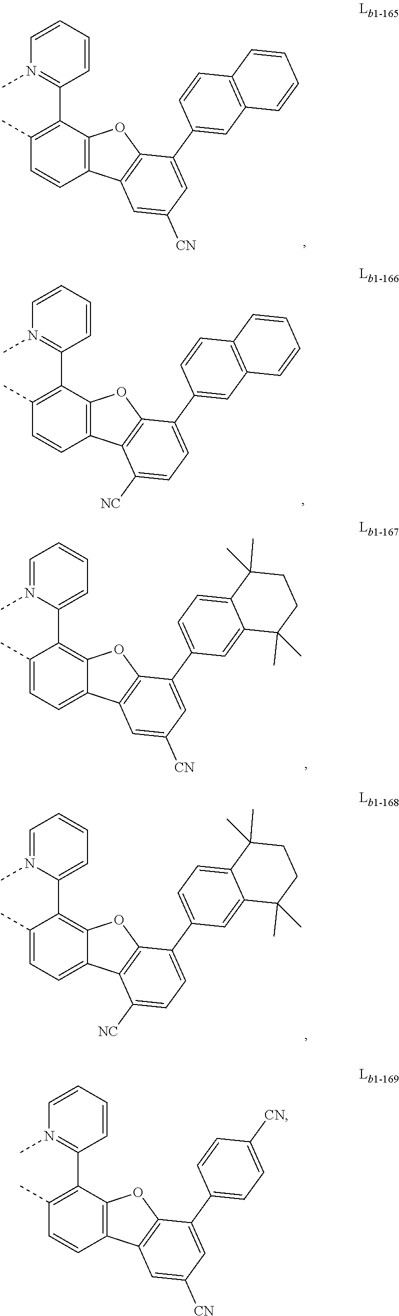 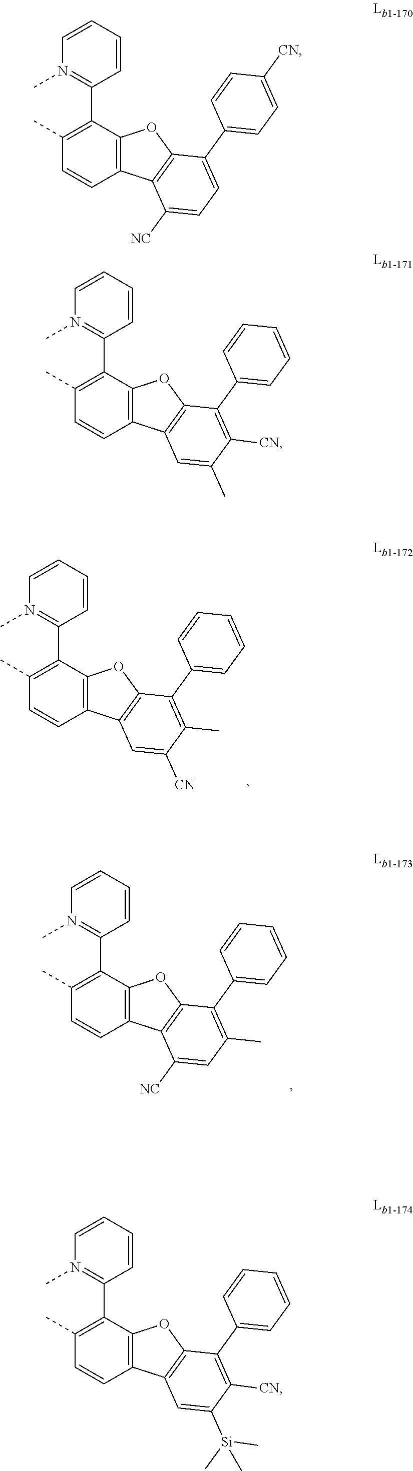 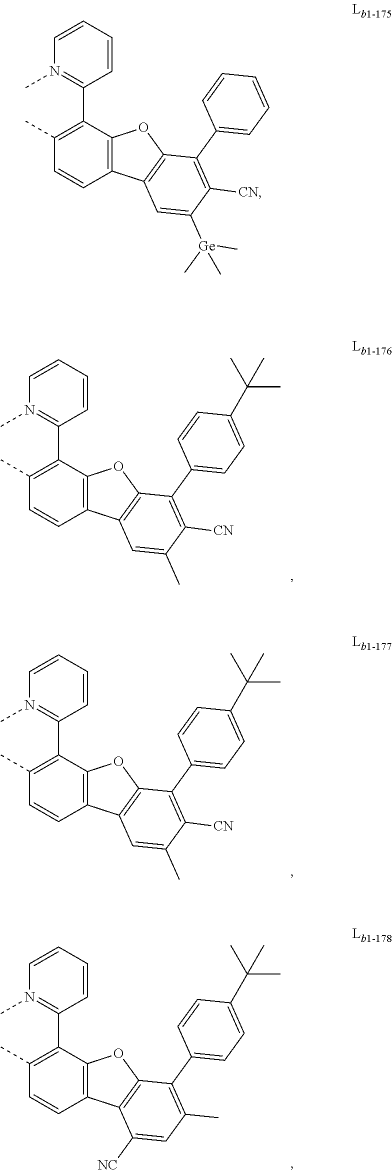 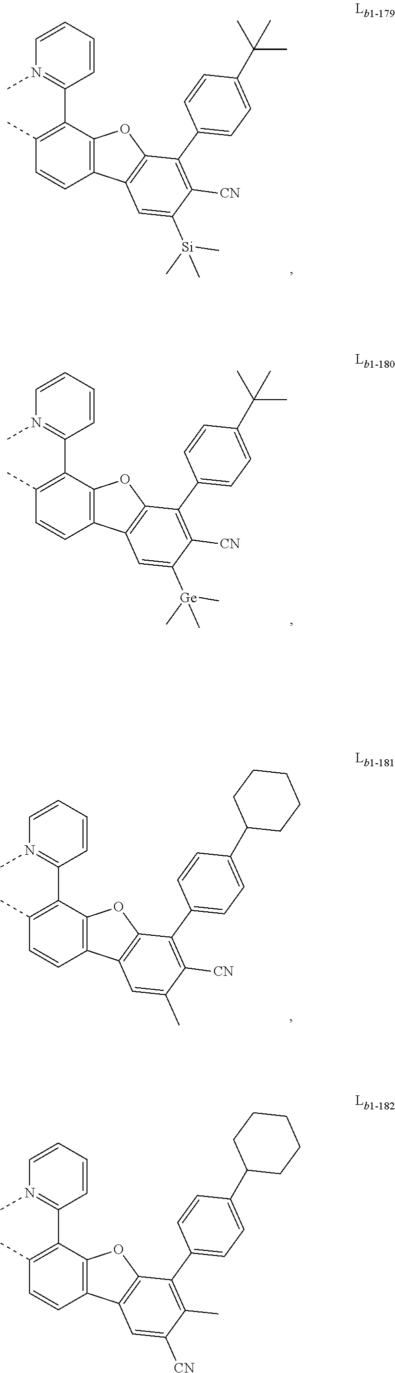 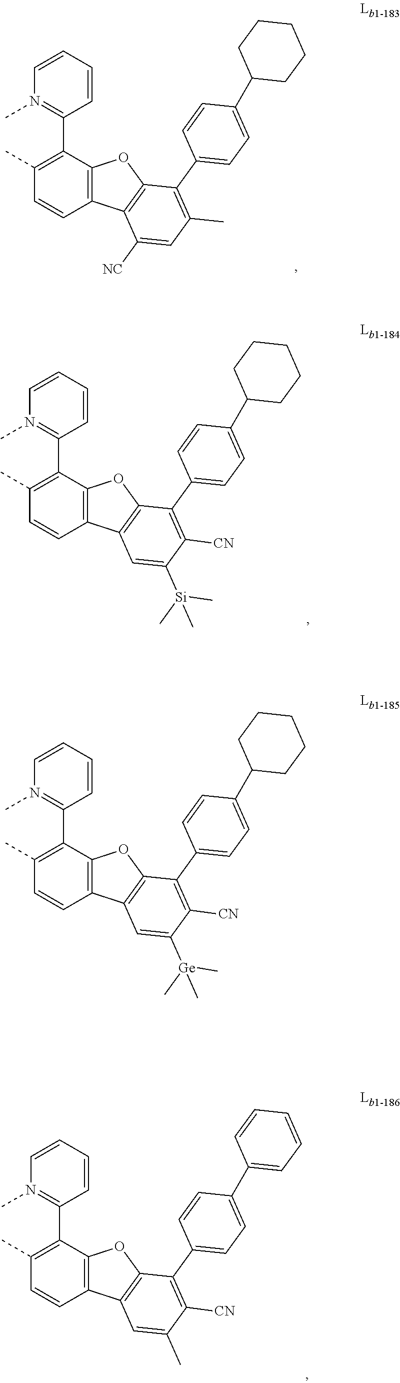 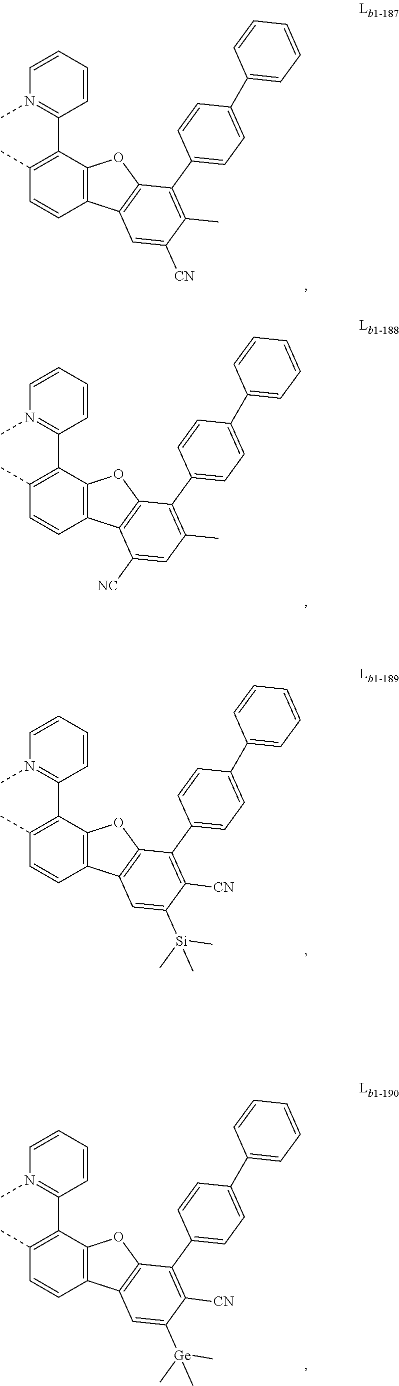 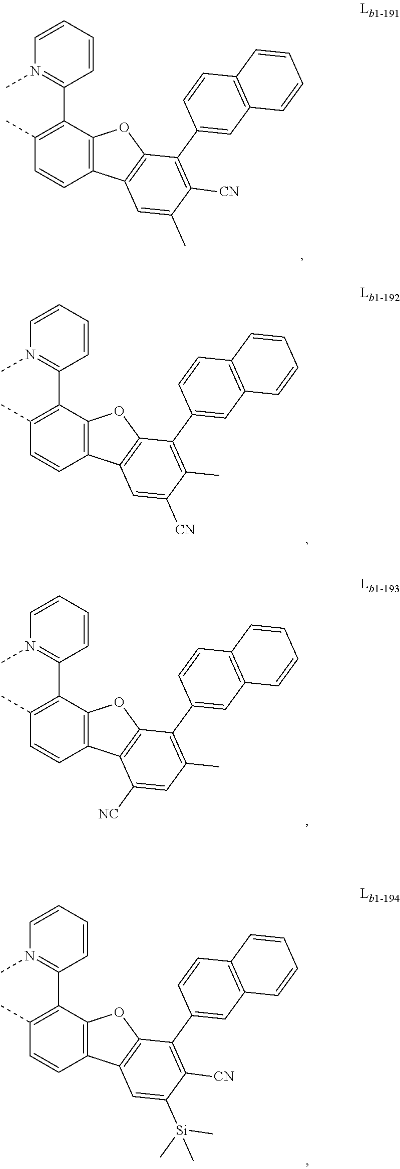 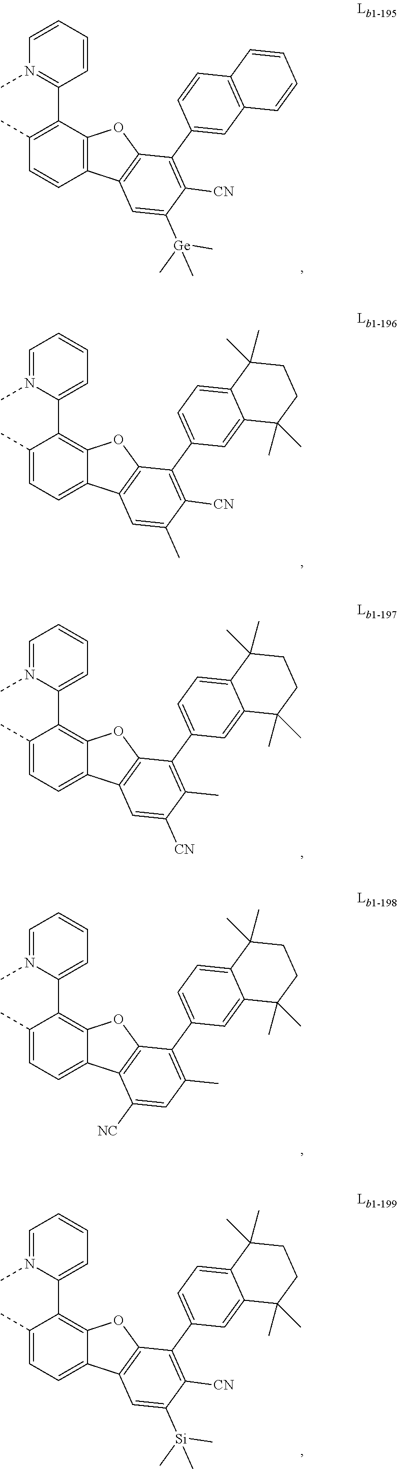 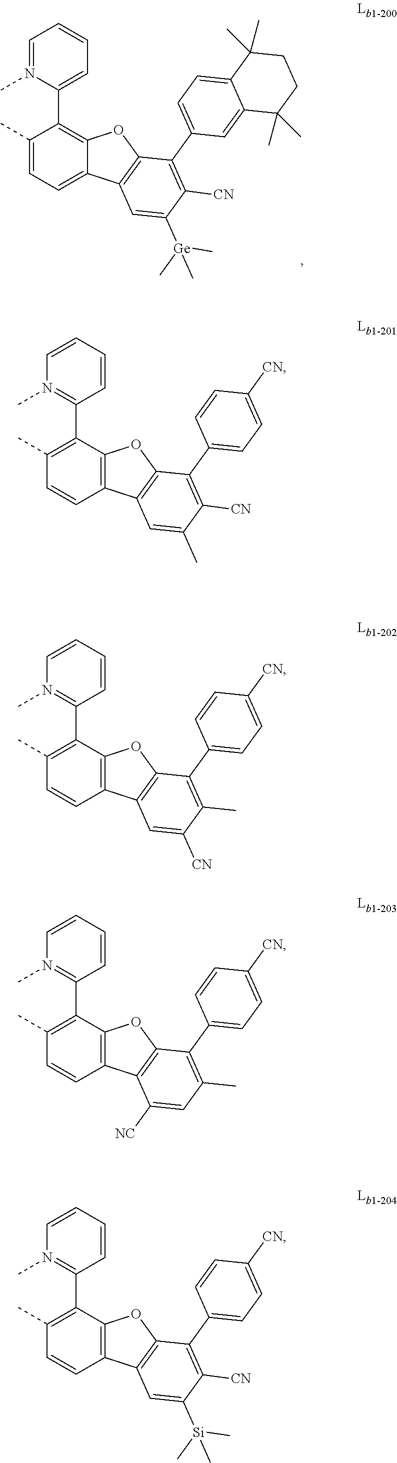 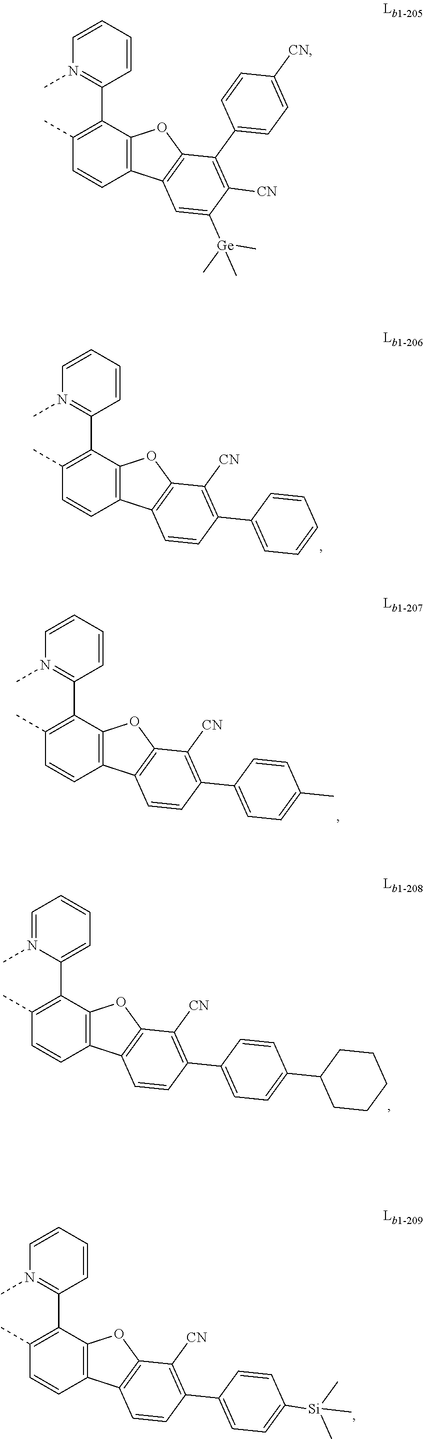 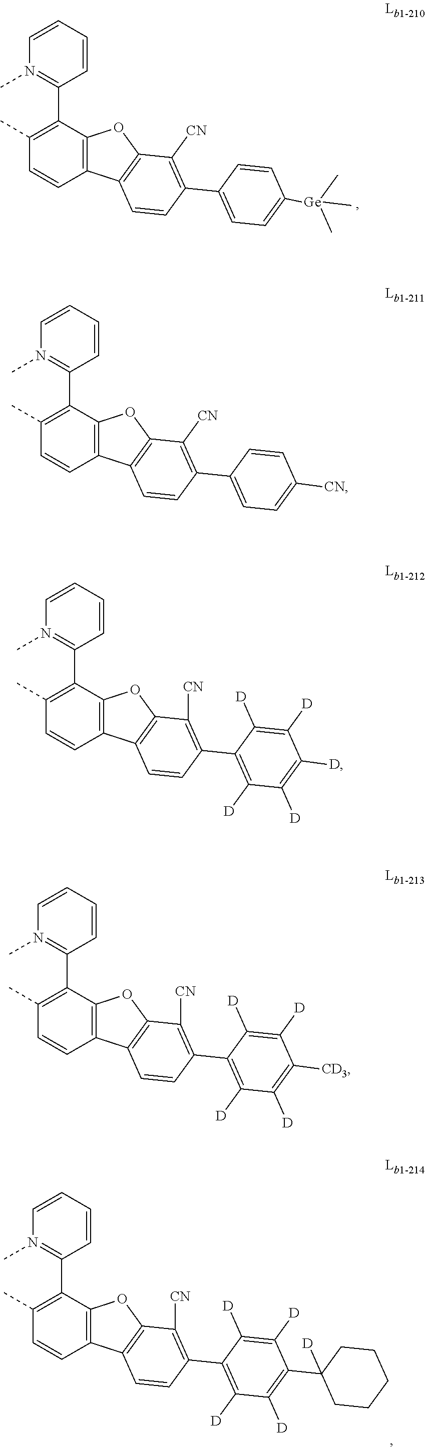 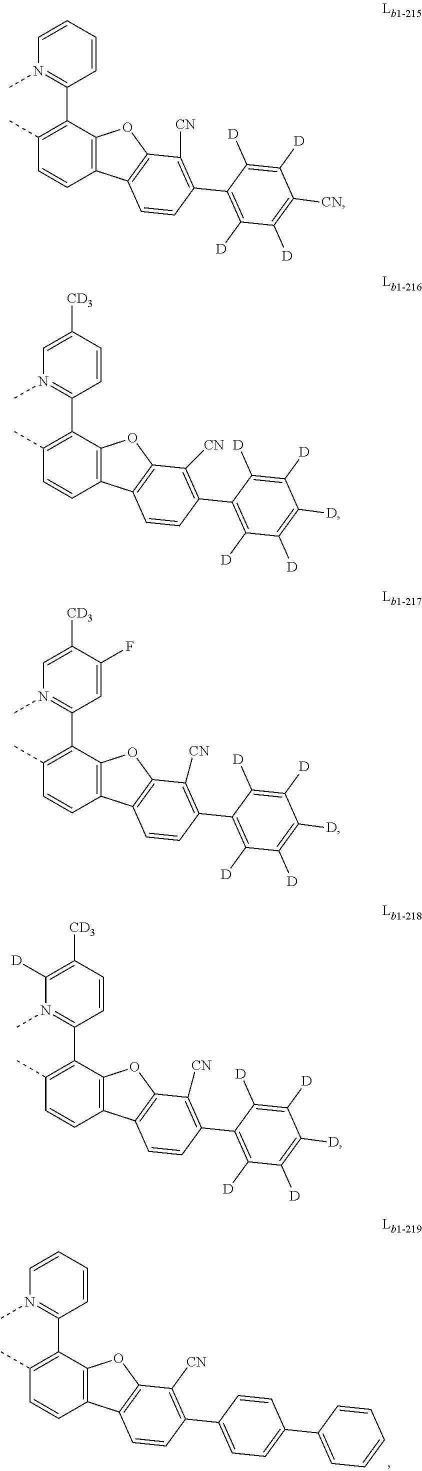 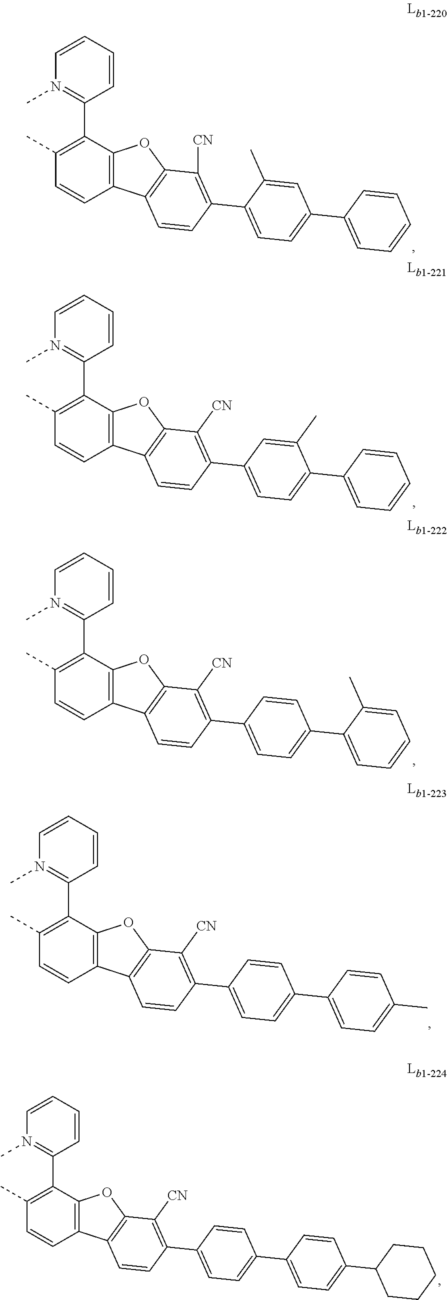 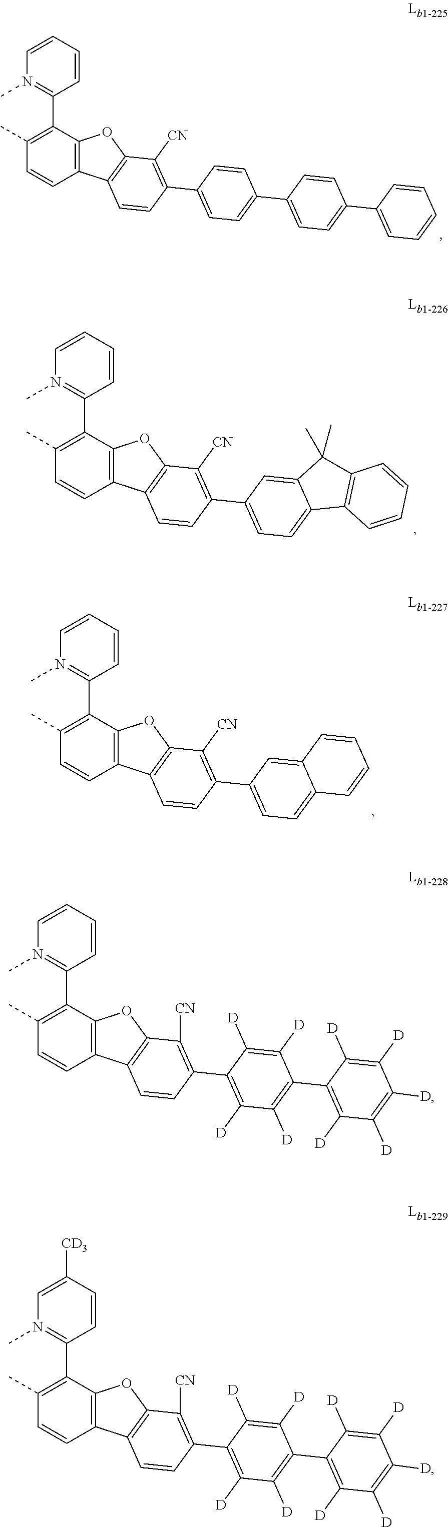 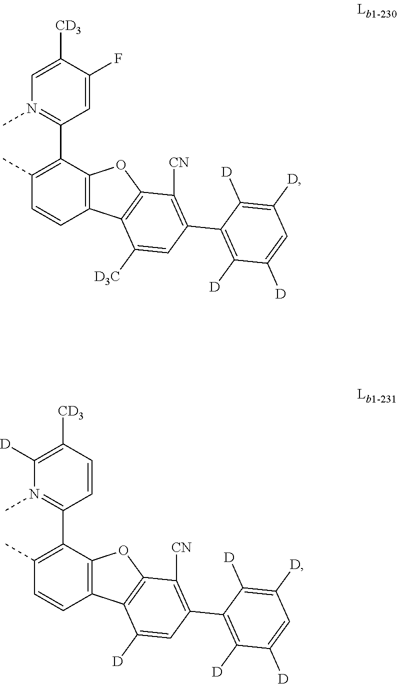 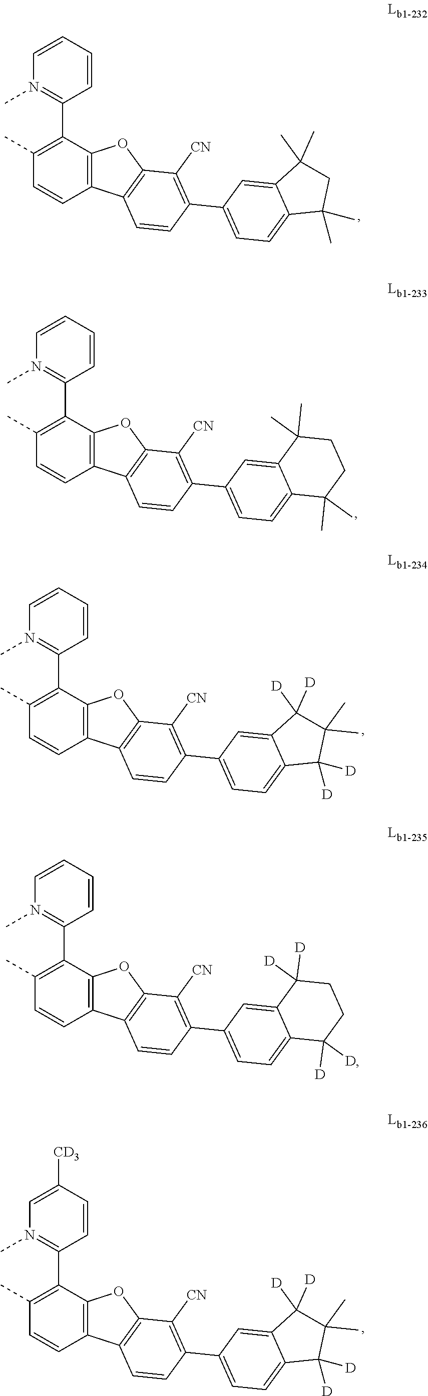 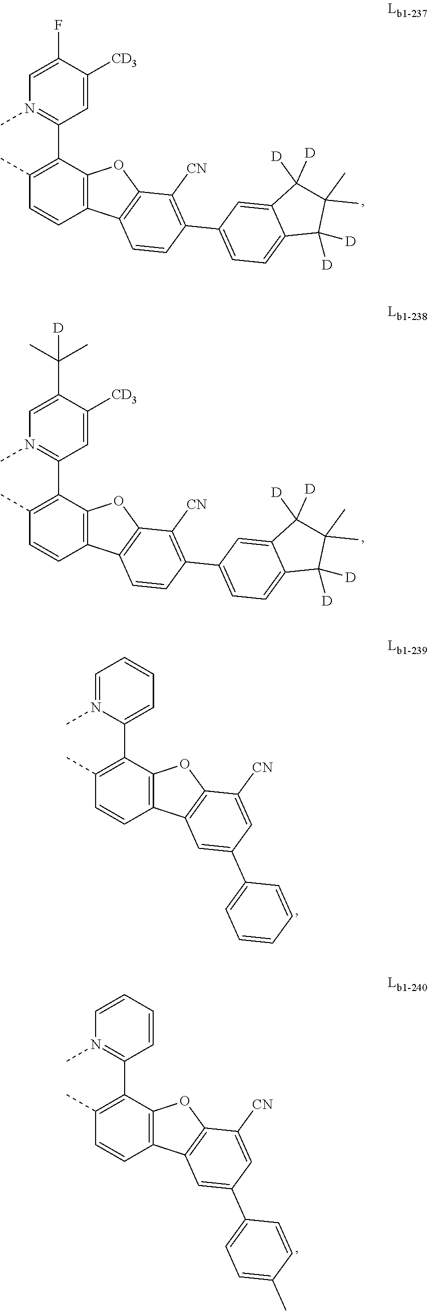 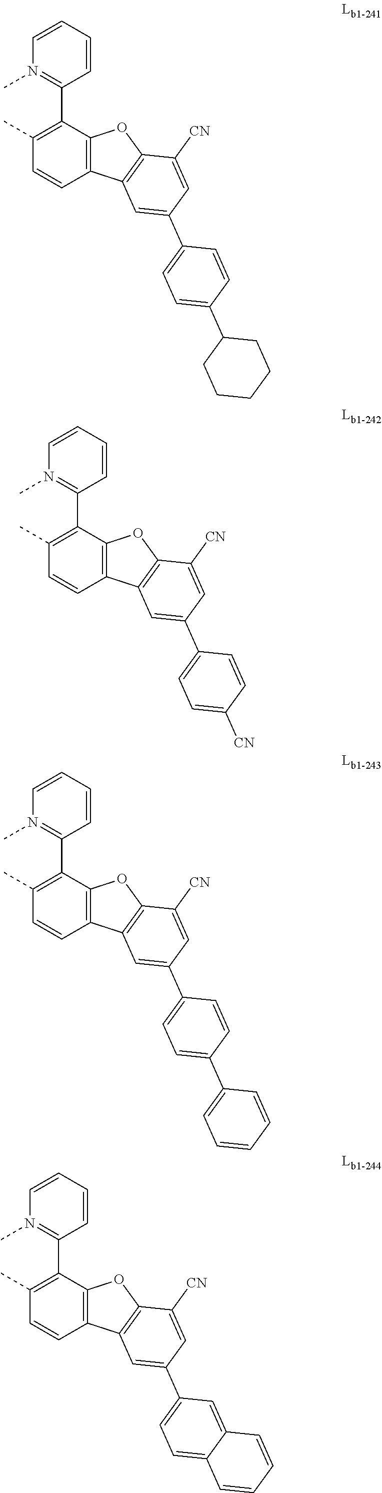 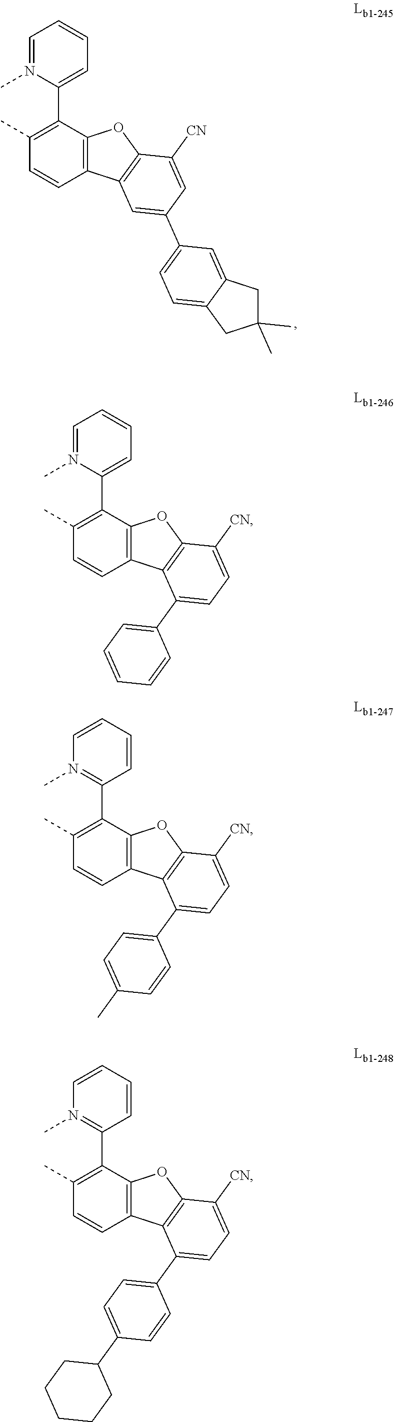 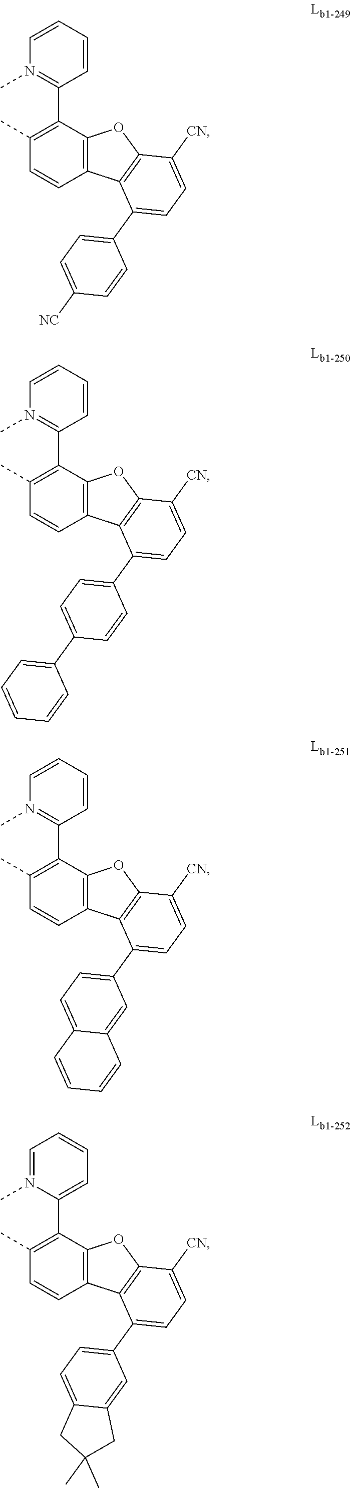 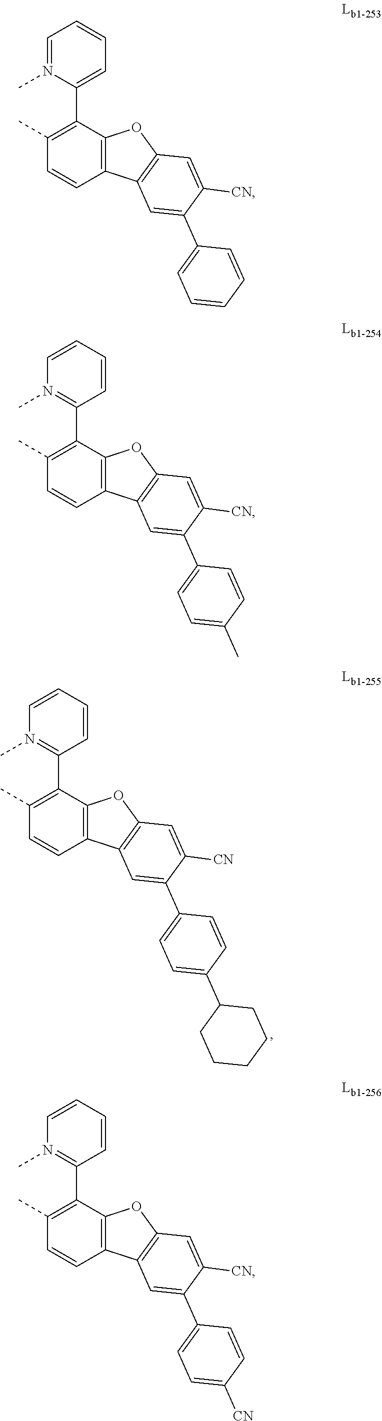 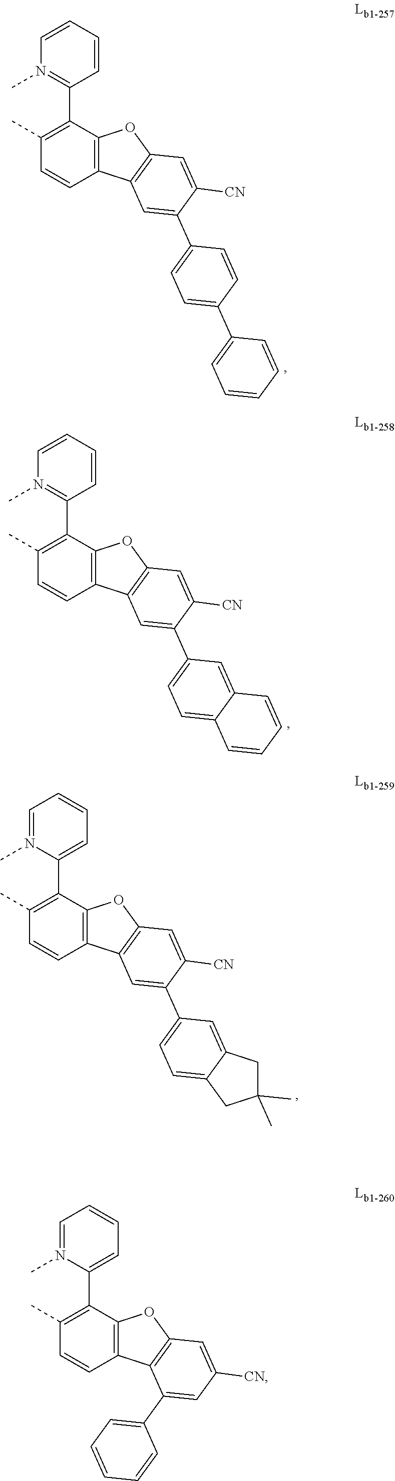 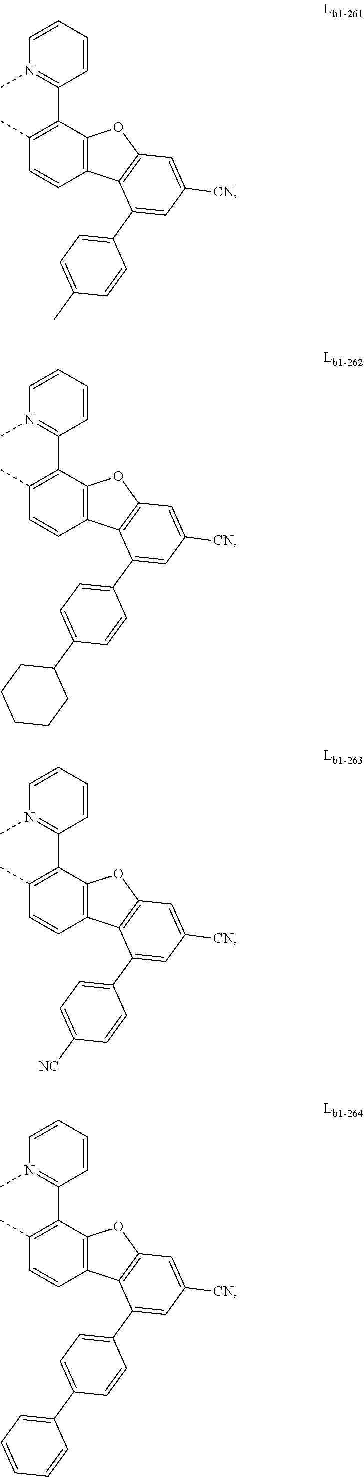 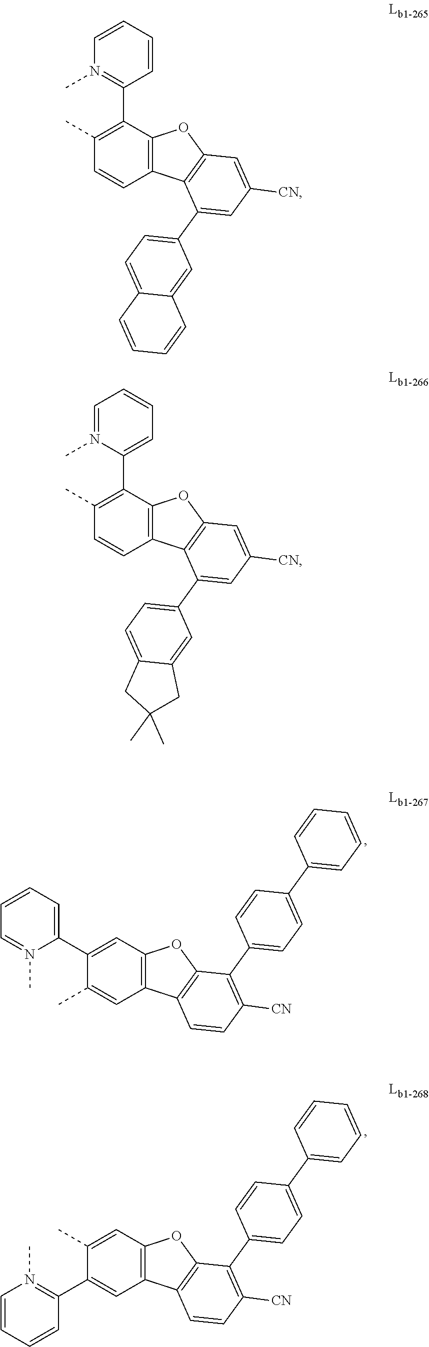 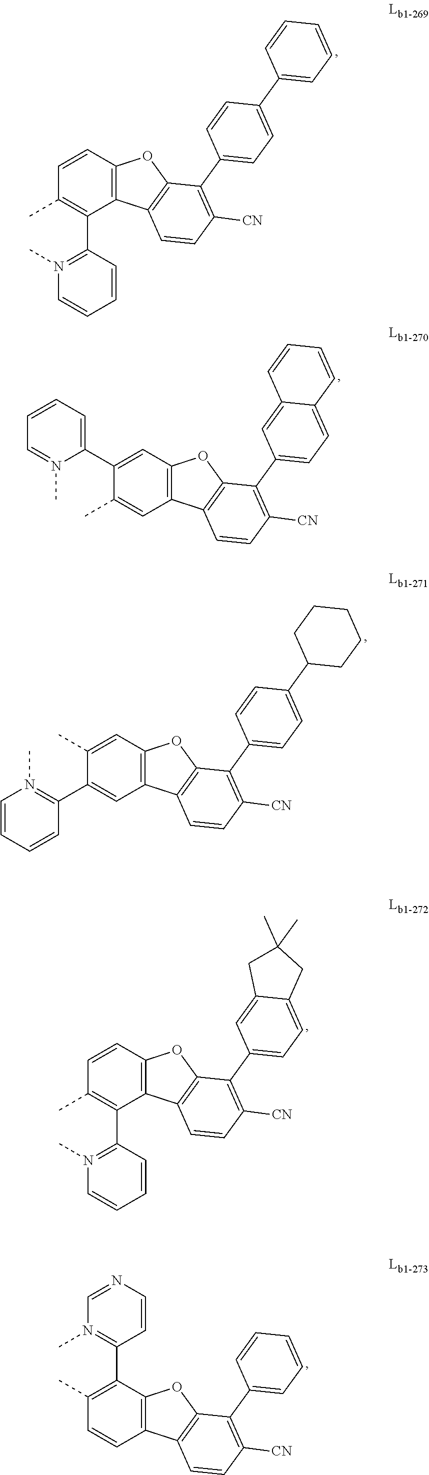 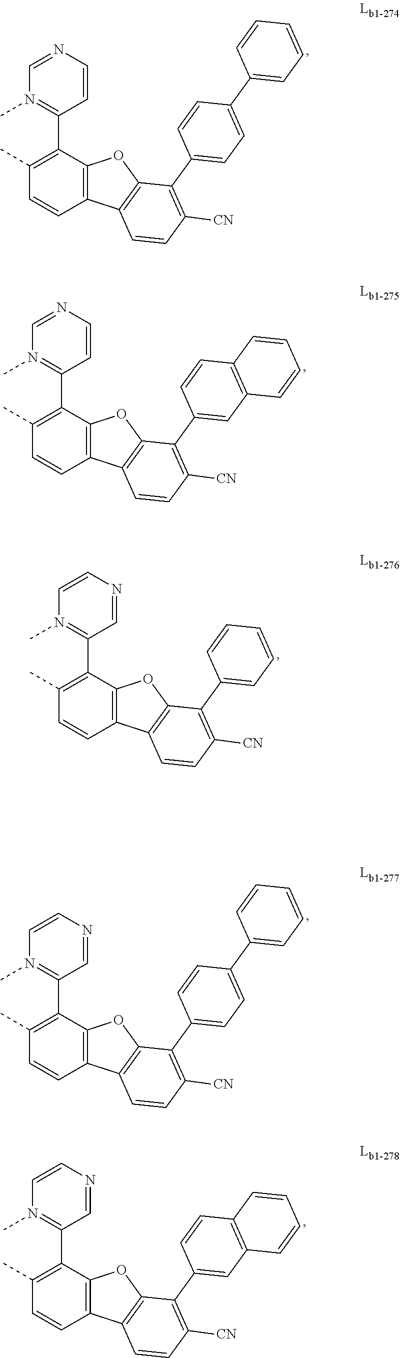 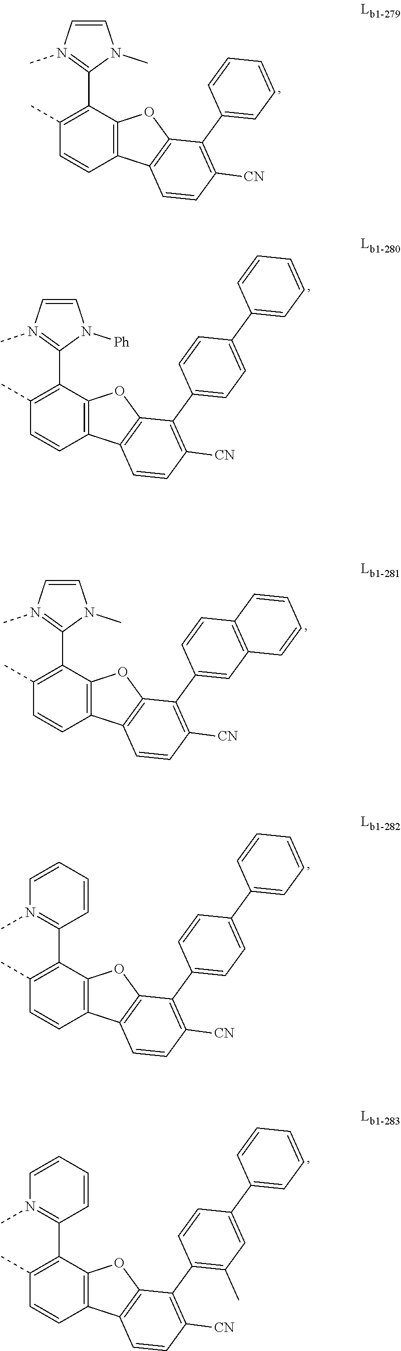 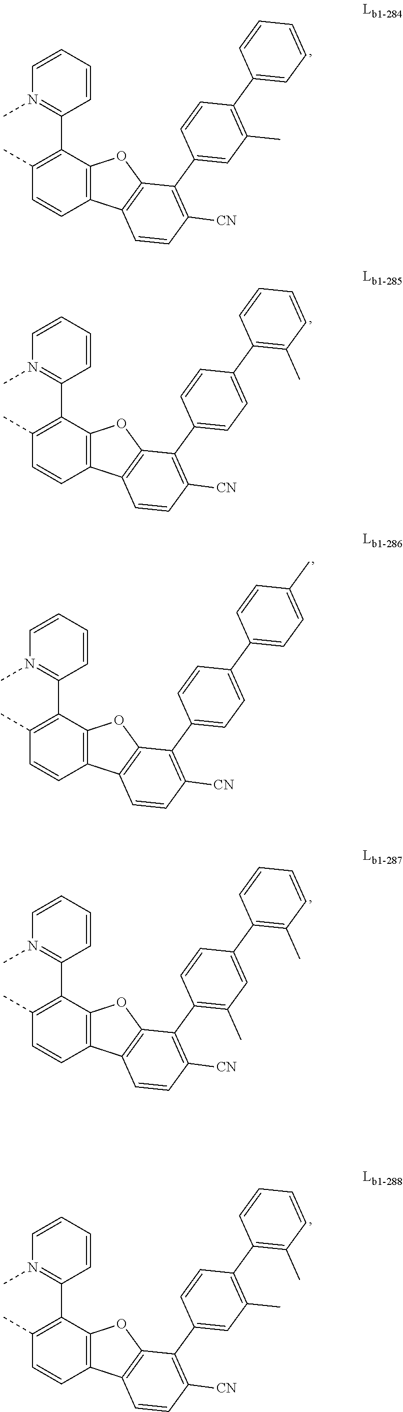 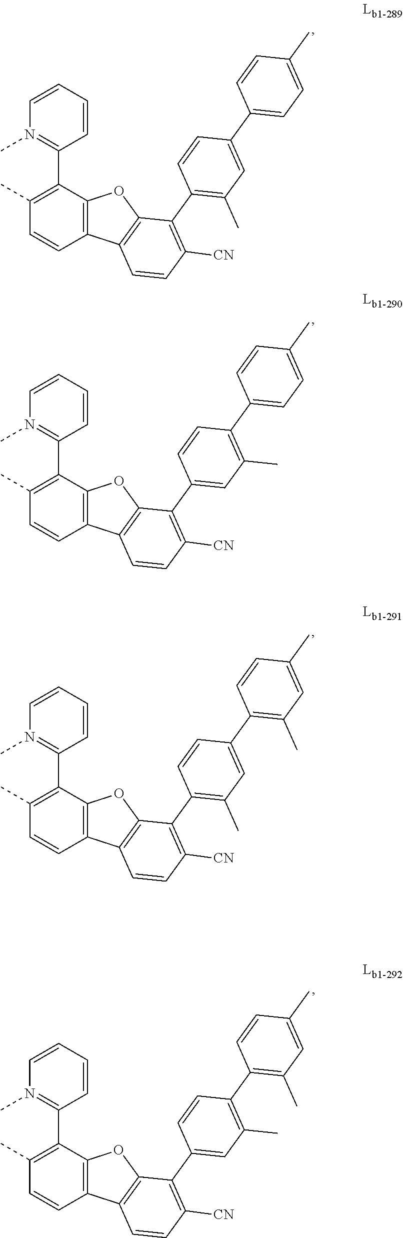 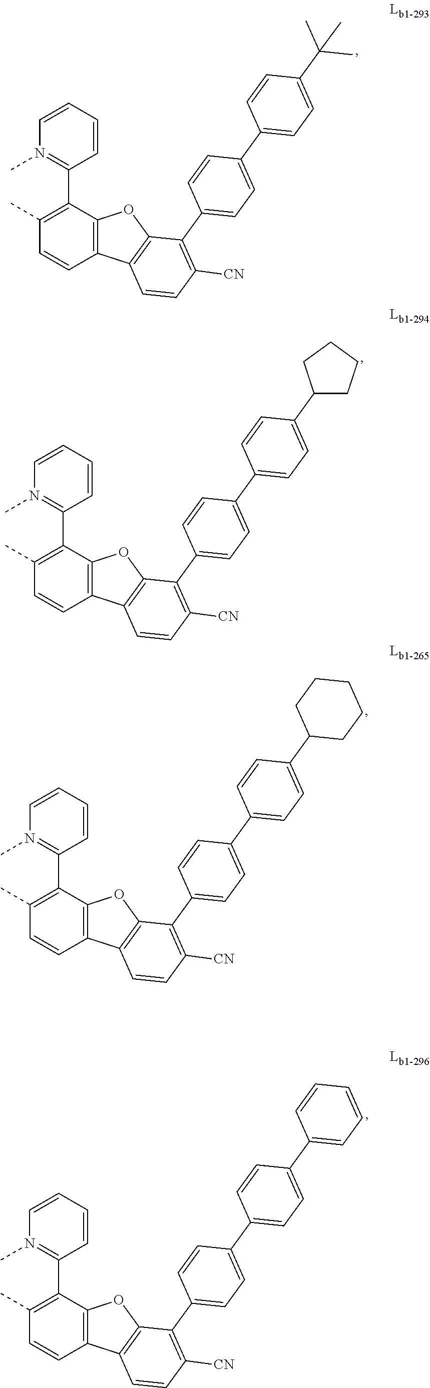 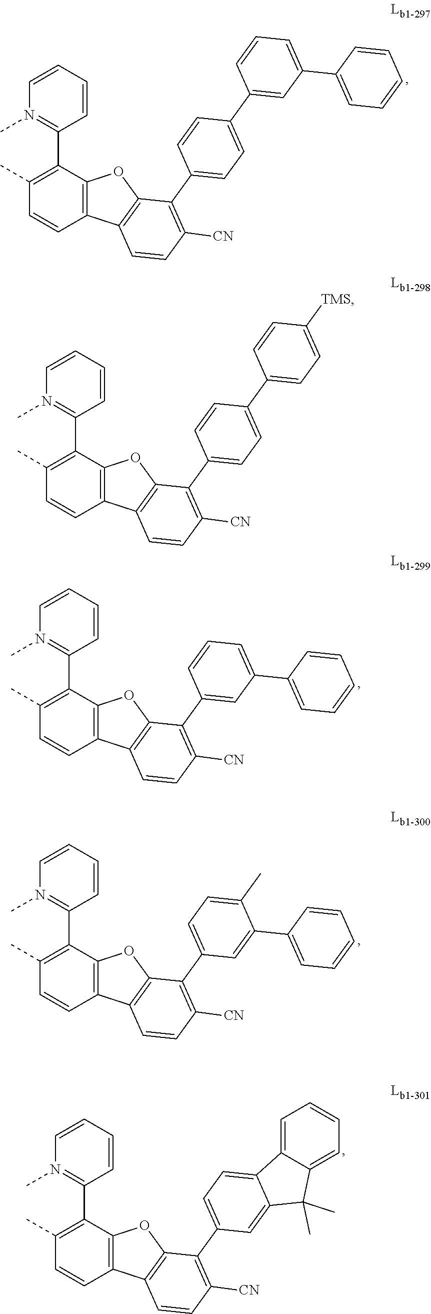 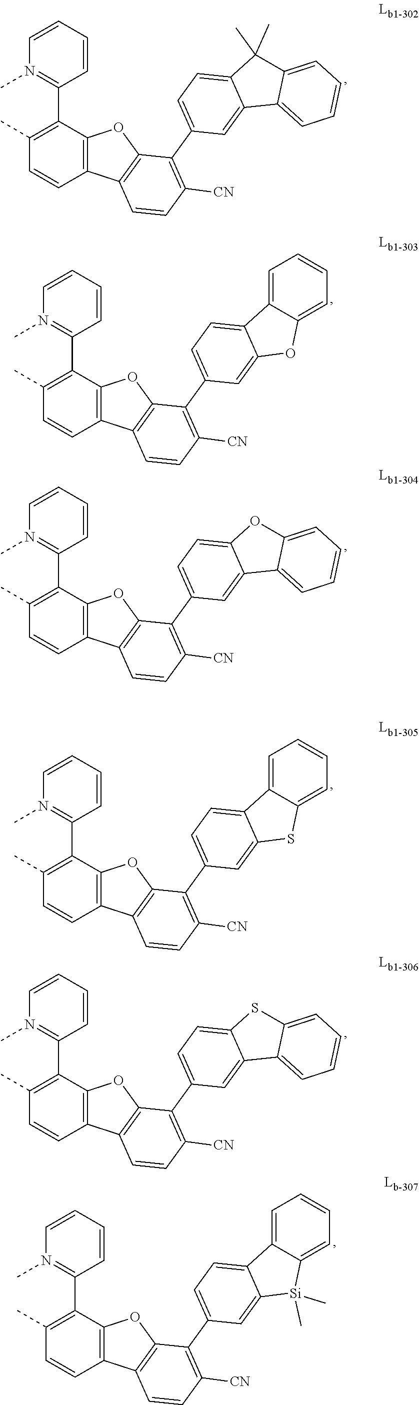 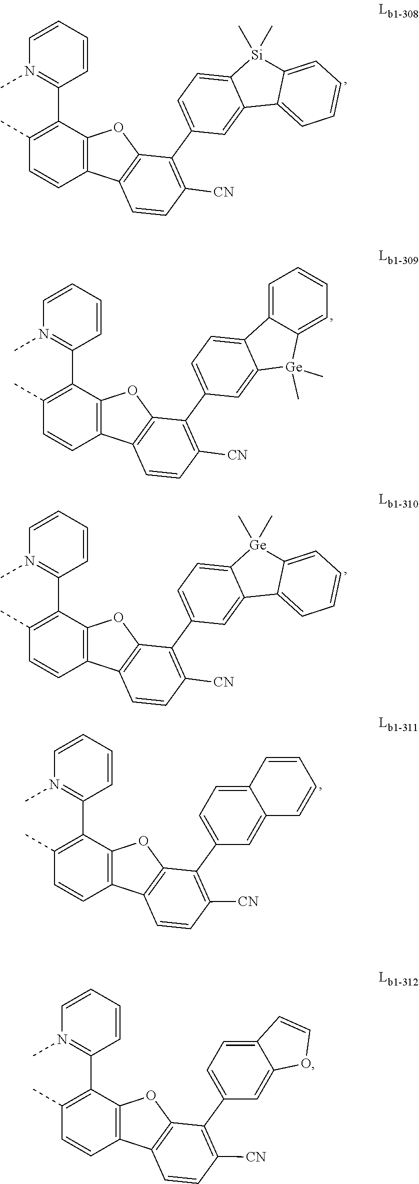 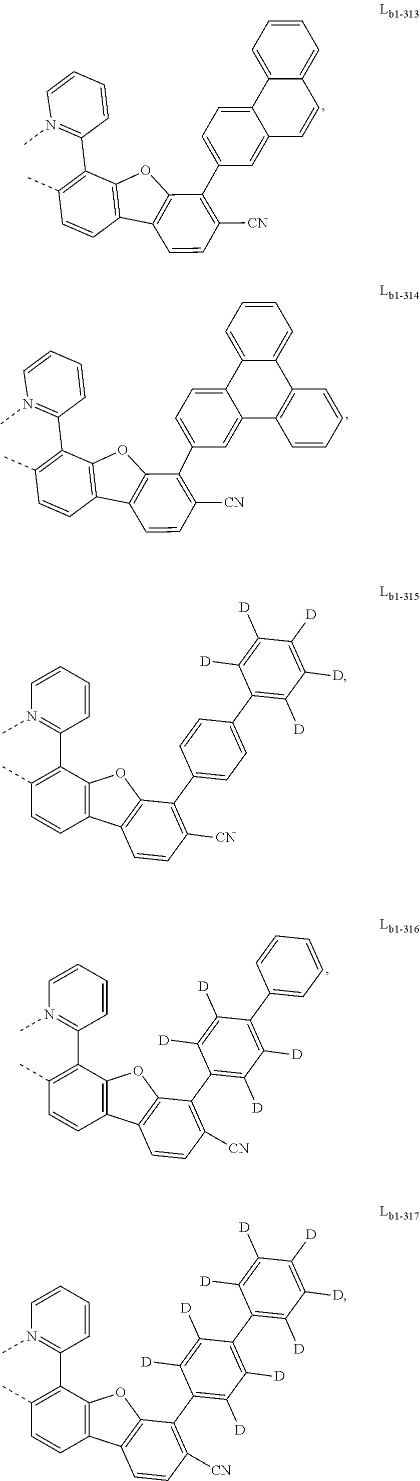 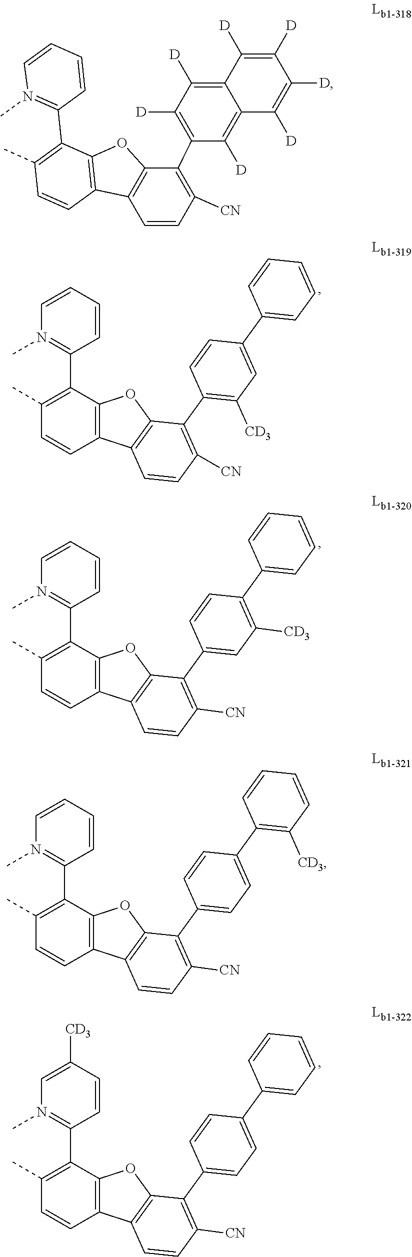 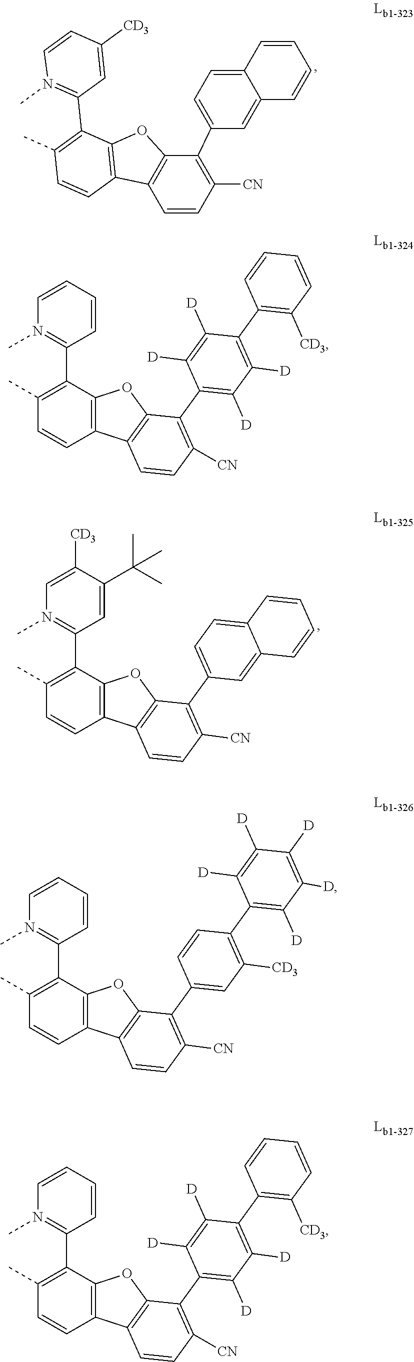 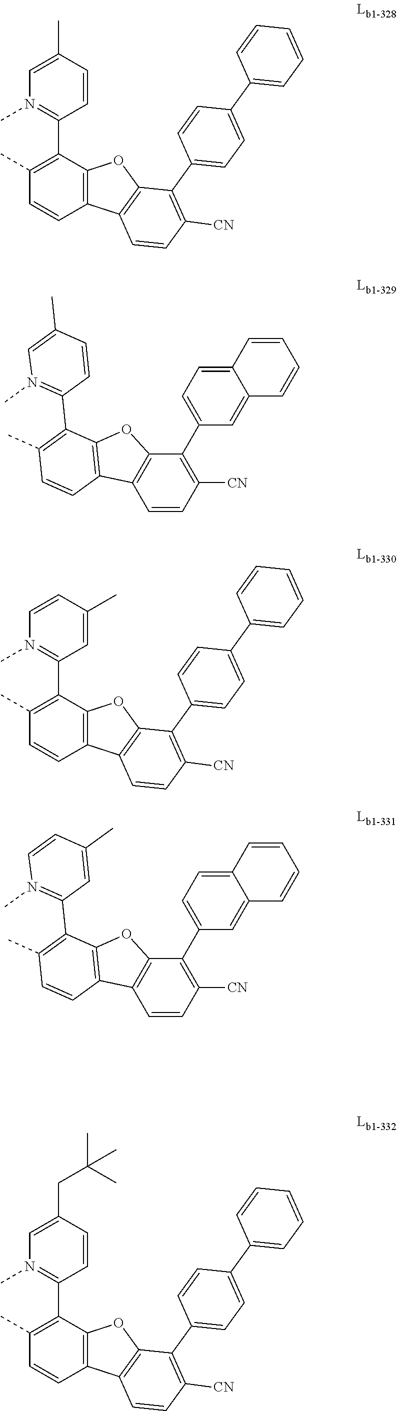 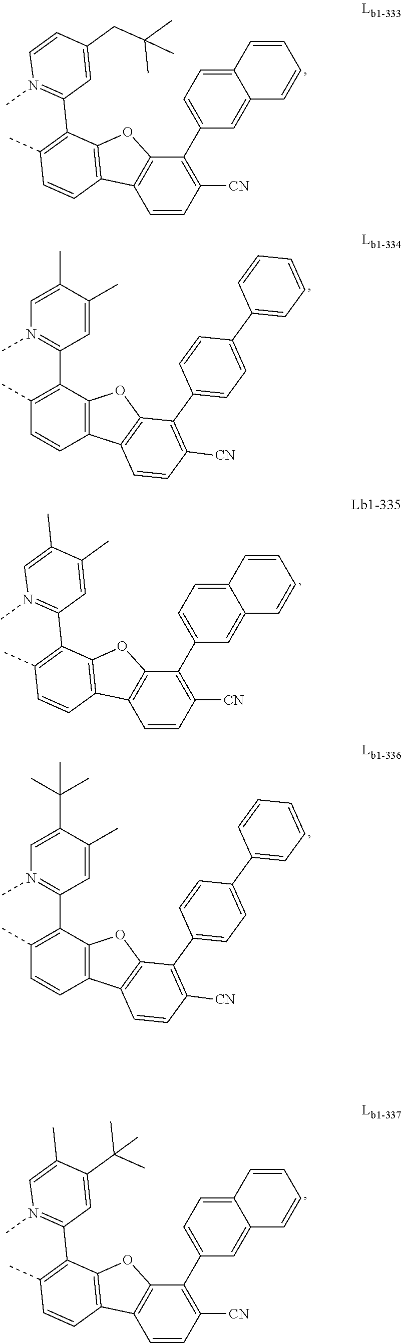 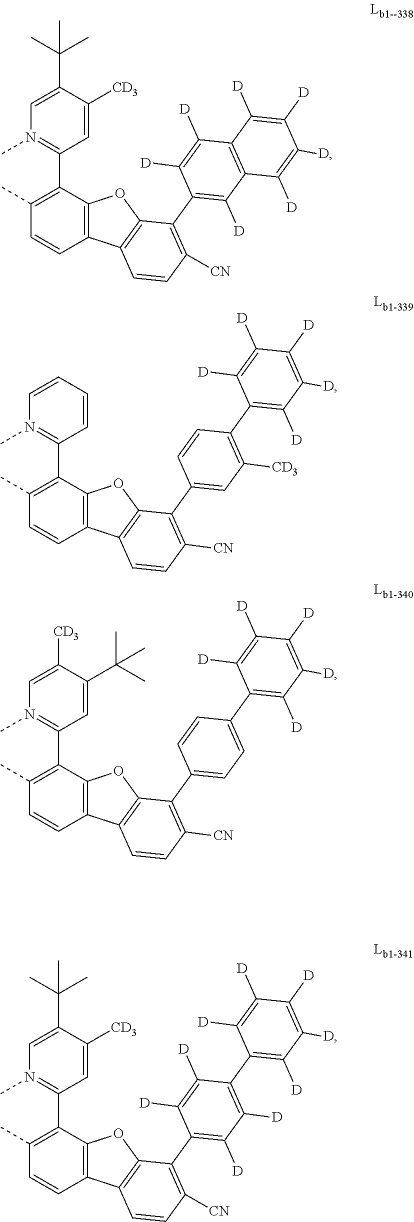 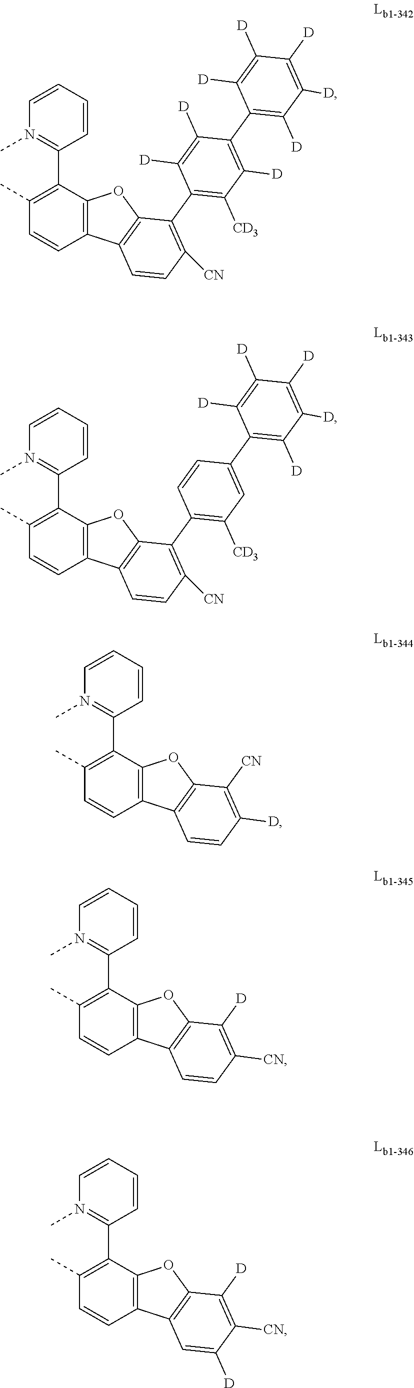 [chemical structure] [chemical structure] [chemical structure] [chemical structure] [chemical structure] [chemical structure] 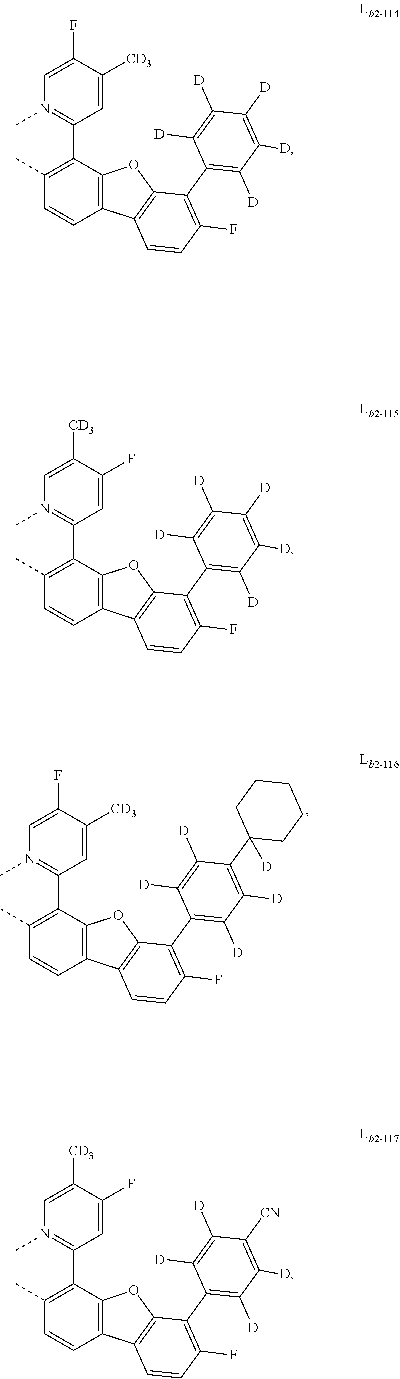 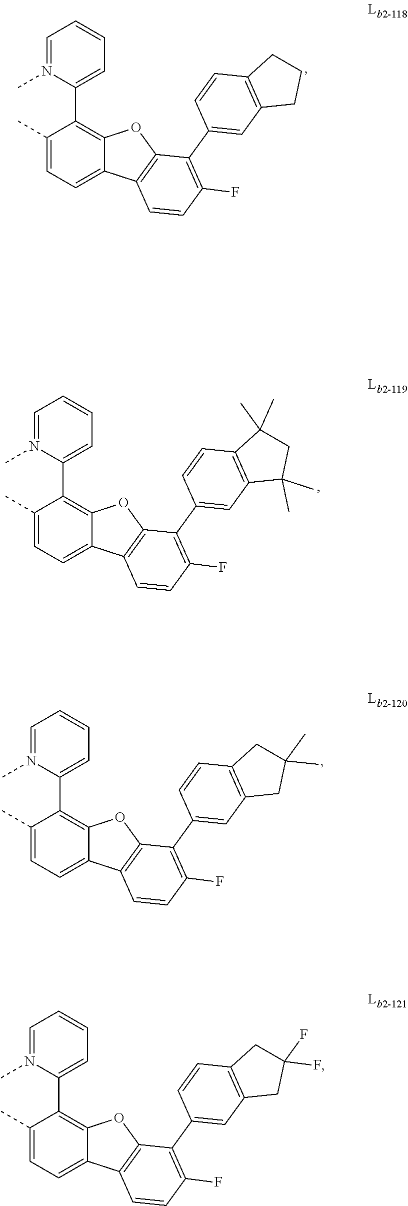 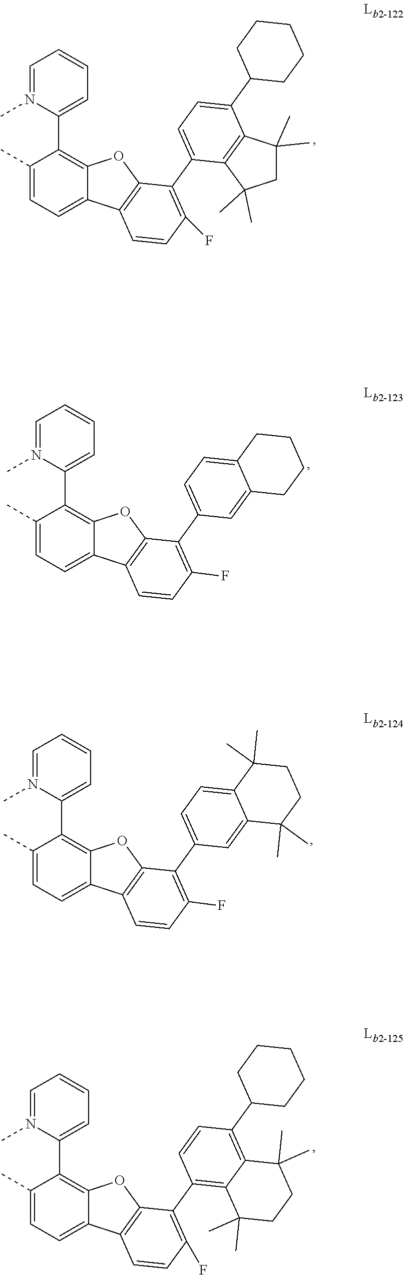 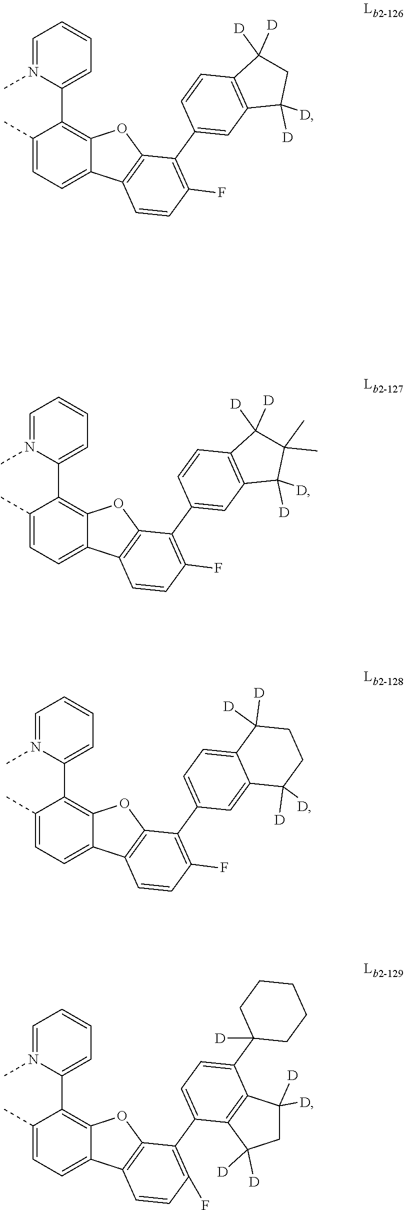 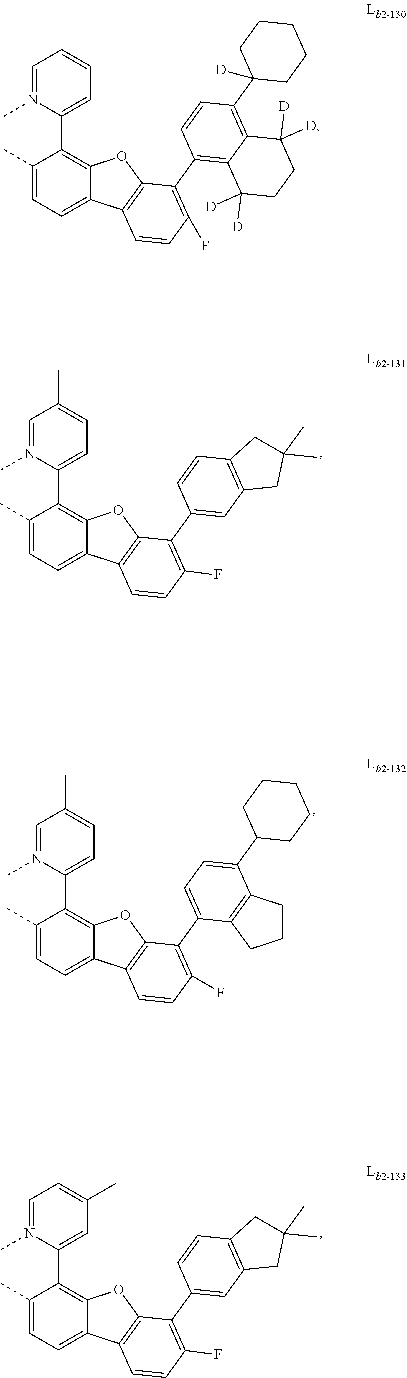 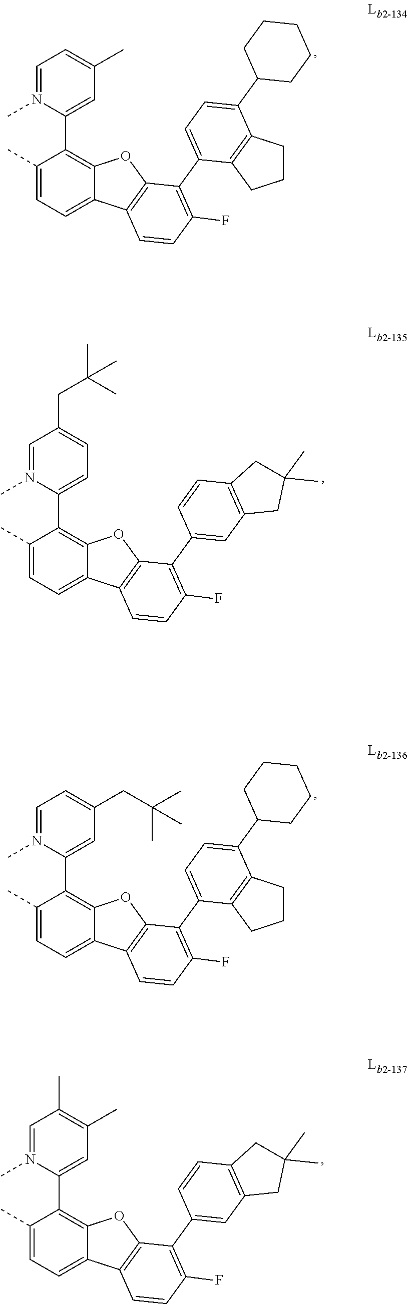 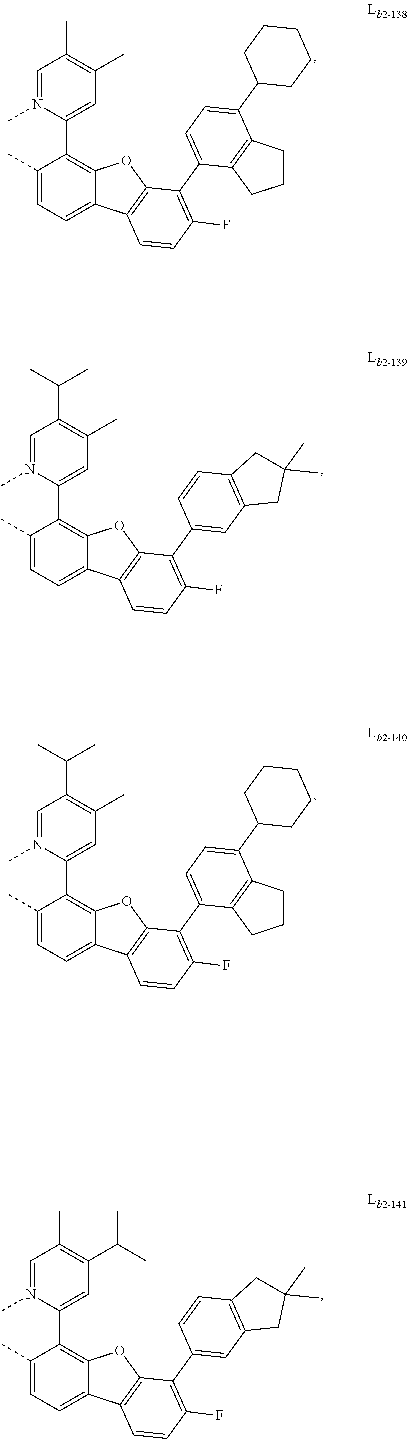 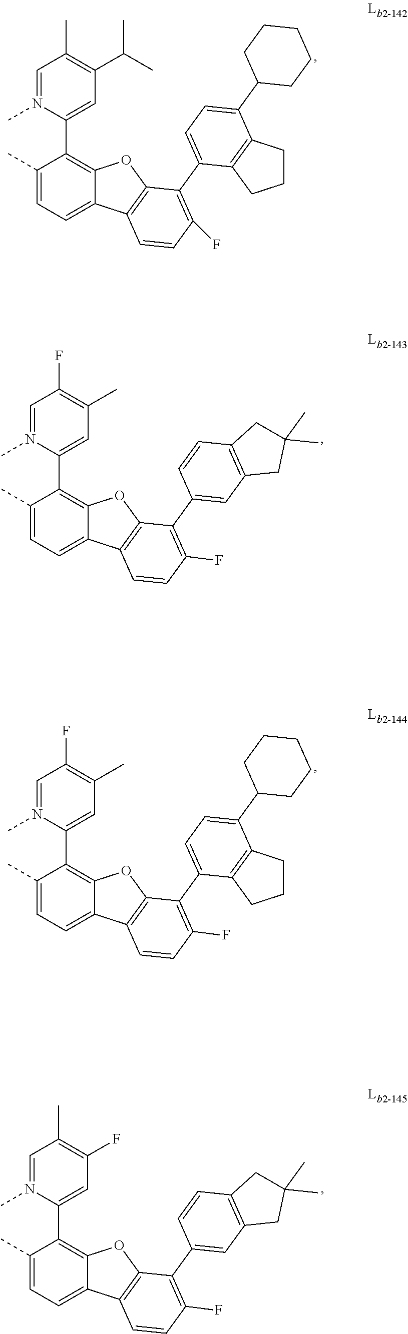 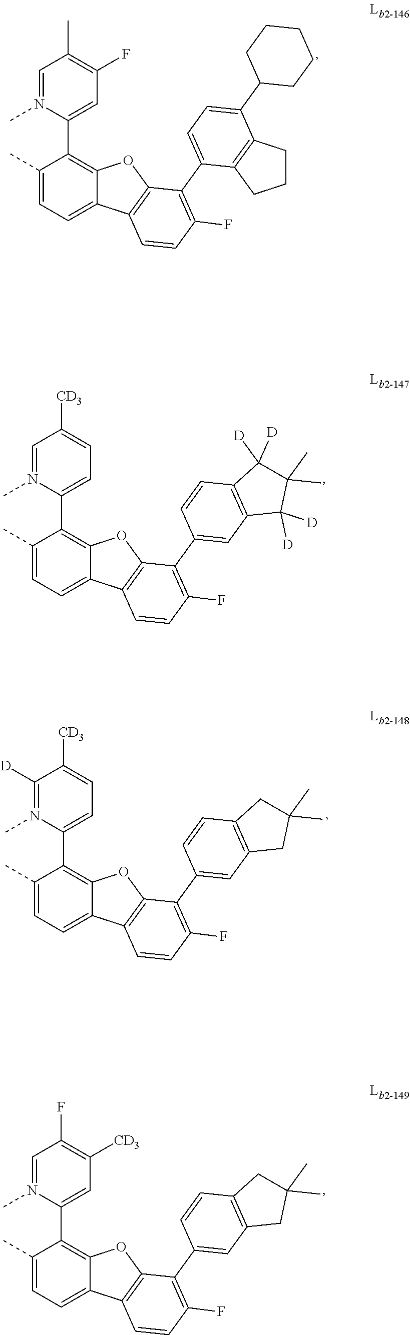 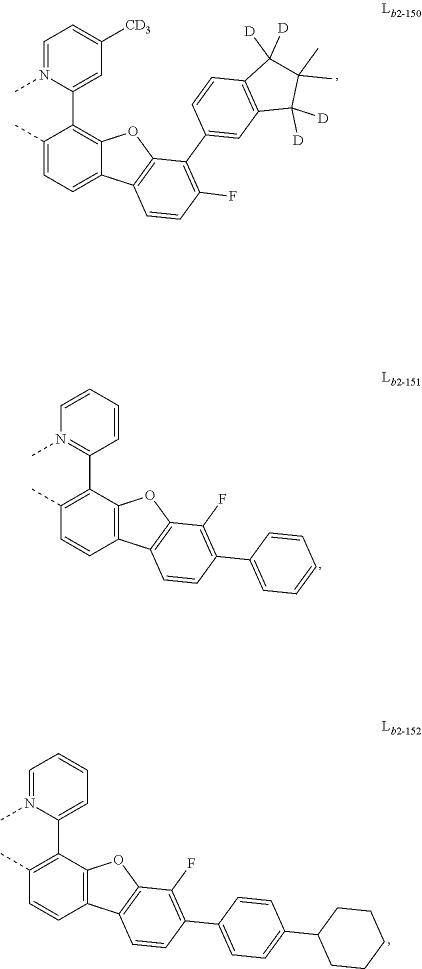 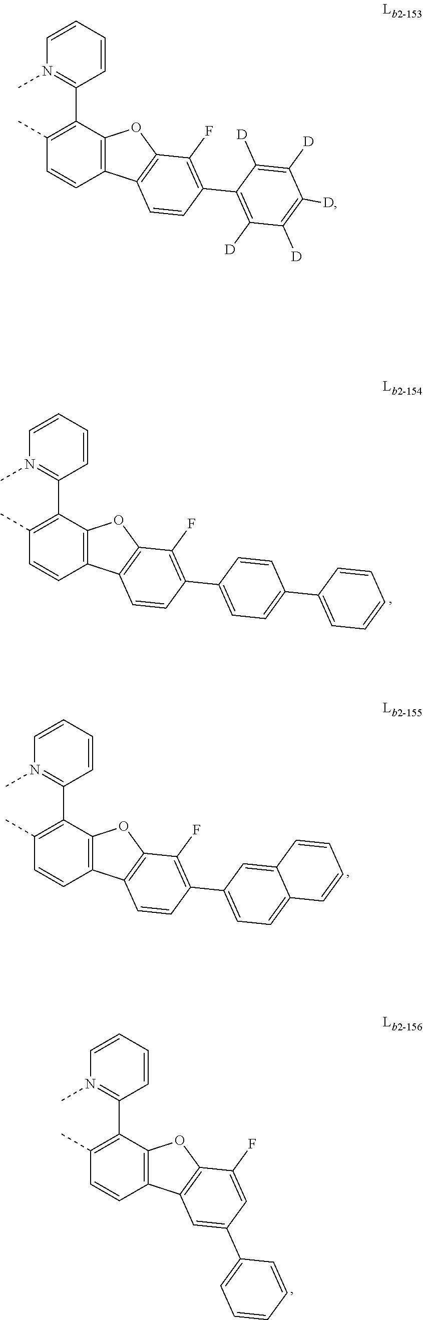 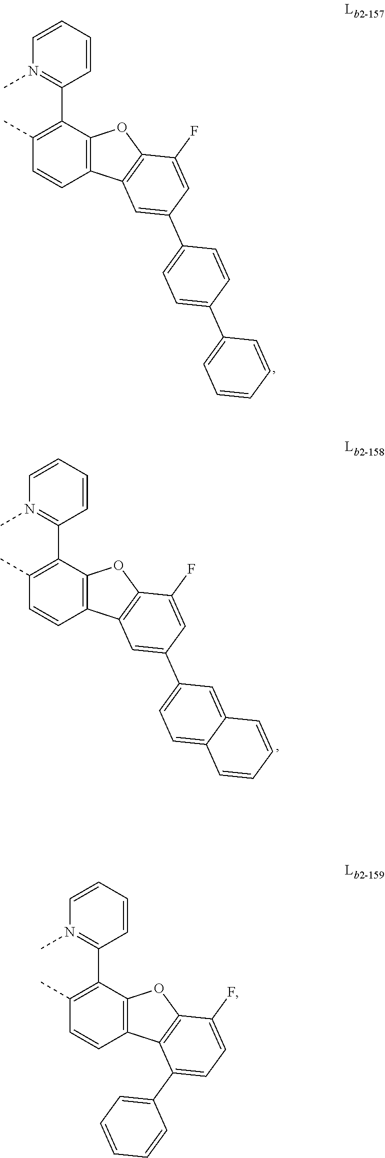 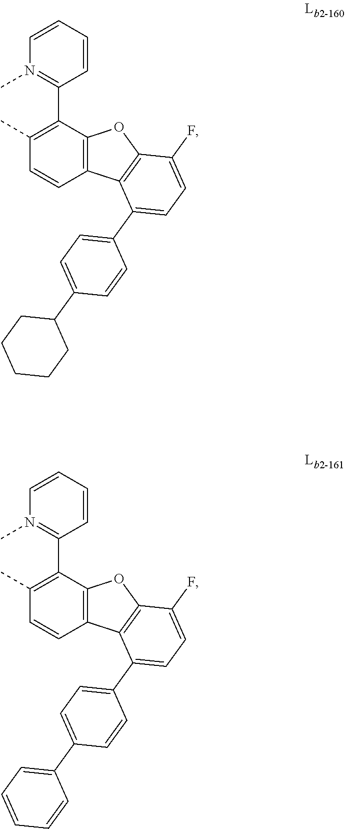 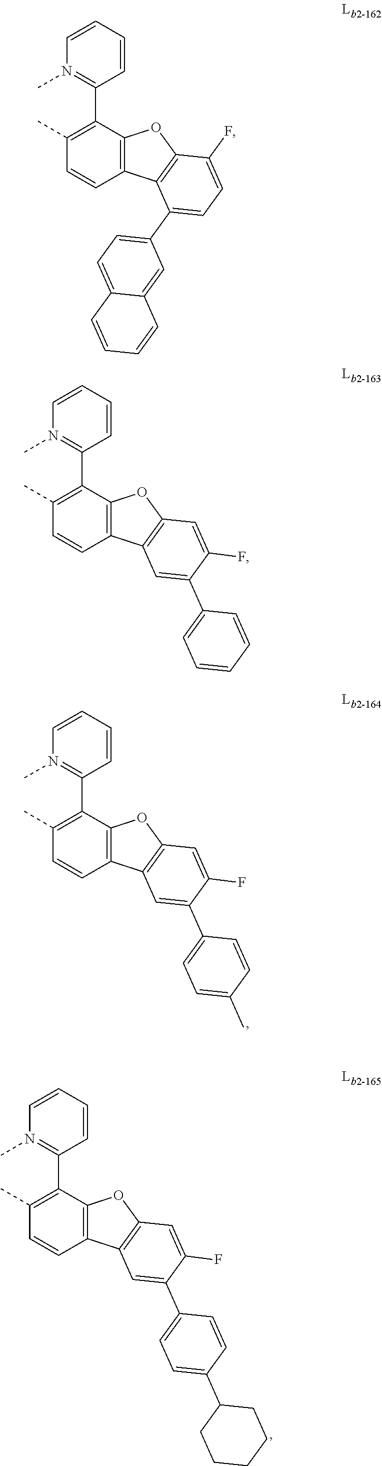 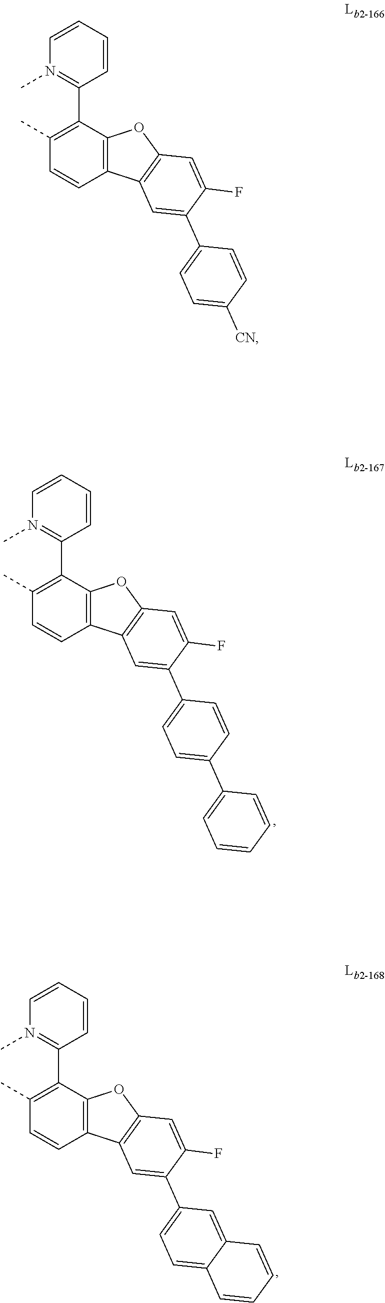 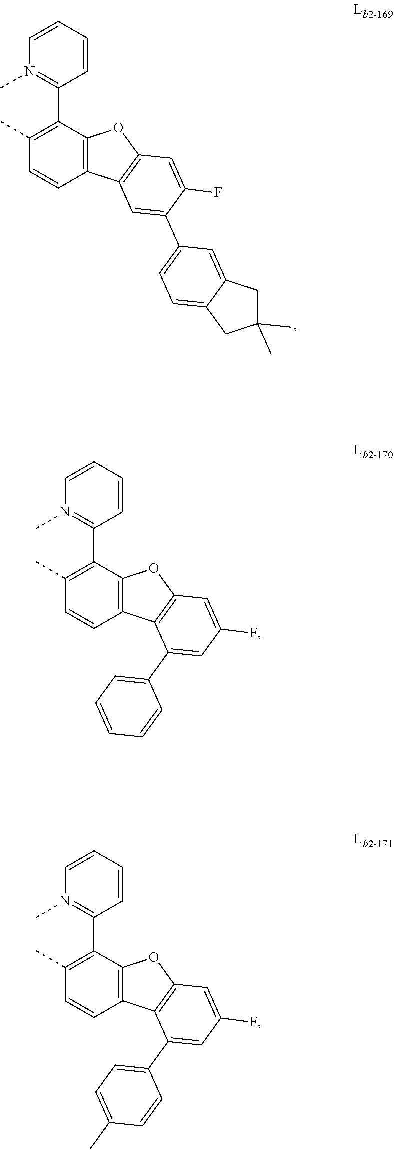 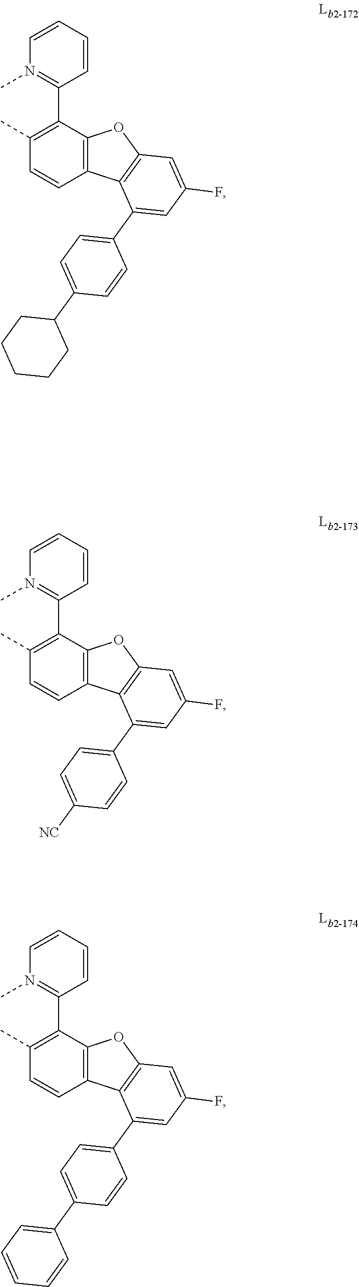 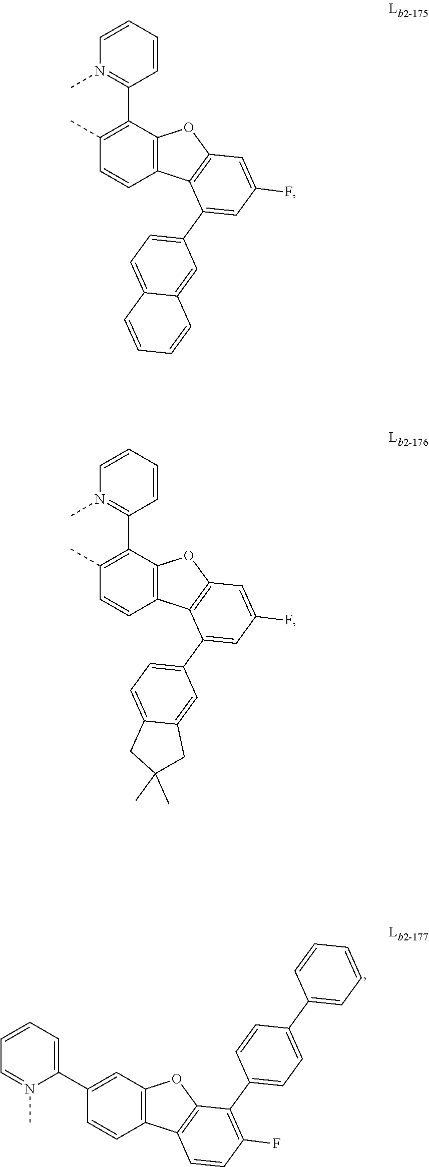 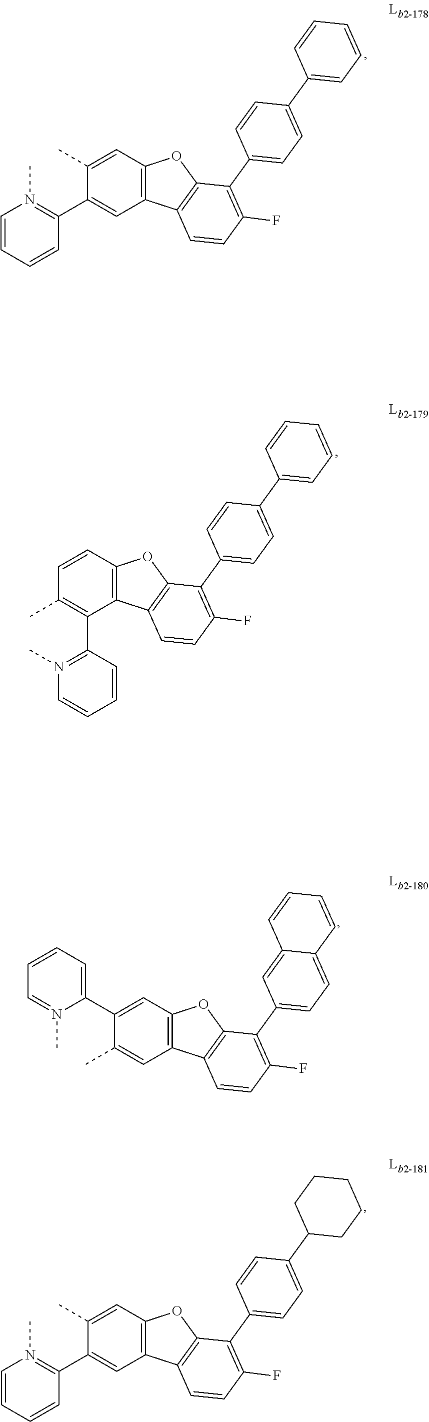 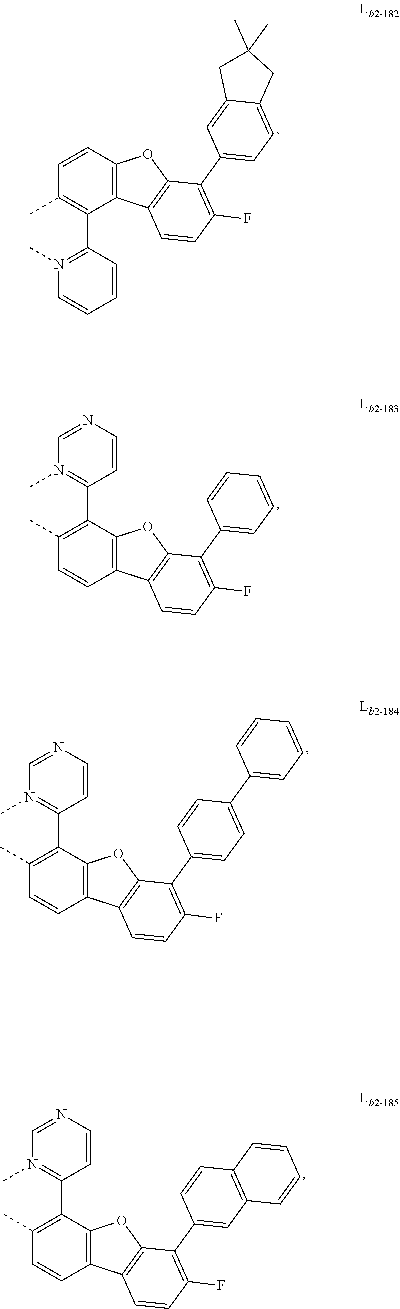 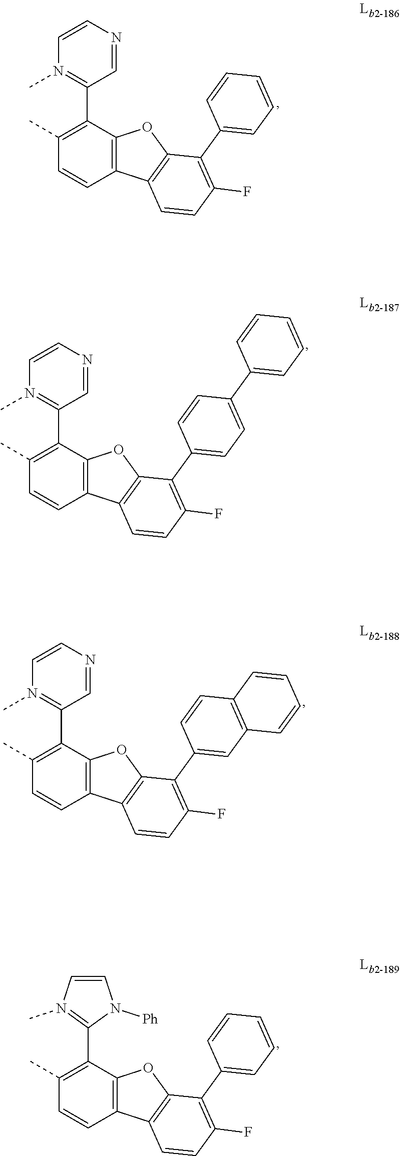 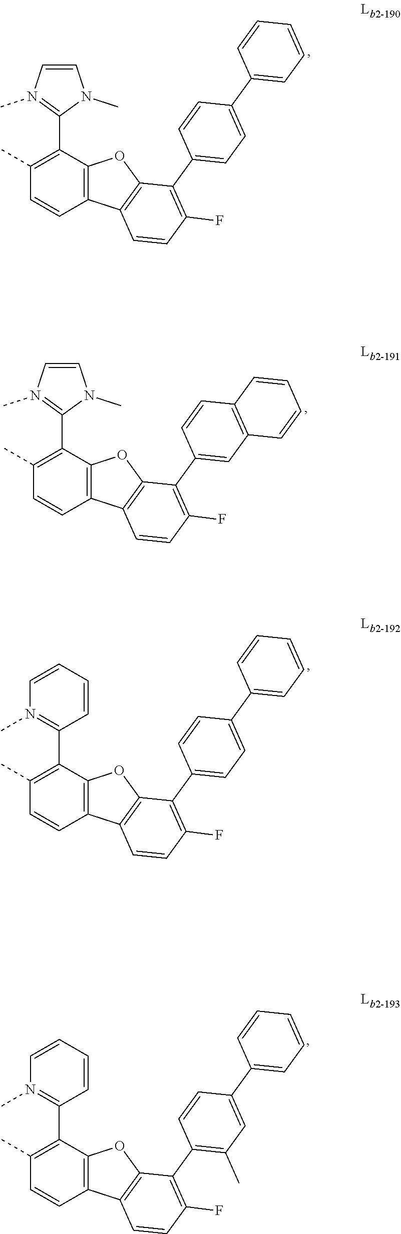 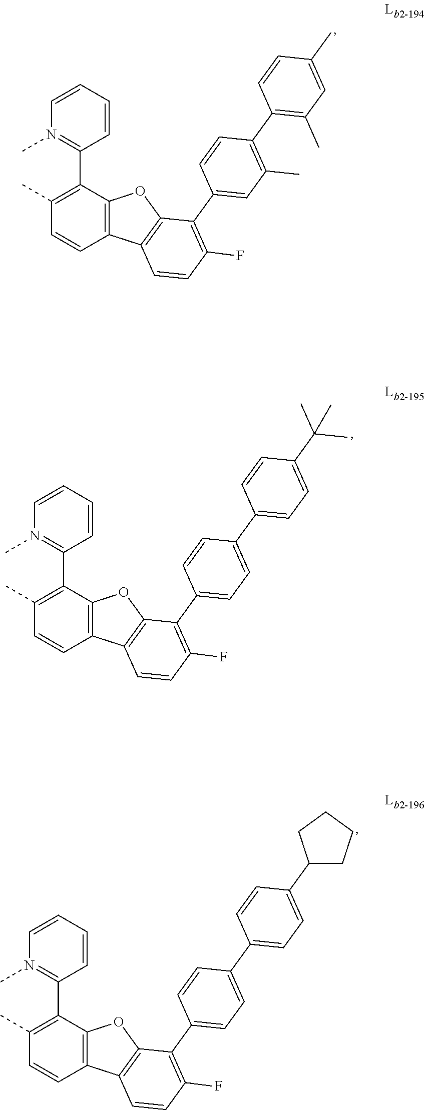 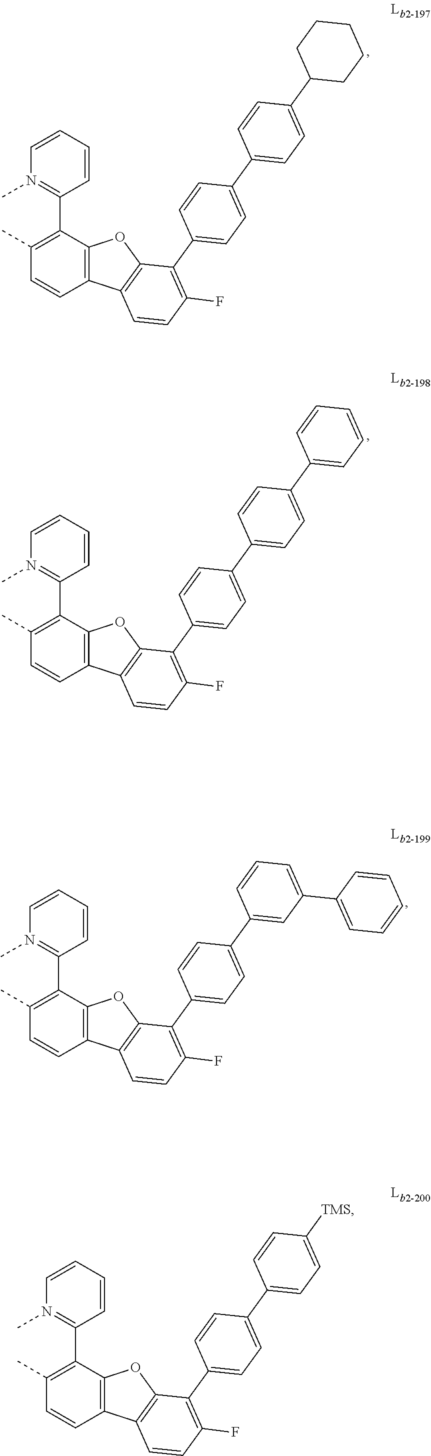 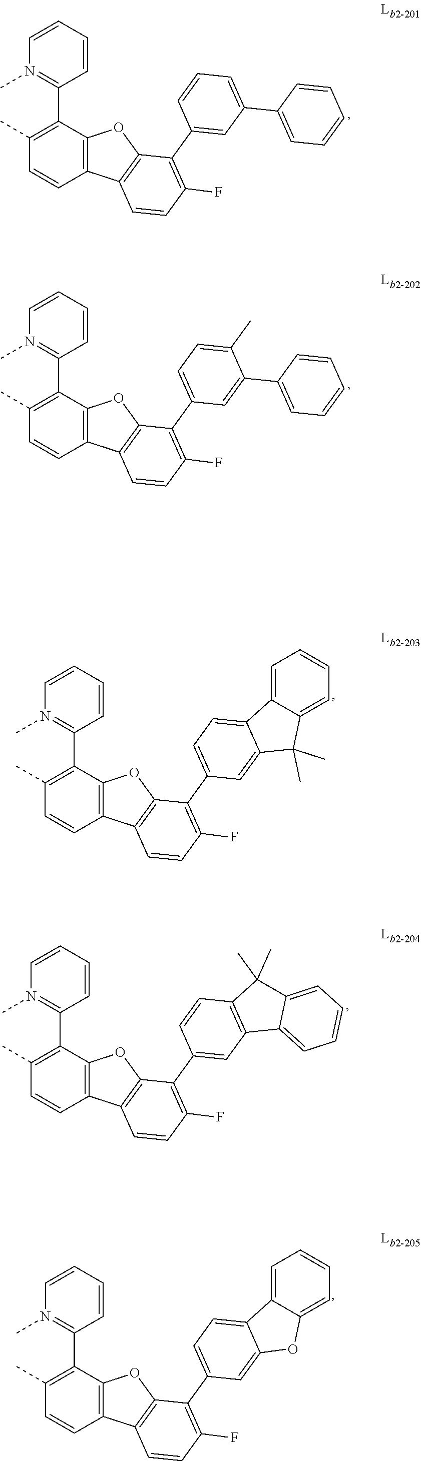 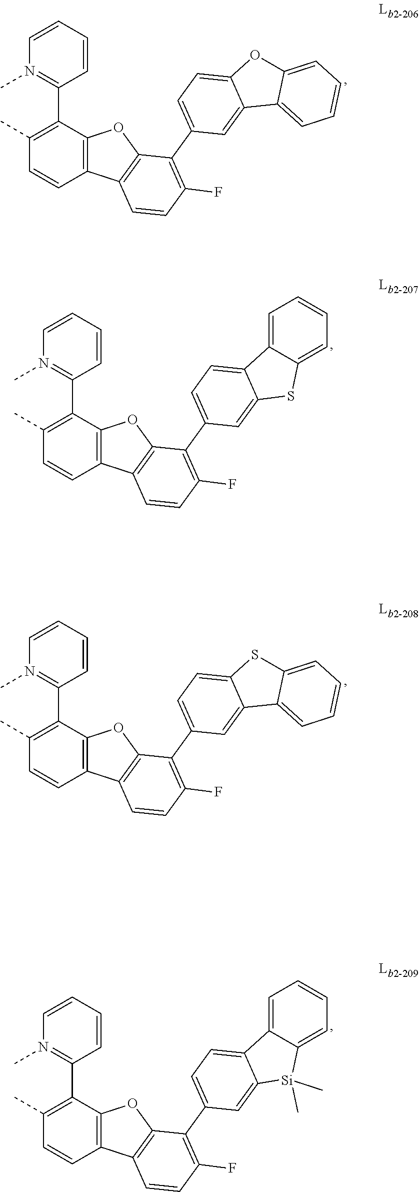 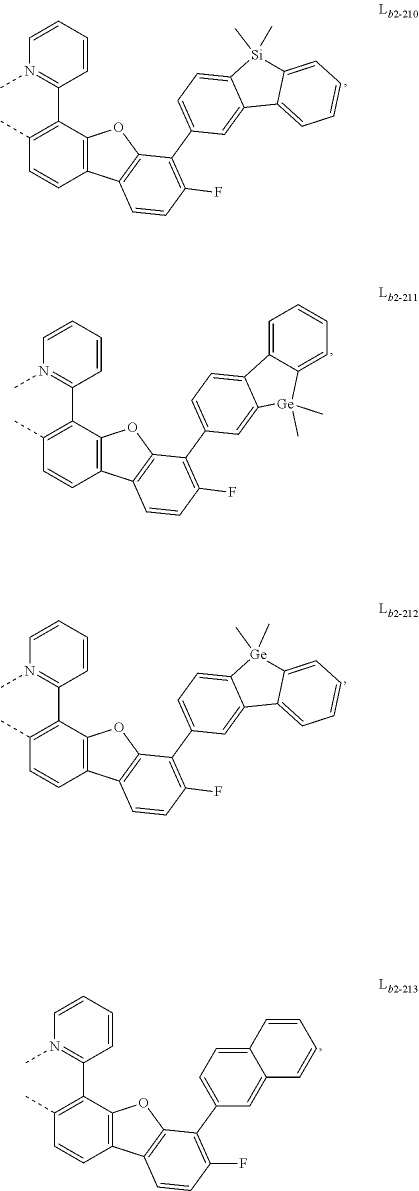 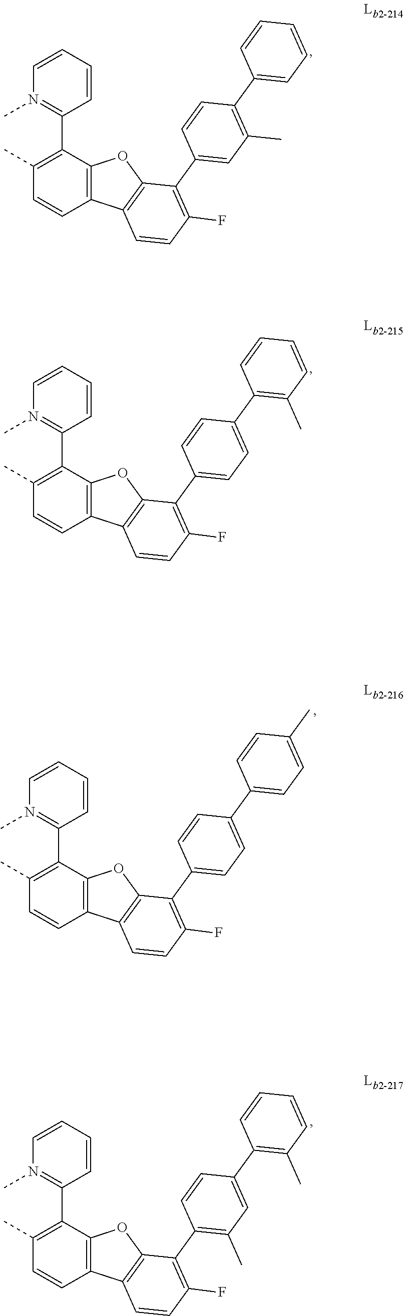 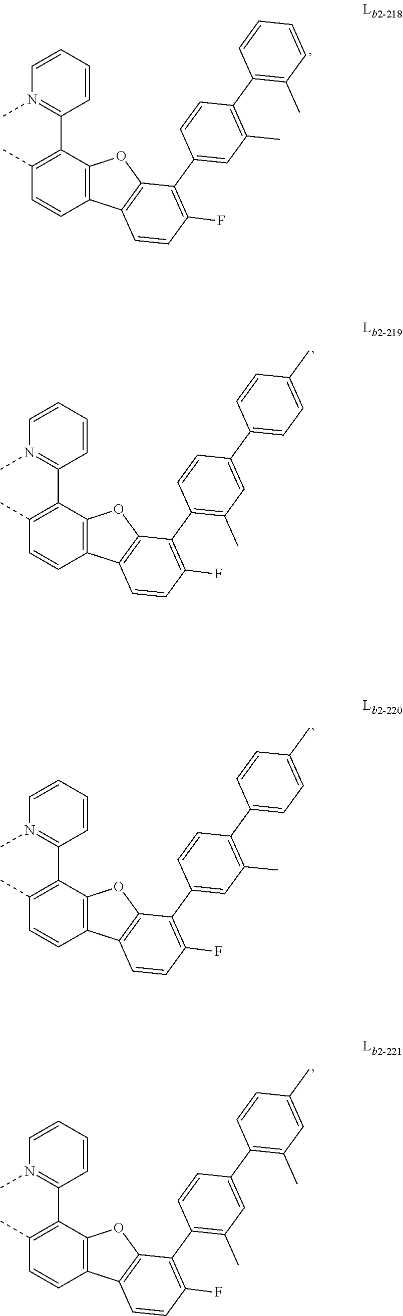 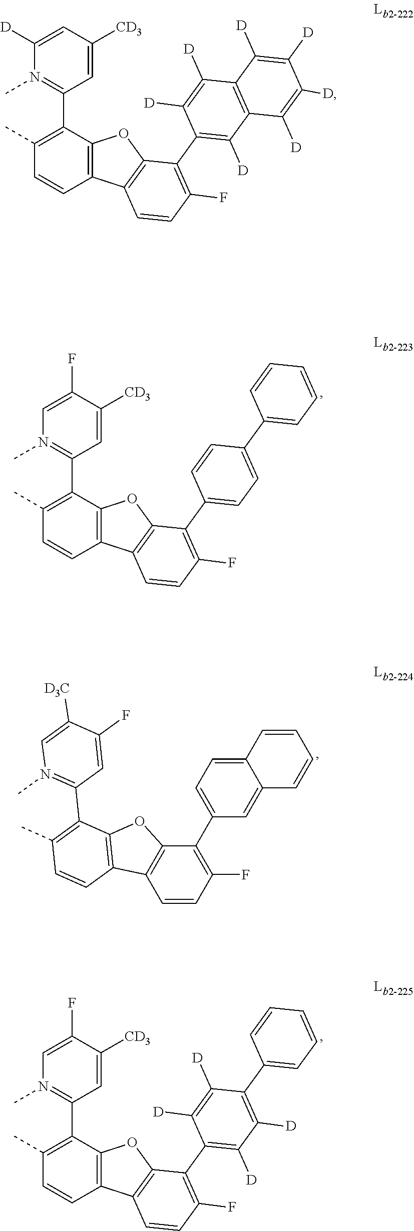 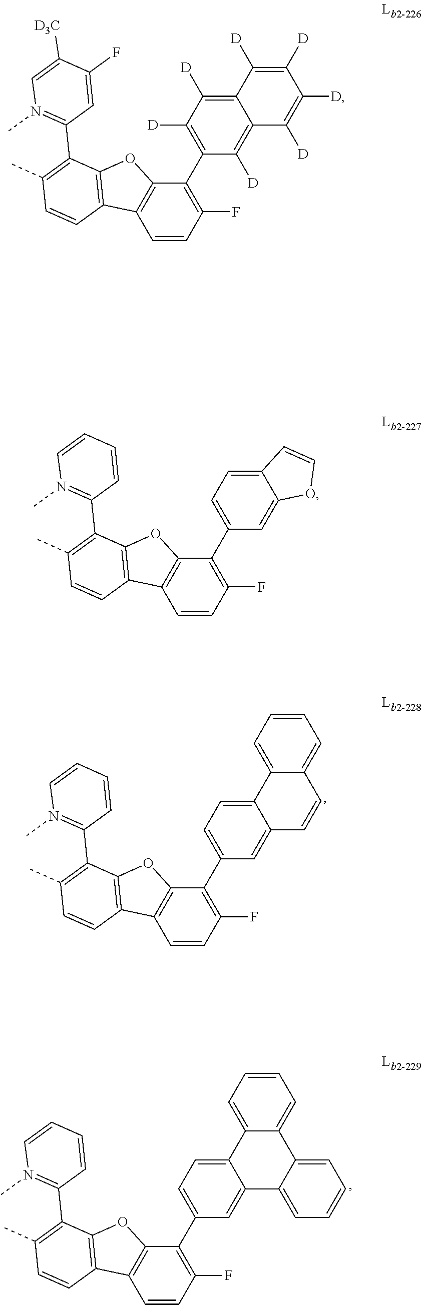 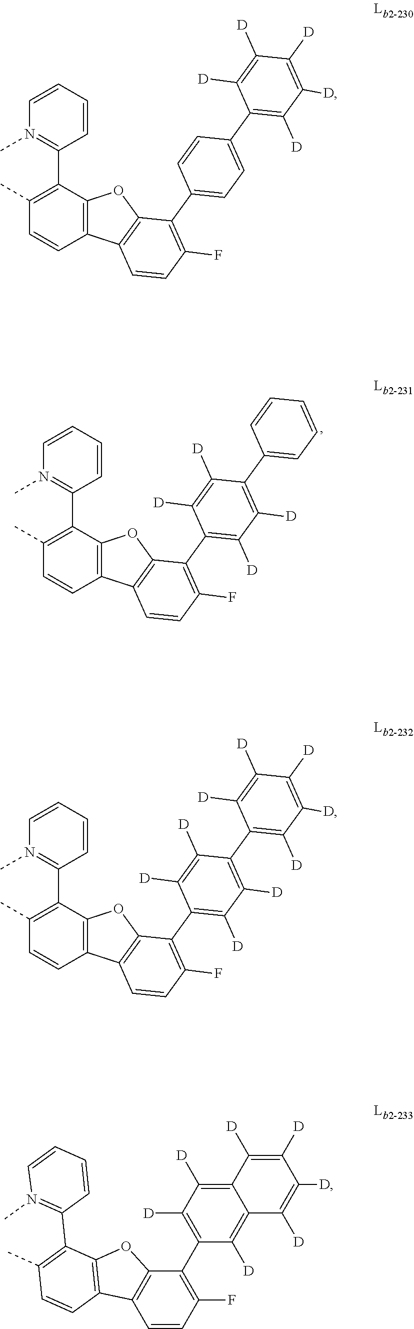 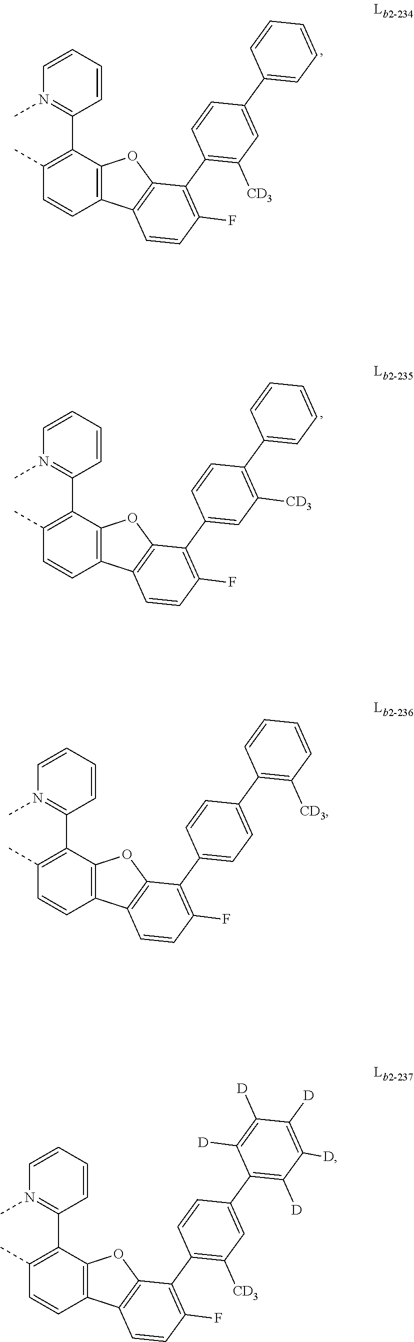 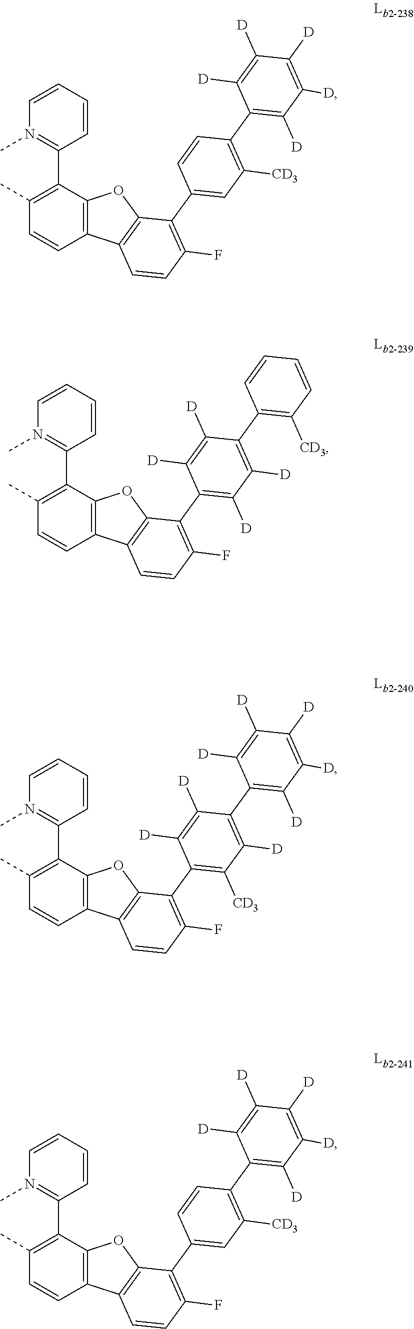 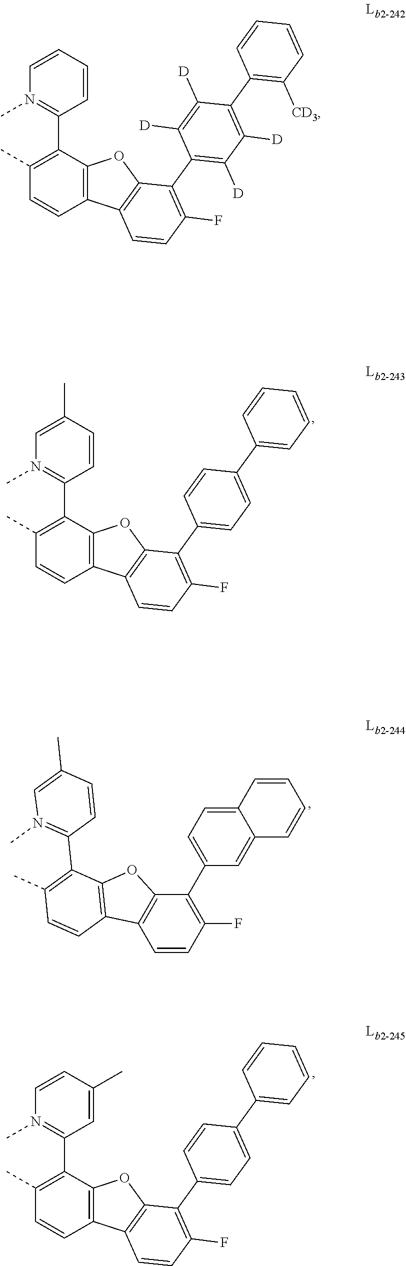 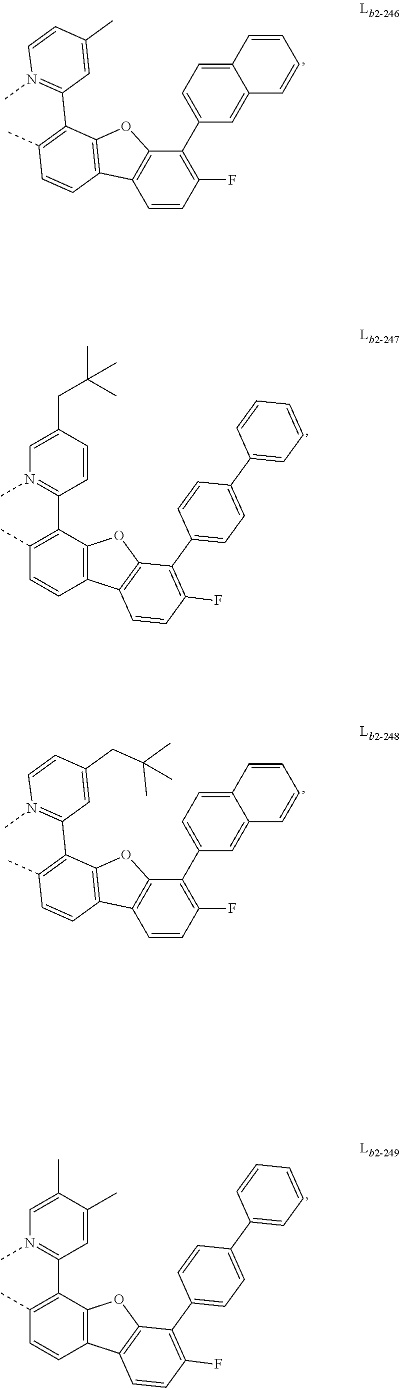 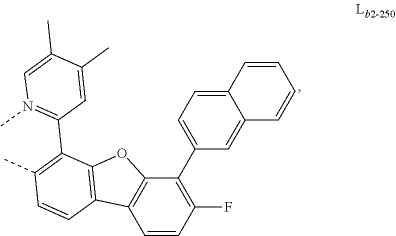 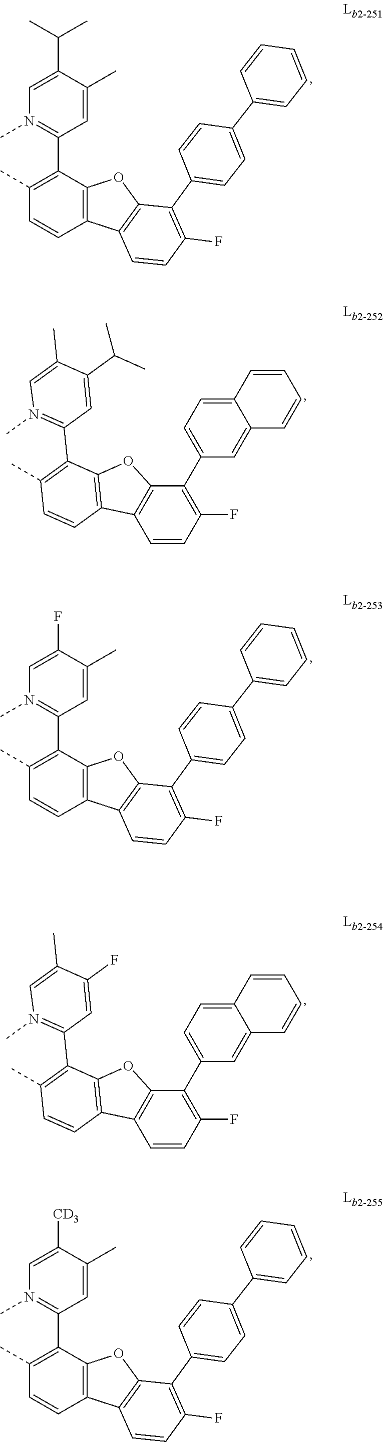 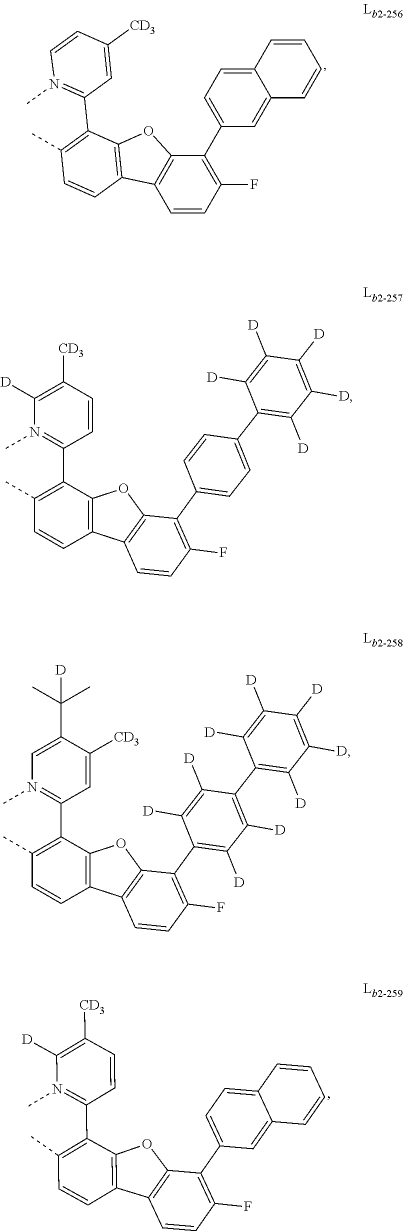 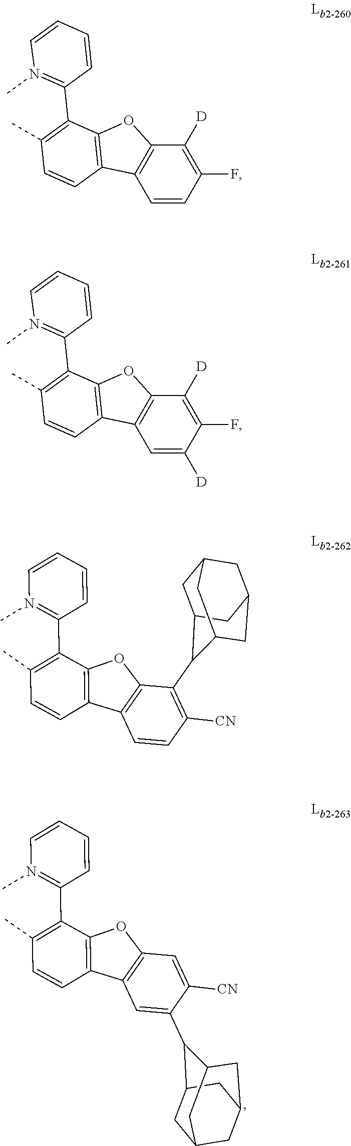 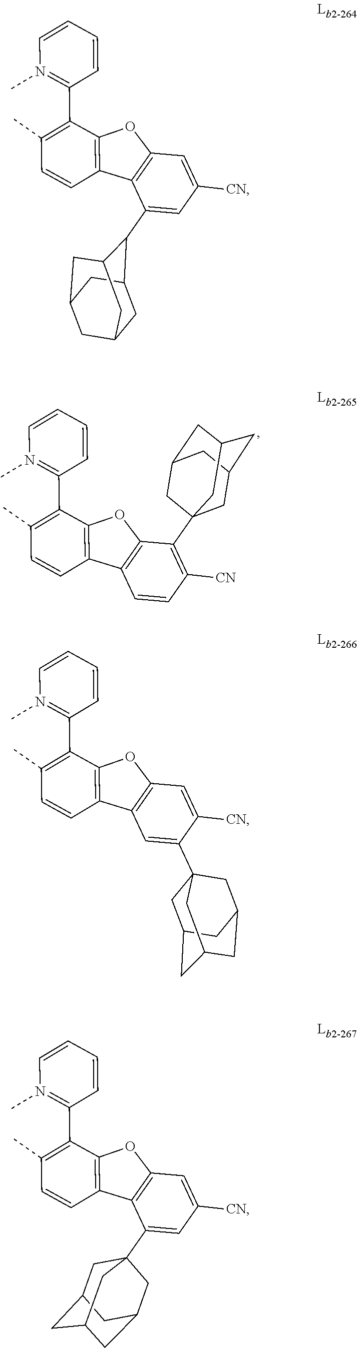 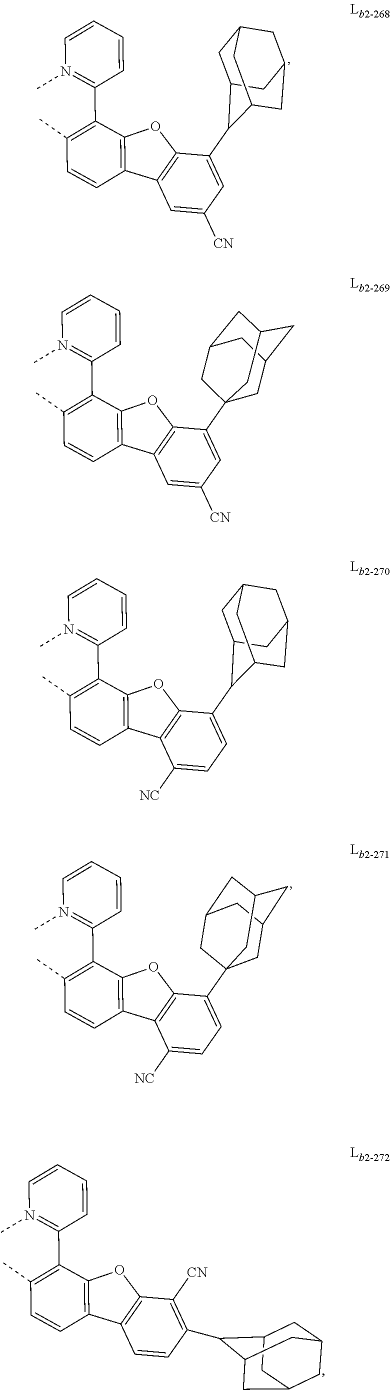 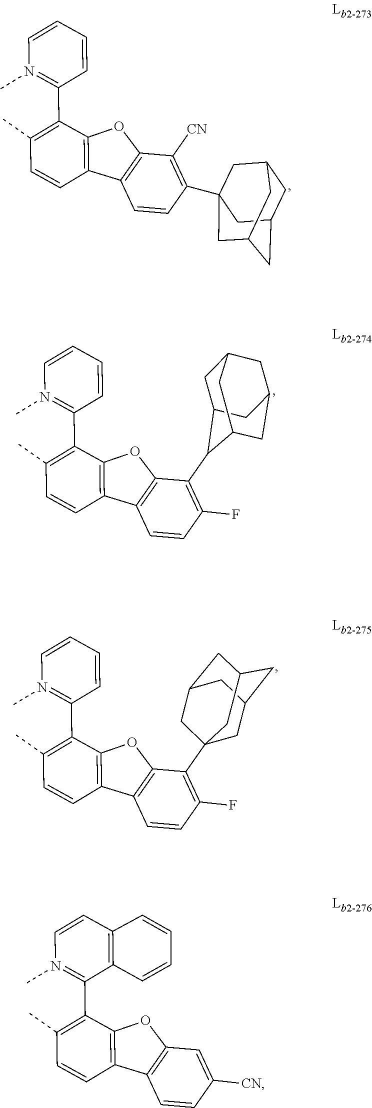 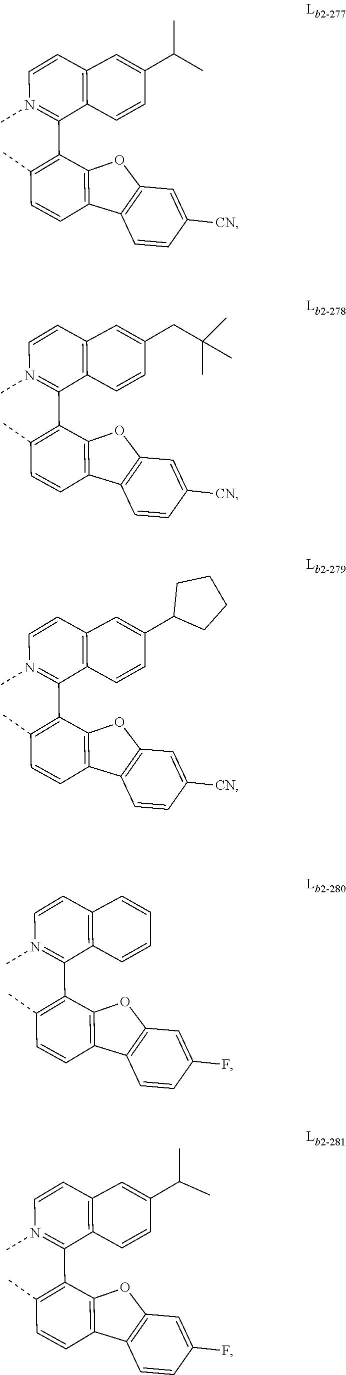 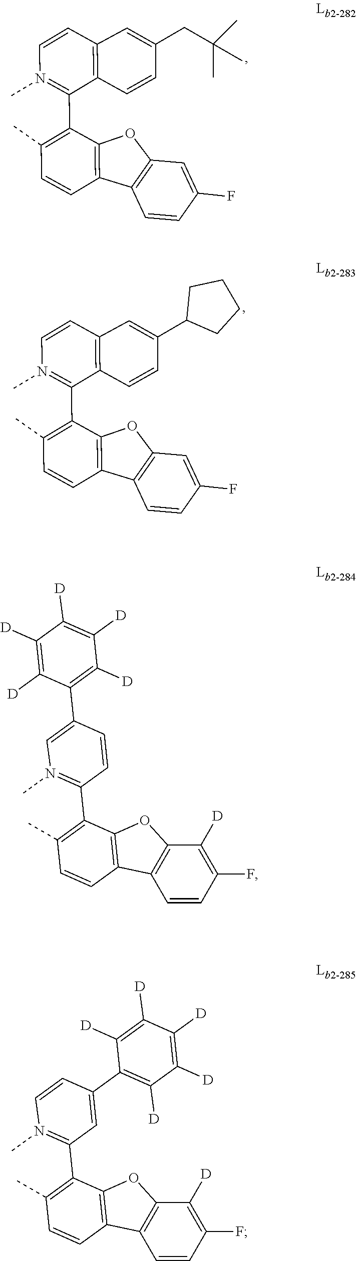 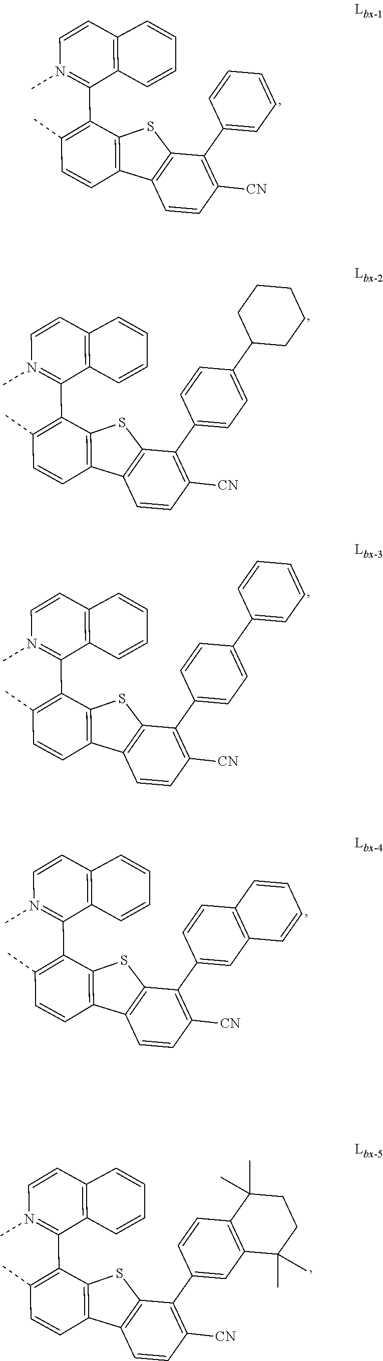 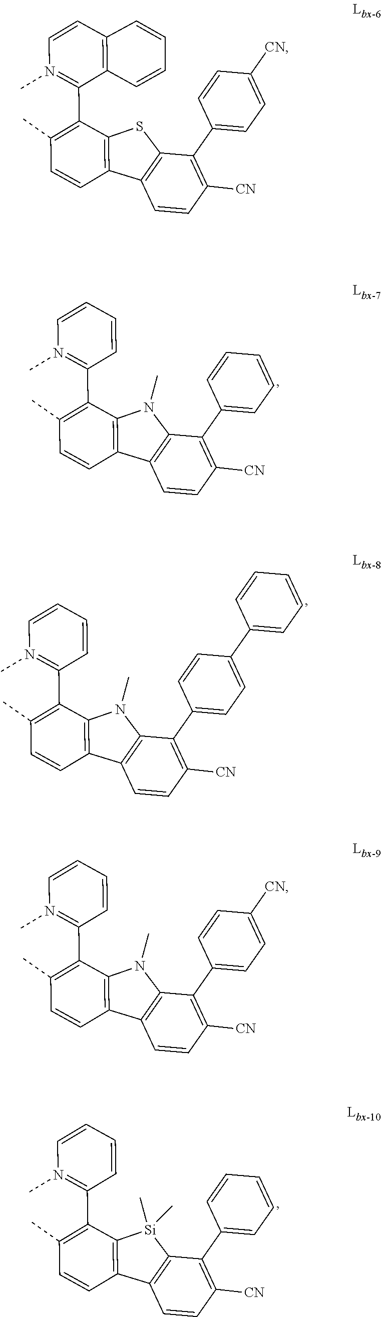 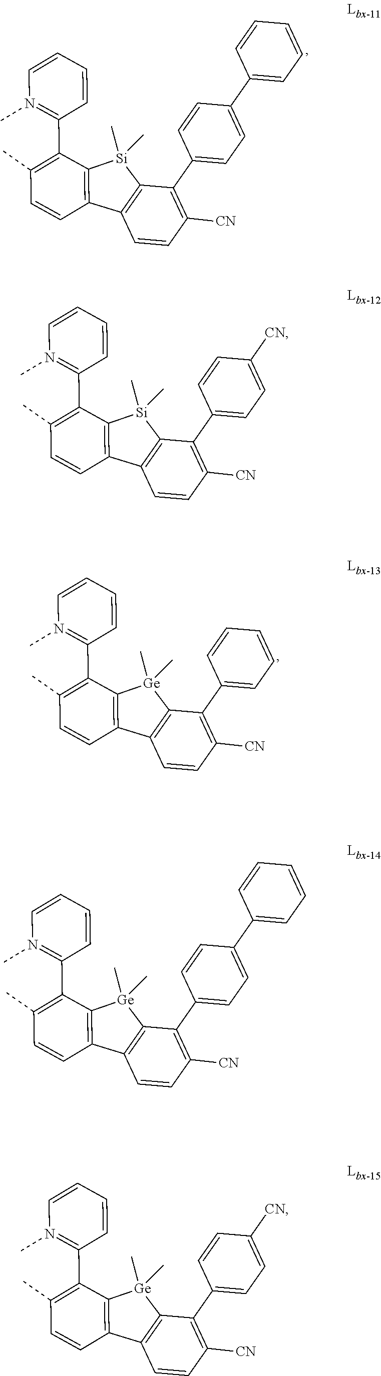 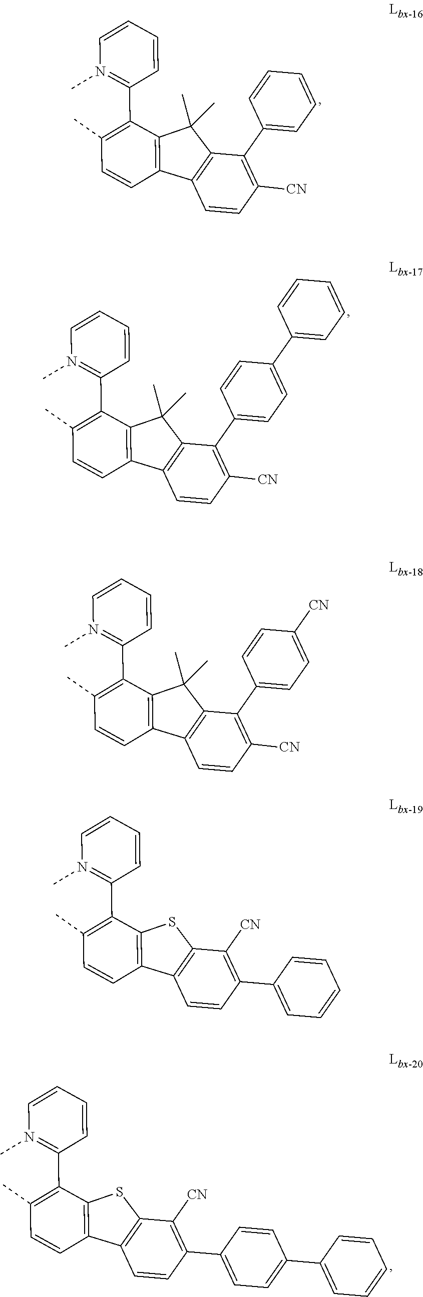 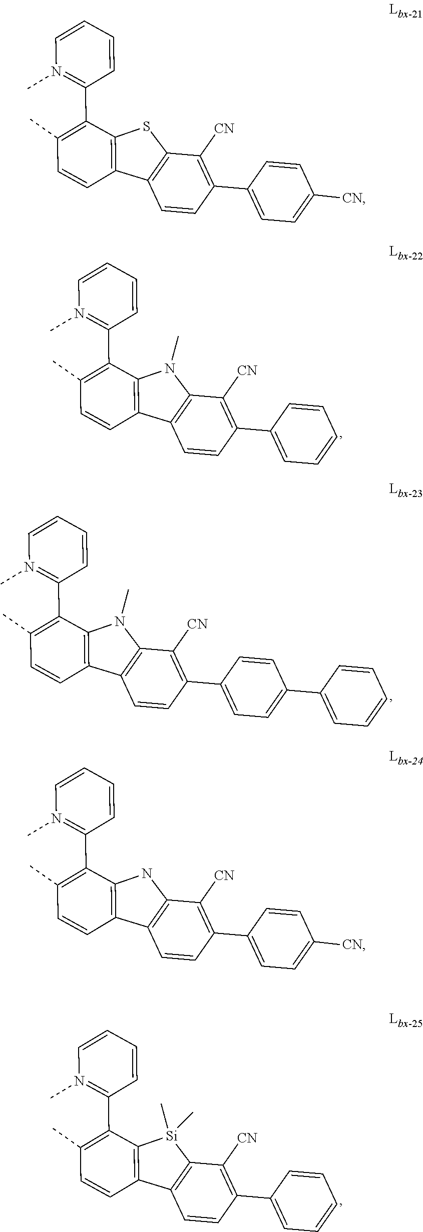 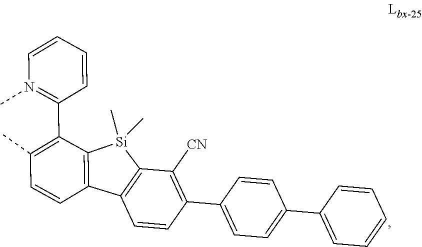 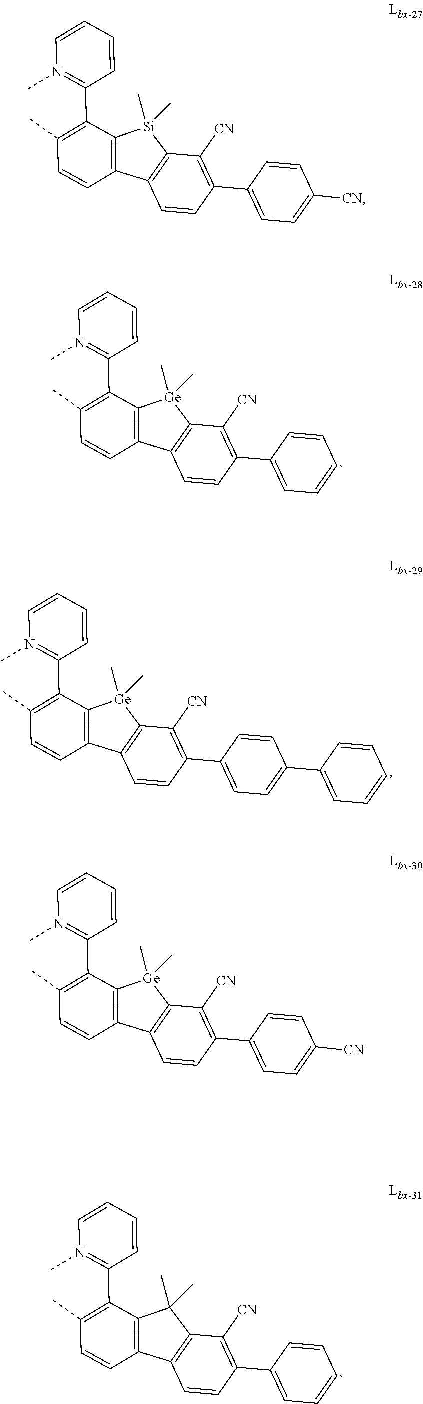 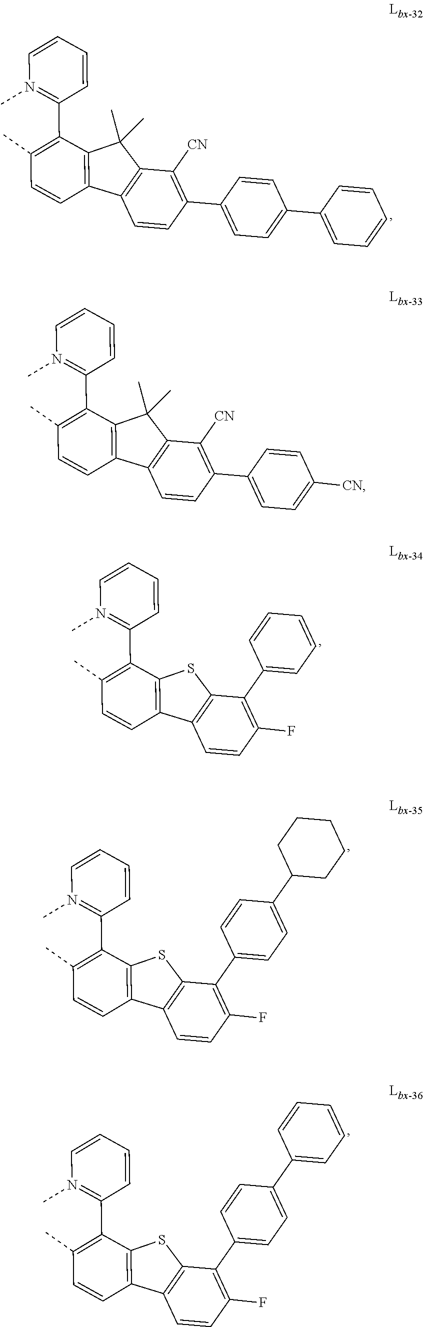 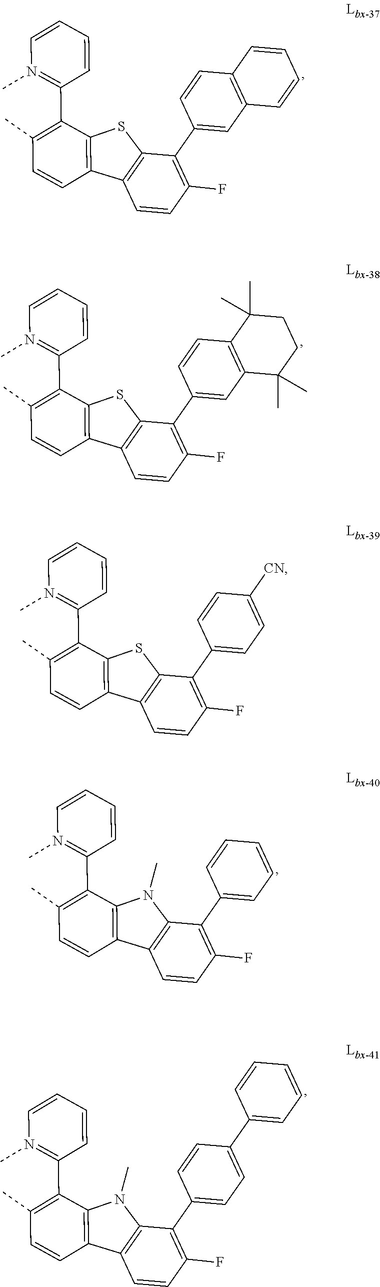 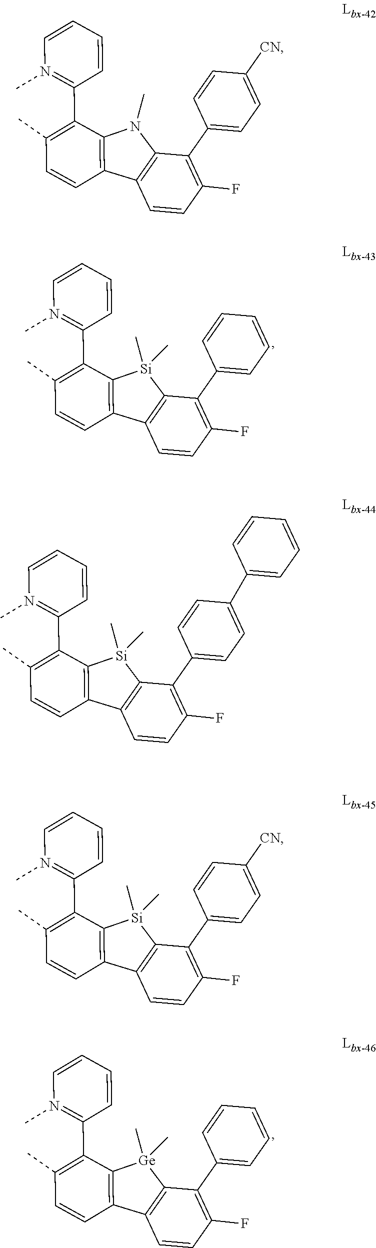 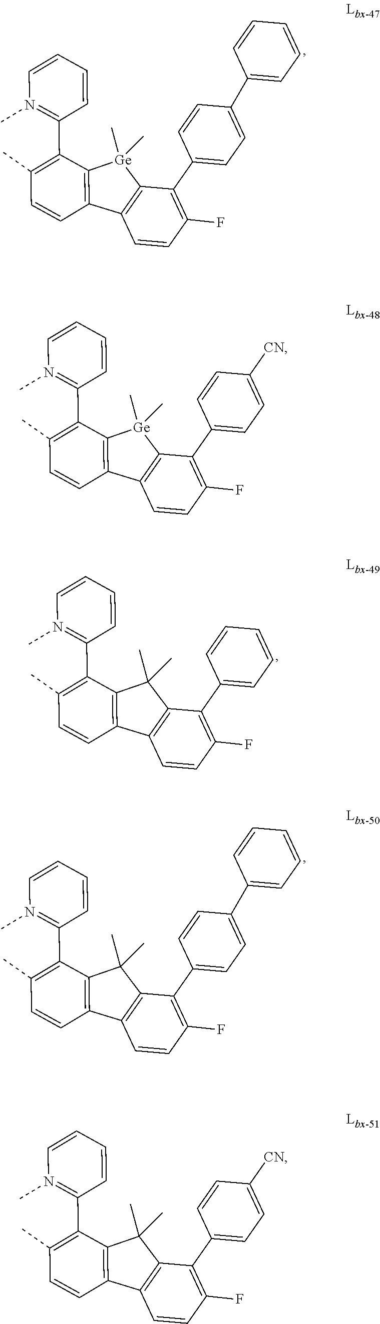 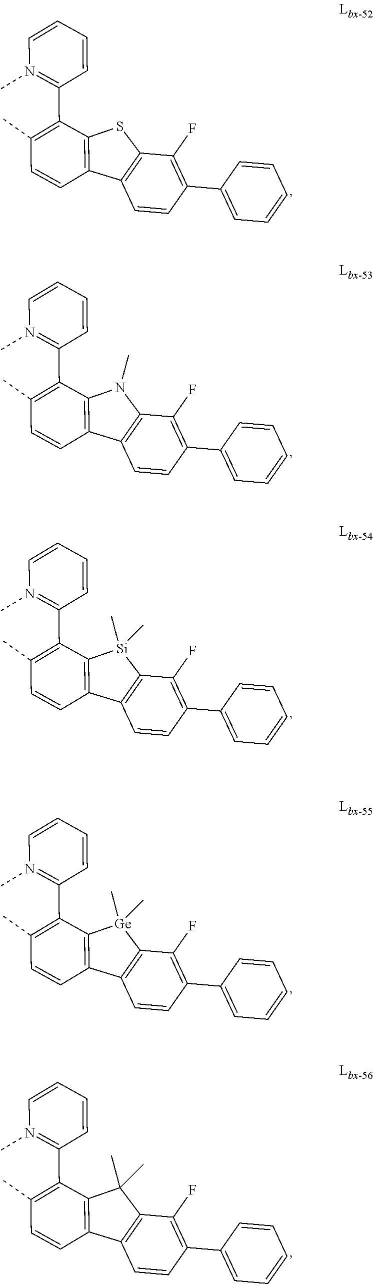 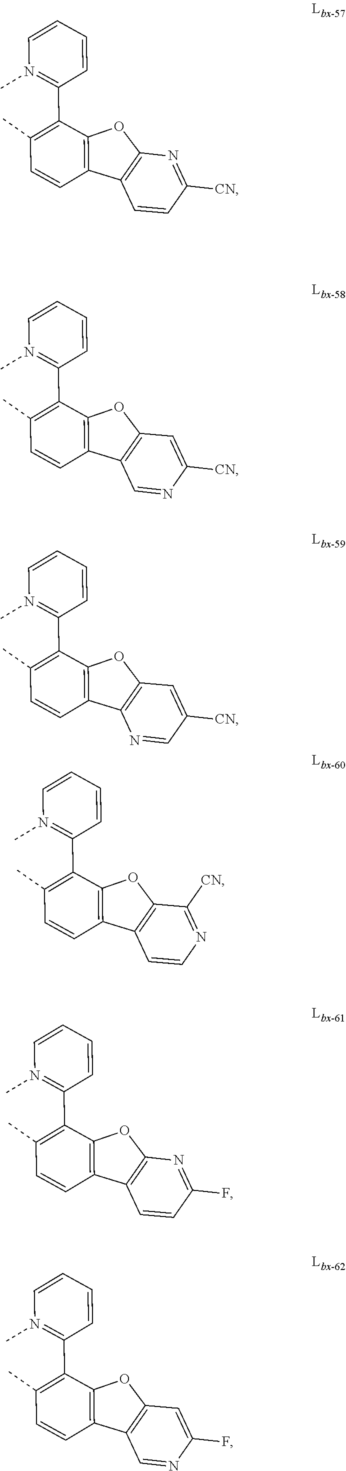 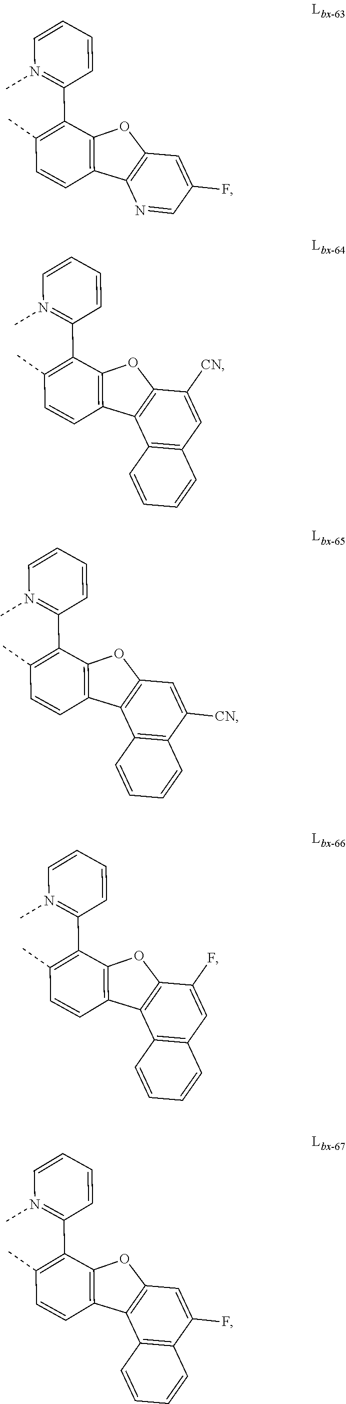 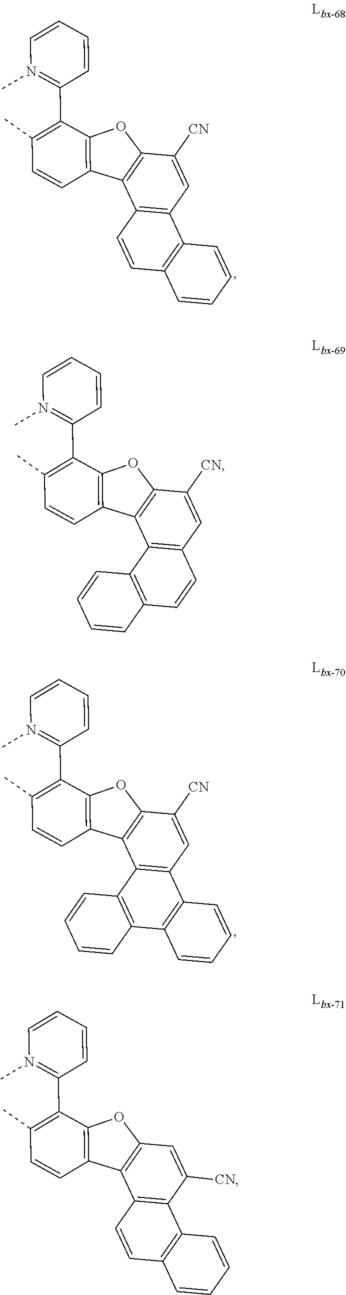 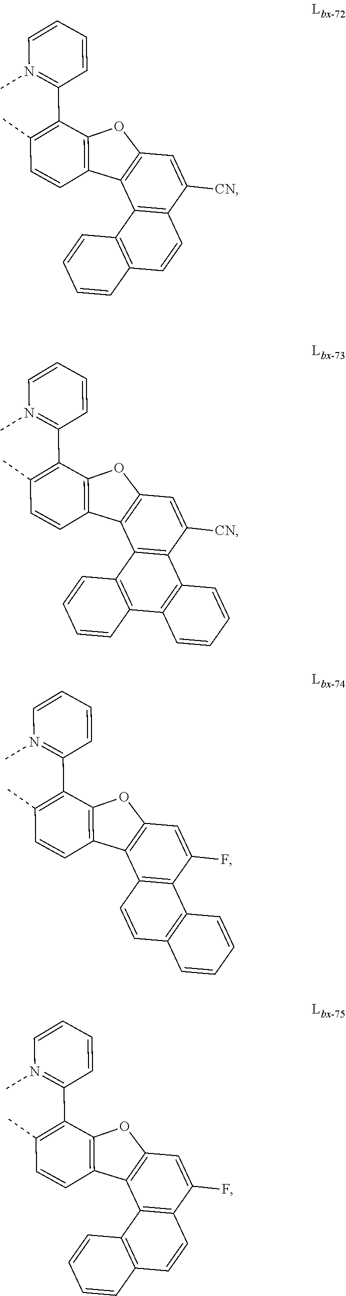 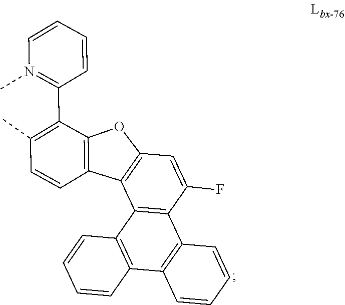
wherein optionally, hydrogen in L_{b1-1} to L_{b1-357}, L_{b2-1} to L_{b2-285} and L_{bx-1} to L_{bx-76} can be partially or fully substituted with deuterium.

19. The metal complex according to claim 1, wherein L_{c} is, at each occurrence identically or differently, selected from the group consisting of the following:

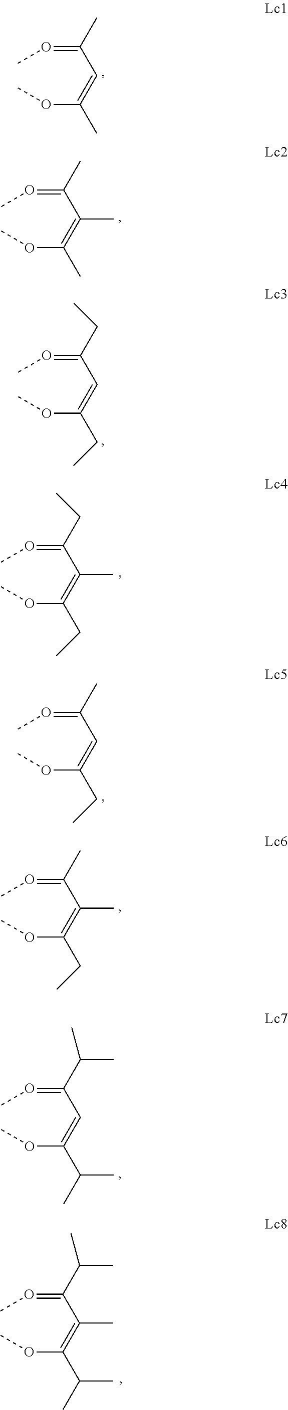

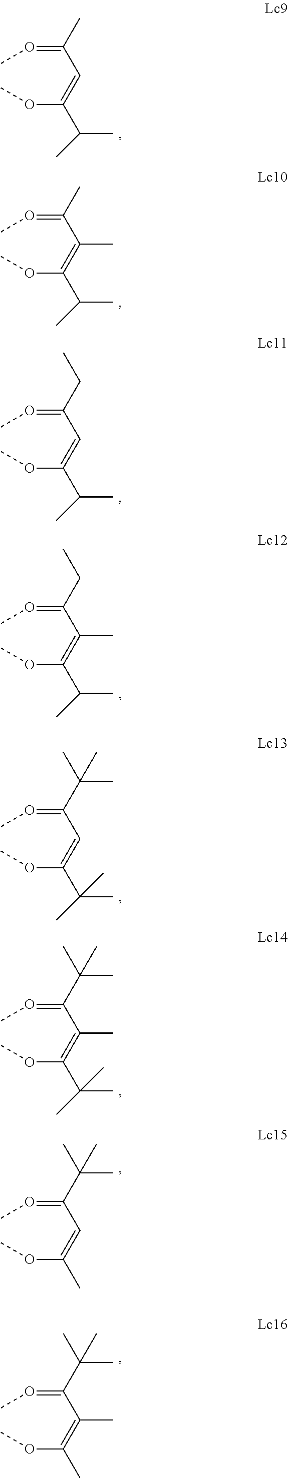

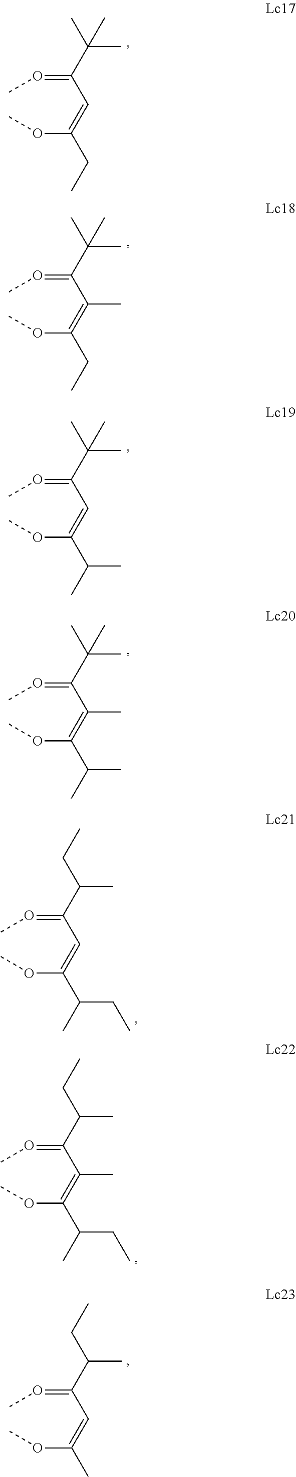

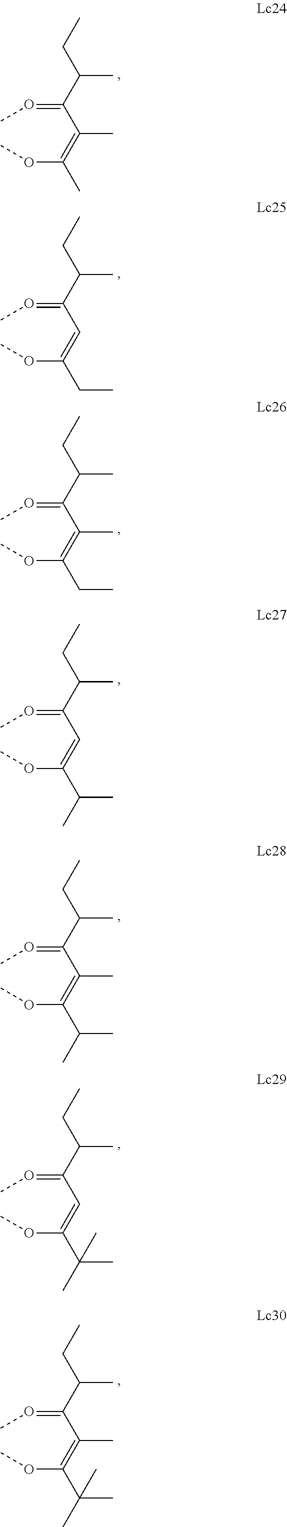

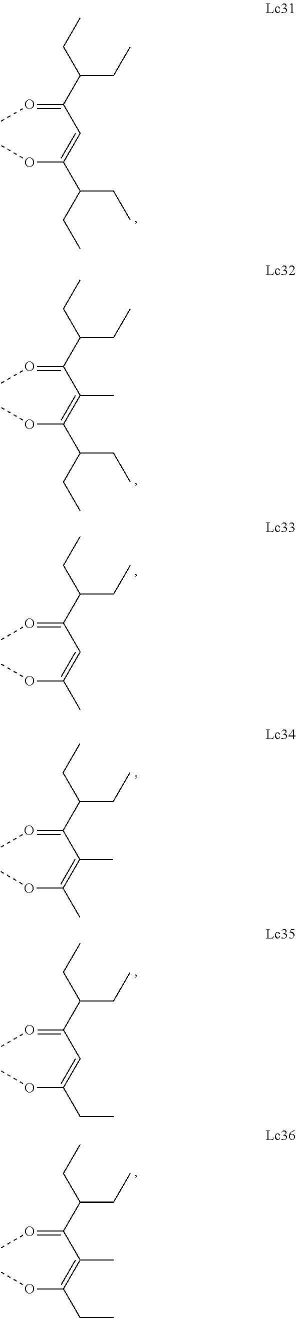

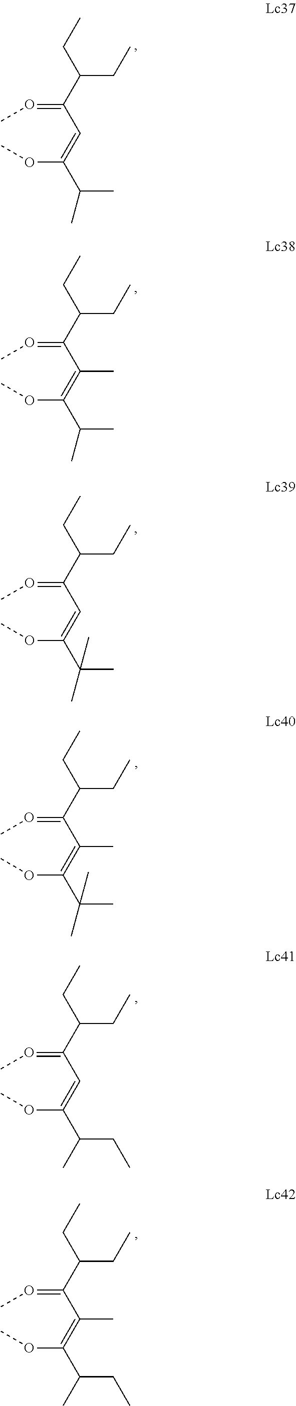

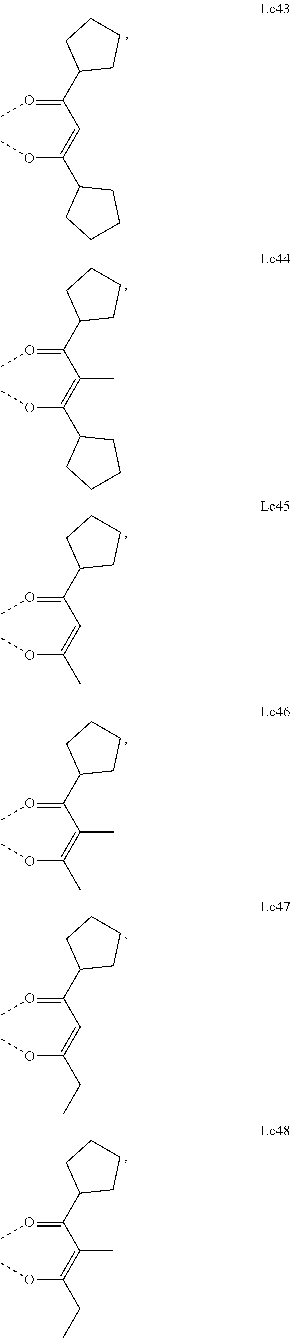

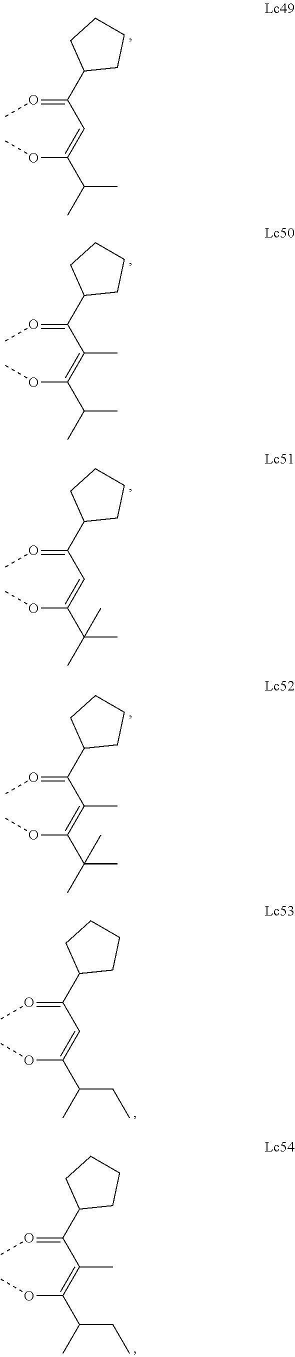

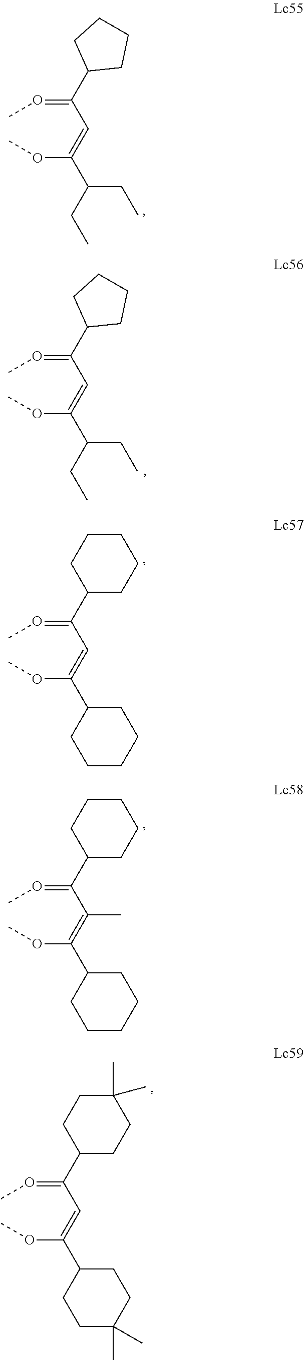

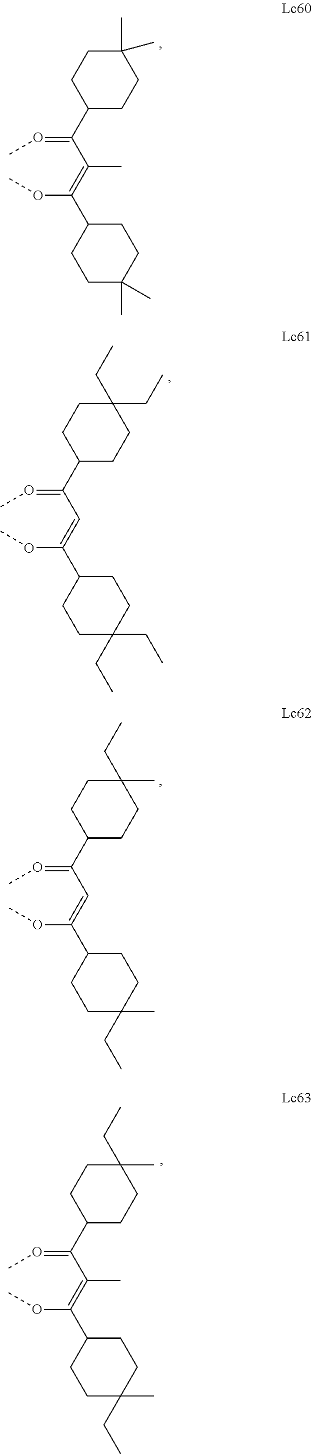

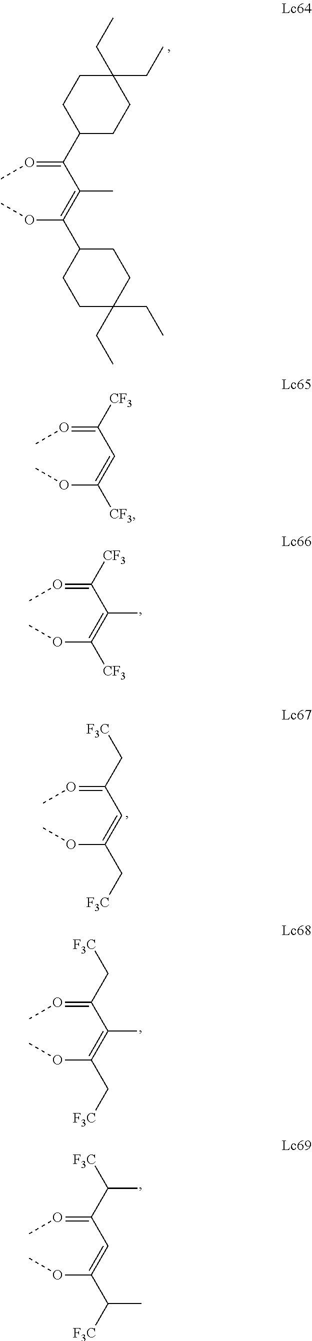

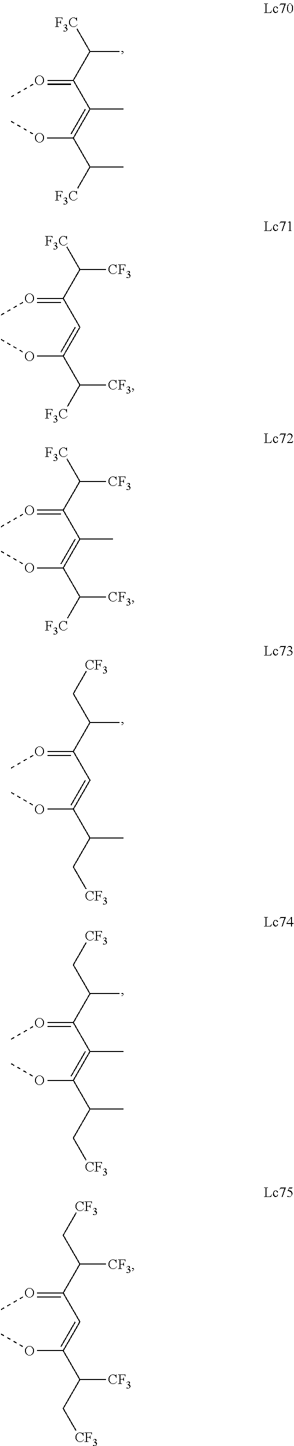

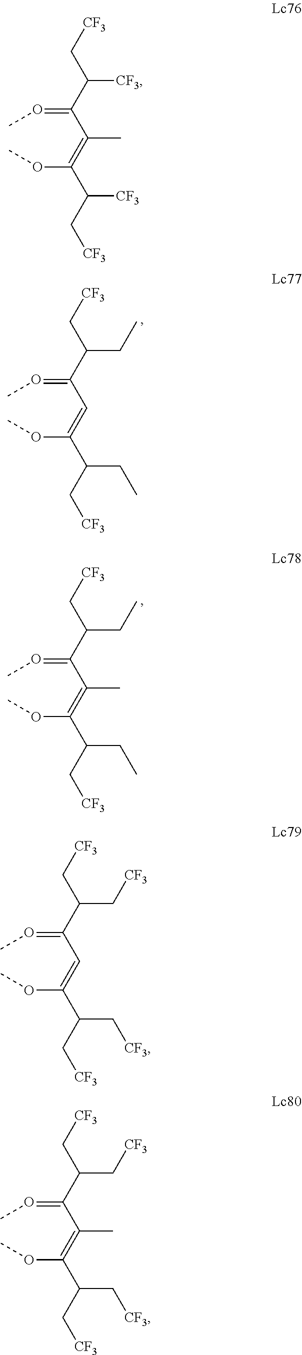

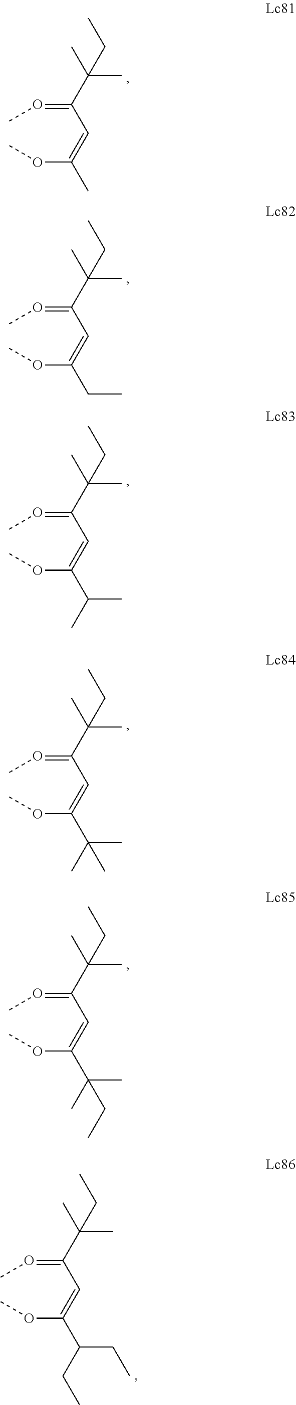

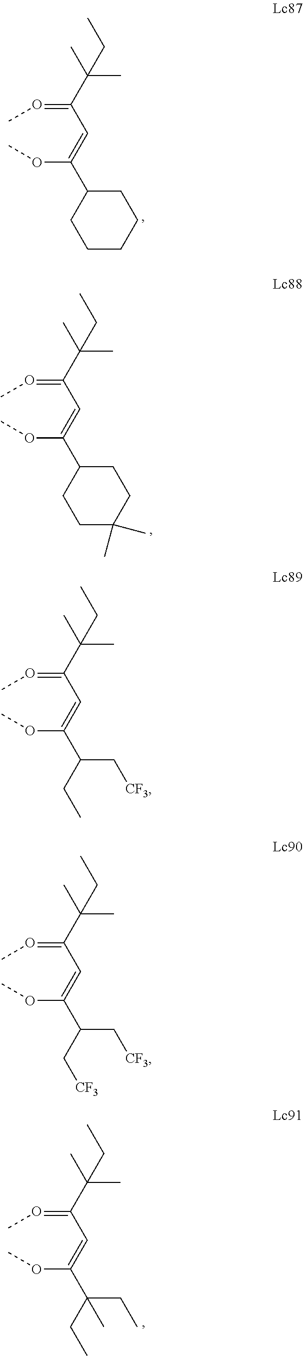

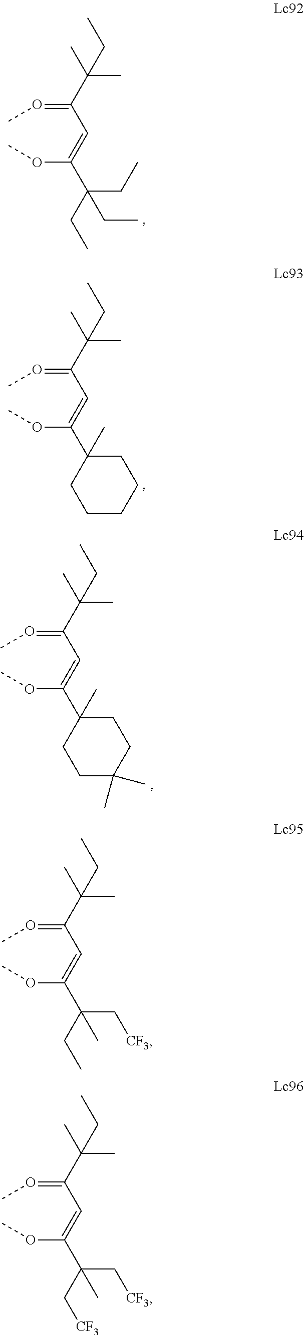

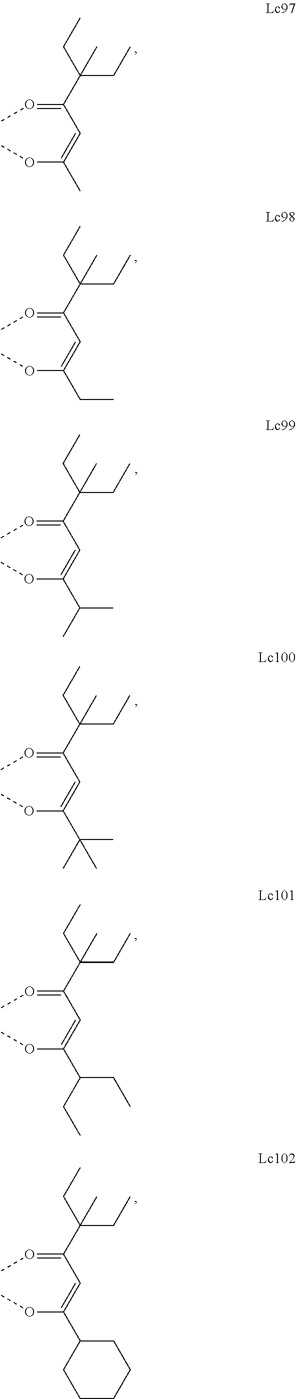

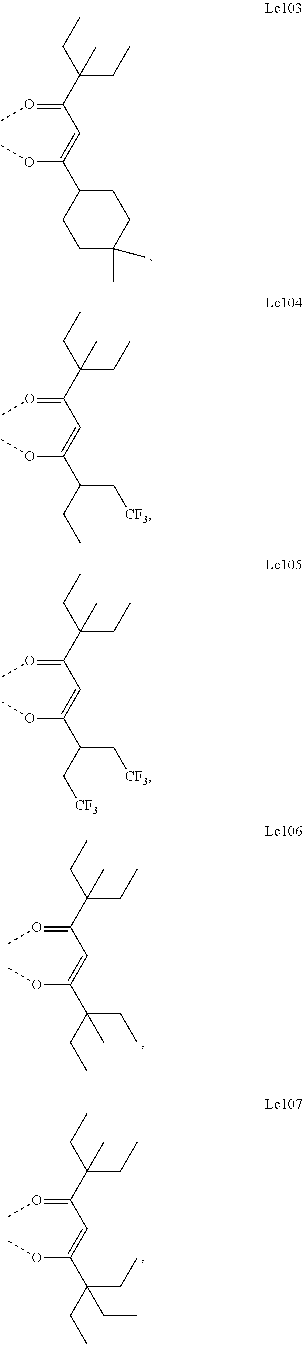

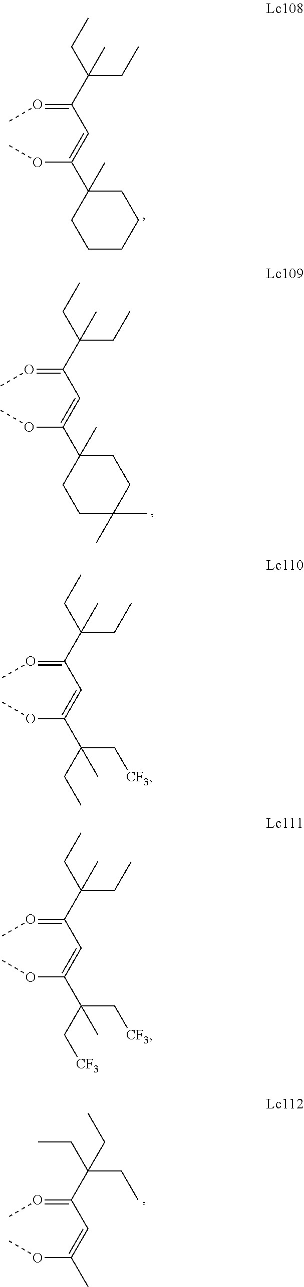

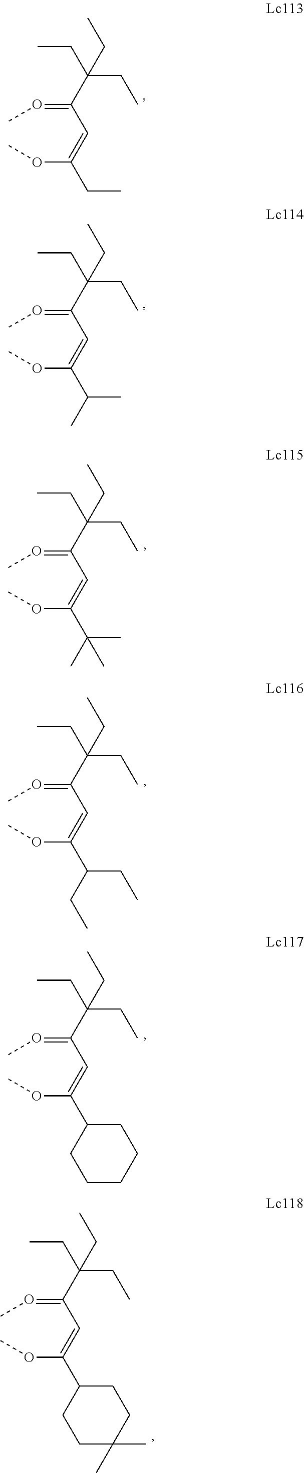

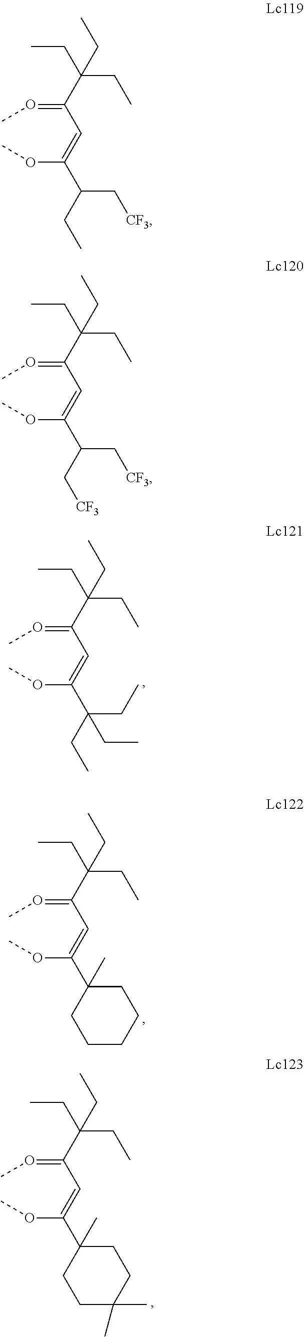

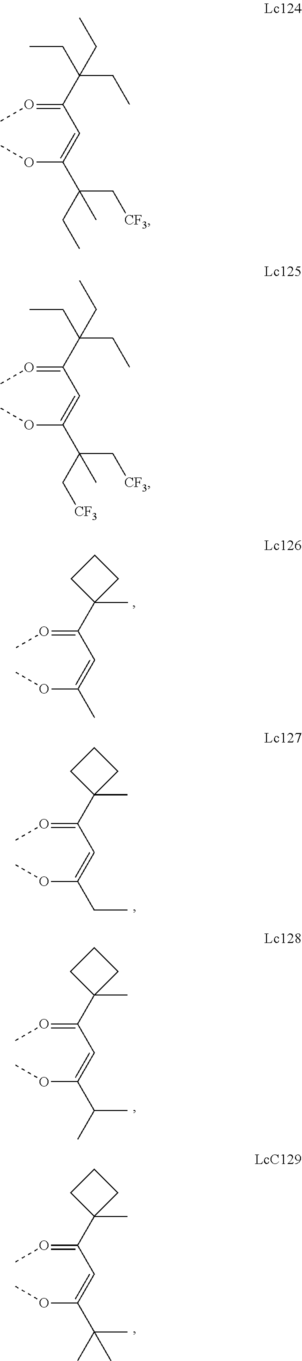

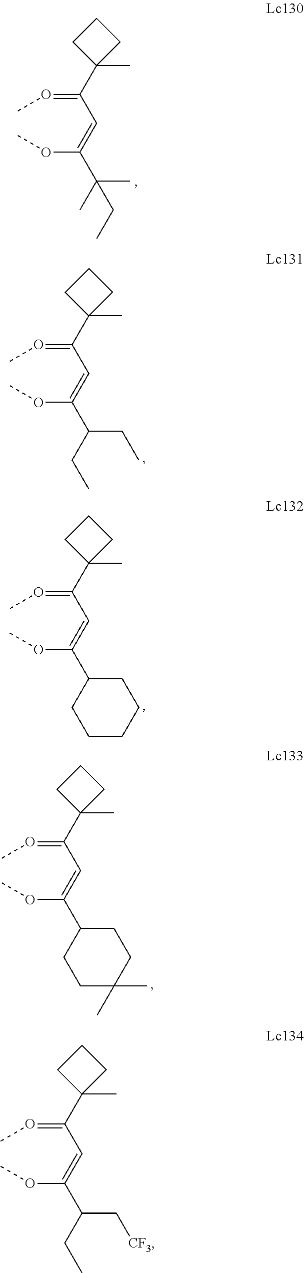

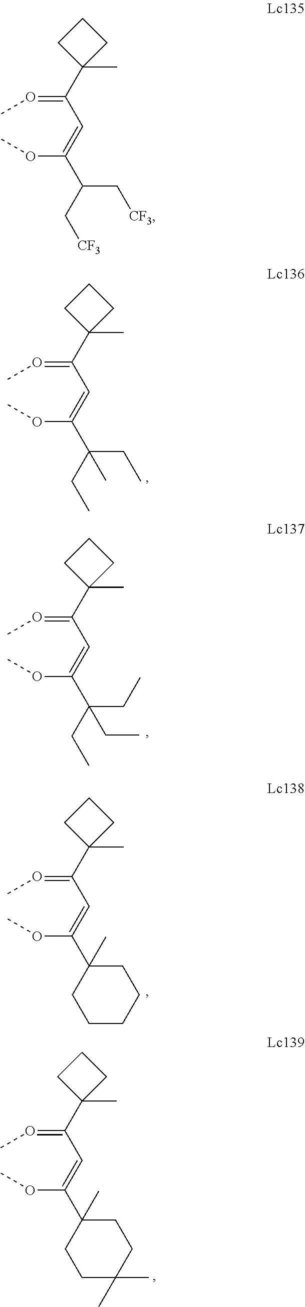

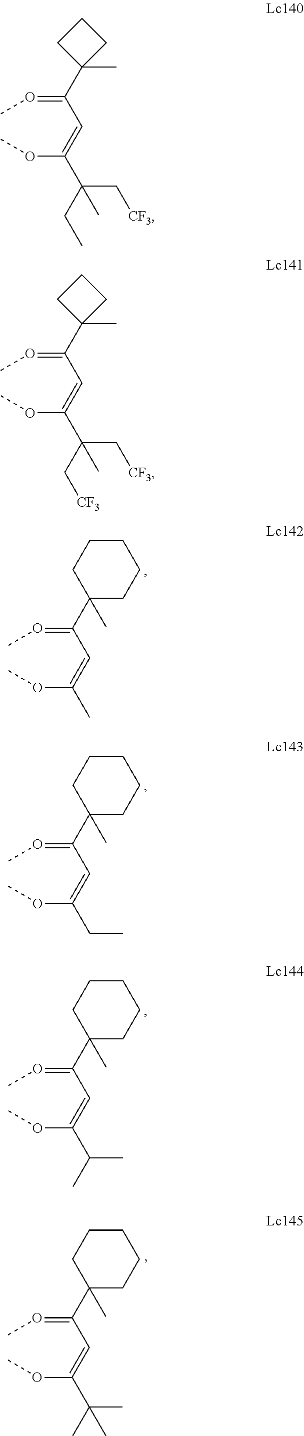

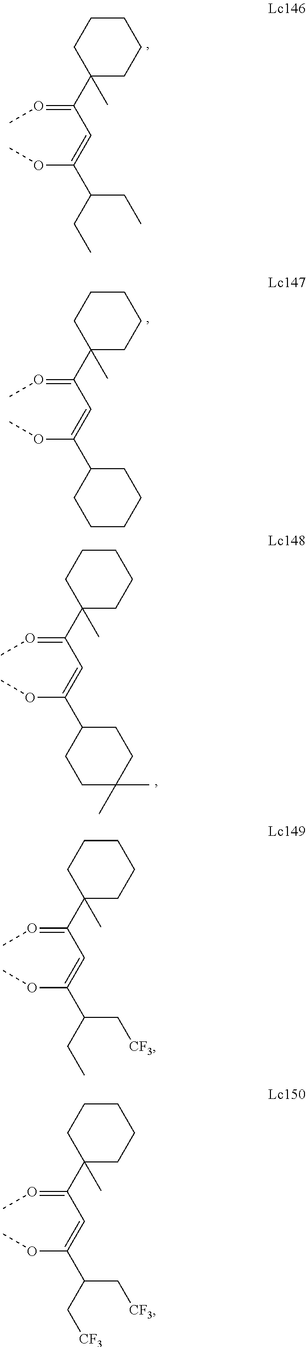

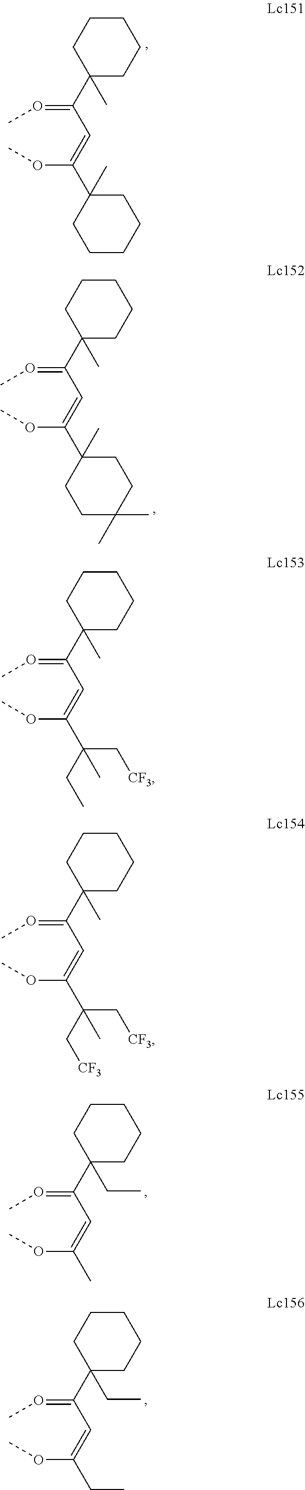

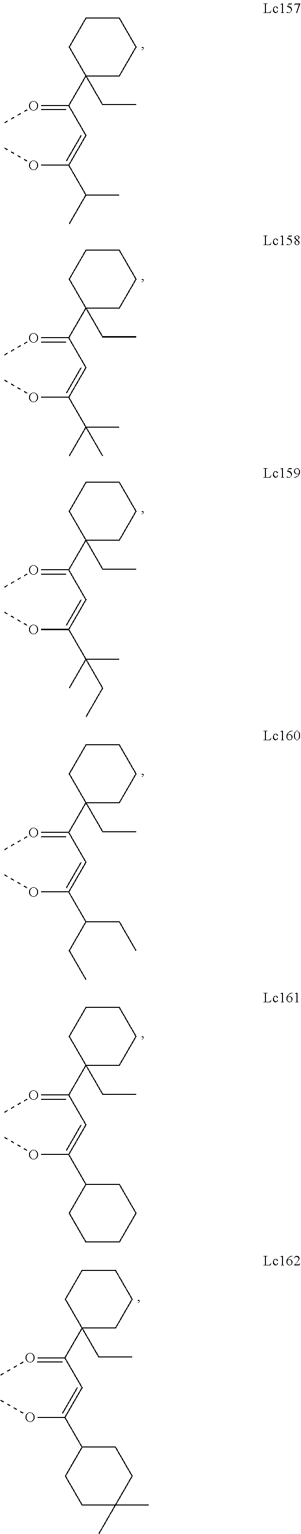

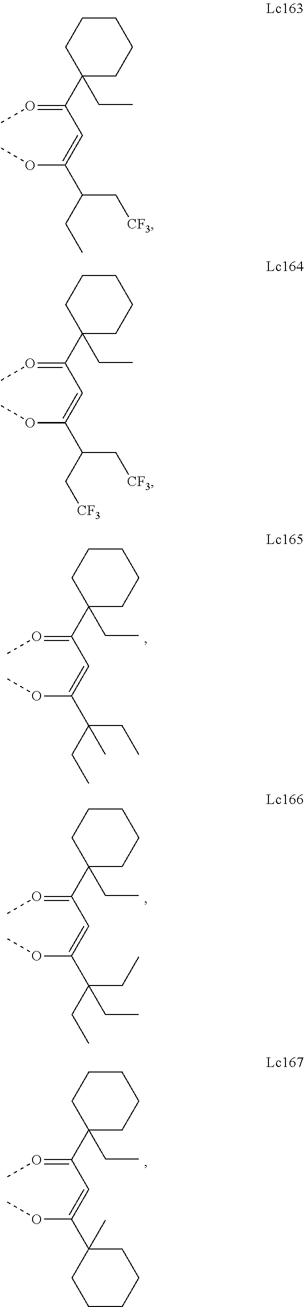

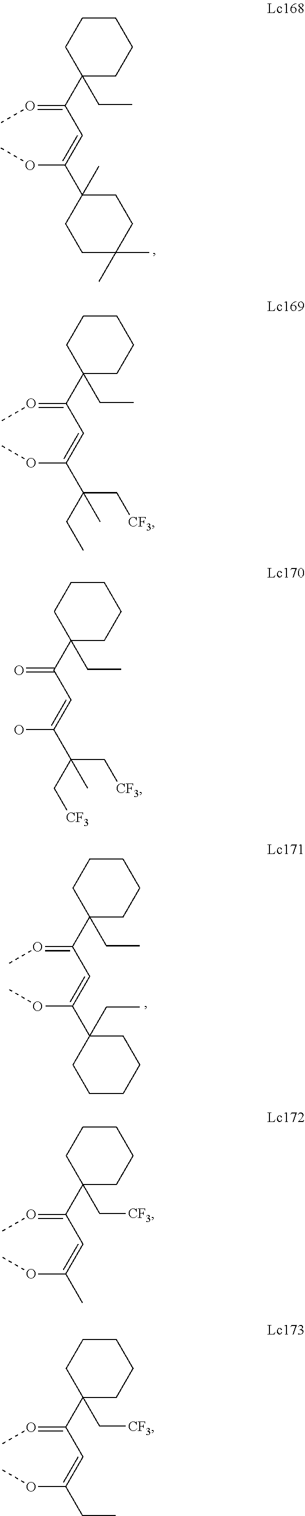

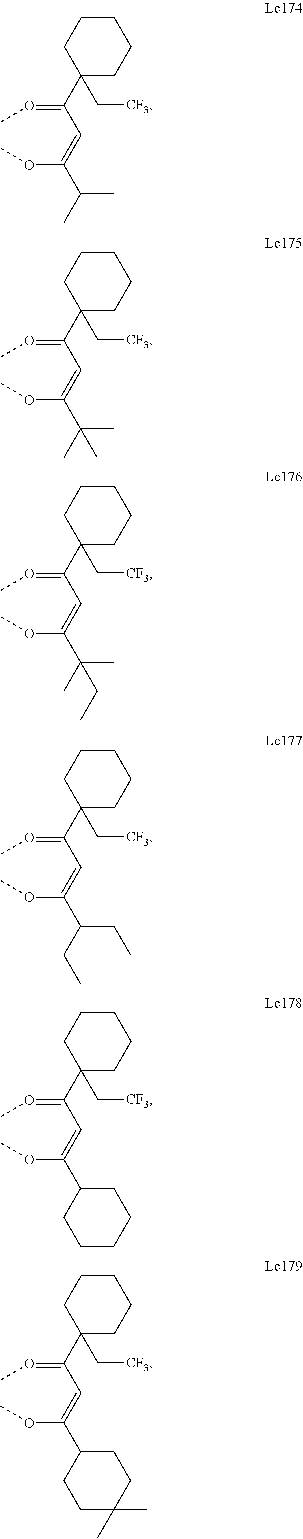

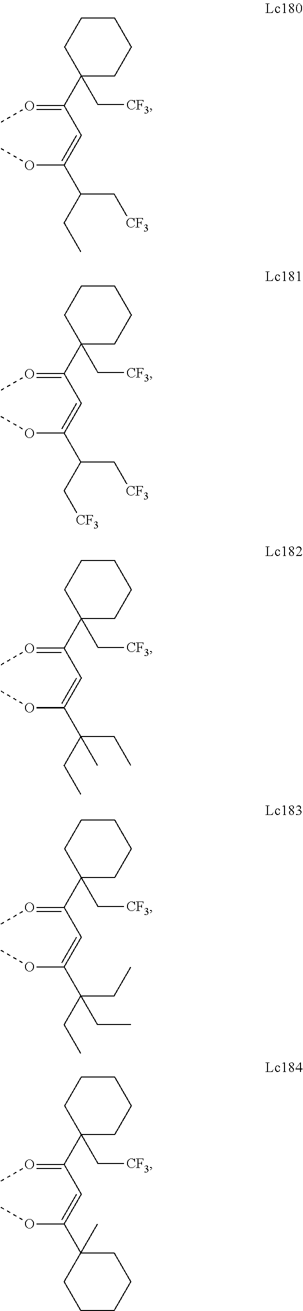

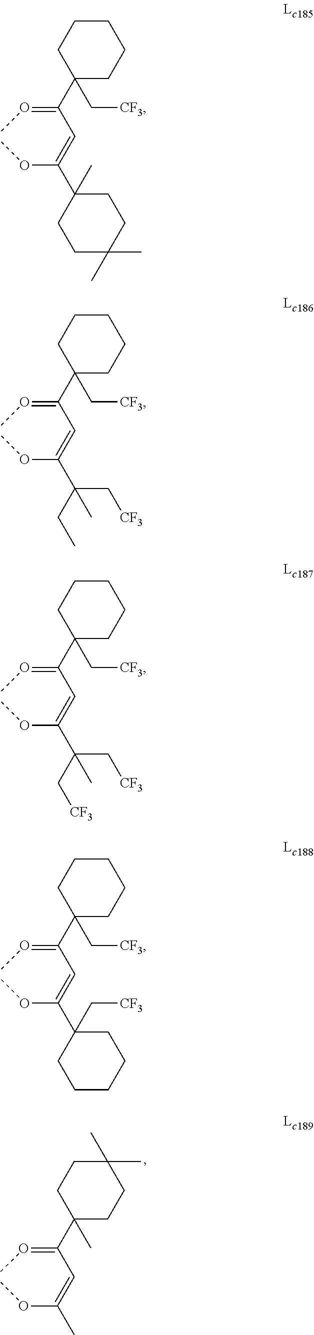

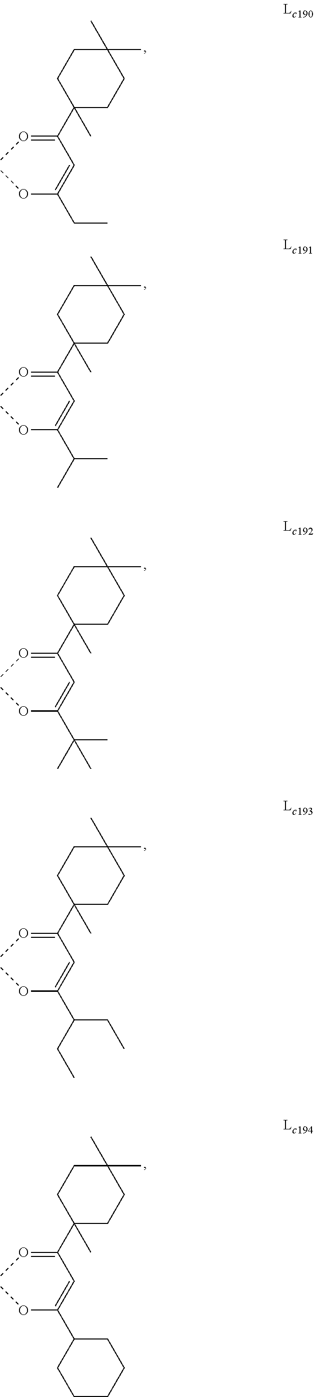

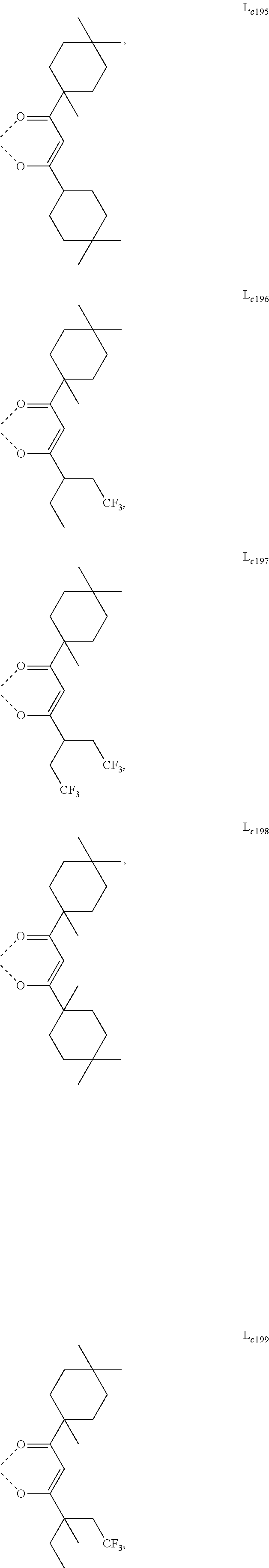

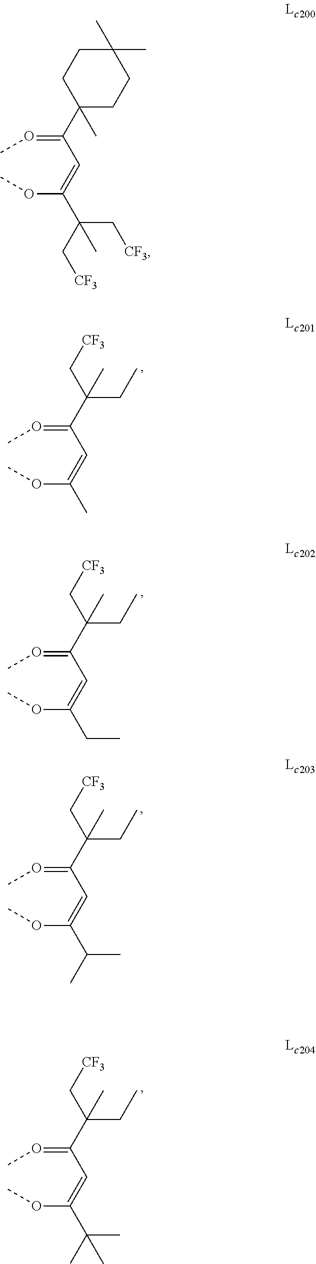

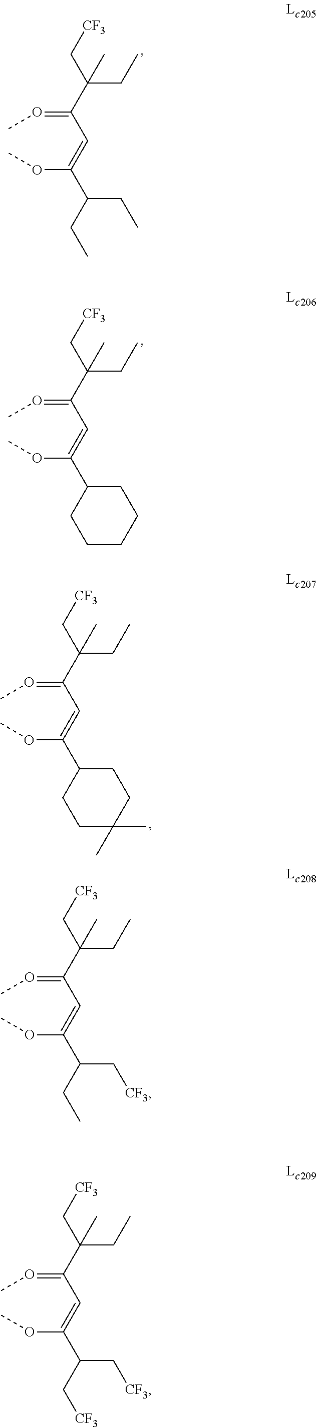

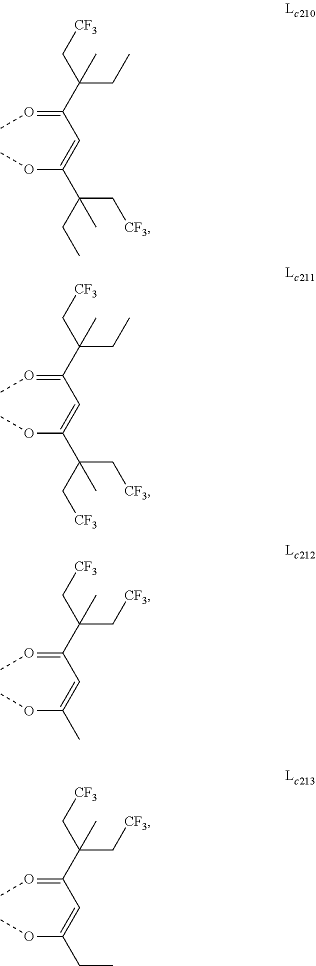

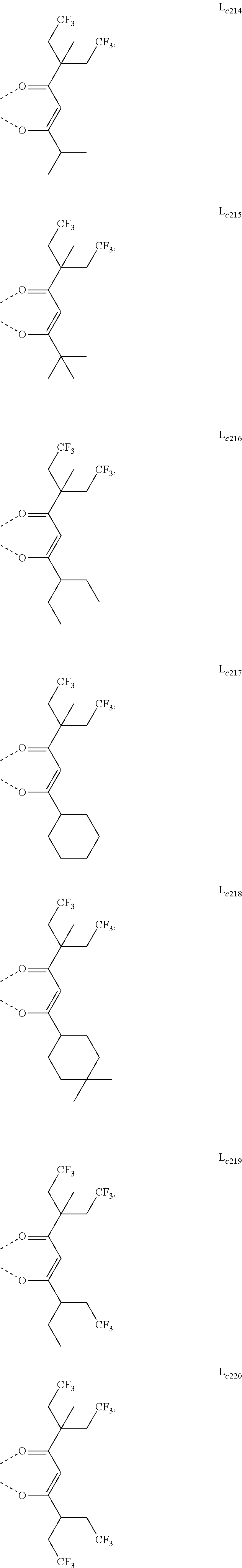

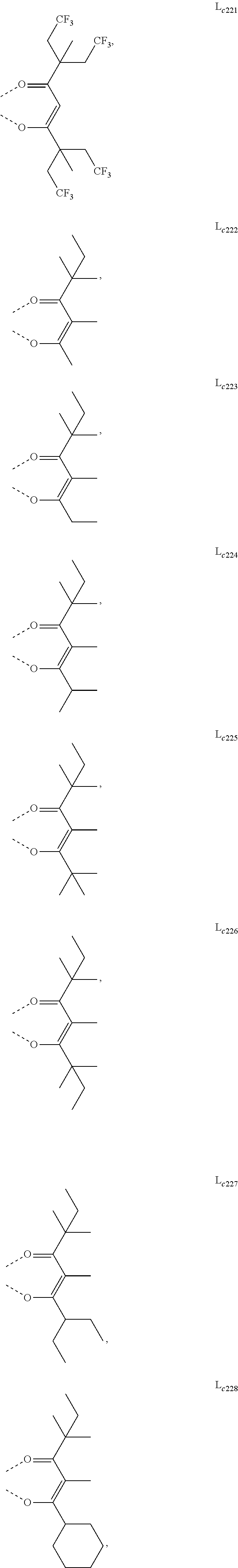

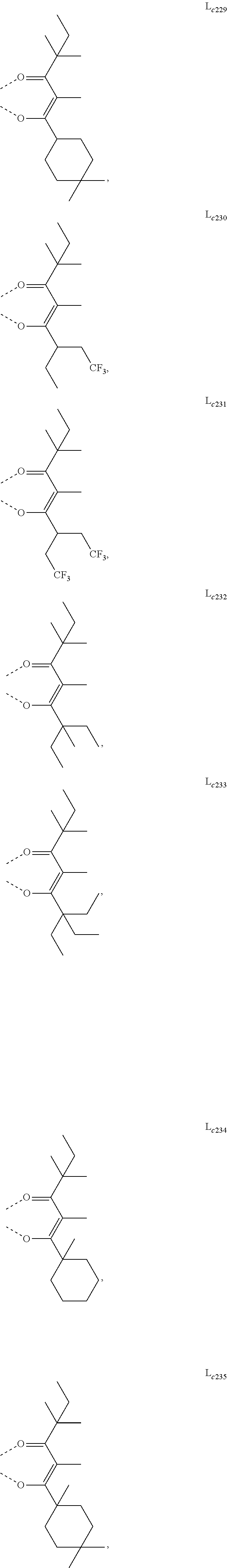

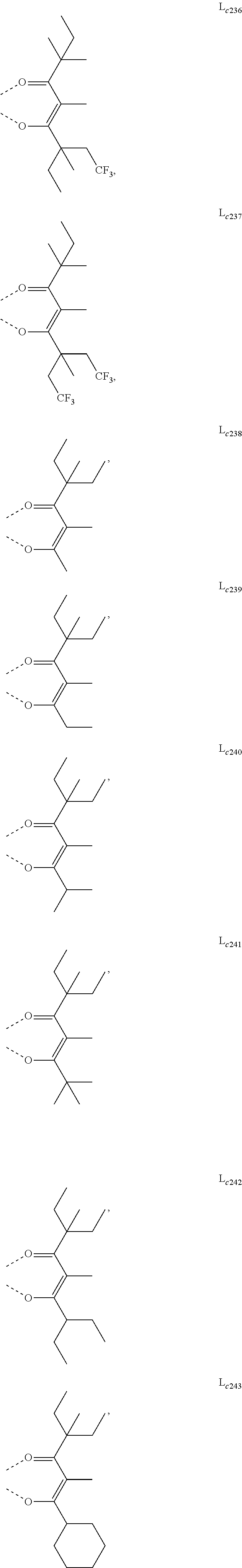

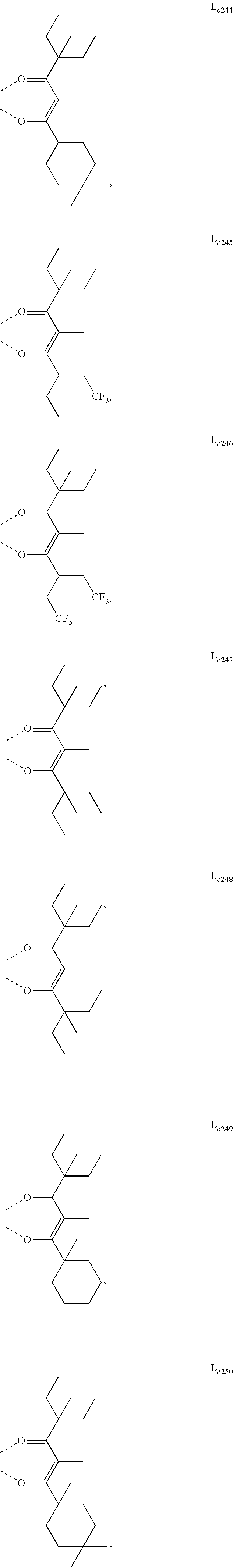

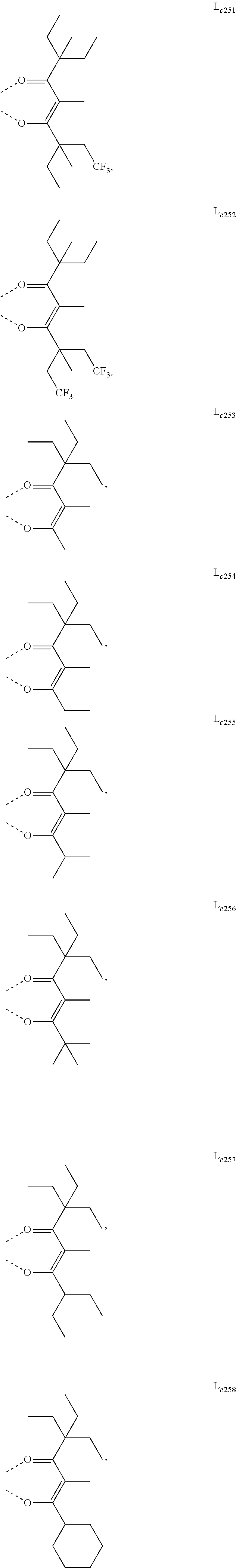

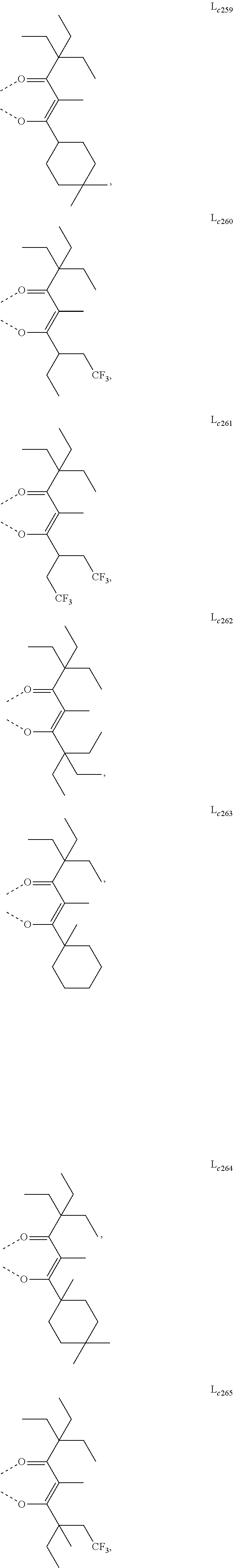

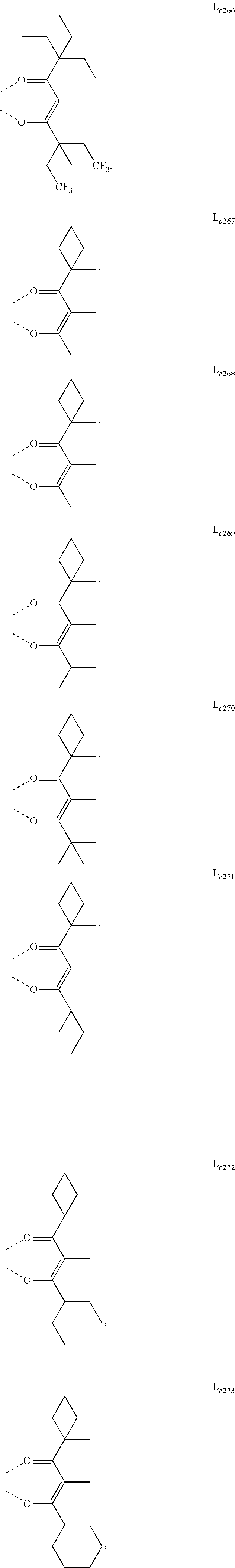

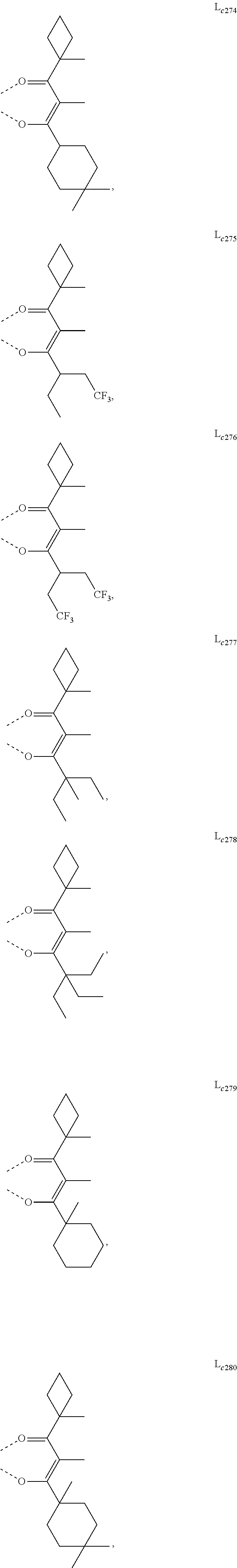

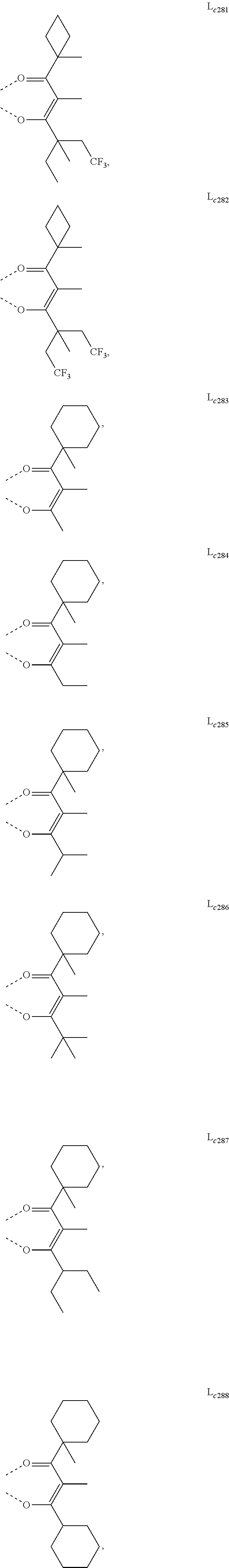

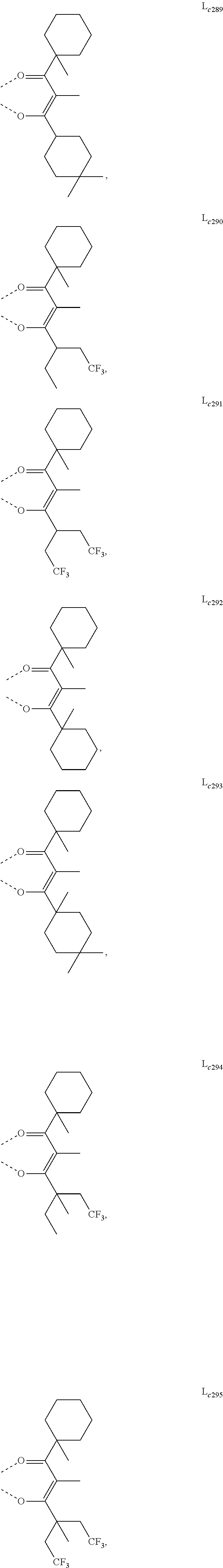

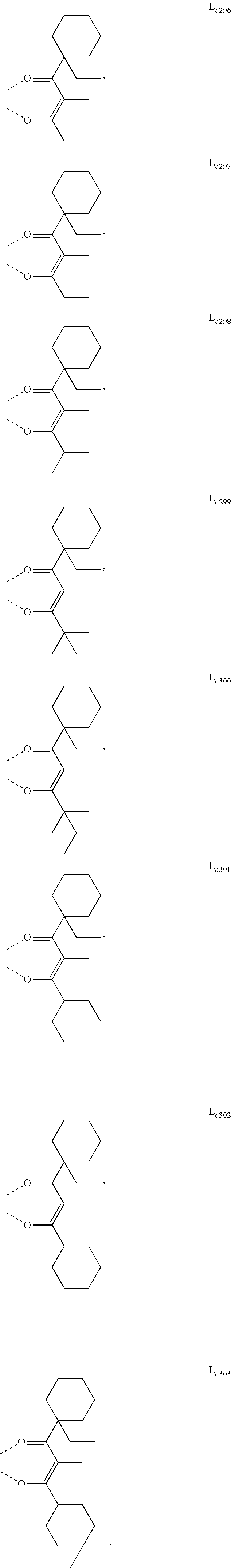

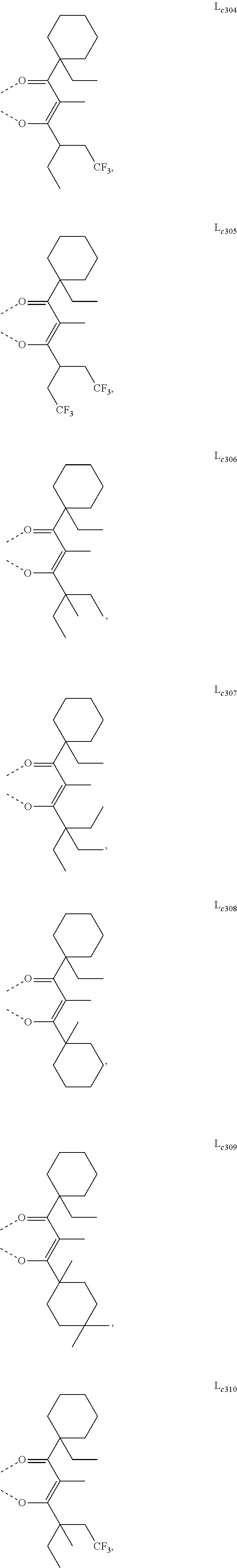

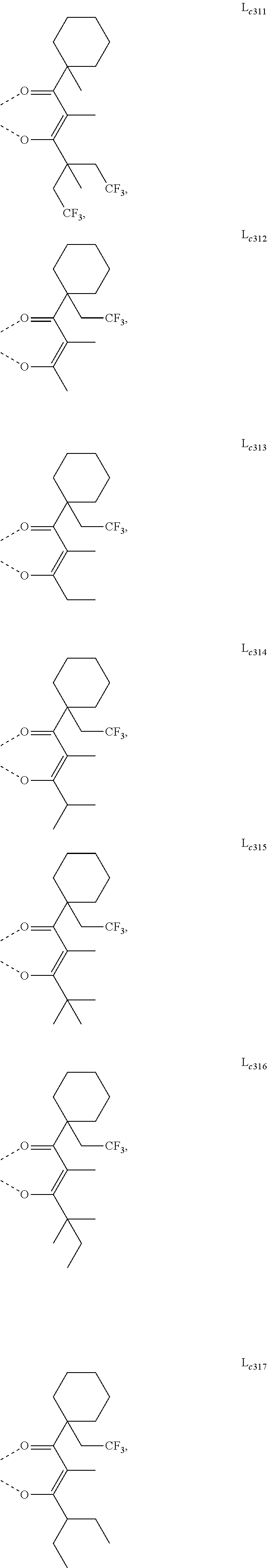

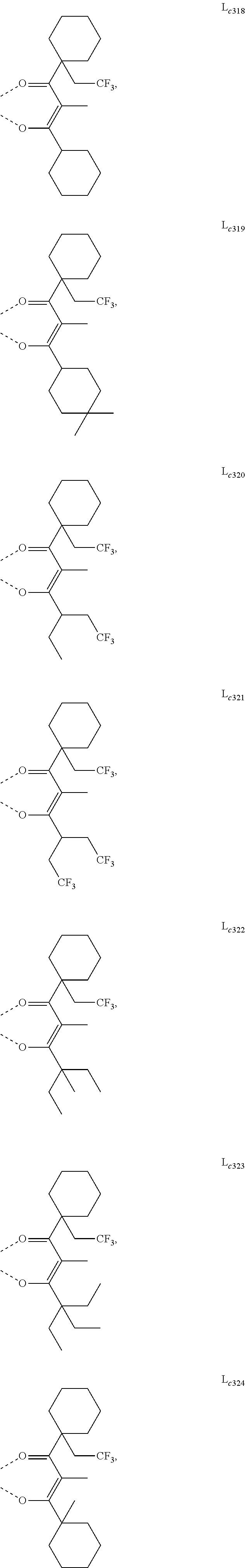

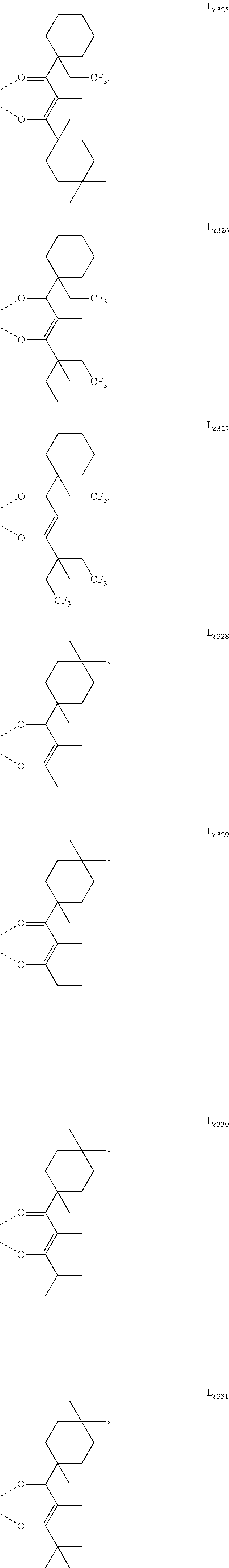

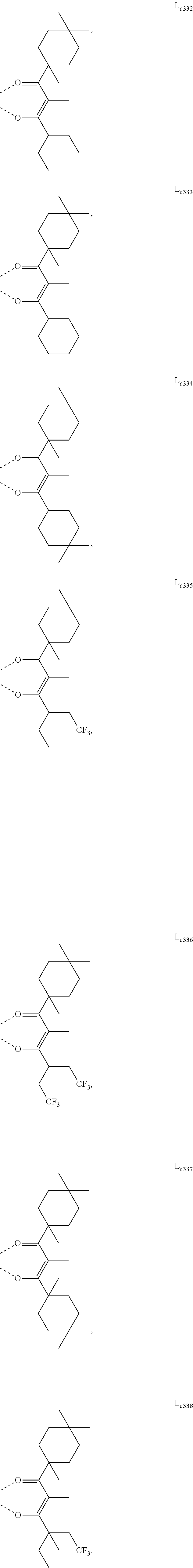

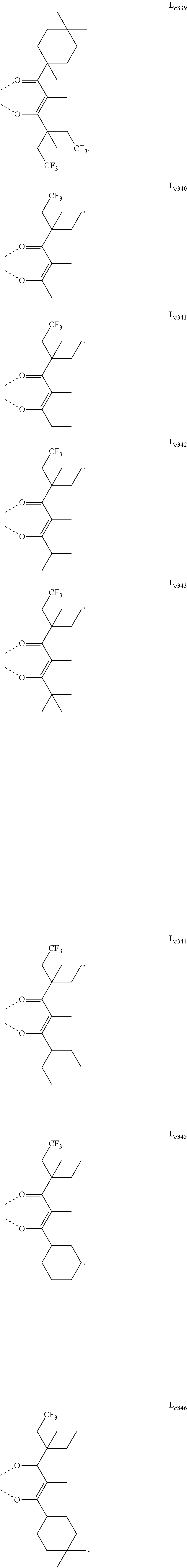

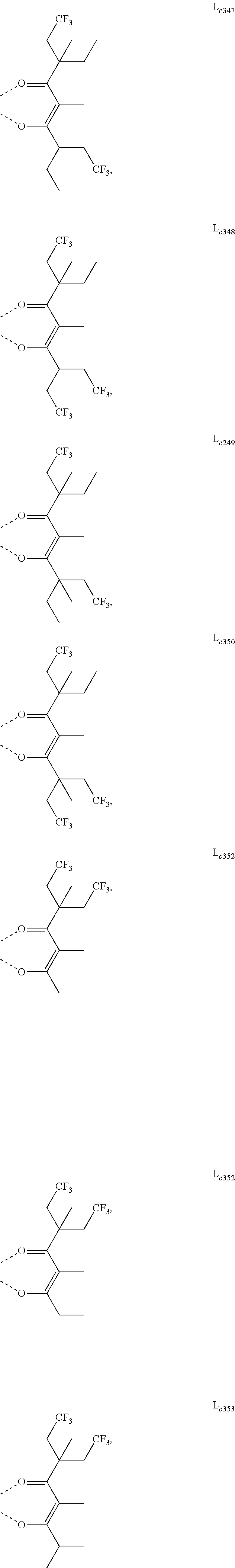

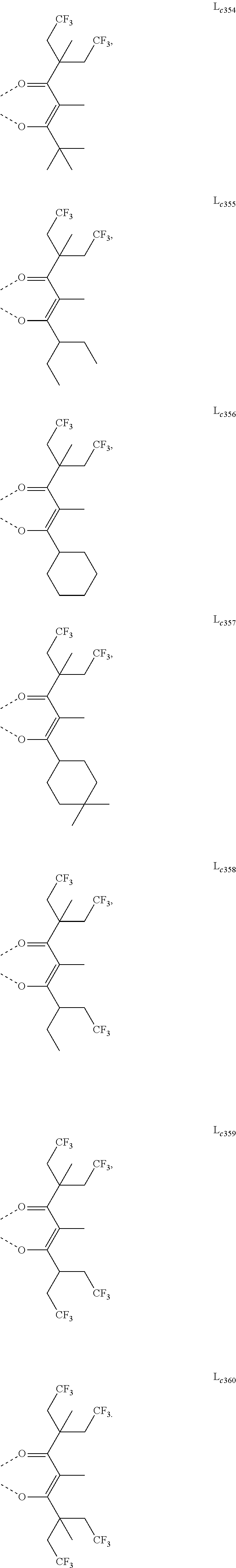

20. The metal complex according to claim 1, wherein the metal complex has a structure of Ir(Lₐ)₂L_{b}, wherein the two Lₐ are identical or different, Lₐ is selected from the group consisting of Lₐ₁₋₁ to Lₐ₁₋₂₃, Lₐ₂₋₁ to Lₐ₂₋₁₁₆ and L_{aD-1} to L_{aD-128}, and L_{b} is selected from the group consisting of L_{b1-1} to L_{b1-357}, L_{b2-1} to L_{b2-285} and L_{bx-1} to L_{bx-76};
preferably, the metal complex is selected from the group consisting of Metal Complex 1 to Metal Complex 1504, wherein Metal Complex 1 to Metal Complex 1504 have the structure of Ir(Lₐ)₂L_{b}, wherein the two Lₐ are identical and Lₐ and L_{b} correspond to structures shown in the following table, respectively:

| Metal | | | Metal | | |
|---|---|---|---|---|---|
| Complex | | | Complex | | |
| No. | Lₐ | L_{b} | No. | Lₐ | L_{b} |
| 1 | Lₐ₁₋₁ | L_{b1-75} | 2 | Lₐ₁₋₂ | L_{b1-75} |
| 3 | Lₐ₁₋₃ | L_{b1-75} | 4 | Lₐ₁₋₄ | L_{b1-75} |
| 5 | Lₐ₁₋₅ | L_{b1-75} | 6 | Lₐ₁₋₆ | L_{b1-75} |
| 7 | Lₐ₁₋₇ | L_{b1-75} | 8 | Lₐ₁₋₈ | L_{b1-75} |
| 9 | Lₐ₁₋₉ | L_{b1-75} | 10 | Lₐ₁₋₁₀ | L_{b1-75} |
| 11 | Lₐ₁₋₁₁ | L_{b1-75} | 12 | Lₐ₁₋₁₂ | L_{b1-75} |
| 13 | Lₐ₁₋₁₃ | L_{b1-75} | 14 | Lₐ₁₋₁₄ | L_{b1-75} |
| 15 | Lₐ₁₋₁₅ | L_{b1-75} | 16 | Lₐ₁₋₁₆ | L_{b1-75} |
| 17 | Lₐ₁₋₁₇ | L_{b1-75} | 18 | Lₐ₁₋₁₈ | L_{b1-75} |
| 19 | Lₐ₁₋₁₉ | L_{b1-75} | 20 | Lₐ₁₋₂₀ | L_{b1-75} |
| 21 | Lₐ₁₋₂₁ | L_{b1-75} | 22 | Lₐ₁₋₂₂ | L_{b1-75} |
| 23 | Lₐ₁₋₂₃ | L_{b1-75} | 24 | Lₐ₁₋₂₄ | L_{b1-75} |
| 25 | Lₐ₁₋₂₅ | L_{b1-75} | 26 | Lₐ₁₋₂₆ | L_{b1-75} |
| 27 | Lₐ₁₋₂₇ | L_{b1-75} | 28 | Lₐ₁₋₂₈ | L_{b1-75} |
| 29 | Lₐ₁₋₂₉ | L_{b1-75} | 30 | Lₐ₁₋₃₀ | L_{b1-75} |
| 31 | Lₐ₁₋₃₁ | L_{b1-75} | 32 | Lₐ₁₋₃₂ | L_{b1-75} |
| 33 | Lₐ₁₋₃₃ | L_{b1-75} | 34 | Lₐ₁₋₃₄ | L_{b1-75} |
| 35 | Lₐ₁₋₃₅ | L_{b1-75} | 36 | Lₐ₁₋₃₆ | L_{b1-75} |
| 37 | Lₐ₁₋₃₇ | L_{b1-75} | 38 | Lₐ₁₋₃₈ | L_{b1-75} |
| 39 | Lₐ₁₋₃₉ | L_{b1-75} | 40 | Lₐ₁₋₄₀ | L_{b1-75} |
| 41 | Lₐ₁₋₄₁ | L_{b1-75} | 42 | Lₐ₁₋₄₂ | L_{b1-75} |
| 43 | Lₐ₁₋₄₃ | L_{b1-75} | 44 | Lₐ₁₋₄₄ | L_{b1-75} |
| 45 | Lₐ₁₋₄₅ | L_{b1-75} | 46 | Lₐ₁₋₄₆ | L_{b1-75} |
| 47 | Lₐ₁₋₄₇ | L_{b1-75} | 48 | Lₐ₁₋₄₈ | L_{b1-75} |
| 49 | Lₐ₁₋₄₉ | L_{b1-75} | 50 | Lₐ₁₋₅₀ | L_{b1-75} |
| 51 | Lₐ₁₋₅₁ | L_{b1-75} | 52 | Lₐ₁₋₅₂ | L_{b1-75} |
| 53 | Lₐ₁₋₅₃ | L_{b1-75} | 54 | Lₐ₁₋₅₄ | L_{b1-75} |
| 55 | Lₐ₁₋₅₅ | L_{b1-75} | 56 | Lₐ₁₋₅₆ | L_{b1-75} |
| 57 | Lₐ₁₋₅₇ | L_{b1-75} | 58 | Lₐ₁₋₅₈ | L_{b1-75} |
| 59 | Lₐ₁₋₅₉ | L_{b1-75} | 60 | Lₐ₁₋₆₀ | L_{b1-75} |
| 61 | Lₐ₁₋₆₁ | L_{b1-75} | 62 | Lₐ₁₋₆₂ | L_{b1-75} |
| 63 | Lₐ₁₋₆₃ | L_{b1-75} | 64 | Lₐ₁₋₆₄ | L_{b1-75} |
| 65 | Lₐ₁₋₆₅ | L_{b1-75} | 66 | Lₐ₁₋₆₆ | L_{b1-75} |
| 67 | Lₐ₁₋₆₇ | L_{b1-75} | 68 | Lₐ₁₋₆₈ | L_{b1-75} |
| 69 | Lₐ₁₋₆₉ | L_{b1-75} | 70 | Lₐ₁₋₇₀ | L_{b1-75} |
| 71 | Lₐ₁₋₇₁ | L_{b1-75} | 72 | Lₐ₁₋₇₂ | L_{b1-75} |
| 73 | Lₐ₁₋₇₃ | L_{b1-75} | 74 | Lₐ₁₋₇₄ | L_{b1-75} |
| 75 | Lₐ₁₋₇₅ | L_{b1-75} | 76 | Lₐ₁₋₇₆ | L_{b1-75} |
| 77 | Lₐ₁₋₇₇ | L_{b1-75} | 78 | Lₐ₁₋₇₈ | L_{b1-75} |
| 79 | Lₐ₁₋₇₉ | L_{b1-75} | 80 | Lₐ₁₋₈₀ | L_{b1-75} |
| 81 | Lₐ₁₋₈₁ | L_{b1-75} | 82 | Lₐ₁₋₈₂ | L_{b1-75} |
| 83 | Lₐ₁₋₈₃ | L_{b1-75} | 84 | Lₐ₁₋₈₄ | L_{b1-75} |
| 85 | Lₐ₁₋₈₅ | L_{b1-75} | 86 | Lₐ₁₋₈₆ | L_{b1-75} |
| 87 | Lₐ₁₋₈₇ | L_{b1-75} | 88 | Lₐ₁₋₈₈ | L_{b1-75} |
| 89 | Lₐ₁₋₈₉ | L_{b1-75} | 90 | Lₐ₁₋₉₀ | L_{b1-75} |
| 91 | Lₐ₁₋₉₁ | L_{b1-75} | 92 | Lₐ₁₋₉₂ | L_{b1-75} |
| 93 | Lₐ₁₋₉₃ | L_{b1-75} | 94 | Lₐ₁₋₉₄ | L_{b1-75} |
| 95 | Lₐ₁₋₉₅ | L_{b1-75} | 96 | Lₐ₁₋₉₆ | L_{b1-75} |
| 97 | Lₐ₁₋₉₇ | L_{b1-75} | 98 | Lₐ₁₋₉₈ | L_{b1-75} |
| 99 | Lₐ₁₋₉₉ | L_{b1-75} | 100 | Lₐ₁₋₁₀₀ | L_{b1-75} |
| 101 | Lₐ₁₋₁₀₁ | L_{b1-75} | 102 | Lₐ₁₋₁₀₂ | L_{b1-75} |
| 103 | Lₐ₁₋₁₀₃ | L_{b1-75} | 104 | Lₐ₁₋₁₀₄ | L_{b1-75} |
| 105 | Lₐ₁₋₁₀₅ | L_{b1-75} | 106 | Lₐ₁₋₁₀₆ | L_{b1-75} |
| 107 | Lₐ₁₋₁₀₇ | L_{b1-75} | 108 | Lₐ₁₋₁₀₈ | L_{b1-75} |
| 109 | Lₐ₁₋₁₀₉ | L_{b1-75} | 110 | Lₐ₁₋₁₁₀ | L_{b1-75} |
| 111 | Lₐ₁₋₁₁₁ | L_{b1-75} | 112 | Lₐ₁₋₁₁₂ | L_{b1-75} |
| 113 | Lₐ₁₋₁₁₃ | L_{b1-75} | 114 | Lₐ₁₋₁₁₄ | L_{b1-75} |
| 115 | Lₐ₁₋₁₁₅ | L_{b1-75} | 116 | Lₐ₁₋₁₁₆ | L_{b1-75} |
| 117 | Lₐ₁₋₁₁₇ | L_{b1-75} | 118 | Lₐ₁₋₁₁₈ | L_{b1-75} |
| 119 | Lₐ₁₋₁₁₉ | L_{b1-75} | 120 | Lₐ₁₋₁₂₀ | L_{b1-75} |
| 121 | Lₐ₁₋₁ | L_{b1-282} | 122 | Lₐ₁₋₂ | L_{b1-282} |
| 123 | Lₐ₁₋₃ | L_{b1-282} | 124 | Lₐ₁₋₄ | L_{b1-282} |
| 125 | Lₐ₁₋₅ | L_{b1-282} | 126 | Lₐ₁₋₆ | L_{b1-282} |
| 127 | Lₐ₁₋₇ | L_{b1-282} | 128 | Lₐ₁₋₈ | L_{b1-282} |
| 129 | Lₐ₁₋₉ | L_{b1-282} | 130 | Lₐ₁₋₁₀ | L_{b1-282} |
| 131 | Lₐ₁₋₁₁ | L_{b1-282} | 132 | Lₐ₁₋₁₂ | L_{b1-282} |
| 133 | Lₐ₁₋₁₃ | L_{b1-282} | 134 | Lₐ₁₋₁₄ | L_{b1-282} |
| 135 | Lₐ₁₋₁₅ | L_{b1-282} | 136 | Lₐ₁₋₁₆ | L_{b1-282} |
| 137 | Lₐ₁₋₁₇ | L_{b1-282} | 138 | Lₐ₁₋₁₈ | L_{b1-282} |
| 139 | Lₐ₁₋₁₉ | L_{b1-282} | 140 | Lₐ₁₋₂₀ | L_{b1-282} |
| 141 | Lₐ₁₋₂₁ | L_{b1-282} | 142 | Lₐ₁₋₂₂ | L_{b1-282} |
| 143 | Lₐ₁₋₂₃ | L_{b1-282} | 144 | Lₐ₁₋₂₄ | L_{b1-282} |
| 145 | Lₐ₁₋₂₅ | L_{b1-282} | 146 | Lₐ₁₋₂₆ | L_{b1-282} |
| 147 | Lₐ₁₋₂₇ | L_{b1-282} | 148 | Lₐ₁₋₂₈ | L_{b1-282} |
| 149 | Lₐ₁₋₂₉ | L_{b1-282} | 150 | Lₐ₁₋₃₀ | L_{b1-282} |
| 151 | Lₐ₁₋₃₁ | L_{b1-282} | 152 | Lₐ₁₋₃₂ | L_{b1-282} |
| 153 | Lₐ₁₋₃₃ | L_{b1-282} | 154 | Lₐ₁₋₃₄ | L_{b1-282} |
| 155 | Lₐ₁₋₃₅ | L_{b1-282} | 156 | Lₐ₁₋₃₆ | L_{b1-282} |
| 157 | Lₐ₁₋₃₇ | L_{b1-282} | 158 | Lₐ₁₋₃₈ | L_{b1-282} |
| 159 | Lₐ₁₋₃₉ | L_{b1-282} | 160 | Lₐ₁₋₄₀ | L_{b1-282} |
| 161 | Lₐ₁₋₄₁ | L_{b1-282} | 162 | Lₐ₁₋₄₂ | L_{b1-282} |
| 163 | Lₐ₁₋₄₃ | L_{b1-282} | 164 | Lₐ₁₋₄₄ | L_{b1-282} |
| 165 | Lₐ₁₋₄₅ | L_{b1-282} | 166 | Lₐ₁₋₄₆ | L_{b1-282} |
| 167 | Lₐ₁₋₄₇ | L_{b1-282} | 168 | Lₐ₁₋₄₈ | L_{b1-282} |
| 169 | Lₐ₁₋₄₉ | L_{b1-282} | 170 | Lₐ₁₋₅₀ | L_{b1-282} |
| 171 | Lₐ₁₋₅₁ | L_{b1-282} | 172 | Lₐ₁₋₅₂ | L_{b1-282} |
| 173 | Lₐ₁₋₅₃ | L_{b1-282} | 174 | Lₐ₁₋₅₄ | L_{b1-282} |
| 175 | Lₐ₁₋₅₅ | L_{b1-282} | 176 | Lₐ₁₋₅₆ | L_{b1-282} |
| 177 | Lₐ₁₋₅₇ | L_{b1-282} | 178 | Lₐ₁₋₅₈ | L_{b1-282} |
| 179 | Lₐ₁₋₅₉ | L_{b1-282} | 180 | Lₐ₁₋₆₀ | L_{b1-282} |
| 181 | Lₐ₁₋₆₁ | L_{b1-282} | 182 | Lₐ₁₋₆₂ | L_{b1-282} |
| 183 | Lₐ₁₋₆₃ | L_{b1-282} | 184 | Lₐ₁₋₆₄ | L_{b1-282} |
| 185 | Lₐ₁₋₆₅ | L_{b1-282} | 186 | Lₐ₁₋₆₆ | L_{b1-282} |
| 187 | Lₐ₁₋₆₇ | L_{b1-282} | 188 | Lₐ₁₋₆₈ | L_{b1-282} |
| 189 | Lₐ₁₋₆₉ | L_{b1-282} | 190 | Lₐ₁₋₇₀ | L_{b1-282} |
| 191 | Lₐ₁₋₇₁ | L_{b1-282} | 192 | Lₐ₁₋₇₂ | L_{b1-282} |
| 193 | Lₐ₁₋₇₃ | L_{b1-282} | 194 | Lₐ₁₋₇₄ | L_{b1-282} |
| 195 | Lₐ₁₋₇₅ | L_{b1-282} | 196 | Lₐ₁₋₇₆ | L_{b1-282} |
| 197 | Lₐ₁₋₇₇ | L_{b1-282} | 198 | Lₐ₁₋₇₈ | L_{b1-282} |
| 199 | Lₐ₁₋₇₉ | L_{b1-282} | 200 | Lₐ₁₋₈₀ | L_{b1-282} |
| 201 | Lₐ₁₋₈₁ | L_{b1-282} | 202 | Lₐ₁₋₈₂ | L_{b1-282} |
| 203 | Lₐ₁₋₈₃ | L_{b1-282} | 204 | Lₐ₁₋₈₄ | L_{b1-282} |
| 205 | Lₐ₁₋₈₅ | L_{b1-282} | 206 | Lₐ₁₋₈₆ | L_{b1-282} |
| 207 | Lₐ₁₋₈₇ | L_{b1-282} | 208 | Lₐ₁₋₈₈ | L_{b1-282} |
| 209 | Lₐ₁₋₈₉ | L_{b1-282} | 210 | Lₐ₁₋₉₀ | L_{b1-282} |
| 211 | Lₐ₁₋₉₁ | L_{b1-282} | 212 | Lₐ₁₋₉₂ | L_{b1-282} |
| 213 | Lₐ₁₋₉₃ | L_{b1-282} | 214 | Lₐ₁₋₉₄ | L_{b1-282} |
| 215 | Lₐ₁₋₉₅ | L_{b1-282} | 216 | Lₐ₁₋₉₆ | L_{b1-282} |
| 217 | Lₐ₁₋₉₇ | L_{b1-282} | 218 | Lₐ₁₋₉₈ | L_{b1-282} |
| 219 | Lₐ₁₋₉₉ | L_{b1-282} | 220 | Lₐ₁₋₁₀₀ | L_{b1-282} |
| 221 | Lₐ₁₋₁₀₁ | L_{b1-282} | 222 | Lₐ₁₋₁₀₂ | L_{b1-282} |
| 223 | Lₐ₁₋₁₀₃ | L_{b1-282} | 224 | Lₐ₁₋₁₀₄ | L_{b1-282} |
| 225 | Lₐ₁₋₁₀₅ | L_{b1-282} | 226 | Lₐ₁₋₁₀₆ | L_{b1-282} |
| 227 | Lₐ₁₋₁₀₇ | L_{b1-282} | 228 | Lₐ₁₋₁₀₈ | L_{b1-282} |
| 229 | Lₐ₁₋₁₀₉ | L_{b1-282} | 230 | Lₐ₁₋₁₁₀ | L_{b1-282} |
| 231 | Lₐ₁₋₁₁₁ | L_{b1-282} | 232 | Lₐ₁₋₁₁₂ | L_{b1-282} |
| 233 | Lₐ₁₋₁₁₃ | L_{b1-282} | 234 | Lₐ₁₋₁₁₄ | L_{b1-282} |
| 235 | Lₐ₁₋₁₁₅ | L_{b1-282} | 236 | Lₐ₁₋₁₁₆ | L_{b1-282} |
| 237 | Lₐ₁₋₁₁₇ | L_{b1-282} | 238 | Lₐ₁₋₁₁₈ | L_{b1-282} |
| 239 | Lₐ₁₋₁₁₉ | L_{b1-282} | 240 | Lₐ₁₋₁₂₀ | L_{b1-282} |
| 241 | Lₐ₁₋₁ | L_{b1-345} | 242 | Lₐ₁₋₂ | L_{b1-345} |
| 243 | Lₐ₁₋₃ | L_{b1-345} | 244 | Lₐ₁₋₄ | L_{b1-345} |
| 245 | Lₐ₁₋₅ | L_{b1-345} | 246 | Lₐ₁₋₆ | L_{b1-345} |
| 247 | Lₐ₁₋₇ | L_{b1-345} | 248 | Lₐ₁₋₈ | L_{b1-345} |
| 249 | Lₐ₁₋₉ | L_{b1-345} | 250 | Lₐ₁₋₁₀ | L_{b1-345} |
| 251 | Lₐ₁₋₁₁ | L_{b1-345} | 252 | Lₐ₁₋₁₂ | L_{b1-345} |
| 253 | Lₐ₁₋₁₃ | L_{b1-345} | 254 | Lₐ₁₋₁₄ | L_{b1-345} |
| 255 | Lₐ₁₋₁₅ | L_{b1-345} | 256 | Lₐ₁₋₁₆ | L_{b1-345} |
| 257 | Lₐ₁₋₁₇ | L_{b1-345} | 258 | Lₐ₁₋₁₈ | L_{b1-345} |
| 259 | Lₐ₁₋₁₉ | L_{b1-345} | 260 | Lₐ₁₋₂₀ | L_{b1-345} |
| 261 | Lₐ₁₋₂₁ | L_{b1-345} | 262 | Lₐ₁₋₂₂ | L_{b1-345} |
| 263 | Lₐ₁₋₂₃ | L_{b1-345} | 264 | Lₐ₁₋₂₄ | L_{b1-345} |
| 265 | Lₐ₁₋₂₅ | L_{b1-345} | 266 | Lₐ₁₋₂₆ | L_{b1-345} |
| 267 | Lₐ₁₋₂₇ | L_{b1-345} | 268 | Lₐ₁₋₂₈ | L_{b1-345} |
| 269 | Lₐ₁₋₂₉ | L_{b1-345} | 270 | Lₐ₁₋₃₀ | L_{b1-345} |
| 271 | Lₐ₁₋₃₁ | L_{b1-345} | 272 | Lₐ₁₋₃₂ | L_{b1-345} |
| 273 | Lₐ₁₋₃₃ | L_{b1-345} | 274 | Lₐ₁₋₃₄ | L_{b1-345} |
| 275 | Lₐ₁₋₃₅ | L_{b1-345} | 276 | Lₐ₁₋₃₆ | L_{b1-345} |
| 277 | Lₐ₁₋₃₇ | L_{b1-345} | 278 | Lₐ₁₋₃₈ | L_{b1-345} |
| 279 | Lₐ₁₋₃₉ | L_{b1-345} | 280 | Lₐ₁₋₄₀ | L_{b1-345} |
| 281 | Lₐ₁₋₄₁ | L_{b1-345} | 282 | Lₐ₁₋₄₂ | L_{b1-345} |
| 283 | Lₐ₁₋₄₃ | L_{b1-345} | 284 | Lₐ₁₋₄₄ | L_{b1-345} |
| 285 | Lₐ₁₋₄₅ | L_{b1-345} | 286 | Lₐ₁₋₄₆ | L_{b1-345} |
| 287 | Lₐ₁₋₄₇ | L_{b1-345} | 288 | Lₐ₁₋₄₈ | L_{b1-345} |
| 289 | Lₐ₁₋₄₉ | L_{b1-345} | 290 | Lₐ₁₋₅₀ | L_{b1-345} |
| 291 | Lₐ₁₋₅₁ | L_{b1-345} | 292 | Lₐ₁₋₅₂ | L_{b1-345} |
| 293 | Lₐ₁₋₅₃ | L_{b1-345} | 294 | Lₐ₁₋₅₄ | L_{b1-345} |
| 295 | Lₐ₁₋₅₅ | L_{b1-345} | 296 | Lₐ₁₋₅₆ | L_{b1-345} |
| 297 | Lₐ₁₋₅₇ | L_{b1-345} | 298 | Lₐ₁₋₅₈ | L_{b1-345} |
| 299 | Lₐ₁₋₅₉ | L_{b1-345} | 300 | Lₐ₁₋₆₀ | L_{b1-345} |
| 301 | Lₐ₁₋₆₁ | L_{b1-345} | 302 | Lₐ₁₋₆₂ | L_{b1-345} |
| 303 | Lₐ₁₋₆₃ | L_{b1-345} | 304 | Lₐ₁₋₆₄ | L_{b1-345} |
| 305 | Lₐ₁₋₆₅ | L_{b1-345} | 306 | Lₐ₁₋₆₆ | L_{b1-345} |
| 307 | Lₐ₁₋₆₇ | L_{b1-345} | 308 | Lₐ₁₋₆₈ | L_{b1-345} |
| 309 | Lₐ₁₋₆₉ | L_{b1-345} | 310 | Lₐ₁₋₇₀ | L_{b1-345} |
| 311 | Lₐ₁₋₇₁ | L_{b1-345} | 312 | Lₐ₁₋₇₂ | L_{b1-345} |
| 313 | Lₐ₁₋₇₃ | L_{b1-345} | 314 | Lₐ₁₋₇₄ | L_{b1-345} |
| 315 | Lₐ₁₋₇₅ | L_{b1-345} | 316 | Lₐ₁₋₇₆ | L_{b1-345} |
| 317 | Lₐ₁₋₇₇ | L_{b1-345} | 318 | Lₐ₁₋₇₈ | L_{b1-345} |
| 319 | Lₐ₁₋₇₉ | L_{b1-345} | 320 | Lₐ₁₋₈₀ | L_{b1-345} |
| 321 | Lₐ₁₋₈₁ | L_{b1-345} | 322 | Lₐ₁₋₈₂ | L_{b1-345} |
| 323 | Lₐ₁₋₈₃ | L_{b1-345} | 324 | Lₐ₁₋₈₄ | L_{b1-345} |
| 325 | Lₐ₁₋₈₅ | L_{b1-345} | 326 | Lₐ₁₋₈₆ | L_{b1-345} |
| 327 | Lₐ₁₋₈₇ | L_{b1-345} | 328 | Lₐ₁₋₈₈ | L_{b1-345} |
| 329 | Lₐ₁₋₈₉ | L_{b1-345} | 330 | Lₐ₁₋₉₀ | L_{b1-345} |
| 331 | Lₐ₁₋₉₁ | L_{b1-345} | 332 | Lₐ₁₋₉₂ | L_{b1-345} |
| 333 | Lₐ₁₋₉₃ | L_{b1-345} | 334 | Lₐ₁₋₉₄ | L_{b1-345} |
| 335 | Lₐ₁₋₉₅ | L_{b1-345} | 336 | Lₐ₁₋₉₆ | L_{b1-345} |
| 337 | Lₐ₁₋₉₇ | L_{b1-345} | 338 | Lₐ₁₋₉₈ | L_{b1-345} |
| 339 | Lₐ₁₋₉₉ | L_{b1-345} | 340 | Lₐ₁₋₁₀₀ | L_{b1-345} |
| 341 | Lₐ₁₋₁₀₁ | L_{b1-345} | 342 | Lₐ₁₋₁₀₂ | L_{b1-345} |
| 343 | Lₐ₁₋₁₀₃ | L_{b1-345} | 345 | Lₐ₁₋₁₀₄ | L_{b1-345} |
| 345 | Lₐ₁₋₁₀₅ | L_{b1-345} | 346 | Lₐ₁₋₁₀₆ | L_{b1-345} |
| 347 | Lₐ₁₋₁₀₇ | L_{b1-345} | 348 | Lₐ₁₋₁₀₈ | L_{b1-345} |
| 349 | Lₐ₁₋₁₀₉ | L_{b1-345} | 350 | Lₐ₁₋₁₁₀ | L_{b1-345} |
| 351 | Lₐ₁₋₁₁₁ | L_{b1-345} | 352 | Lₐ₁₋₁₁₂ | L_{b1-345} |
| 353 | Lₐ₁₋₁₁₃ | L_{b1-345} | 354 | Lₐ₁₋₁₁₄ | L_{b1-345} |
| 355 | Lₐ₁₋₁₁₅ | L_{b1-345} | 356 | Lₐ₁₋₁₁₆ | L_{b1-345} |
| 357 | Lₐ₁₋₁₁₇ | L_{b1-345} | 358 | Lₐ₁₋₁₁₈ | L_{b1-345} |
| 359 | Lₐ₁₋₁₁₉ | L_{b1-345} | 360 | Lₐ₁₋₁₂₀ | L_{b1-345} |
| 361 | Lₐ₁₋₁ | L_{b2-67} | 362 | Lₐ₁₋₂ | L_{b2-67} |
| 363 | Lₐ₁₋₃ | L_{b2-67} | 364 | Lₐ₁₋₄ | L_{b2-67} |
| 365 | Lₐ₁₋₅ | L_{b2-67} | 366 | Lₐ₁₋₆ | L_{b2-67} |
| 367 | Lₐ₁₋₇ | L_{b2-67} | 368 | Lₐ₁₋₈ | L_{b2-67} |
| 369 | Lₐ₁₋₉ | L_{b2-67} | 370 | Lₐ₁₋₁₀ | L_{b2-67} |
| 371 | Lₐ₁₋₁₁ | L_{b2-67} | 372 | Lₐ₁₋₁₂ | L_{b2-67} |
| 373 | Lₐ₁₋₁₃ | L_{b2-67} | 374 | Lₐ₁₋₁₄ | L_{b2-67} |
| 375 | Lₐ₁₋₁₅ | L_{b2-67} | 376 | Lₐ₁₋₁₆ | L_{b2-67} |
| 377 | Lₐ₁₋₁₇ | L_{b2-67} | 378 | Lₐ₁₋₁₈ | L_{b2-67} |
| 379 | Lₐ₁₋₁₉ | L_{b2-67} | 380 | Lₐ₁₋₂₀ | L_{b2-67} |
| 381 | Lₐ₁₋₂₁ | L_{b2-67} | 382 | Lₐ₁₋₂₂ | L_{b2-67} |
| 383 | Lₐ₁₋₂₃ | L_{b2-67} | 384 | Lₐ₁₋₂₄ | L_{b2-67} |
| 385 | Lₐ₁₋₂₅ | L_{b2-67} | 386 | Lₐ₁₋₂₆ | L_{b2-67} |
| 387 | Lₐ₁₋₂₇ | L_{b2-67} | 388 | Lₐ₁₋₂₈ | L_{b2-67} |
| 389 | Lₐ₁₋₂₉ | L_{b2-67} | 390 | Lₐ₁₋₃₀ | L_{b2-67} |
| 391 | Lₐ₁₋₃₁ | L_{b2-67} | 392 | Lₐ₁₋₃₂ | L_{b2-67} |
| 393 | Lₐ₁₋₃₃ | L_{b2-67} | 394 | Lₐ₁₋₃₄ | L_{b2-67} |
| 395 | Lₐ₁₋₃₅ | L_{b2-67} | 396 | Lₐ₁₋₃₆ | L_{b2-67} |
| 397 | Lₐ₁₋₃₇ | L_{b2-67} | 398 | Lₐ₁₋₃₈ | L_{b2-67} |
| 399 | Lₐ₁₋₃₉ | L_{b2-67} | 400 | Lₐ₁₋₄₀ | L_{b2-67} |
| 401 | Lₐ₁₋₄₁ | L_{b2-67} | 402 | Lₐ₁₋₄₂ | L_{b2-67} |
| 403 | Lₐ₁₋₄₃ | L_{b2-67} | 404 | Lₐ₁₋₄₄ | L_{b2-67} |
| 405 | Lₐ₁₋₄₅ | L_{b2-67} | 406 | Lₐ₁₋₄₆ | L_{b2-67} |
| 407 | Lₐ₁₋₄₇ | L_{b2-67} | 408 | Lₐ₁₋₄₈ | L_{b2-67} |
| 409 | Lₐ₁₋₄₉ | L_{b2-67} | 410 | Lₐ₁₋₅₀ | L_{b2-67} |
| 411 | Lₐ₁₋₅₁ | L_{b2-67} | 412 | Lₐ₁₋₅₂ | L_{b2-67} |
| 413 | Lₐ₁₋₅₃ | L_{b2-67} | 414 | Lₐ₁₋₅₄ | L_{b2-67} |
| 415 | Lₐ₁₋₅₅ | L_{b2-67} | 416 | Lₐ₁₋₅₆ | L_{b2-67} |
| 417 | Lₐ₁₋₅₇ | L_{b2-67} | 418 | Lₐ₁₋₅₈ | L_{b2-67} |
| 419 | Lₐ₁₋₅₉ | L_{b2-67} | 420 | Lₐ₁₋₆₀ | L_{b2-67} |
| 421 | Lₐ₁₋₆₁ | L_{b2-67} | 422 | Lₐ₁₋₆₂ | L_{b2-67} |
| 423 | Lₐ₁₋₆₃ | L_{b2-67} | 424 | Lₐ₁₋₆₄ | L_{b2-67} |
| 425 | Lₐ₁₋₆₅ | L_{b2-67} | 426 | Lₐ₁₋₆₆ | L_{b2-67} |
| 427 | Lₐ₁₋₆₇ | L_{b2-67} | 428 | Lₐ₁₋₆₈ | L_{b2-67} |
| 429 | Lₐ₁₋₆₉ | L_{b2-67} | 430 | Lₐ₁₋₇₀ | L_{b2-67} |
| 431 | Lₐ₁₋₇₁ | L_{b2-67} | 432 | Lₐ₁₋₇₂ | L_{b2-67} |
| 433 | Lₐ₁₋₇₃ | L_{b2-67} | 434 | Lₐ₁₋₇₄ | L_{b2-67} |
| 435 | Lₐ₁₋₇₅ | L_{b2-67} | 436 | Lₐ₁₋₇₆ | L_{b2-67} |
| 437 | Lₐ₁₋₇₇ | L_{b2-67} | 438 | Lₐ₁₋₇₈ | L_{b2-67} |
| 439 | Lₐ₁₋₇₉ | L_{b2-67} | 440 | Lₐ₁₋₈₀ | L_{b2-67} |
| 441 | Lₐ₁₋₈₁ | L_{b2-67} | 442 | Lₐ₁₋₈₂ | L_{b2-67} |
| 443 | Lₐ₁₋₈₃ | L_{b2-67} | 444 | Lₐ₁₋₈₄ | L_{b2-67} |
| 445 | Lₐ₁₋₈₅ | L_{b2-67} | 446 | Lₐ₁₋₈₆ | L_{b2-67} |
| 447 | Lₐ₁₋₈₇ | L_{b2-67} | 448 | Lₐ₁₋₈₈ | L_{b2-67} |
| 449 | Lₐ₁₋₈₉ | L_{b2-67} | 450 | Lₐ₁₋₉₀ | L_{b2-67} |
| 451 | Lₐ₁₋₉₁ | L_{b2-67} | 452 | Lₐ₁₋₉₂ | L_{b2-67} |
| 453 | Lₐ₁₋₉₃ | L_{b2-67} | 454 | Lₐ₁₋₉₄ | L_{b2-67} |
| 455 | Lₐ₁₋₉₅ | L_{b2-67} | 456 | Lₐ₁₋₉₆ | L_{b2-67} |
| 457 | Lₐ₁₋₉₇ | L_{b2-67} | 458 | Lₐ₁₋₉₈ | L_{b2-67} |
| 459 | Lₐ₁₋₉₉ | L_{b2-67} | 460 | Lₐ₁₋₁₀₀ | L_{b2-67} |
| 461 | Lₐ₁₋₁₀₁ | L_{b2-67} | 462 | Lₐ₁₋₁₀₂ | L_{b2-67} |
| 463 | Lₐ₁₋₁₀₃ | L_{b2-67} | 464 | Lₐ₁₋₁₀₄ | L_{b2-67} |
| 465 | Lₐ₁₋₁₀₅ | L_{b2-67} | 466 | Lₐ₁₋₁₀₆ | L_{b2-67} |
| 467 | Lₐ₁₋₁₀₇ | L_{b2-67} | 468 | Lₐ₁₋₁₀₈ | L_{b2-67} |
| 469 | Lₐ₁₋₁₀₉ | L_{b2-67} | 470 | Lₐ₁₋₁₁₀ | L_{b2-67} |
| 471 | Lₐ₁₋₁₁₁ | L_{b2-67} | 472 | Lₐ₁₋₁₁₂ | L_{b2-67} |
| 473 | Lₐ₁₋₁₁₃ | L_{b2-67} | 474 | Lₐ₁₋₁₁₄ | L_{b2-67} |
| 475 | Lₐ₁₋₁₁₅ | L_{b2-67} | 476 | Lₐ₁₋₁₁₆ | L_{b2-67} |
| 477 | Lₐ₁₋₁₁₇ | L_{b2-67} | 478 | Lₐ₁₋₁₁₈ | L_{b2-67} |
| 479 | Lₐ₁₋₁₁₉ | L_{b2-67} | 480 | Lₐ₁₋₁₂₀ | L_{b2-67} |
| 481 | Lₐ₁₋₁ | L_{b2-192} | 482 | Lₐ₁₋₂ | L_{b2-192} |
| 483 | Lₐ₁₋₃ | L_{b2-192} | 484 | Lₐ₁₋₄ | L_{b2-192} |
| 485 | Lₐ₁₋₅ | L_{b2-192} | 486 | Lₐ₁₋₆ | L_{b2-192} |
| 487 | Lₐ₁₋₇ | L_{b2-192} | 488 | Lₐ₁₋₈ | L_{b2-192} |
| 489 | Lₐ₁₋₉ | L_{b2-192} | 490 | Lₐ₁₋₁₀ | L_{b2-192} |
| 491 | Lₐ₁₋₁₁ | L_{b2-192} | 492 | Lₐ₁₋₁₂ | L_{b2-192} |
| 493 | Lₐ₁₋₁₃ | L_{b2-192} | 494 | Lₐ₁₋₁₄ | L_{b2-192} |
| 495 | Lₐ₁₋₁₅ | L_{b2-192} | 496 | Lₐ₁₋₁₆ | L_{b2-192} |
| 497 | Lₐ₁₋₁₇ | L_{b2-192} | 498 | Lₐ₁₋₁₈ | L_{b2-192} |
| 499 | Lₐ₁₋₁₉ | L_{b2-192} | 500 | Lₐ₁₋₂₀ | L_{b2-192} |
| 501 | Lₐ₁₋₂₁ | L_{b2-192} | 502 | Lₐ₁₋₂₂ | L_{b2-192} |
| 503 | Lₐ₁₋₂₃ | L_{b2-192} | 504 | Lₐ₁₋₂₄ | L_{b2-192} |
| 505 | Lₐ₁₋₂₅ | L_{b2-192} | 506 | Lₐ₁₋₂₆ | L_{b2-192} |
| 507 | Lₐ₁₋₂₇ | L_{b2-192} | 508 | Lₐ₁₋₂₈ | L_{b2-192} |
| 509 | Lₐ₁₋₂₉ | L_{b2-192} | 510 | Lₐ₁₋₃₀ | L_{b2-192} |
| 511 | Lₐ₁₋₃₁ | L_{b2-192} | 512 | Lₐ₁₋₃₂ | L_{b2-192} |
| 513 | Lₐ₁₋₃₃ | L_{b2-192} | 514 | Lₐ₁₋₃₄ | L_{b2-192} |
| 515 | Lₐ₁₋₃₅ | L_{b2-192} | 516 | Lₐ₁₋₃₆ | L_{b2-192} |
| 517 | Lₐ₁₋₃₇ | L_{b2-192} | 518 | Lₐ₁₋₃₈ | L_{b2-192} |
| 519 | Lₐ₁₋₃₉ | L_{b2-192} | 520 | Lₐ₁₋₄₀ | L_{b2-192} |
| 521 | Lₐ₁₋₄₁ | L_{b2-192} | 522 | Lₐ₁₋₄₂ | L_{b2-192} |
| 523 | Lₐ₁₋₄₃ | L_{b2-192} | 524 | Lₐ₁₋₄₄ | L_{b2-192} |
| 525 | Lₐ₁₋₄₅ | L_{b2-192} | 526 | Lₐ₁₋₄₆ | L_{b2-192} |
| 527 | Lₐ₁₋₄₇ | L_{b2-192} | 528 | Lₐ₁₋₄₈ | L_{b2-192} |
| 529 | Lₐ₁₋₄₉ | L_{b2-192} | 530 | Lₐ₁₋₅₀ | L_{b2-192} |
| 531 | Lₐ₁₋₅₁ | L_{b2-192} | 532 | Lₐ₁₋₅₂ | L_{b2-192} |
| 533 | Lₐ₁₋₅₃ | L_{b2-192} | 534 | Lₐ₁₋₅₄ | L_{b2-192} |
| 535 | Lₐ₁₋₅₅ | L_{b2-192} | 536 | Lₐ₁₋₅₆ | L_{b2-192} |
| 537 | Lₐ₁₋₅₇ | L_{b2-192} | 538 | Lₐ₁₋₅₈ | L_{b2-192} |
| 539 | Lₐ₁₋₅₉ | L_{b2-192} | 540 | Lₐ₁₋₆₀ | L_{b2-192} |
| 541 | Lₐ₁₋₆₁ | L_{b2-192} | 542 | Lₐ₁₋₆₂ | L_{b2-192} |
| 543 | Lₐ₁₋₆₃ | L_{b2-192} | 544 | Lₐ₁₋₆₄ | L_{b2-192} |
| 545 | Lₐ₁₋₆₅ | L_{b2-192} | 546 | Lₐ₁₋₆₆ | L_{b2-192} |
| 547 | Lₐ₁₋₆₇ | L_{b2-192} | 548 | Lₐ₁₋₆₈ | L_{b2-192} |
| 549 | Lₐ₁₋₆₉ | L_{b2-192} | 550 | Lₐ₁₋₇₀ | L_{b2-192} |
| 551 | Lₐ₁₋₇₁ | L_{b2-192} | 552 | Lₐ₁₋₇₂ | L_{b2-192} |
| 553 | Lₐ₁₋₇₃ | L_{b2-192} | 554 | Lₐ₁₋₇₄ | L_{b2-192} |
| 555 | Lₐ₁₋₇₅ | L_{b2-192} | 556 | Lₐ₁₋₇₆ | L_{b2-192} |
| 557 | Lₐ₁₋₇₇ | L_{b2-192} | 558 | Lₐ₁₋₇₈ | L_{b2-192} |
| 559 | Lₐ₁₋₇₉ | L_{b2-192} | 560 | Lₐ₁₋₈₀ | L_{b2-192} |
| 561 | Lₐ₁₋₈₁ | L_{b2-192} | 562 | Lₐ₁₋₈₂ | L_{b2-192} |
| 563 | Lₐ₁₋₈₃ | L_{b2-192} | 564 | Lₐ₁₋₈₄ | L_{b2-192} |
| 565 | Lₐ₁₋₈₅ | L_{b2-192} | 566 | Lₐ₁₋₈₆ | L_{b2-192} |
| 567 | Lₐ₁₋₈₇ | L_{b2-192} | 568 | Lₐ₁₋₈₈ | L_{b2-192} |
| 569 | Lₐ₁₋₈₉ | L_{b2-192} | 570 | Lₐ₁₋₉₀ | L_{b2-192} |
| 571 | Lₐ₁₋₉₁ | L_{b2-192} | 572 | Lₐ₁₋₉₂ | L_{b2-192} |
| 573 | Lₐ₁₋₉₃ | L_{b2-192} | 574 | Lₐ₁₋₉₄ | L_{b2-192} |
| 575 | Lₐ₁₋₉₅ | L_{b2-192} | 576 | Lₐ₁₋₉₆ | L_{b2-192} |
| 577 | Lₐ₁₋₉₇ | L_{b2-192} | 578 | Lₐ₁₋₉₈ | L_{b2-192} |
| 579 | Lₐ₁₋₉₉ | L_{b2-192} | 580 | Lₐ₁₋₁₀₀ | L_{b2-192} |
| 581 | Lₐ₁₋₁₀₁ | L_{b2-192} | 582 | Lₐ₁₋₁₀₂ | L_{b2-192} |
| 583 | Lₐ₁₋₁₀₃ | L_{b2-192} | 584 | Lₐ₁₋₁₀₄ | L_{b2-192} |
| 585 | Lₐ₁₋₁₀₅ | L_{b2-192} | 586 | Lₐ₁₋₁₀₆ | L_{b2-192} |
| 587 | Lₐ₁₋₁₀₇ | L_{b2-192} | 588 | Lₐ₁₋₁₀₈ | L_{b2-192} |
| 589 | Lₐ₁₋₁₀₉ | L_{b2-192} | 590 | Lₐ₁₋₁₁₀ | L_{b2-192} |
| 591 | Lₐ₁₋₁₁₁ | L_{b2-192} | 592 | Lₐ₁₋₁₁₂ | L_{b2-192} |
| 593 | Lₐ₁₋₁₁₃ | L_{b2-192} | 594 | Lₐ₁₋₁₁₄ | L_{b2-192} |
| 595 | Lₐ₁₋₁₁₅ | L_{b2-192} | 596 | Lₐ₁₋₁₁₆ | L_{b2-192} |
| 597 | Lₐ₁₋₁₁₇ | L_{b2-192} | 598 | Lₐ₁₋₁₁₈ | L_{b2-192} |
| 599 | Lₐ₁₋₁₁₉ | L_{b2-192} | 600 | Lₐ₁₋₁₂₀ | L_{b2-192} |
| 601 | L_{aD-1} | L_{b1-1} | 602 | L_{aD-1} | L_{b1-2} |
| 603 | L_{aD-1} | L_{b1-3} | 604 | L_{aD-1} | L_{b1-4} |
| 605 | L_{aD-1} | L_{b1-5} | 606 | L_{aD-1} | L_{b1-6} |
| 607 | L_{aD-1} | L_{b1-7} | 608 | L_{aD-1} | L_{b1-8} |
| 609 | L_{aD-1} | L_{b1-9} | 610 | L_{aD-1} | L_{b1-10} |
| 611 | L_{aD-1} | L_{b1-11} | 612 | L_{aD-1} | L_{b1-12} |
| 613 | L_{aD-1} | L_{b1-13} | 614 | L_{aD-1} | L_{b1-14} |
| 615 | L_{aD-1} | L_{b1-15} | 616 | L_{aD-1} | L_{b1-16} |
| 617 | L_{aD-1} | L_{b1-17} | 618 | L_{aD-1} | L_{b1-18} |
| 619 | L_{aD-1} | L_{b1-45} | 620 | L_{aD-1} | L_{b1-49} |
| 621 | L_{aD-1} | L_{b1-50} | 622 | L_{aD-1} | L_{b1-57} |
| 623 | L_{aD-1} | L_{b1-58} | 624 | L_{aD-1} | L_{b1-59} |
| 625 | L_{aD-1} | L_{b1-60} | 626 | L_{aD-1} | L_{b1-61} |
| 627 | L_{aD-1} | L_{b1-71} | 628 | L_{aD-1} | L_{b1-72} |
| 629 | L_{aD-1} | L_{b1-73} | 630 | L_{aD-1} | L_{b1-74} |
| 631 | L_{aD-1} | L_{b1-75} | 632 | L_{aD-1} | L_{b1-76} |
| 633 | L_{aD-1} | L_{b1-77} | 634 | L_{aD-1} | L_{b1-78} |
| 635 | L_{aD-1} | L_{b1-79} | 636 | L_{aD-1} | L_{b1-80} |
| 637 | L_{aD-1} | L_{b1-81} | 638 | L_{aD-1} | L_{b1-82} |
| 639 | L_{aD-1} | L_{b1-83} | 640 | L_{aD-1} | L_{b1-84} |
| 641 | L_{aD-1} | L_{b1-85} | 642 | L_{aD-1} | L_{b1-86} |
| 643 | L_{aD-1} | L_{b1-87} | 644 | L_{aD-1} | L_{b1-88} |
| 645 | L_{aD-1} | L_{b1-89} | 646 | L_{aD-1} | L_{b1-90} |
| 647 | L_{aD-1} | L_{b1-91} | 648 | L_{aD-1} | L_{b1-92} |
| 649 | L_{aD-1} | L_{b1-93} | 650 | L_{aD-1} | L_{b1-94} |
| 651 | L_{aD-1} | L_{b1-102} | 652 | L_{aD-1} | L_{b1-103} |
| 653 | L_{aD-1} | L_{b1-104} | 654 | L_{aD-1} | L_{b1-105} |
| 655 | L_{aD-1} | L_{b1-106} | 656 | L_{aD-1} | L_{b1-107} |
| 657 | L_{aD-1} | L_{b1-108} | 658 | L_{aD-1} | L_{b1-109} |
| 659 | L_{aD-1} | L_{b1-120} | 660 | L_{aD-1} | L_{b1-121} |
| 661 | L_{aD-1} | L_{b1-122} | 662 | L_{aD-1} | L_{b1-123} |
| 663 | L_{aD-1} | L_{b1-131} | 664 | L_{aD-1} | L_{b1-132} |
| 665 | L_{aD-1} | L_{b1-133} | 666 | L_{aD-1} | L_{b1-134} |
| 667 | L_{aD-1} | L_{b1-135} | 668 | L_{aD-1} | L_{b1-136} |
| 669 | L_{aD-1} | L_{b1-159} | 670 | L_{aD-1} | L_{b1-160} |
| 671 | L_{aD-1} | L_{b1-161} | 672 | L_{aD-1} | L_{b1-162} |
| 673 | L_{aD-1} | L_{b1-163} | 674 | L_{aD-1} | L_{b1-164} |
| 675 | L_{aD-1} | L_{b1-206} | 676 | L_{aD-1} | L_{b1-207} |
| 677 | L_{aD-1} | L_{b1-208} | 678 | L_{aD-1} | L_{b1-209} |
| 679 | L_{aD-1} | L_{b1-210} | 680 | L_{aD-1} | L_{b1-211} |
| 681 | L_{aD-1} | L_{b1-212} | 682 | L_{aD-1} | L_{b1-213} |
| 683 | L_{aD-1} | L_{b1-214} | 684 | L_{aD-1} | L_{b1-215} |
| 685 | L_{aD-1} | L_{b1-216} | 686 | L_{aD-1} | L_{b1-217} |
| 687 | L_{aD-1} | L_{b1-267} | 688 | L_{aD-1} | L_{b1-268} |
| 689 | L_{aD-1} | L_{b1-269} | 690 | L_{aD-1} | L_{b1-270} |
| 691 | L_{aD-1} | L_{b1-273} | 692 | L_{aD-1} | L_{b1-275} |
| 693 | L_{aD-1} | L_{b1-279} | 694 | L_{aD-1} | L_{b1-280} |
| 695 | L_{aD-1} | L_{b1-282} | 696 | L_{aD-1} | L_{b1-283} |
| 697 | L_{aD-1} | L_{b1-284} | 698 | L_{aD-1} | L_{b1-285} |
| 699 | L_{aD-1} | L_{b1-286} | 700 | L_{aD-1} | L_{b1-287} |
| 701 | L_{aD-1} | L_{b1-288} | 702 | L_{aD-1} | L_{b1-289} |
| 703 | L_{aD-1} | L_{b1-290} | 704 | L_{aD-1} | L_{b1-291} |
| 705 | L_{aD-1} | L_{b1-292} | 706 | L_{aD-1} | L_{b1-293} |
| 707 | L_{aD-1} | L_{b1-294} | 708 | L_{aD-1} | L_{b1-295} |
| 709 | L_{aD-1} | L_{b1-299} | 710 | L_{aD-1} | L_{b1-300} |
| 711 | L_{aD-1} | L_{b1-301} | 712 | L_{aD-1} | L_{b1-302} |
| 713 | L_{aD-1} | L_{b1-303} | 714 | L_{aD-1} | L_{b1-304} |
| 715 | L_{aD-1} | L_{b1-305} | 716 | L_{aD-1} | L_{b1-306} |
| 717 | L_{aD-1} | L_{b1-307} | 718 | L_{aD-1} | L_{b1-308} |
| 719 | L_{aD-1} | L_{b1-315} | 720 | L_{aD-1} | L_{b1-316} |
| 721 | L_{aD-1} | L_{b1-317} | 722 | L_{aD-1} | L_{b1-318} |
| 723 | L_{aD-1} | L_{b1-319} | 724 | L_{aD-1} | L_{b1-320} |
| 725 | L_{aD-1} | L_{b1-321} | 726 | L_{aD-1} | L_{b1-322} |
| 727 | L_{aD-1} | L_{b1-323} | 728 | L_{aD-1} | L_{b1-324} |
| 729 | L_{aD-1} | L_{b1-325} | 730 | L_{aD-1} | L_{b1-326} |
| 731 | L_{aD-1} | L_{b1-344} | 732 | L_{aD-1} | L_{b1-345} |
| 733 | L_{aD-1} | L_{b1-346} | 734 | L_{aD-1} | L_{b1-347} |
| 735 | L_{aD-1} | L_{b2-1} | 736 | L_{aD-1} | L_{b2-2} |
| 737 | L_{aD-1} | L_{b2-3} | 738 | L_{aD-1} | L_{b2-4} |
| 739 | L_{aD-1} | L_{b2-5} | 740 | L_{aD-1} | L_{b2-6} |
| 741 | L_{aD-1} | L_{b2-7} | 742 | L_{aD-1} | L_{b2-8} |
| 743 | L_{aD-1} | L_{b2-9} | 744 | L_{aD-1} | L_{b2-10} |
| 745 | L_{aD-1} | L_{b2-11} | 746 | L_{aD-1} | L_{b2-12} |
| 747 | L_{aD-1} | L_{b2-13} | 748 | L_{aD-1} | L_{b2-14} |
| 749 | L_{aD-1} | L_{b2-49} | 750 | L_{aD-1} | L_{b2-50} |
| 751 | L_{aD-1} | L_{b2-51} | 752 | L_{aD-1} | L_{b2-52} |
| 753 | L_{aD-1} | L_{b2-53} | 754 | L_{aD-1} | L_{b2-54} |
| 755 | L_{aD-1} | L_{b2-55} | 756 | L_{aD-1} | L_{b2-56} |
| 757 | L_{aD-1} | L_{b2-57} | 758 | L_{aD-1} | L_{b2-58} |
| 759 | L_{aD-1} | L_{b2-59} | 760 | L_{aD-1} | L_{b2-60} |
| 761 | L_{aD-1} | L_{b2-61} | 762 | L_{aD-1} | L_{b2-62} |
| 763 | L_{aD-1} | L_{b2-63} | 764 | L_{aD-1} | L_{b2-64} |
| 765 | L_{aD-1} | L_{b2-65} | 766 | L_{aD-1} | L_{b2-66} |
| 767 | L_{aD-1} | L_{b2-67} | 768 | L_{aD-1} | L_{b2-68} |
| 769 | L_{aD-1} | L_{b2-69} | 770 | L_{aD-1} | L_{b2-70} |
| 771 | L_{aD-1} | L_{b2-227} | 772 | L_{aD-1} | L_{b2-228} |
| 773 | L_{aD-1} | L_{b2-229} | 774 | L_{aD-1} | L_{b2-230} |
| 775 | L_{aD-1} | L_{b2-231} | 776 | L_{aD-1} | L_{b2-232} |
| 777 | L_{aD-1} | L_{b2-233} | 778 | L_{aD-1} | L_{b2-234} |
| 779 | L_{aD-1} | L_{b2-235} | 780 | L_{aD-1} | L_{b2-236} |
| 781 | L_{aD-1} | L_{b2-237} | 782 | L_{aD-1} | L_{b2-238} |
| 783 | L_{aD-1} | L_{b2-239} | 784 | L_{aD-1} | L_{b2-240} |
| 785 | L_{aD-1} | L_{b2-241} | 786 | L_{aD-1} | L_{b2-242} |
| 787 | L_{aD-1} | L_{b2-243} | 788 | L_{aD-1} | L_{b2-244} |
| 789 | L_{aD-1} | L_{b2-245} | 790 | L_{aD-1} | L_{b2-246} |
| 791 | L_{aD-1} | L_{b2-247} | 792 | L_{aD-1} | L_{b2-248} |
| 793 | L_{aD-1} | L_{b2-249} | 794 | L_{aD-1} | L_{b2-250} |
| 795 | L_{aD-1} | L_{b2-251} | 796 | L_{aD-1} | L_{b2-252} |
| 797 | L_{aD-1} | L_{b2-253} | 798 | L_{aD-1} | L_{b2-254} |
| 799 | L_{aD-1} | L_{b2-255} | 800 | L_{aD-1} | L_{b2-256} |
| 801 | L_{aD-1} | L_{b2-257} | 802 | L_{aD-1} | L_{b2-258} |
| 803 | L_{aD-1} | L_{b2-259} | 804 | L_{aD-1} | L_{b2-260} |
| 805 | L_{aD-1} | L_{b2-261} | 806 | L_{aD-1} | L_{b2-262} |
| 807 | L_{aD-1} | L_{b2-263} | 808 | L_{aD-1} | L_{b2-264} |
| 809 | L_{aD-1} | L_{b2-265} | 810 | L_{aD-1} | L_{b2-266} |
| 811 | L_{aD-1} | L_{b2-267} | 812 | L_{aD-1} | L_{b2-268} |
| 813 | L_{aD-1} | L_{b2-269} | 814 | L_{aD-1} | L_{b2-270} |
| 815 | L_{aD-1} | L_{b2-271} | 816 | L_{aD-1} | L_{b2-272} |
| 817 | L_{aD-1} | L_{b2-273} | 818 | L_{aD-1} | L_{b2-274} |
| 819 | L_{aD-1} | L_{b2-275} | 820 | L_{aD-1} | L_{bx-1} |
| 821 | L_{aD-1} | L_{bx-6} | 822 | L_{aD-1} | L_{bx-34} |
| 823 | L_{aD-2} | L_{b1-1} | 824 | L_{aD-2} | L_{b1-2} |
| 825 | L_{aD-2} | L_{b1-3} | 826 | L_{aD-2} | L_{b1-4} |
| 827 | L_{aD-2} | L_{b1-5} | 828 | L_{aD-2} | L_{b1-6} |
| 829 | L_{aD-2} | L_{b1-7} | 830 | L_{aD-2} | L_{b1-8} |
| 831 | L_{aD-2} | L_{b1-9} | 832 | L_{aD-2} | L_{b1-10} |
| 833 | L_{aD-2} | L_{b1-11} | 834 | L_{aD-2} | L_{b1-12} |
| 835 | L_{aD-2} | L_{b1-13} | 836 | L_{aD-2} | L_{b1-14} |
| 837 | L_{aD-2} | L_{b1-15} | 838 | L_{aD-2} | L_{b1-16} |
| 839 | L_{aD-2} | L_{b1-17} | 840 | L_{aD-2} | L_{b1-18} |
| 841 | L_{aD-2} | L_{b1-45} | 842 | L_{aD-2} | L_{b1-49} |
| 843 | L_{aD-2} | L_{b1-50} | 844 | L_{aD-2} | L_{b1-57} |
| 845 | L_{aD-2} | L_{b1-58} | 846 | L_{aD-2} | L_{b1-59} |
| 847 | L_{aD-2} | L_{b1-60} | 848 | L_{aD-2} | L_{b1-61} |
| 849 | L_{aD-2} | L_{b1-71} | 850 | L_{aD-2} | L_{b1-72} |
| 851 | L_{aD-2} | L_{b1-73} | 852 | L_{aD-2} | L_{b1-74} |
| 853 | L_{aD-2} | L_{b1-75} | 854 | L_{aD-2} | L_{b1-76} |
| 855 | L_{aD-2} | L_{b1-77} | 856 | L_{aD-2} | L_{b1-78} |
| 857 | L_{aD-2} | L_{b1-79} | 858 | L_{aD-2} | L_{b1-80} |
| 859 | L_{aD-2} | L_{b1-81} | 860 | L_{aD-2} | L_{b1-82} |
| 861 | L_{aD-2} | L_{b1-83} | 862 | L_{aD-2} | L_{b1-84} |
| 863 | L_{aD-2} | L_{b1-85} | 864 | L_{aD-2} | L_{b1-86} |
| 865 | L_{aD-2} | L_{b1-87} | 866 | L_{aD-2} | L_{b1-88} |
| 867 | L_{aD-2} | L_{b1-89} | 868 | L_{aD-2} | L_{b1-90} |
| 869 | L_{aD-2} | L_{b1-91} | 870 | L_{aD-2} | L_{b1-92} |
| 871 | L_{aD-2} | L_{b1-93} | 872 | L_{aD-2} | L_{b1-94} |
| 873 | L_{aD-2} | L_{b1-102} | 874 | L_{aD-2} | L_{b1-103} |
| 875 | L_{aD-2} | L_{b1-104} | 876 | L_{aD-2} | L_{b1-105} |
| 877 | L_{aD-2} | L_{b1-106} | 878 | L_{aD-2} | L_{b1-107} |
| 879 | L_{aD-2} | L_{b1-108} | 880 | L_{aD-2} | L_{b1-109} |
| 881 | L_{aD-2} | L_{b1-120} | 882 | L_{aD-2} | L_{b1-121} |
| 883 | L_{aD-2} | L_{b1-122} | 884 | L_{aD-2} | L_{b1-123} |
| 885 | L_{aD-2} | L_{b1-131} | 886 | L_{aD-2} | L_{b1-132} |
| 887 | L_{aD-2} | L_{b1-133} | 888 | L_{aD-2} | L_{b1-134} |
| 889 | L_{aD-2} | L_{b1-135} | 890 | L_{aD-2} | L_{b1-136} |
| 891 | L_{aD-2} | L_{b1-159} | 892 | L_{aD-2} | L_{b1-160} |
| 893 | L_{aD-2} | L_{b1-161} | 894 | L_{aD-2} | L_{b1-162} |
| 895 | L_{aD-2} | L_{b1-163} | 896 | L_{aD-2} | L_{b1-164} |
| 897 | L_{aD-2} | L_{b1-206} | 898 | L_{aD-2} | L_{b1-207} |
| 899 | L_{aD-2} | L_{b1-208} | 900 | L_{aD-2} | L_{b1-209} |
| 901 | L_{aD-2} | L_{b1-210} | 902 | L_{aD-2} | L_{b1-211} |
| 903 | L_{aD-2} | L_{b1-212} | 904 | L_{aD-2} | L_{b1-213} |
| 905 | L_{aD-2} | L_{b1-214} | 906 | L_{aD-2} | L_{b1-215} |
| 907 | L_{aD-2} | L_{b1-216} | 908 | L_{aD-2} | L_{b1-217} |
| 909 | L_{aD-2} | L_{b1-267} | 910 | L_{aD-2} | L_{b1-268} |
| 911 | L_{aD-2} | L_{b1-269} | 912 | L_{aD-2} | L_{b1-270} |
| 913 | L_{aD-2} | L_{b1-273} | 914 | L_{aD-2} | L_{b1-275} |
| 915 | L_{aD-2} | L_{b1-279} | 916 | L_{aD-2} | L_{b1-280} |
| 917 | L_{aD-2} | L_{b1-282} | 918 | L_{aD-2} | L_{b1-283} |
| 919 | L_{aD-2} | L_{b1-284} | 920 | L_{aD-2} | L_{b1-285} |
| 921 | L_{aD-2} | L_{b1-286} | 922 | L_{aD-2} | L_{b1-287} |
| 923 | L_{aD-2} | L_{b1-288} | 924 | L_{aD-2} | L_{b1-289} |
| 925 | L_{aD-2} | L_{b1-290} | 926 | L_{aD-2} | L_{b1-291} |
| 927 | L_{aD-2} | L_{b1-292} | 928 | L_{aD-2} | L_{b1-293} |
| 929 | L_{aD-2} | L_{b1-294} | 930 | L_{aD-2} | L_{b1-295} |
| 931 | L_{aD-2} | L_{b1-299} | 932 | L_{aD-2} | L_{b1-300} |
| 933 | L_{aD-2} | L_{b1-301} | 934 | L_{aD-2} | L_{b1-302} |
| 935 | L_{aD-2} | L_{b1-303} | 936 | L_{aD-2} | L_{b1-304} |
| 937 | L_{aD-2} | L_{b1-305} | 938 | L_{aD-2} | L_{b1-306} |
| 939 | L_{aD-2} | L_{b1-307} | 940 | L_{aD-2} | L_{b1-308} |
| 941 | L_{aD-2} | L_{b1-315} | 942 | L_{aD-2} | L_{b1-316} |
| 943 | L_{aD-2} | L_{b1-317} | 944 | L_{aD-2} | L_{b1-318} |
| 945 | L_{aD-2} | L_{b1-319} | 946 | L_{aD-2} | L_{b1-320} |
| 947 | L_{aD-2} | L_{b1-321} | 948 | L_{aD-2} | L_{b1-322} |
| 949 | L_{aD-2} | L_{b1-323} | 950 | L_{aD-2} | L_{b1-324} |
| 951 | L_{aD-2} | L_{b1-325} | 952 | L_{aD-2} | L_{b1-326} |
| 953 | L_{aD-2} | L_{b1-344} | 954 | L_{aD-2} | L_{b1-345} |
| 955 | L_{aD-2} | L_{b1-346} | 956 | L_{aD-2} | L_{b1-347} |
| 957 | L_{aD-2} | L_{b2-1} | 958 | L_{aD-2} | L_{b2-2} |
| 959 | L_{aD-2} | L_{b2-3} | 960 | L_{aD-2} | L_{b2-4} |
| 961 | L_{aD-2} | L_{b2-5} | 962 | L_{aD-2} | L_{b2-6} |
| 963 | L_{aD-2} | L_{b2-7} | 964 | L_{aD-2} | L_{b2-8} |
| 965 | L_{aD-2} | L_{b2-9} | 966 | L_{aD-2} | L_{b2-10} |
| 967 | L_{aD-2} | L_{b2-11} | 968 | L_{aD-2} | L_{b2-12} |
| 969 | L_{aD-2} | L_{b2-13} | 970 | L_{aD-2} | L_{b2-14} |
| 971 | L_{aD-2} | L_{b2-49} | 972 | L_{aD-2} | L_{b2-50} |
| 973 | L_{aD-2} | L_{b2-51} | 974 | L_{aD-2} | L_{b2-52} |
| 975 | L_{aD-2} | L_{b2-53} | 976 | L_{aD-2} | L_{b2-54} |
| 977 | L_{aD-2} | L_{b2-55} | 978 | L_{aD-2} | L_{b2-56} |
| 979 | L_{aD-2} | L_{b2-57} | 980 | L_{aD-2} | L_{b2-58} |
| 981 | L_{aD-2} | L_{b2-59} | 982 | L_{aD-2} | L_{b2-60} |
| 983 | L_{aD-2} | L_{b2-61} | 984 | L_{aD-2} | L_{b2-62} |
| 985 | L_{aD-2} | L_{b2-63} | 986 | L_{aD-2} | L_{b2-64} |
| 987 | L_{aD-2} | L_{b2-65} | 988 | L_{aD-2} | L_{b2-66} |
| 989 | L_{aD-2} | L_{b2-67} | 990 | L_{aD-2} | L_{b2-68} |
| 991 | L_{aD-2} | L_{b2-69} | 992 | L_{aD-2} | L_{b2-70} |
| 993 | L_{aD-2} | L_{b2-227} | 994 | L_{aD-2} | L_{b2-228} |
| 995 | L_{aD-2} | L_{b2-229} | 996 | L_{aD-2} | L_{b2-230} |
| 997 | L_{aD-2} | L_{b2-231} | 998 | L_{aD-2} | L_{b2-232} |
| 999 | L_{aD-2} | L_{b2-233} | 1000 | L_{aD-2} | L_{b2-234} |
| 1001 | L_{aD-2} | L_{b2-235} | 1002 | L_{aD-2} | L_{b2-236} |
| 1003 | L_{aD-2} | L_{b2-237} | 1004 | L_{aD-2} | L_{b2-238} |
| 1005 | L_{aD-2} | L_{b2-239} | 1006 | L_{aD-2} | L_{b2-240} |
| 1007 | L_{aD-2} | L_{b2-241} | 1008 | L_{aD-2} | L_{b2-242} |
| 1009 | L_{aD-2} | L_{b2-243} | 1010 | L_{aD-2} | L_{b2-244} |
| 1011 | L_{aD-2} | L_{b2-245} | 1012 | L_{aD-2} | L_{b2-246} |
| 1013 | L_{aD-2} | L_{b2-247} | 1014 | L_{aD-2} | L_{b2-248} |
| 1015 | L_{aD-2} | L_{b2-249} | 1016 | L_{aD-2} | L_{b2-250} |
| 1017 | L_{aD-2} | L_{b2-251} | 1018 | L_{aD-2} | L_{b2-252} |
| 1019 | L_{aD-2} | L_{b2-253} | 1020 | L_{aD-2} | L_{b2-254} |
| 1021 | L_{aD-2} | L_{b2-255} | 1022 | L_{aD-2} | L_{b2-256} |
| 1023 | L_{aD-2} | L_{b2-257} | 1024 | L_{aD-2} | L_{b2-258} |
| 1025 | L_{aD-2} | L_{b2-259} | 1026 | L_{aD-2} | L_{b2-260} |
| 1027 | L_{aD-2} | L_{b2-261} | 1028 | L_{aD-2} | L_{b2-262} |
| 1029 | L_{aD-2} | L_{b2-263} | 1030 | L_{aD-2} | L_{b2-264} |
| 1031 | L_{aD-2} | L_{b2-265} | 1032 | L_{aD-2} | L_{b2-266} |
| 1033 | L_{aD-2} | L_{b2-267} | 1034 | L_{aD-2} | L_{b2-268} |
| 1035 | L_{aD-2} | L_{b2-269} | 1036 | L_{aD-2} | L_{b2-270} |
| 1037 | L_{aD-2} | L_{b2-271} | 1038 | L_{aD-2} | L_{b2-272} |
| 1039 | L_{aD-2} | L_{b2-273} | 1040 | L_{aD-2} | L_{b2-274} |
| 1041 | L_{aD-2} | L_{b2-275} | 1042 | L_{aD-2} | L_{bx-1} |
| 1043 | L_{aD-2} | L_{bx-6} | 1044 | L_{aD-2} | L_{bx-34} |
| 1045 | L_{aD-12} | L_{b1-1} | 1046 | L_{aD-12} | L_{b1-2} |
| 1047 | L_{aD-12} | L_{b1-3} | 1048 | L_{aD-12} | L_{b1-4} |
| 1049 | L_{aD-12} | L_{b1-5} | 1050 | L_{aD-12} | L_{b1-6} |
| 1051 | L_{aD-12} | L_{b1-7} | 1052 | L_{aD-12} | L_{b1-8} |
| 1053 | L_{aD-12} | L_{b1-9} | 1054 | L_{aD-12} | L_{b1-10} |
| 1055 | L_{aD-12} | L_{b1-11} | 1056 | L_{aD-12} | L_{b1-12} |
| 1057 | L_{aD-12} | L_{b1-13} | 1058 | L_{aD-12} | L_{b1-14} |
| 1059 | L_{aD-12} | L_{b1-15} | 1060 | L_{aD-12} | L_{b1-16} |
| 1061 | L_{aD-12} | L_{b1-17} | 1062 | L_{aD-12} | L_{b1-18} |
| 1063 | L_{aD-12} | L_{b1-45} | 1064 | L_{aD-12} | L_{b1-49} |
| 1065 | L_{aD-12} | L_{b1-50} | 1066 | L_{aD-12} | L_{b1-57} |
| 1067 | L_{aD-12} | L_{b1-58} | 1068 | L_{aD-12} | L_{b1-59} |
| 1069 | L_{aD-12} | L_{b1-60} | 1070 | L_{aD-12} | L_{b1-61} |
| 1071 | L_{aD-12} | L_{b1-71} | 1072 | L_{aD-12} | L_{b1-72} |
| 1073 | L_{aD-12} | L_{b1-73} | 1074 | L_{aD-12} | L_{b1-74} |
| 1075 | L_{aD-12} | L_{b1-75} | 1076 | L_{aD-12} | L_{b1-76} |
| 1077 | L_{aD-12} | L_{b1-77} | 1078 | L_{aD-12} | L_{b1-78} |
| 1079 | L_{aD-12} | L_{b1-79} | 1080 | L_{aD-12} | L_{b1-80} |
| 1081 | L_{aD-12} | L_{b1-81} | 1082 | L_{aD-12} | L_{b1-82} |
| 1083 | L_{aD-12} | L_{b1-83} | 1084 | L_{aD-12} | L_{b1-84} |
| 1085 | L_{aD-12} | L_{b1-85} | 1086 | L_{aD-12} | L_{b1-86} |
| 1087 | L_{aD-12} | L_{b1-87} | 1088 | L_{aD-12} | L_{b1-88} |
| 1089 | L_{aD-12} | L_{b1-89} | 1090 | L_{aD-12} | L_{b1-90} |
| 1091 | L_{aD-12} | L_{b1-91} | 1092 | L_{aD-12} | L_{b1-92} |
| 1093 | L_{aD-12} | L_{b1-93} | 1094 | L_{aD-12} | L_{b1-94} |
| 1095 | L_{aD-12} | L_{b1-102} | 1096 | L_{aD-12} | L_{b1-103} |
| 1097 | L_{aD-12} | L_{b1-104} | 1098 | L_{aD-12} | L_{b1-105} |
| 1099 | L_{aD-12} | L_{b1-106} | 1100 | L_{aD-12} | L_{b1-107} |
| 1101 | L_{aD-12} | L_{b1-108} | 1102 | L_{aD-12} | L_{b1-109} |
| 1103 | L_{aD-12} | L_{b1-120} | 1104 | L_{aD-12} | L_{b1-121} |
| 1105 | L_{aD-12} | L_{b1-122} | 1106 | L_{aD-12} | L_{b1-123} |
| 1107 | L_{aD-12} | L_{b1-131} | 1108 | L_{aD-12} | L_{b1-132} |
| 1109 | L_{aD-12} | L_{b1-133} | 1110 | L_{aD-12} | L_{b1-134} |
| 1111 | L_{aD-12} | L_{b1-135} | 1112 | L_{aD-12} | L_{b1-136} |
| 1113 | L_{aD-12} | L_{b1-159} | 1114 | L_{aD-12} | L_{b1-160} |
| 1115 | L_{aD-12} | L_{b1-161} | 1116 | L_{aD-12} | L_{b1-162} |
| 1117 | L_{aD-12} | L_{b1-163} | 1118 | L_{aD-12} | L_{b1-164} |
| 1119 | L_{aD-12} | L_{b1-206} | 1120 | L_{aD-12} | L_{b1-207} |
| 1121 | L_{aD-12} | L_{b1-208} | 1122 | L_{aD-12} | L_{b1-209} |
| 1123 | L_{aD-12} | L_{b1-210} | 1124 | L_{aD-12} | L_{b1-211} |
| 1125 | L_{aD-12} | L_{b1-212} | 1126 | L_{aD-12} | L_{b1-213} |
| 1127 | L_{aD-12} | L_{b1-214} | 1128 | L_{aD-12} | L_{b1-215} |
| 1129 | L_{aD-12} | L_{b1-216} | 1130 | L_{aD-12} | L_{b1-217} |
| 1131 | L_{aD-12} | L_{b1-267} | 1132 | L_{aD-12} | L_{b1-268} |
| 1133 | L_{aD-12} | L_{b1-269} | 1134 | L_{aD-12} | L_{b1-270} |
| 1135 | L_{aD-12} | L_{b1-273} | 1136 | L_{aD-12} | L_{b1-275} |
| 1137 | L_{aD-12} | L_{b1-279} | 1138 | L_{aD-12} | L_{b1-280} |
| 1139 | L_{aD-12} | L_{b1-282} | 1140 | L_{aD-12} | L_{b1-283} |
| 1141 | L_{aD-12} | L_{b1-284} | 1142 | L_{aD-12} | L_{b1-285} |
| 1143 | L_{aD-12} | L_{b1-286} | 1144 | L_{aD-12} | L_{b1-287} |
| 1145 | L_{aD-12} | L_{b1-288} | 1146 | L_{aD-12} | L_{b1-289} |
| 1147 | L_{aD-12} | L_{b1-290} | 1148 | L_{aD-12} | L_{b1-291} |
| 1149 | L_{aD-12} | L_{b1-292} | 1150 | L_{aD-12} | L_{b1-293} |
| 1151 | L_{aD-12} | L_{b1-294} | 1152 | L_{aD-12} | L_{b1-295} |
| 1153 | L_{aD-12} | L_{b1-299} | 1154 | L_{aD-12} | L_{b1-300} |
| 1155 | L_{aD-12} | L_{b1-301} | 1156 | L_{aD-12} | L_{b1-302} |
| 1157 | L_{aD-12} | L_{b1-303} | 1158 | L_{aD-12} | L_{b1-304} |
| 1159 | L_{aD-12} | L_{b1-305} | 1160 | L_{aD-12} | L_{b1-306} |
| 1161 | L_{aD-12} | L_{b1-307} | 1162 | L_{aD-12} | L_{b1-308} |
| 1163 | L_{aD-12} | L_{b1-315} | 1164 | L_{aD-12} | L_{b1-316} |
| 1165 | L_{aD-12} | L_{b1-317} | 1166 | L_{aD-12} | L_{b1-318} |
| 1167 | L_{aD-12} | L_{b1-319} | 1168 | L_{aD-12} | L_{b1-320} |
| 1169 | L_{aD-12} | L_{b1-321} | 1170 | L_{aD-12} | L_{b1-322} |
| 1171 | L_{aD-12} | L_{b1-323} | 1172 | L_{aD-12} | L_{b1-324} |
| 1173 | L_{aD-12} | L_{b1-325} | 1174 | L_{aD-12} | L_{b1-326} |
| 1175 | L_{aD-12} | L_{b1-344} | 1176 | L_{aD-12} | L_{b1-345} |
| 1177 | L_{aD-12} | L_{b1-346} | 1178 | L_{aD-12} | L_{b1-347} |
| 1179 | L_{aD-12} | L_{b2-1} | 1180 | L_{aD-12} | L_{b2-2} |
| 1181 | L_{aD-12} | L_{b2-3} | 1182 | L_{aD-12} | L_{b2-4} |
| 1183 | L_{aD-12} | L_{b2-5} | 1184 | L_{aD-12} | L_{b2-6} |
| 1185 | L_{aD-12} | L_{b2-7} | 1186 | L_{aD-12} | L_{b2-8} |
| 1187 | L_{aD-12} | L_{b2-9} | 1188 | L_{aD-12} | L_{b2-10} |
| 1189 | L_{aD-12} | L_{b2-11} | 1190 | L_{aD-12} | L_{b2-12} |
| 1191 | L_{aD-12} | L_{b2-13} | 1192 | L_{aD-12} | L_{b2-14} |
| 1193 | L_{aD-12} | L_{b2-49} | 1194 | L_{aD-12} | L_{b2-50} |
| 1195 | L_{aD-12} | L_{b2-51} | 1196 | L_{aD-12} | L_{b2-52} |
| 1197 | L_{aD-12} | L_{b2-53} | 1198 | L_{aD-12} | L_{b2-54} |
| 1199 | L_{aD-12} | L_{b2-55} | 1200 | L_{aD-12} | L_{b2-56} |
| 1201 | L_{aD-12} | L_{b2-57} | 1202 | L_{aD-12} | L_{b2-58} |
| 1203 | L_{aD-12} | L_{b2-59} | 1204 | L_{aD-12} | L_{b2-60} |
| 1205 | L_{aD-12} | L_{b2-61} | 1206 | L_{aD-12} | L_{b2-62} |
| 1207 | L_{aD-12} | L_{b2-63} | 1208 | L_{aD-12} | L_{b2-64} |
| 1209 | L_{aD-12} | L_{b2-65} | 1210 | L_{aD-12} | L_{b2-66} |
| 1211 | L_{aD-12} | L_{b2-67} | 1212 | L_{aD-12} | L_{b2-68} |
| 1213 | L_{aD-12} | L_{b2-69} | 1214 | L_{aD-12} | L_{b2-70} |
| 1215 | L_{aD-12} | L_{b2-227} | 1216 | L_{aD-12} | L_{b2-228} |
| 1217 | L_{aD-12} | L_{b2-229} | 1218 | L_{aD-12} | L_{b2-230} |
| 1219 | L_{aD-12} | L_{b2-231} | 1220 | L_{aD-12} | L_{b2-232} |
| 1221 | L_{aD-12} | L_{b2-233} | 1222 | L_{aD-12} | L_{b2-234} |
| 1223 | L_{aD-12} | L_{b2-235} | 1224 | L_{aD-12} | L_{b2-236} |
| 1225 | L_{aD-12} | L_{b2-237} | 1226 | L_{aD-12} | L_{b2-238} |
| 1227 | L_{aD-12} | L_{b2-239} | 1228 | L_{aD-12} | L_{b2-240} |
| 1229 | L_{aD-12} | L_{b2-241} | 1230 | L_{aD-12} | L_{b2-242} |
| 1231 | L_{aD-12} | L_{b2-243} | 1232 | L_{aD-12} | L_{b2-244} |
| 1233 | L_{aD-12} | L_{b2-245} | 1234 | L_{aD-12} | L_{b2-246} |
| 1235 | L_{aD-12} | L_{b2-247} | 1236 | L_{aD-12} | L_{b2-248} |
| 1237 | L_{aD-12} | L_{b2-249} | 1238 | L_{aD-12} | L_{b2-250} |
| 1239 | L_{aD-12} | L_{b2-251} | 1240 | L_{aD-12} | L_{b2-252} |
| 1241 | L_{aD-12} | L_{b2-253} | 1242 | L_{aD-12} | L_{b2-254} |
| 1243 | L_{aD-12} | L_{b2-255} | 1244 | L_{aD-12} | L_{b2-256} |
| 1245 | L_{aD-12} | L_{b2-257} | 1246 | L_{aD-12} | L_{b2-258} |
| 1247 | L_{aD-12} | L_{b2-259} | 1248 | L_{aD-12} | L_{b2-260} |
| 1249 | L_{aD-12} | L_{b2-261} | 1250 | L_{aD-12} | L_{b2-262} |
| 1251 | L_{aD-12} | L_{b2-263} | 1252 | L_{aD-12} | L_{b2-264} |
| 1253 | L_{aD-12} | L_{b2-265} | 1254 | L_{aD-12} | L_{b2-266} |
| 1255 | L_{aD-12} | L_{b2-267} | 1256 | L_{aD-12} | L_{b2-268} |
| 1257 | L_{aD-12} | L_{b2-269} | 1258 | L_{aD-12} | L_{b2-270} |
| 1259 | L_{aD-12} | L_{b2-271} | 1260 | L_{aD-12} | L_{b2-272} |
| 1261 | L_{aD-12} | L_{b2-273} | 1262 | L_{aD-12} | L_{b2-274} |
| 1263 | L_{aD-12} | L_{b2-275} | 1264 | L_{aD-12} | L_{bx-1} |
| 1265 | L_{aD-12} | L_{bx-6} | 1266 | L_{aD-12} | L_{bx-34} |
| 1267 | L_{aD-127} | L_{b1-1} | 1268 | L_{aD-127} | L_{b1-2} |
| 1269 | L_{aD-127} | L_{b1-3} | 1270 | L_{aD-127} | L_{b1-4} |
| 1271 | L_{aD-127} | L_{b1-5} | 1272 | L_{aD-127} | L_{b1-6} |
| 1273 | L_{aD-127} | L_{b1-7} | 1274 | L_{aD-127} | L_{b1-8} |
| 1275 | L_{aD-127} | L_{b1-9} | 1276 | L_{aD-127} | L_{b1-10} |
| 1277 | L_{aD-127} | L_{b1-11} | 1278 | L_{aD-127} | L_{b1-12} |
| 1279 | L_{aD-127} | L_{b1-13} | 1280 | L_{aD-127} | L_{b1-14} |
| 1281 | L_{aD-127} | L_{b1-15} | 1282 | L_{aD-127} | L_{b1-16} |
| 1283 | L_{aD-127} | L_{b1-17} | 1284 | L_{aD-127} | L_{b1-18} |
| 1285 | L_{aD-127} | L_{b1-45} | 1286 | L_{aD-127} | L_{b1-49} |
| 1287 | L_{aD-127} | L_{b1-50} | 1288 | L_{aD-127} | L_{b1-57} |
| 1289 | L_{aD-127} | L_{b1-58} | 1290 | L_{aD-127} | L_{b1-59} |
| 1291 | L_{aD-127} | L_{b1-60} | 1292 | L_{aD-127} | L_{b1-61} |
| 1293 | L_{aD-127} | L_{b1-71} | 1294 | L_{aD-127} | L_{b1-72} |
| 1295 | L_{aD-127} | L_{b1-73} | 1296 | L_{aD-127} | L_{b1-74} |
| 1297 | L_{aD-127} | L_{b1-75} | 1298 | L_{aD-127} | L_{b1-76} |
| 1299 | L_{aD-127} | L_{b1-77} | 1300 | L_{aD-127} | L_{b1-78} |
| 1301 | L_{aD-127} | L_{b1-79} | 1302 | L_{aD-127} | L_{b1-80} |
| 1303 | L_{aD-127} | L_{b1-81} | 1304 | L_{aD-127} | L_{b1-82} |
| 1305 | L_{aD-127} | L_{b1-83} | 1306 | L_{aD-127} | L_{b1-84} |
| 1307 | L_{aD-127} | L_{b1-85} | 1308 | L_{aD-127} | L_{b1-86} |
| 1309 | L_{aD-127} | L_{b1-87} | 1310 | L_{aD-127} | L_{b1-88} |
| 1311 | L_{aD-127} | L_{b1-89} | 1312 | L_{aD-127} | L_{b1-90} |
| 1313 | L_{aD-127} | L_{b1-91} | 1314 | L_{aD-127} | L_{b1-92} |
| 1315 | L_{aD-127} | L_{b1-93} | 1316 | L_{aD-127} | L_{b1-94} |
| 1317 | L_{aD-127} | L_{b1-102} | 1318 | L_{aD-127} | L_{b1-103} |
| 1319 | L_{aD-127} | L_{b1-104} | 1320 | L_{aD-127} | L_{b1-105} |
| 1321 | L_{aD-127} | L_{b1-106} | 1322 | L_{aD-127} | L_{b1-107} |
| 1323 | L_{aD-127} | L_{b1-108} | 1324 | L_{aD-127} | L_{b1-109} |
| 1325 | L_{aD-127} | L_{b1-120} | 1326 | L_{aD-127} | L_{b1-121} |
| 1327 | L_{aD-127} | L_{b1-122} | 1328 | L_{aD-127} | L_{b1-123} |
| 1329 | L_{aD-127} | L_{b1-131} | 1330 | L_{aD-127} | L_{b1-132} |
| 1331 | L_{aD-127} | L_{b1-133} | 1332 | L_{aD-127} | L_{b1-134} |
| 1333 | L_{aD-127} | L_{b1-135} | 1334 | L_{aD-127} | L_{b1-136} |
| 1335 | L_{aD-127} | L_{b1-159} | 1336 | L_{aD-127} | L_{b1-160} |
| 1337 | L_{aD-127} | L_{b1-161} | 1338 | L_{aD-127} | L_{b1-162} |
| 1339 | L_{aD-127} | L_{b1-163} | 1340 | L_{aD-127} | L_{b1-164} |
| 1341 | L_{aD-127} | L_{b1-206} | 1342 | L_{aD-127} | L_{b1-207} |
| 1343 | L_{aD-127} | L_{b1-208} | 1344 | L_{aD-127} | L_{b1-209} |
| 1345 | L_{aD-127} | L_{b1-210} | 1346 | L_{aD-127} | L_{b1-211} |
| 1347 | L_{aD-127} | L_{b1-212} | 1348 | L_{aD-127} | L_{b1-213} |
| 1349 | L_{aD-127} | L_{b1-214} | 1350 | L_{aD-127} | L_{b1-215} |
| 1351 | L_{aD-127} | L_{b1-216} | 1352 | L_{aD-127} | L_{b1-217} |
| 1353 | L_{aD-127} | L_{b1-267} | 1354 | L_{aD-127} | L_{b1-268} |
| 1355 | L_{aD-127} | L_{b1-269} | 1356 | L_{aD-127} | L_{b1-270} |
| 1357 | L_{aD-127} | L_{b1-273} | 1358 | L_{aD-127} | L_{b1-275} |
| 1359 | L_{aD-127} | L_{b1-279} | 1360 | L_{aD-127} | L_{b1-280} |
| 1361 | L_{aD-127} | L_{b1-282} | 1362 | L_{aD-127} | L_{b1-283} |
| 1363 | L_{aD-127} | L_{b1-284} | 1364 | L_{aD-127} | L_{b1-285} |
| 1365 | L_{aD-127} | L_{b1-286} | 1366 | L_{aD-127} | L_{b1-287} |
| 1367 | L_{aD-127} | L_{b1-288} | 1368 | L_{aD-127} | L_{b1-289} |
| 1369 | L_{aD-127} | L_{b1-290} | 1370 | L_{aD-127} | L_{b1-291} |
| 1371 | L_{aD-127} | L_{b1-292} | 1372 | L_{aD-127} | L_{b1-293} |
| 1373 | L_{aD-127} | L_{b1-294} | 1374 | L_{aD-127} | L_{b1-295} |
| 1375 | L_{aD-127} | L_{b1-299} | 1376 | L_{aD-127} | L_{b1-300} |
| 1377 | L_{aD-127} | L_{b1-301} | 1378 | L_{aD-127} | L_{b1-302} |
| 1379 | L_{aD-127} | L_{b1-303} | 1380 | L_{aD-127} | L_{b1-304} |
| 1381 | L_{aD-127} | L_{b1-305} | 1382 | L_{aD-127} | L_{b1-306} |
| 1383 | L_{aD-127} | L_{b1-307} | 1384 | L_{aD-127} | L_{b1-308} |
| 1385 | L_{aD-127} | L_{b1-315} | 1386 | L_{aD-127} | L_{b1-316} |
| 1387 | L_{aD-127} | L_{b1-317} | 1388 | L_{aD-127} | L_{b1-318} |
| 1389 | L_{aD-127} | L_{b1-319} | 1390 | L_{aD-127} | L_{b1-320} |
| 1391 | L_{aD-127} | L_{b1-321} | 1392 | L_{aD-127} | L_{b1-322} |
| 1393 | L_{aD-127} | L_{b1-323} | 1394 | L_{aD-127} | L_{b1-324} |
| 1395 | L_{aD-127} | L_{b1-325} | 1396 | L_{aD-127} | L_{b1-326} |
| 1397 | L_{aD-127} | L_{b1-344} | 1398 | L_{aD-127} | L_{b1-345} |
| 1399 | L_{aD-127} | L_{b1-346} | 1400 | L_{aD-127} | L_{b1-347} |
| 1401 | L_{aD-127} | L_{b2-1} | 1402 | L_{aD-127} | L_{b2-2} |
| 1403 | L_{aD-127} | L_{b2-3} | 1404 | L_{aD-127} | L_{b2-4} |
| 1405 | L_{aD-127} | L_{b2-5} | 1406 | L_{aD-127} | L_{b2-6} |
| 1407 | L_{aD-127} | L_{b2-7} | 1408 | L_{aD-127} | L_{b2-8} |
| 1409 | L_{aD-127} | L_{b2-9} | 1410 | L_{aD-127} | L_{b2-10} |
| 1411 | L_{aD-127} | L_{b2-11} | 1412 | L_{aD-127} | L_{b2-12} |
| 1413 | L_{aD-127} | L_{b2-13} | 1414 | L_{aD-127} | L_{b2-14} |
| 1415 | L_{aD-127} | L_{b2-49} | 1416 | L_{aD-127} | L_{b2-50} |
| 1417 | L_{aD-127} | L_{b2-51} | 1418 | L_{aD-127} | L_{b2-52} |
| 1419 | L_{aD-127} | L_{b2-53} | 1420 | L_{aD-127} | L_{b2-54} |
| 1421 | L_{aD-127} | L_{b2-55} | 1422 | L_{aD-127} | L_{b2-56} |
| 1423 | L_{aD-127} | L_{b2-57} | 1424 | L_{aD-127} | L_{b2-58} |
| 1425 | L_{aD-127} | L_{b2-59} | 1426 | L_{aD-127} | L_{b2-60} |
| 1427 | L_{aD-127} | L_{b2-61} | 1428 | L_{aD-127} | L_{b2-62} |
| 1429 | L_{aD-127} | L_{b2-63} | 1430 | L_{aD-127} | L_{b2-64} |
| 1431 | L_{aD-127} | L_{b2-65} | 1432 | L_{aD-127} | L_{b2-66} |
| 1433 | L_{aD-127} | L_{b2-67} | 1434 | L_{aD-127} | L_{b2-68} |
| 1435 | L_{aD-127} | L_{b2-69} | 1436 | L_{aD-127} | L_{b2-70} |
| 1437 | L_{aD-127} | L_{b2-227} | 1438 | L_{aD-127} | L_{b2-228} |
| 1439 | L_{aD-127} | L_{b2-229} | 1440 | L_{aD-127} | L_{b2-230} |
| 1441 | L_{aD-127} | L_{b2-231} | 1442 | L_{aD-127} | L_{b2-232} |
| 1443 | L_{aD-127} | L_{b2-233} | 1444 | L_{aD-127} | L_{b2-234} |
| 1445 | L_{aD-127} | L_{b2-235} | 1446 | L_{aD-127} | L_{b2-236} |
| 1447 | L_{aD-127} | L_{b2-237} | 1448 | L_{aD-127} | L_{b2-238} |
| 1449 | L_{aD-127} | L_{b2-239} | 1450 | L_{aD-127} | L_{b2-240} |
| 1451 | L_{aD-127} | L_{b2-241} | 1452 | L_{aD-127} | L_{b2-242} |
| 1453 | L_{aD-127} | L_{b2-243} | 1454 | L_{aD-127} | L_{b2-244} |
| 1455 | L_{aD-127} | L_{b2-245} | 1456 | L_{aD-127} | L_{b2-246} |
| 1457 | L_{aD-127} | L_{b2-247} | 1458 | L_{aD-127} | L_{b2-248} |
| 1459 | L_{aD-127} | L_{b2-249} | 1460 | L_{aD-127} | L_{b2-250} |
| 1461 | L_{aD-127} | L_{b2-251} | 1462 | L_{aD-127} | L_{b2-252} |
| 1463 | L_{aD-127} | L_{b2-253} | 1464 | L_{aD-127} | L_{b2-254} |
| 1465 | L_{aD-127} | L_{b2-255} | 1466 | L_{aD-127} | L_{b2-256} |
| 1467 | L_{aD-127} | L_{b2-257} | 1468 | L_{aD-127} | L_{b2-258} |
| 1469 | L_{aD-127} | L_{b2-259} | 1470 | L_{aD-127} | L_{b2-260} |
| 1471 | L_{aD-127} | L_{b2-261} | 1472 | L_{aD-127} | L_{b2-262} |
| 1473 | L_{aD-127} | L_{b2-263} | 1474 | L_{aD-127} | L_{b2-264} |
| 1475 | L_{aD-127} | L_{b2-265} | 1476 | L_{aD-127} | L_{b2-266} |
| 1477 | L_{aD-127} | L_{b2-267} | 1478 | L_{aD-127} | L_{b2-268} |
| 1479 | L_{aD-127} | L_{b2-269} | 1480 | L_{aD-127} | L_{b2-270} |
| 1481 | L_{aD-127} | L_{b2-271} | 1482 | L_{aD-127} | L_{b2-272} |
| 1483 | L_{aD-127} | L_{b2-273} | 1484 | L_{aD-127} | L_{b2-274} |
| 1485 | L_{aD-127} | L_{b2-275} | 1486 | L_{aD-127} | L_{bx-1} |
| 1487 | L_{aD-127} | L_{bx-6} | 1488 | L_{aD-127} | L_{bx-34} |
| 1489 | Lₐ₁₋₁₃ | L_{b1-356} | 1490 | Lₐ₁₋₁₃ | L_{b1-357} |
| 1491 | Lₐ₁₋₁₃ | L_{b2-284} | 1492 | Lₐ₁₋₁₃ | L_{b2-285} |
| 1493 | Lₐ₁₋₁₂₂ | L_{b1-1} | 1494 | Lₐ₁₋₁₂₂ | L_{b1-75} |
| 1495 | Lₐ₁₋₁₂₂ | L_{b1-282} | 1496 | Lₐ₁₋₁₂₂ | L_{b1-345} |
| 1497 | Lₐ₁₋₁₂₂ | L_{b2-49} | 1498 | Lₐ₁₋₁₂₂ | L_{b2-192} |
| 1499 | Lₐ₁₋₁₂₃ | L_{b1-1} | 1500 | Lₐ₁₋₁₂₃ | L_{b1-75} |
| 1501 | Lₐ₁₋₁₂₃ | L_{b1-282} | 1502 | Lₐ₁₋₁₂₃ | L_{b1-345} |
| 1503 | Lₐ₁₋₁₂₃ | L_{b2-49} | 1504 | Lₐ₁₋₁₂₃ | L_{b2-192} |

21. An electroluminescent device, comprising:
an anode,
a cathode, and
an organic layer disposed between the anode and the cathode, wherein at least one layer of the organic layer comprises the metal complex according to claim 1.

22. The electroluminescent device according to claim 21, wherein the organic layer comprising the metal complex is an emissive layer.

23. The electroluminescent device according to claim 22, wherein the emissive layer further comprises a first host compound;
preferably, the emissive layer further comprises a second host compound; and
more preferably, at least one of the first host compound and the second host compound comprises at least one chemical group selected from the group consisting of benzene, pyridine, pyrimidine, triazine, carbazole, azacarbazole, indolocarbazole, dibenzothiophene, azadibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene and combinations thereof.

24. The electroluminescent device according to claim 23, wherein the metal complex is doped in the first host compound and the second host compound, and the weight of the metal complex accounts for 1% to 30% of the total weight of the emissive layer; and
preferably, the weight of the metal complex accounts for 3% to 13% of the total weight of the emissive layer.

25. A compound composition, comprising the metal complex according to claim 1.
